(19) United States
(12) Patent Application Publication
(10) Pub. No.: US 2021/0399231 A1
(43) Pub. Date: Dec. 23, 2021

(54) ORGANIC ELECTROLUMINESCENT DEVICE

(71) Applicant: ROHM AND HAAS ELECTRONIC MATERIALS KOREA LTD., Chungcheongnam-do (KR)

(72) Inventors: Yoo-Jin DOH, Gyeonggi-do (KR); Kyoung-Jin PARK, Gyeonggi-do (KR); Chi-Sik KIM, Gyeonggi-do (KR); Jeong-Eun YANG, Gyeonggi-do (KR); Ji-Song JUN, Gyeonggi-do (KR); Hyun KIM, Gyeonggi-do (KR); Hyo-Jung LEE, Gyeonggi-do (KR); Hyun-Ju KANG, Gyeonggi-do (KR)

(21) Appl. No.: 17/272,621

(22) PCT Filed: Sep. 3, 2019
(86) PCT No.: PCT/KR2019/011290

§ 371 Date: Mar. 1, 2021

(30) Foreign Application Priority Data
Sep. 3, 2018 (KR) 10-2018-0104399
Sep. 2, 2019 (KR) 10-2019-0107970

(51) Int. Cl. H01L 51/00

(52) U.S. Cl. CPC H01L 51/0072; H01L 51/0067; H01L 51/006; H01L 51/5012; H01L 51/0074; H01L 51/0052; H01L 2251/5384; H01L 51/0073

(57) ABSTRACT

The present disclosure relates to an organic electroluminescent device comprising a compound represented by formula 1, and can provide an organic electroluminescent device having a plurality of light-emitting layers, which is superior in driving voltage, luminous efficiency, external quantum efficiency, and/or color coordinate properties as compared to the conventional organic electroluminescent device.

### TECHNICAL FIELD

The present disclosure relates to an organic electroluminescent device comprising an organic electroluminescent compound.

### BACKGROUND ART

An electroluminescent (EL) device is a self-light-emitting device which has advantages in that it provides a wider viewing angle, a greater contrast ratio, and a faster response time. An organic EL device was first developed by Eastman Kodak in 1987, by using small aromatic diamine molecules and aluminum complexes as materials for forming a light-emitting layer [Appl. Phys. Lett. 51, 913, 1987].

The white organic electroluminescent device uses a technology of implementing white light by mixing light emitting materials of various wavelengths. In order to implement white, a light-emitting layer including a material having blue (B) and yellow green (YG) wavelengths, or a material having blue (B), red (R) and green (G) wavelengths is used. The light emission characteristics can be adjusted according to the light-emitting layer structure. The organic electroluminescent device may be classified into a single light-emitting layer (single-EML), a multiple light-emitting layer (Multiple-EML), and a tandem structure in which devices are stacked, etc., according to the structure of the light-emitting layer.

The tandem organic electroluminescent device, which corresponds to a technology currently commercialized, is a structure in which two or more independent OLED devices are connected in series. This has the advantage that each OLED device is bonded to a charge generation layer to individually optimize the unit OLED device, so that the control of light emission efficiency and color is easy. In addition, in the tandem organic electroluminescent device, individual OLED devices are driven with the same amount of current, and brightness and current efficiency at the same current can be multiplied by the number of OLED devices connected. Thus, the tandem organic electroluminescent device is currently mainly used as a technology for mass-producing OLED TV.

Korean Patent Application Laid-Open No. 2010-0072644 discloses one embodiment of an organic electroluminescent device for improving color stability of a blue light-emitting layer. However, there is still a need to improve the characteristics of the luminous efficiency, quantum efficiency and/or color coordinate of OLED devices.

### DISCLOSURE OF INVENTION

### Technical Problem

The objective of the present disclosure is to provide an organic electroluminescent device having a plurality of light-emitting layers, which is superior in driving voltage, luminous efficiency, external quantum efficiency and/or color coordinate characteristics as compared to conventional organic electroluminescent devices.

### Solution to Problem

The present inventors found that an organic electroluminescent device comprising the compound of the present disclosure can improve charge recombination efficiency and increase red light emission, thereby improving the external quantum efficiency. Specifically, the above objective can be achieved by an organic electroluminescent device comprising an anode, a cathode, and a plurality of light-emitting layers between the anode and the cathode, wherein at least one of the plurality of light-emitting layers comprises a compound represented by the following formula 1:

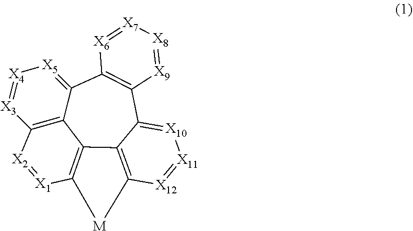

wherein

M represents

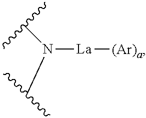

### O or S;

X₁ to X₁₂, each independently, represent N or CR₁;

La represents a single bond, a substituted or unsubstituted (C1-C30)alkylene, a substituted or unsubstituted (C6-C30)arylene, a substituted or unsubstituted (3- to 30-membered)heteroarylene, or a substituted or unsubstituted (C3-C30)cycloalkylene;

Ar and R₁, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, a substituted or unsubstituted (C1-C30)alkyl(C6-C30)arylamino, or a substituted or unsubstituted (C6-C30)aryl(3- to 30-membered)heteroarylamino; or two or more adjacent Ar's may be linked to each other to form a ring(s) and two or more adjacent R₁'s may be linked to each other to form a ring(s); where if a plurality of R₁'s is present, each of R₁ may be the same or different; and

a represents an integer of 1 or 2, in which if a is an integer of 2, each of Ar may be the same or different.

### Advantageous Effects of Invention

According to the present disclosure, an organic electroluminescent device having a plurality of light-emitting layers, which is superior in driving voltage, luminous efficiency, external quantum efficiency, and/or color coordinate characteristics as compared to conventional organic electroluminescent devices is provided, and it is possible to manufacture a display system or a lighting system using the same.

### BRIEF DESCRIPTION OF DRAWINGS

FIG. 1 schematically illustrates a structure of an organic electroluminescent device according to one embodiment of the present disclosure.

FIG. 2 illustrates a representative formula of the compound represented by formula 1 according to the present disclosure.

FIG. 3 illustrates the intensity according to the wavelength of the organic electroluminescent device produced in Comparative Example 1 and Device Examples 2 to 4.

FIG. 4 illustrates the intensity according to the wavelength of the organic electroluminescent device produced in Comparative Example 1 and Device Examples 5 to 7.

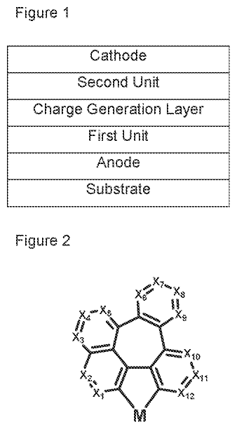

### MODE FOR THE INVENTION

Hereinafter, the present disclosure will be described in detail. However, the following description is intended to explain the disclosure, and is not meant in any way to restrict the scope of the disclosure.

The compound represented by formula 1 will be described in more detail, as follows.

In formula 1, M represents

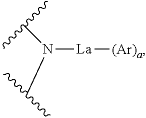

### O or S.

In formula 1, X₁ to X₁₂, each independently, represent N or CR₁. According to one embodiment of the present disclosure, X₁ to X₁₂ may all represent CR₁. According to another embodiment of the present disclosure, any one of X₁ to X₁₂ may represent N. According to another embodiment of the present disclosure, any two of X₁ to X₁₂ may represent N.

In formula 1, a represents an integer of 1 or 2, in which if a is an integer of 2, each of Ar may be the same or different.

In formula 1, La represents a single bond, a substituted or unsubstituted (C1-C30)alkylene, a substituted or unsubstituted (C6-C30)arylene, a substituted or unsubstituted (3- to 30-membered)heteroarylene, or a substituted or unsubstituted (C3-C30)cycloalkylene; preferably, a single bond, a substituted or unsubstituted (C6-C25)arylene, or a substituted or unsubstituted (5- to 25-membered)heteroarylene; and more preferably, a single bond, an unsubstituted (C6-C18)arylene, or an unsubstituted (5- to 18-membered)heteroarylene. The heteroarylene may include at least one of nitrogen, oxygen and sulfur- and preferably may include at least one of nitrogen and sulfur. For example, La may represent a single bond, a phenylene, a naphthylene, a biphenylene, a pyridylene, a pyrimidinylene, a triazinylene, an isoquinolinylene, a quinazolinylene, a naphthyridinylene, a quinoxalinylene, a benzoquinoxalinylene, an indoloquinoxalinylene, a benzothienopyrimidinylene, a pyridopyrazinylene, or a benzoquinazolinylene.

In formula 1, Ar and R₁, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, a substituted or unsubstituted (C1-C30)alkyl(C6-C30)arylamino, or a substituted or unsubstituted (C6-C30)aryl(3- to 30-membered)heteroarylamino; or two or more adjacent Ar's may be linked to each other to form a substituted or unsubstituted, mono- or polycyclic, (C3-C30) alicyclic or aromatic ring, or a combination thereof, two or more adjacent R₁'s may be linked to each other to form a substituted or unsubstituted, mono- or polycyclic, (C3-C30) alicyclic or aromatic ring, or a combination thereof, the carbon atom(s) in the alicyclic or aromatic ring, or a combination thereof may be replaced with at least one heteroatom selected from nitrogen, oxygen, and sulfur.

Preferably. Ar may represent a substituted or unsubstituted (C6-C25)aryl, a substituted or unsubstituted (5- to 25-membered)heteroaryl, a substituted or unsubstituted di(C6-C25)arylamino, or a substituted or unsubstituted (C6-C25)aryl(5- to 25-membered)heteroarylamino. More preferably, Ar may represent a (C6-C18)aryl unsubstituted or substituted with at least one of deuterium, a (C1-C10)alkyl(s), and a (C6-C18)aryl(s); a (5-to 25-membered)heteroaryl unsubstituted or substituted with at least one of a (C1-C10)alkyl(s) and a (C6-C12)aryl(s); a di(C6-C25)arylamino unsubstituted or substituted with a (C1-C6)alkyl(s); or an unsubstituted (C6-C18)aryl(5- to 25-membered)heteroarylamino. According to one embodiment of the present disclosure, Ar may represent a substituted or unsubstituted phenyl, a substituted or unsubstituted naphthyl, a substituted or unsubstituted biphenyl, a substituted or unsubstituted terphenyl, a substituted or unsubstituted fluorenyl, a substituted or unsubstituted fluoranthenyl, a substituted or unsubstituted triazinyl, a substituted or unsubstituted pyridyl, a substituted or unsubstituted triazolopyridyl, a substituted or unsubstituted pyrimidinyl, a substituted or unsubstituted benzothienopyrimidinyl, a substituted or unsubstituted acenaphthopyrimidinyl, a substituted or unsubstituted quinazolinyl, a substituted or unsubstituted benzoquinazolinyl, a substituted or unsubstituted quinoxalinyl, a substituted or unsubstituted benzoquinoxalinyl, a substituted or unsubstituted dibenzoquinoxalinyl, a substituted or unsubstituted indoloquinoxalinyl, a substituted or unsubstituted quinolyl, a substituted or unsubstituted benzoquinolyl, a substituted or unsubstituted isoquinolyl, a substituted or unsubstituted benzoisoquinolyl, a substituted or unsubstituted benzothienoquinolyl, a substituted or unsubstituted benzofuroquinolyl, a substituted or unsubstituted trazolyl, a substituted or unsubstituted pyrazolyl, a substituted or unsubstituted carbazolyl, a substituted or unsubstituted dibenzothiophenyl, a substituted or unsubstituted benzothiophenyl, a substituted or unsubstituted dibenzofuranyl, a substituted or unsubstituted benzofuranyl, a substituted or unsubstituted naphthyridinyl, a substituted or unsubstituted benzothiazolinyl, a substituted or unsubstituted phenanthroimidazolyl, a substituted or unsubstituted diphenylamino, a substituted or unsubstituted phenylbiphenylamino, a substituted or unsubstituted fluorenylphenylamino, a substituted or unsubstituted dibenzothiophenylphenylamino, or a substituted or unsubstituted dibenzofuranylphenylamino. According to another embodiment of the present disclosure. Ar may represent a phenyl unsubstituted or substituted with at least one of deuterium and a naphthyl(s); an unsubstituted naphthyl; an unsubstituted biphenyl; an unsubstituted terphenyl; a fluorenyl substituted with a methyl(s); an unsubstituted fluoranthenyl; a triazinyl unsubstituted or substituted with at least one of a phenyl(s) and a naphthyl(s); a pyridyl unsubstituted or substituted with a phenyl(s); a triazolopyridyl substituted with a phenyl(s); a pyrimidinyl unsubstituted or substituted with a phenyl(s); a quinazolinyl substituted with a phenyl(s); an isoquinolyl substituted with a phenyl(s); a carbazolyl unsubstituted or substituted with a phenyl(s); an unsubstituted dibenzothiophenyl; a dibenzofuranyl unsubstituted or substituted with a phenyl(s); a naphthyridinyl substituted with a phenyl(s); an unsubstituted diphenylamino; an unsubstituted phenylbiphenylamino; a dimethylfluorenylphenylamino; a benzothienopyrimidinyl substituted with a phenyl(s); an unsubstituted benzothienoquinolyl; an unsubstituted benzofuroquinolyl; a benzoquinazolinyl substituted with a phenyl(s); a benzothiazolinyl substituted with a phenyl(s); a quinoxalinyl substituted with a phenyl(s); a benzoquinoxalinyl substituted with a phenyl(s); an unsubstituted dibenzoquinoxalinyl; an indoloquinoxalinyl substituted with a phenyl(s); a phenanthroimidazolyl substituted with a phenyl(s); an unsubstituted dibenzothiophenylphenylamino; an unsubstituted dibenzofuranylphenylamino; a nitrogen-containing (17-membered)heteroaryl substituted with a methyl(s); a nitrogen- and oxygen-containing (25-membered)heteroaryl; or a acenaphthopyrimidinyl substituted with a phenyl(s).

Preferably, R₁ may represent hydrogen, a substituted or unsubstituted (C6-C25)aryl, or a substituted or unsubstituted (3- to 25-membered)heteroaryl; or two or more adjacent R₁'s may be linked to each other to form a substituted or unsubstituted, mono- or polycyclic, (C3-C25) alicyclic or aromatic ring, or a combination thereof, whose carbon atom(s) may be replaced with at least one heteroatom selected from nitrogen, oxygen, and sulfur. More preferably, R₁ may represent hydrogen, a substituted or unsubstituted (C6-C18)aryl, or a substituted or unsubstituted (5- to 18-membered)heteroaryl; or two or more adjacent R₁'s may be linked to each other to form a substituted or unsubstituted, mono- or polycyclic, (C3-C18) aromatic ring, whose carbon atom(s) may be replaced with at least one heteroatom selected from nitrogen, oxygen, and sulfur. Even more preferably, R₁ may represent hydrogen; a (C6-C12)aryl unsubstituted or substituted with a (5- to 18-membered)heteroaryl(s); or a (5- to 13-membered)heteroaryl unsubstituted or substituted with a (C6-C18)aryl(s); or two or more adjacent R₁'s may be linked to each other to form a substituted or unsubstituted, mono- or polycyclic, (C3-C10) aromatic ring, whose carbon atom(s) may be replaced with at least one heteroatom selected from nitrogen, oxygen, and sulfur. For example, R₁ may represent hydrogen; a phenyl unsubstituted or substituted with a diphenyltriazinyl(s); a diphenyltriazinyl; a quinazolinyl substituted with a phenyl(s); or an unsubstituted pyridyl; or two adjacent R₁'s may be linked to each other to form an unsubstituted benzene ring, an indene ring substituted with at least one of a methyl(s) and a phenyl(s), an unsubstituted pyridine ring, an unsubstituted benzothiophene ring, an unsubstituted benzofuran ring, or an indole ring substituted with a phenyl(s) or a phenylquinoxalinyl(s). If a plurality of R₁'s is present, each of R₁ may be the same or different.

According to one embodiment of the present disclosure, in formula 1, at least two adjacent ones of X₁ to X₁₂ are CR₁, and two adjacent R₁'s may be fused as any one of the following formulas 2 to 6 to form a ring(s). One or more rings may be formed in one compound represented by the formula 1. For example, the ring may be fused with the benzene ring of the backbone to form a dibenzothiophene ring, a dibenzofuran ring, a naphthalene ring, a fluorene ring, or a substituted or unsubstituted carbazole ring.

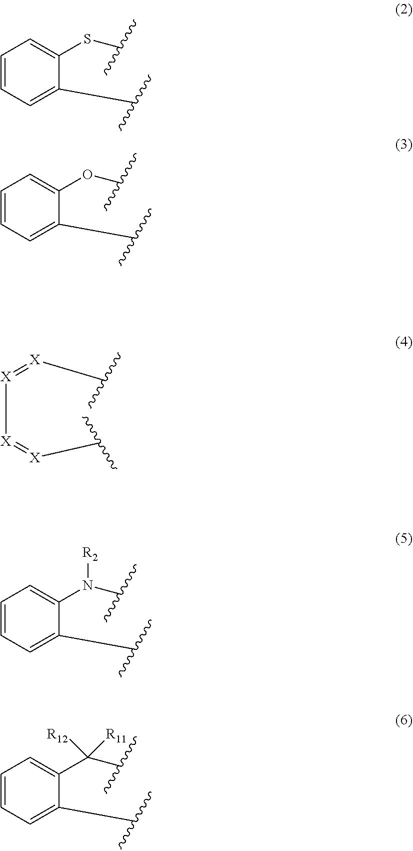

In formulas 2 to 6, [symbol] represents a linking site of C and R₁ in CR₁.

In formula 4, X represents N or CH. According to one embodiment of the present disclosure, X may all represent CH. According to another embodiment of the present disclosure, any one of X may represent N.

In formula 5, R₂ represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino. Preferably, R₂ represents a substituted or unsubstituted (C6-C25)aryl, or a substituted or unsubstituted (5- to 25-membered)heteroaryl. More preferably, R₂ represents an unsubstituted (C6-C18)aryl, or a (5- to 18-membered)heteroaryl unsubstituted or substituted with a (C6-C18)aryl(s). For example, R₂ may represent an unsubstituted phenyl, or a quinoxalinyl substituted with a phenyl(s).

In formula 6, R₁₁ and R₁₂, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, or a substituted or unsubstituted (C3-C30)cycloalkyl; or R₁₁ and R₁₂ may be linked to each other to form a substituted or unsubstituted, mono- or polycyclic, (C3-C30) alicyclic or aromatic ring, or a combination thereof, whose carbon atom(s) may be replaced with at least one heteroatom selected from nitrogen, oxygen, and sulfur. Preferably, R₁₁ and R₁₂, each independently, represent hydrogen, a substituted or unsubstituted (C1-C6)alkyl, or a substituted or unsubstituted (C6-C12)aryl; or R₁₁ and R₁₂ may be linked to each other to form a substituted or unsubstituted, mono- or polycyclic, (C5-C10) alicyclic or aromatic ring, or a combination thereof. More preferably, R₁₁ and R₁₂, each independently, represent hydrogen, an unsubstituted (C1-C6)alkyl, or an unsubstituted (C6-C12)aryl; or R₁₁ and R₁₂ may be linked to each other to form a spiro ring. For example, R₁₁ and R₁₂, each independently, represent hydrogen, a methyl, or a phenyl. R₁ and R₁₂ may be the same or different. According to one embodiment of the present disclosure, R₁₁ and R₁₂ may be the same.

In the present disclosure, a heteroaryl(ene) or a heterocycloalkyl, each independently, may contain at least one heteroatom selected from B, N, O, S, Si, and P, and preferably, at least one heteroatom selected from N, O, and S. In addition, the heteroatom may be bonded to at least one selected from the group consisting of hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, and a substituted or unsubstituted (C1-C30)alkyl(C6-C30)arylamino.

The compound represented by the formula 1 may be represented by any one of the following formulas 7 to 10.

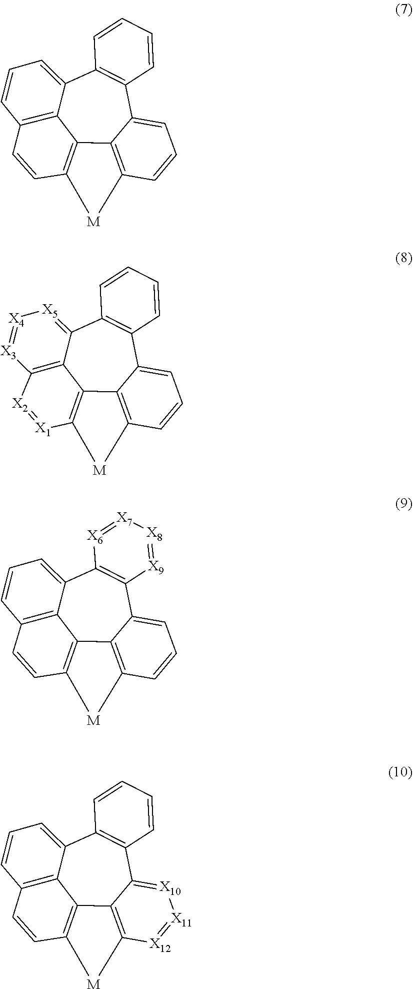

In formulas 7 to 10, X₁ to X₁₂, and M are as defined in the formula 1 above.

Herein, the term “(C1-C30)alkyl(ene)” is meant to be a linear or branched alkyl(ene) having 1 to 30 carbon atoms constituting the chain, in which the number of carbon atoms is preferably 1 to 20, and more preferably 1 to 10. The above alkyl may include methyl, ethyl, n-propyl, isopropyl, n-butyl, isobutyl, tert-butyl, etc. The term “(C2-C30)alkenyl” is meant to be a linear or branched alkenyl having 2 to 30 carbon atoms constituting the chain, in which the number of carbon atoms is preferably 2 to 20, and more preferably 2 to 10. The above alkenyl may include vinyl, 1-propenyl, 2-propenyl, 1-butenyl, 2-butenyl, 3-butenyl, 2-methylbut-2-enyl, etc. The term “(C2-C30)alkynyl” is meant to be a linear or branched alkynyl having 2 to 30 carbon atoms constituting the chain, in which the number of carbon atoms is preferably 2 to 20, and more preferably 2 to 10. The above alkynyl may include ethynyl, 1-propynyl, 2-propynyl, 1-butynyl, 2-butynyl, 3-butynyl, 1-methylpent-2-ynyl, etc. The term “(C3-C30)cycloalkyl(ene)” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, etc. The term “(3- to 7-membered)heterocycloalkyl” is meant to be a cycloalkyl having 3 to 7, preferably 5 to 7, ring backbone atoms, and including at least one heteroatom selected from the group consisting of B, N, O, S, Si, and P, and preferably the group consisting of O, S, and N. The above heterocycloalkyl may include tetrahydrofuran, pyrrolidine, thiolan, tetrahydropyran, etc. The term “(C6-C30)aryl(ene)” is meant to be a monocyclic or fused ring radical derived from an aromatic hydrocarbon having 6 to 30 ring backbone carbon atoms, in which the number of the ring backbone carbon atoms is preferably 6 to 25, more preferably 6 to 18. The above aryl may be partially saturated, and may comprise a spiro structure. The above aryl may include phenyl, biphenyl, terphenyl, naphthyl, binaphthyl, phenylnaphthyl, naphthylphenyl, phenylterphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, spirobifluorenyl, etc. More specifically, the aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzofluorenyl, dibenzofluorenyl, 2-biphenylyl, 3-biphenylyl, 4-biphenylyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, p-tert-butylphenyl, p-(2-phenylpropyl)phenyl, 4′-methylbiphenylyl, 4″-tert-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, etc.

The term “(3- to 30-membered)heteroaryl(ene)” is an aryl or an arylene having 3 to 30 ring backbone atoms, and including at least one, preferably 1 to 4 heteroatoms selected from the group consisting of B, N, O, S, Si, and P. The above heteroaryl(ene) may be a monocyclic ring, or a fused ring condensed with at least one benzene ring; may be partially saturated; may be one formed by linking at least one heteroaryl or aryl group to a heteroaryl group via a single bond(s); and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, benzimidazolyl, benzothiazolyl, benzoisothiazolyl, benzoisoxazolyl, benzoxazolyl, isoindolyl, indolyl, benzoindolyl, indazolyl, benzothiadiazolyl, quinolyl, isoquinolyl, cinnolinyl, quinazolinyl, benzoquinazolinyl, quinoxalinyl, benzoquinoxalinyl, naphthyridinyl, carbazolyl, benzocarbazolyl, dibenzocarbazolyl, phenoxazinyl, phenothiazinyl, phenanthridinyl, benzodioxolyl, dihydroacridinyl, etc. More specifically, the heteroaryl may include 1-pyrrolyl, 2-pyrrolyl, 3-pyrrolyl, pyrazinyl, 2-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridinyl, 3-imidazopyridinyl, 5-imidazopyridinyl, 6-imidazopyridinyl, 7-imidazopyridinyl, 8-imidazopyridinyl, 3-pyridinyl, 4-pyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazolyl-1-yl, azacarbazolyl-2-yl, azacarbazolyl-3-yl, azacarbazolyl-4-yl, azacarbazolyl-5-yl, azacarbazolyl-6-yl, azacarbazolyl-7-yl, azacarbazolyl-8-yl, azacarbazolyl-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-tert-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-tert-butyl-1-indolyl, 4-tert-butyl-1-indolyl, 2-tert-butyl-3-indolyl, 4-tert-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, etc. “Halogen” includes F, Cl, Br, and I.

In addition, “ortho (o-),” “meta (m-),” and “para (p-)” are prefixes, which represent the relative positions of substituents, respectively. Ortho indicates that two substituents are adjacent to each other, and for example, when two substituents in a benzene derivative occupy positions 1 and 2, it is called an ortho position. Meta indicates that two substituents are at positions 1 and 3, and for example, when two substituents in a benzene derivative occupy positions 1 and 3, it is called a meta position. Para indicates that two substituents are at positions 1 and 4, and for example, when two substituents in a benzene derivative occupy positions 1 and 4, it is called a para position.

Herein, “substituted” in the expression “substituted or unsubstituted” means that a hydrogen atom in a certain functional group is replaced with another atom or another functional group, i.e., a substituent. In the present disclosure, the substituents of the substituted (C1-C30)alkyl(ene), the substituted (C6-C30)aryl(ene), the substituted (3- to 30-membered)heteroaryl(ene), the substituted (C3-C30)cycloalkyl(ene), the substituted (C1-C30)alkoxy, the substituted tri(C1-C30)alkylsilyl, the substituted di(C1-C30)alkyl(C6-C30)arylsilyl, the substituted (C1-C30)alkyldi(C6-C30)arylsilyl, the substituted tri(C6-C30)arylsilyl, the substituted mono- or di-(C1-C30)alkylamino, the substituted mono- or di-(C6-C30)arylamino, the substituted (C1-C30)alkyl(C6-C30)arylamino, and the substituted (C6-C30)aryl(3- to 30-membered)heteroarylamino, each independently, are at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (3- to 30-membered)heteroaryl unsubstituted or substituted with a (C6-C30)aryl(s); a (C6-C30)aryl unsubstituted or substituted with a (3- to 30-membered)heteroaryl(s); a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di-(C1-C30)alkylamino; a mono- or di-(C6-C30)arylamino unsubstituted or substituted with a (C1-C30)alkyl(s); a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl. According to one embodiment of the present disclosure, the substituents, each independently, are at least one selected from the group consisting of deuterium; a (C1-C20)alkyl; an unsubstituted (C6-C25)aryl; and a (5-to 25-membered)heteroaryl unsubstituted or substituted with a (C6-C25)aryl(s). According to another embodiment of the present disclosure, the substituents, each independently, are at least one selected from the group consisting of deuterium; a (C1-C10)alkyl; an unsubstituted (C6-C18)aryl; and a (5- to 18-membered)heteroaryl substituted with a (C6-C18)aryl(s). For example, the substituents, each independently, may be at least one selected from the group consisting of deuterium, a methyl, a phenyl, a naphthyl, a diphenyltriazinyl, and a phenylquinoxalinyl.

The compound represented by the formula 1 may be specifically exemplified by the following compounds, but is not limited thereto.

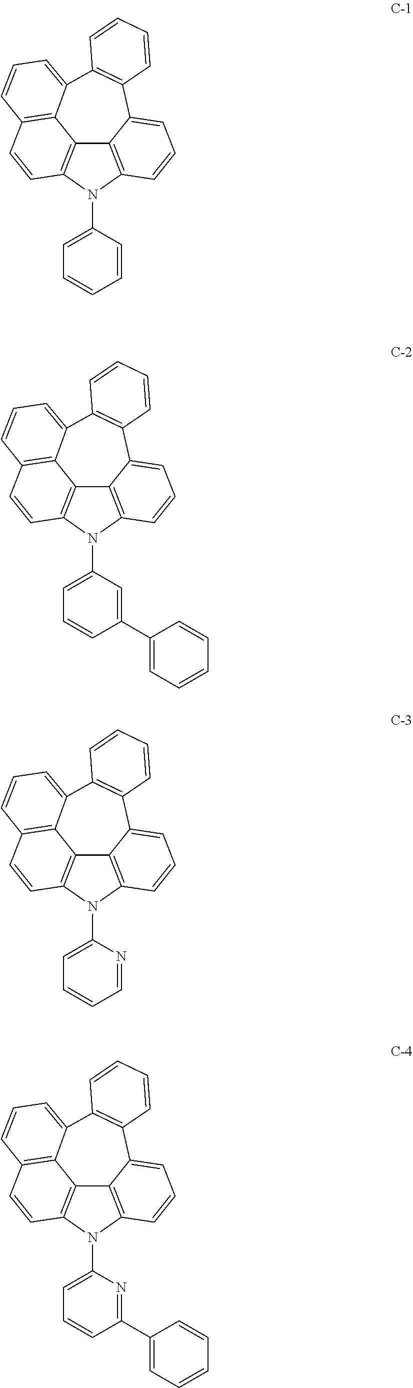 [SMILES: c1ccc(-n2c3cccc4c3c3c5c(cccc5ccc32)-c2ccccc2-4)cc1 ; c1ccc(-c2cccc(-n3c4cccc5c4c4c6c(cccc6ccc43)-c3ccccc3-5)c2)cc1 ; c1ccc(-n2c3cccc4c3c3c5c(cccc5ccc32)-c2ccccc2-4)nc1 ; c1ccc(-c2cccc(-n3c4cccc5c4c4c6c(cccc6ccc43)-c3ccccc3-5)n2)cc1]

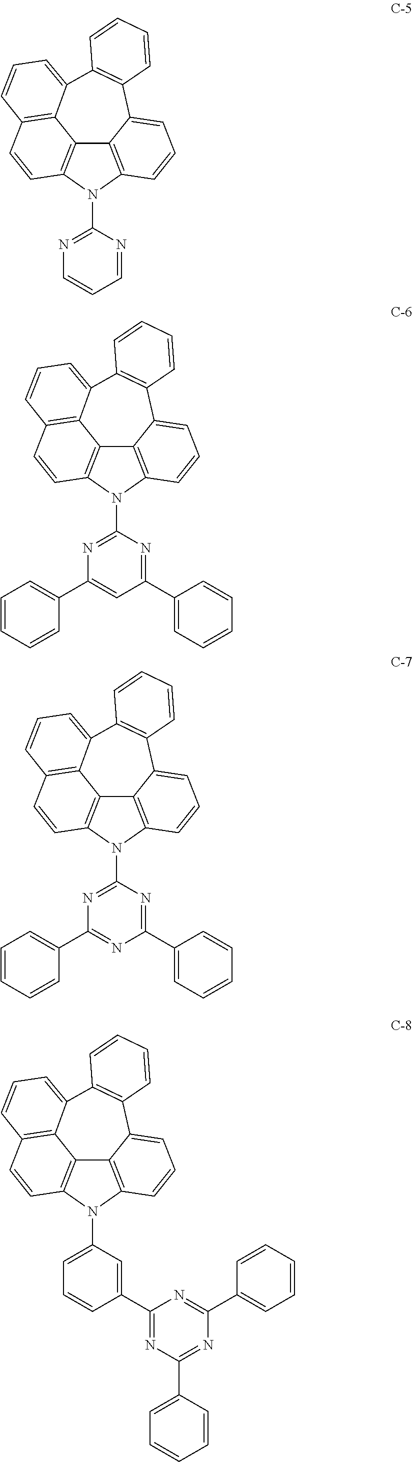 [SMILES: c1cnc(-n2c3cccc4c3c3c5c(cccc5ccc32)-c2ccccc2-4)nc1 ; c1ccc(-c2cc(-c3ccccc3)nc(-n3c4cccc5c4c4c6c(cccc6ccc43)-c3ccccc3-5)n2)cc1 ; c1ccc(-c2nc(-c3ccccc3)nc(-n3c4cccc5c4c4c6c(cccc6ccc43)-c3ccccc3-5)n2)cc1 ; c1ccc(-c2nc(-c3ccccc3)nc(-c3cccc(-n4c5cccc6c5c5c7c(cccc7ccc54)-c4ccccc4-6)c3)n2)cc1]

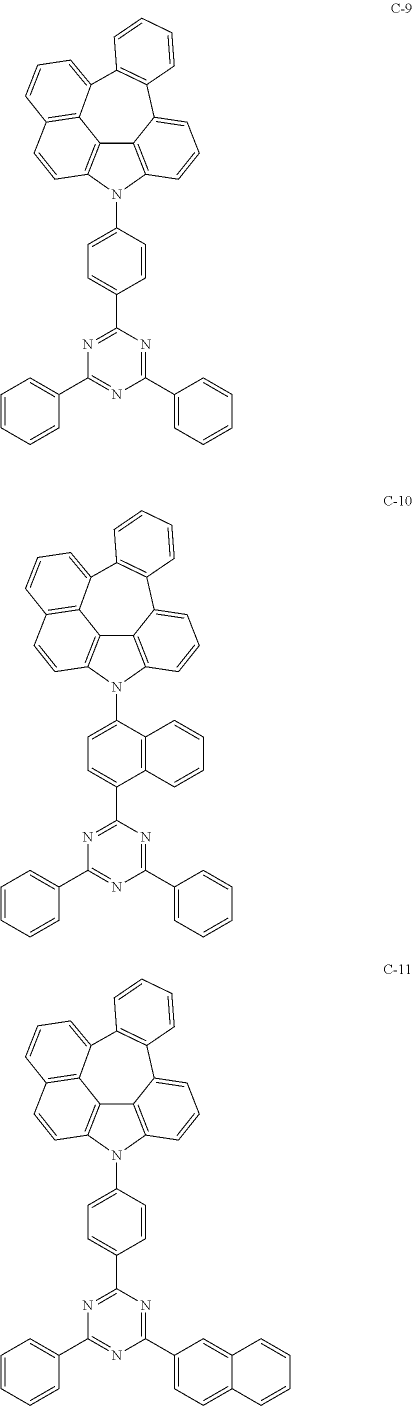 [SMILES: c1ccc(-c2nc(-c3ccccc3)nc(-c3ccc(-n4c5cccc6c5c5c7c(cccc7ccc54)-c4ccccc4-6)cc3)n2)cc1 ; c1ccc(-c2nc(-c3ccccc3)nc(-c3ccc(-n4c5cccc6c5c5c7c(cccc7ccc54)-c4ccccc4-6)c4ccccc34)n2)cc1 ; c1ccc(-c2nc(-c3ccc(-n4c5cccc6c5c5c7c(cccc7ccc54)-c4ccccc4-6)cc3)nc(-c3ccc4ccccc4c3)n2)cc1]

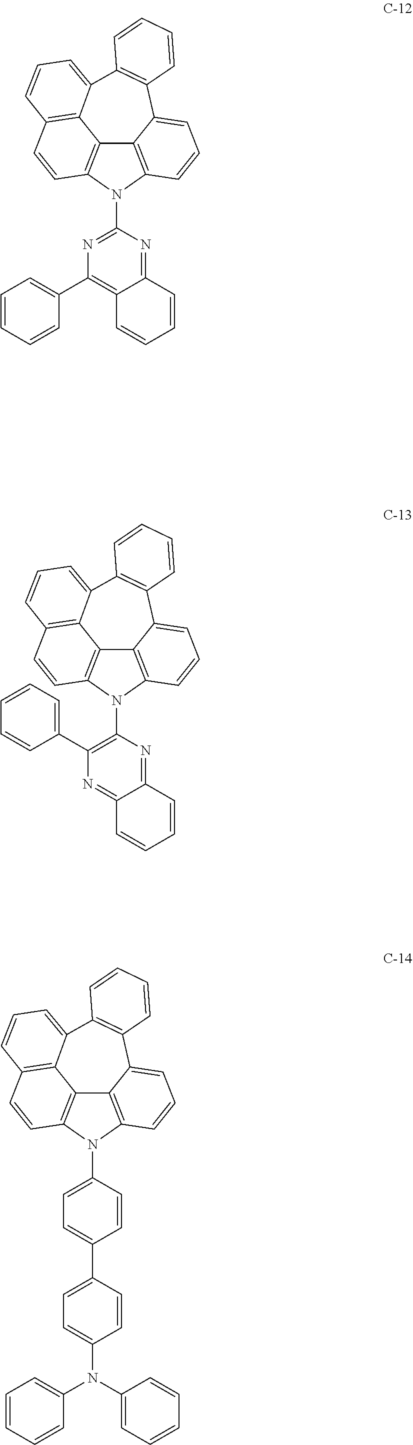 [SMILES: c1ccc(-c2nc(-n3c4cccc5c4c4c6c(cccc6ccc43)-c3ccccc3-5)nc3ccccc23)cc1 ; c1ccc(-c2nc3ccccc3nc2-n2c3cccc4c3c3c5c(cccc5ccc32)-c2ccccc2-4)cc1 ; c1ccc(N(c2ccccc2)c2ccc(-c3ccc(-n4c5cccc6c5c5c7c(cccc7ccc54)-c4ccccc4-6)cc3)cc2)cc1]

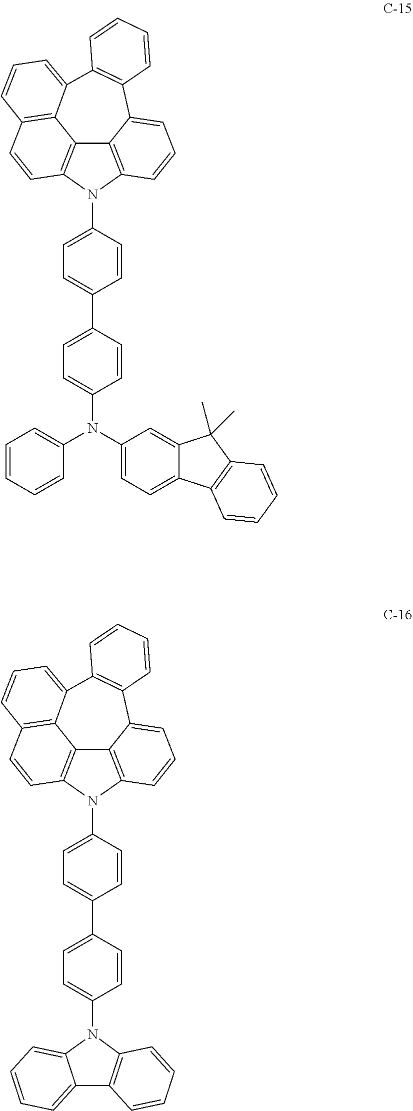 [SMILES: CC1(C)c2ccccc2-c2ccc(N(c3ccccc3)c3ccc(-c4ccc(-n5c6cccc7c6c6c8c(cccc8ccc65)-c5ccccc5-7)cc4)cc3)cc21 ; c1ccc2c(c1)-c1cccc3ccc4c(c13)c1c-2cccc1n4-c1ccc(-c2ccc(-n3c4ccccc4c4ccccc43)cc2)cc1]

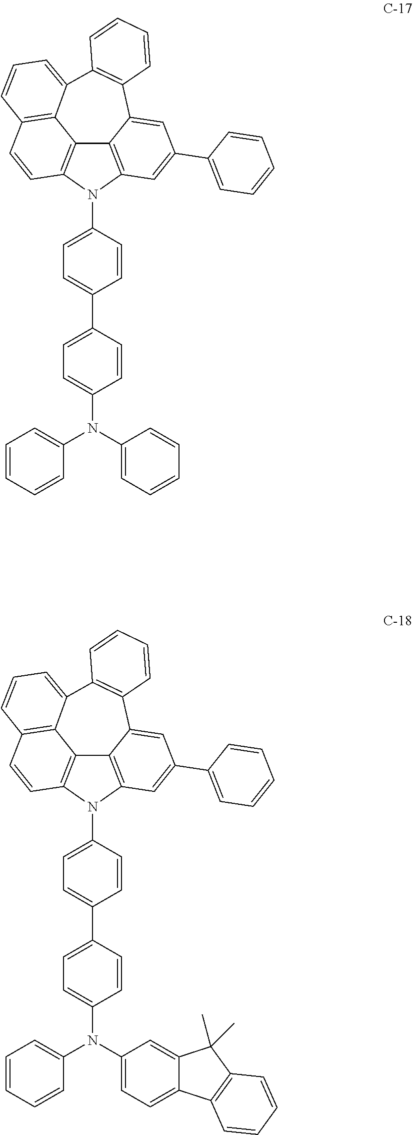 [SMILES: c1ccc(-c2cc3c4c5c6c(cccc6ccc5n(-c5ccc(-c6ccc(N(c7ccccc7)c7ccccc7)cc6)cc5)c4c2)-c2ccccc2-3)cc1 ; CC1(C)c2ccccc2-c2ccc(N(c3ccccc3)c3ccc(-c4ccc(-n5c6cc(-c7ccccc7)cc7c6c6c8c(cccc8ccc65)-c5ccccc5-7)cc4)cc3)cc21]

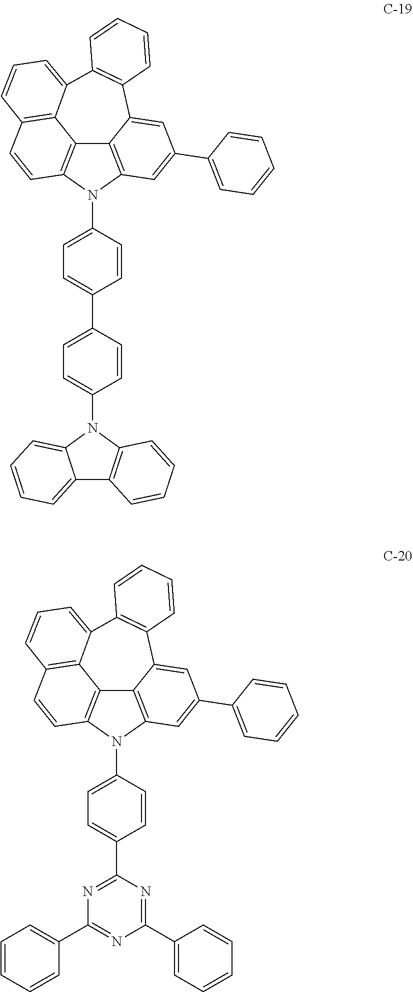 [SMILES: c1ccc(-c2cc3c4c5c6c(cccc6ccc5n(-c5ccc(-c6ccc(-n7c8ccccc8c8ccccc87)cc6)cc5)c4c2)-c2ccccc2-3)cc1 ; c1ccc(-c2cc3c4c5c6c(cccc6ccc5n(-c5ccc(-c6nc(-c7ccccc7)nc(-c7ccccc7)n6)cc5)c4c2)-c2ccccc2-3)cc1]

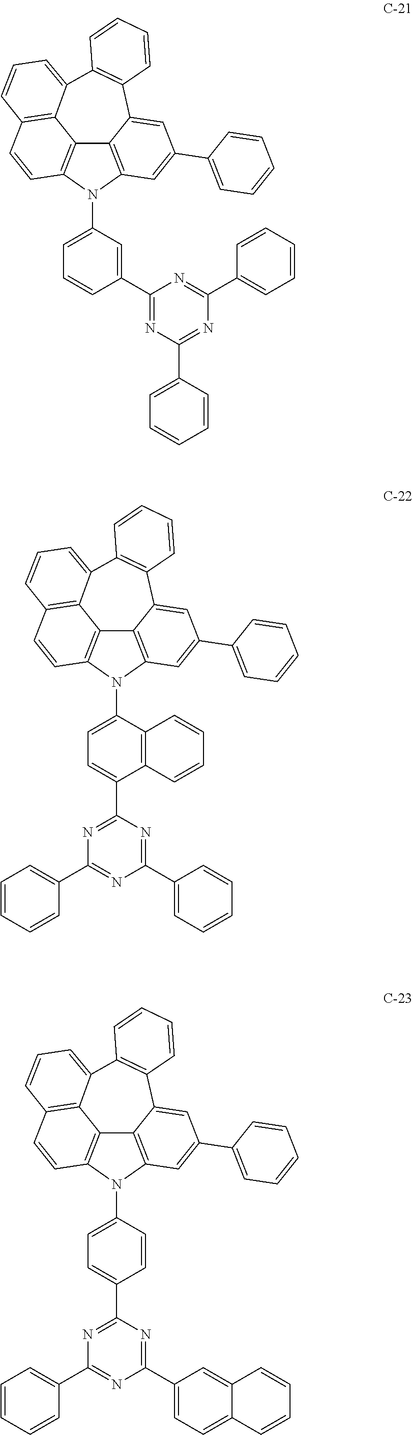 [SMILES: c1ccc(-c2cc3c4c5c6c(cccc6ccc5n(-c5cccc(-c6nc(-c7ccccc7)nc(-c7ccccc7)n6)c5)c4c2)-c2ccccc2-3)cc1 ; c1ccc(-c2cc3c4c5c6c(cccc6ccc5n(-c5ccc(-c6nc(-c7ccccc7)nc(-c7ccccc7)n6)c6ccccc56)c4c2)-c2ccccc2-3)cc1 ; c1ccc(-c2cc3c4c5c6c(cccc6ccc5n(-c5ccc(-c6nc(-c7ccccc7)nc(-c7ccc8ccccc8c7)n6)cc5)c4c2)-c2ccccc2-3)cc1]

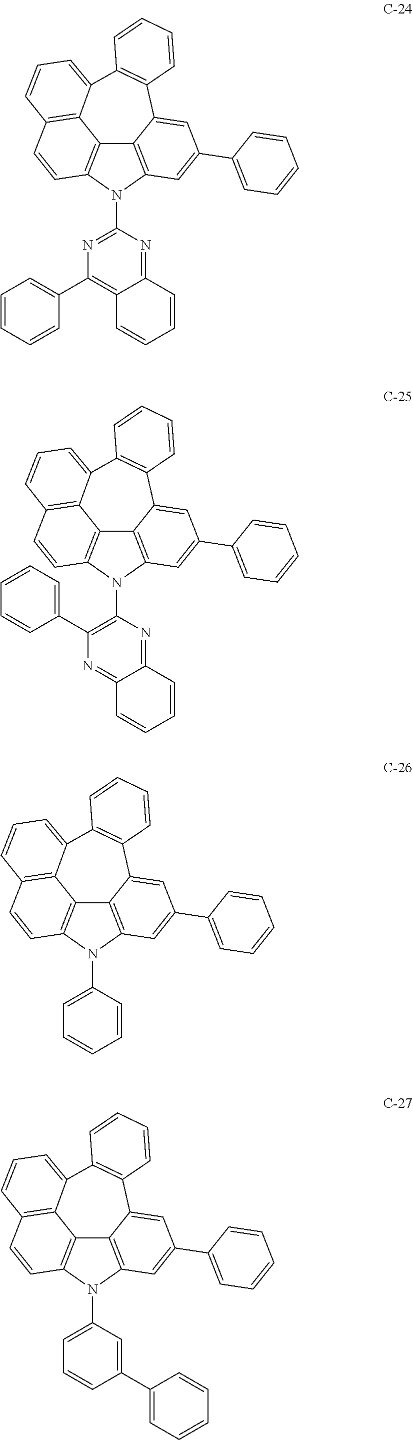 [SMILES: c1ccc(-c2cc3c4c5c6c(cccc6ccc5n(-c5nc(-c6ccccc6)c6ccccc6n5)c4c2)-c2ccccc2-3)cc1 ; c1ccc(-c2cc3c4c5c6c(cccc6ccc5n(-c5nc6ccccc6nc5-c5ccccc5)c4c2)-c2ccccc2-3)cc1 ; c1ccc(-c2cc3c4c5c6c(cccc6ccc5n(-c5ccccc5)c4c2)-c2ccccc2-3)cc1 ; c1ccc(-c2cccc(-n3c4cc(-c5ccccc5)cc5c4c4c6c(cccc6ccc43)-c3ccccc3-5)c2)cc1]

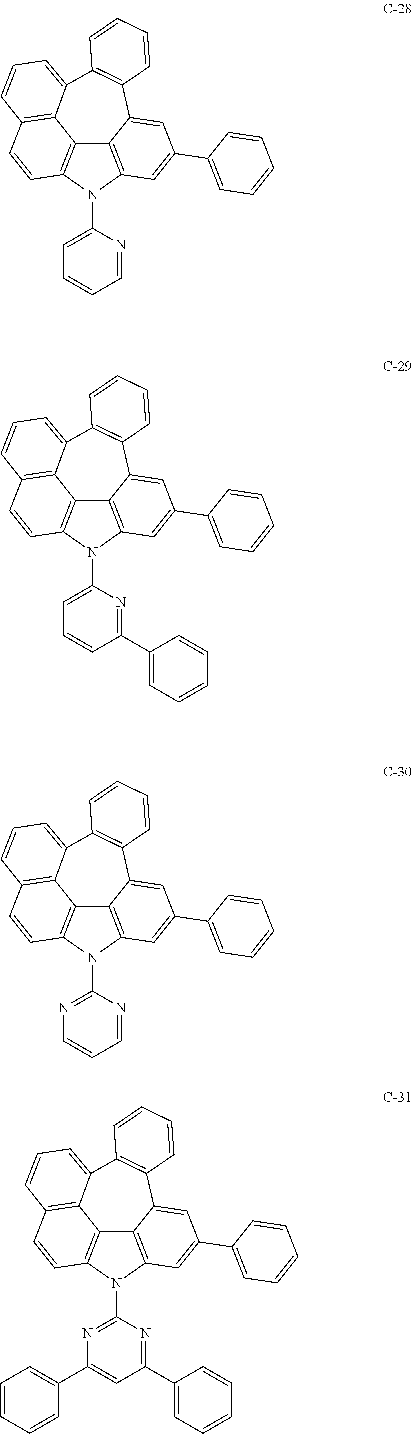 [SMILES: c1ccc(-c2cc3c4c5c6c(cccc6ccc5n(-c5ccccn5)c4c2)-c2ccccc2-3)cc1 ; c1ccc(-c2cc3c4c5c6c(cccc6ccc5n(-c5cccc(-c6ccccc6)n5)c4c2)-c2ccccc2-3)cc1 ; c1ccc(-c2cc3c4c5c6c(cccc6ccc5n(-c5ncccn5)c4c2)-c2ccccc2-3)cc1 ; c1ccc(-c2cc3c4c5c6c(cccc6ccc5n(-c5nc(-c6ccccc6)cc(-c6ccccc6)n5)c4c2)-c2ccccc2-3)cc1]

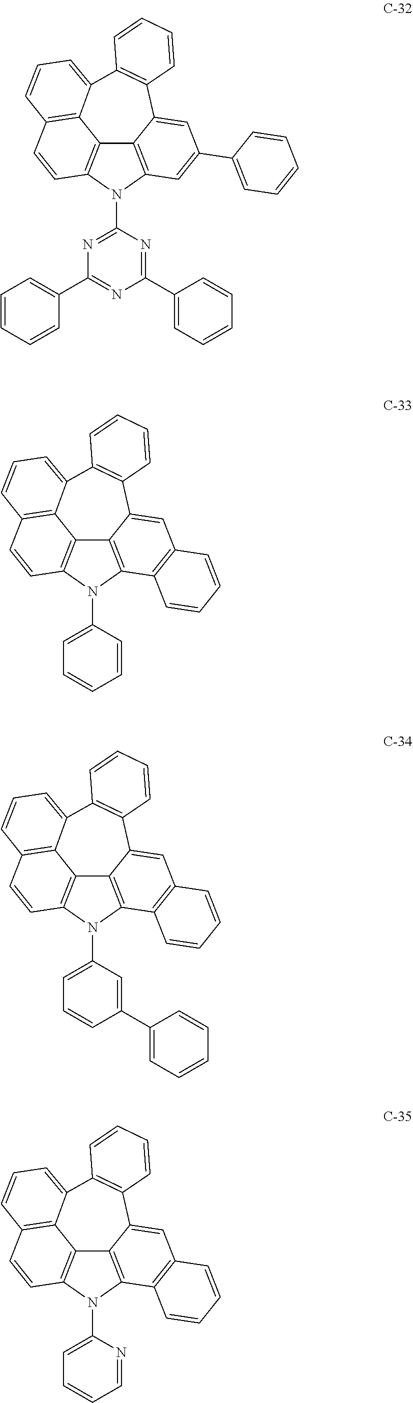 [SMILES: c1ccc(-c2cc3c4c5c6c(cccc6ccc5n(-c5nc(-c6ccccc6)nc(-c6ccccc6)n5)c4c2)-c2ccccc2-3)cc1 ; c1ccc(-n2c3ccc4cccc5c4c3c3c(cc4ccccc4c32)-c2ccccc2-5)cc1 ; c1ccc(-c2cccc(-n3c4ccc5cccc6c5c4c4c(cc5ccccc5c43)-c3ccccc3-6)c2)cc1 ; c1ccc(-n2c3ccc4cccc5c4c3c3c(cc4ccccc4c32)-c2ccccc2-5)nc1]

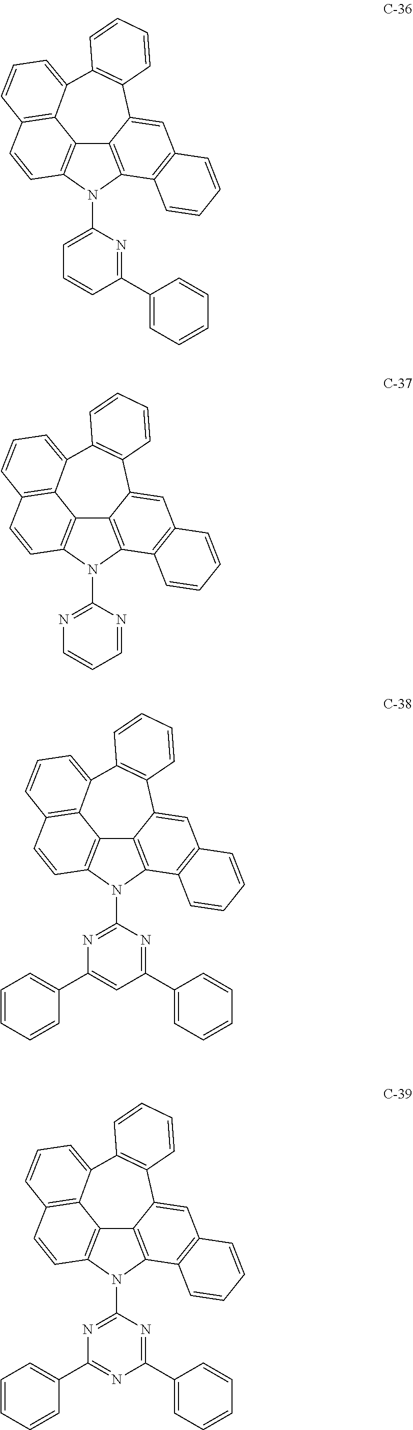 [SMILES: c1ccc(-c2cccc(-n3c4ccc5cccc6c5c4c4c(cc5ccccc5c43)-c3ccccc3-6)n2)cc1 ; c1cnc(-n2c3ccc4cccc5c4c3c3c(cc4ccccc4c32)-c2ccccc2-5)nc1 ; c1ccc(-c2cc(-c3ccccc3)nc(-n3c4ccc5cccc6c5c4c4c(cc5ccccc5c43)-c3ccccc3-6)n2)cc1 ; c1ccc(-c2nc(-c3ccccc3)nc(-n3c4ccc5cccc6c5c4c4c(cc5ccccc5c43)-c3ccccc3-6)n2)cc1]

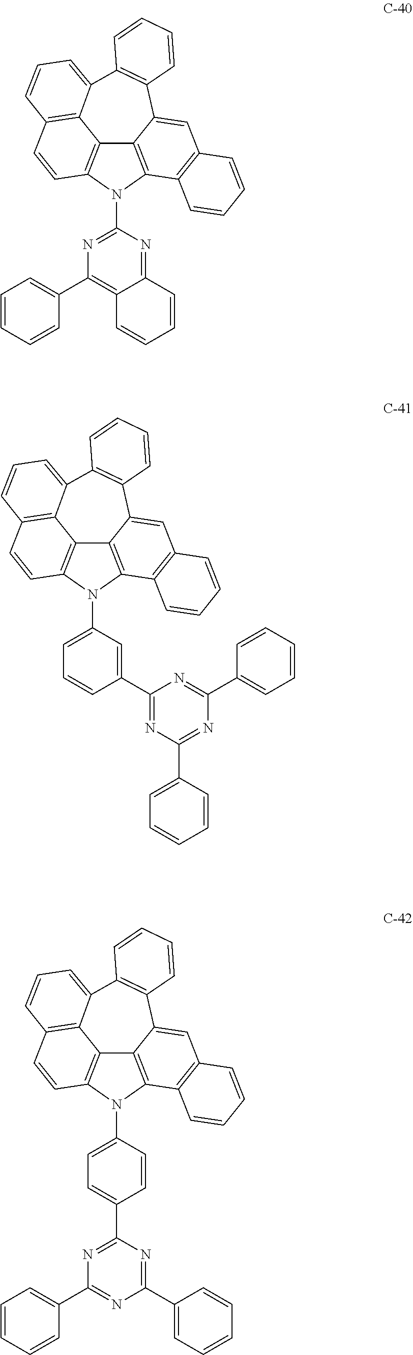 [SMILES: c1ccc(-c2nc(-n3c4ccc5cccc6c5c4c4c(cc5ccccc5c43)-c3ccccc3-6)nc3ccccc23)cc1 ; c1ccc(-c2nc(-c3ccccc3)nc(-c3cccc(-n4c5ccc6cccc7c6c5c5c(cc6ccccc6c54)-c4ccccc4-7)c3)n2)cc1 ; c1ccc(-c2nc(-c3ccccc3)nc(-c3ccc(-n4c5ccc6cccc7c6c5c5c(cc6ccccc6c54)-c4ccccc4-7)cc3)n2)cc1]

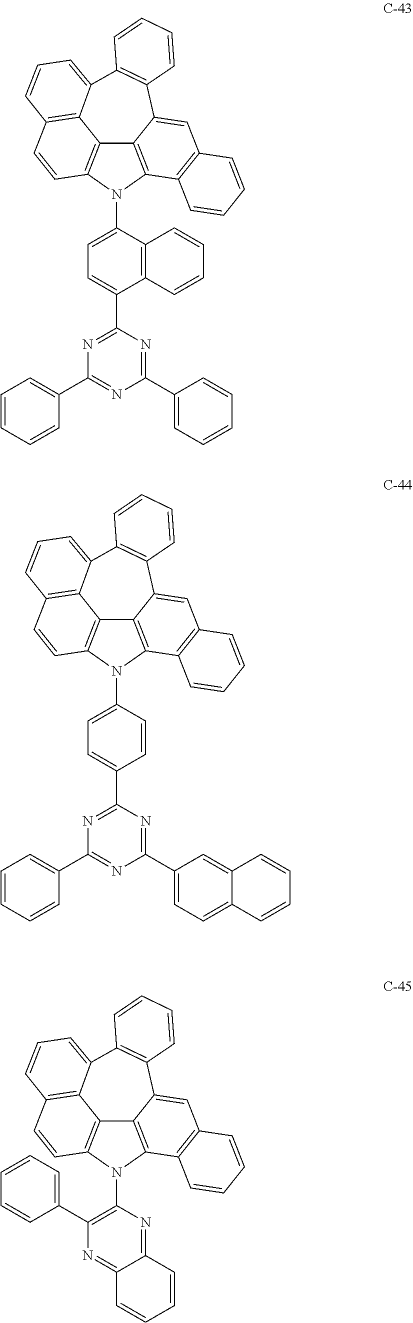 [SMILES: c1ccc(-c2nc(-c3ccccc3)nc(-c3ccc(-n4c5ccc6cccc7c6c5c5c(cc6ccccc6c54)-c4ccccc4-7)c4ccccc34)n2)cc1 ; c1ccc(-c2nc(-c3ccc(-n4c5ccc6cccc7c6c5c5c(cc6ccccc6c54)-c4ccccc4-7)cc3)nc(-c3ccc4ccccc4c3)n2)cc1 ; c1ccc(-c2nc3ccccc3nc2-n2c3ccc4cccc5c4c3c3c(cc4ccccc4c32)-c2ccccc2-5)cc1]

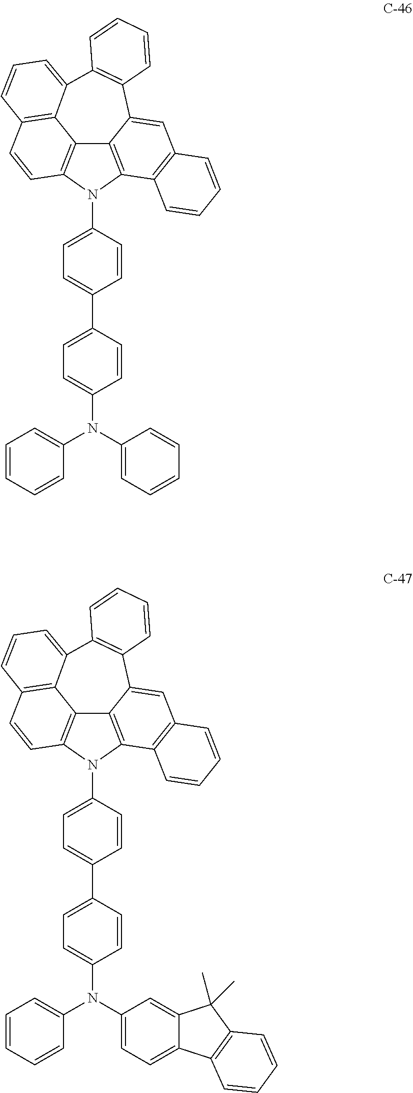 [SMILES: c1ccc(N(c2ccccc2)c2ccc(-c3ccc(-n4c5ccc6cccc7c6c5c5c(cc6ccccc6c54)-c4ccccc4-7)cc3)cc2)cc1 ; CC1(C)c2ccccc2-c2ccc(N(c3ccccc3)c3ccc(-c4ccc(-n5c6ccc7cccc8c7c6c6c(cc7ccccc7c65)-c5ccccc5-8)cc4)cc3)cc21]

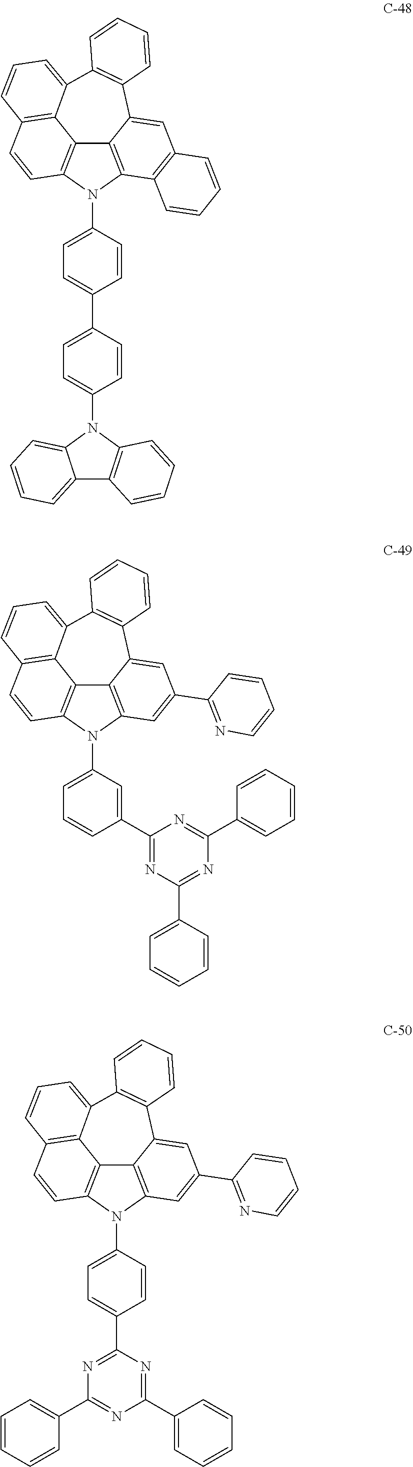

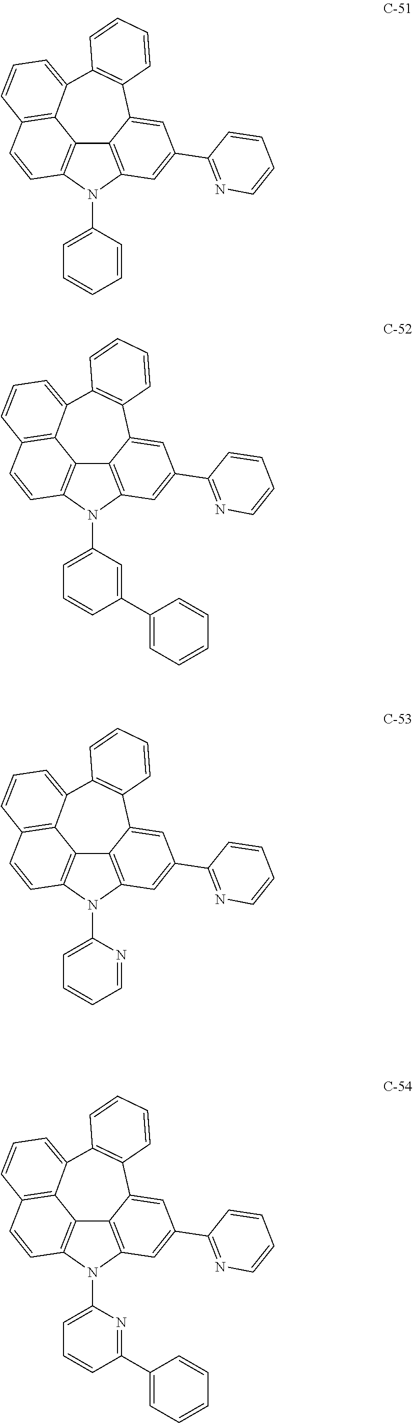 [SMILES: c1ccc(-n2c3cc(-c4ccccn4)cc4c3c3c5c(cccc5ccc32)-c2ccccc2-4)cc1 ; c1ccc(-c2cccc(-n3c4cc(-c5ccccn5)cc5c4c4c6c(cccc6ccc43)-c3ccccc3-5)c2)cc1 ; c1ccc(-c2cc3c4c5c6c(cccc6ccc5n(-c5ccccn5)c4c2)-c2ccccc2-3)nc1 ; c1ccc(-c2cccc(-n3c4cc(-c5ccccn5)cc5c4c4c6c(cccc6ccc43)-c3ccccc3-5)n2)cc1]

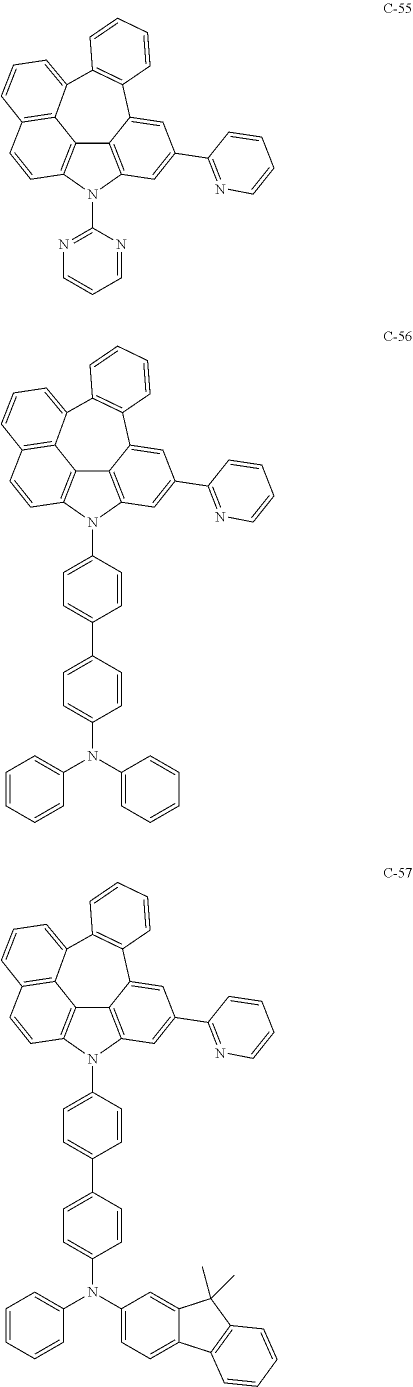 [SMILES: c1ccc(-c2cc3c4c5c6c(cccc6ccc5n(-c5ncccn5)c4c2)-c2ccccc2-3)nc1 ; c1ccc(N(c2ccccc2)c2ccc(-c3ccc(-n4c5cc(-c6ccccn6)cc6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cc(-c7ccccn7)cc7c6c6c8c(cccc8ccc65)-c5ccccc5-7)cc4)cc3)cc21]

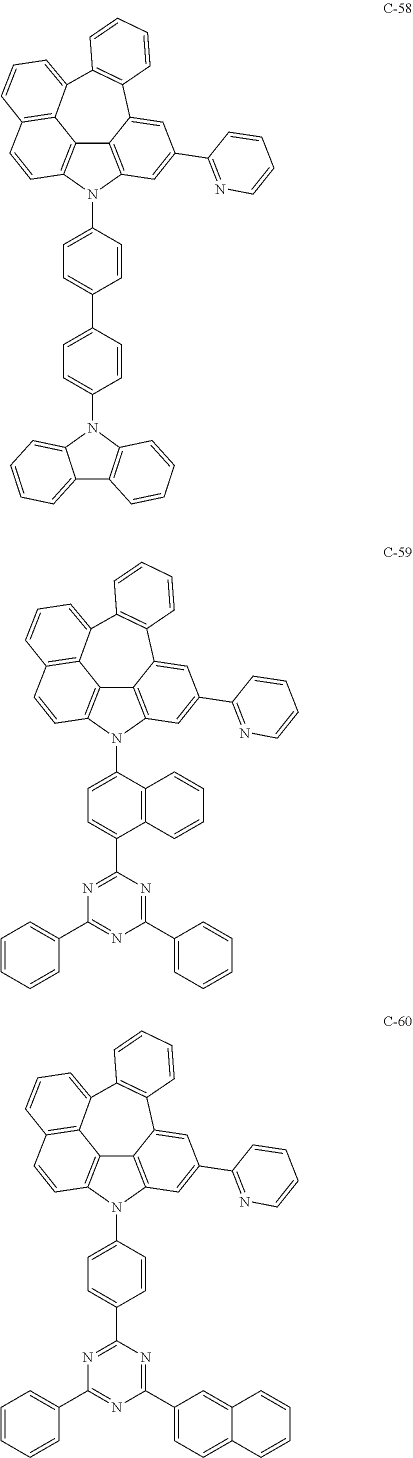 [SMILES: c1ccc(-c2cc3c4c5c6c(cccc6ccc5n(-c5ccc(-c6ccc(-n7c8ccccc8c8ccccc87)cc6)cc5)c4c2)-c2ccccc2-3)nc1 ; c1ccc(-c2nc(-c3ccccc3)nc(-c3ccc(-n4c5cc(-c6ccccn6)cc6c5c5c7c(cccc7ccc54)-c4ccccc4-6)c4ccccc34)n2)cc1 ; c1ccc(-c2nc(-c3ccc(-n4c5cc(-c6ccccn6)cc6c5c5c7c(cccc7ccc54)-c4ccccc4-6)cc3)nc(-c3ccc4ccccc4c3)n2)cc1]

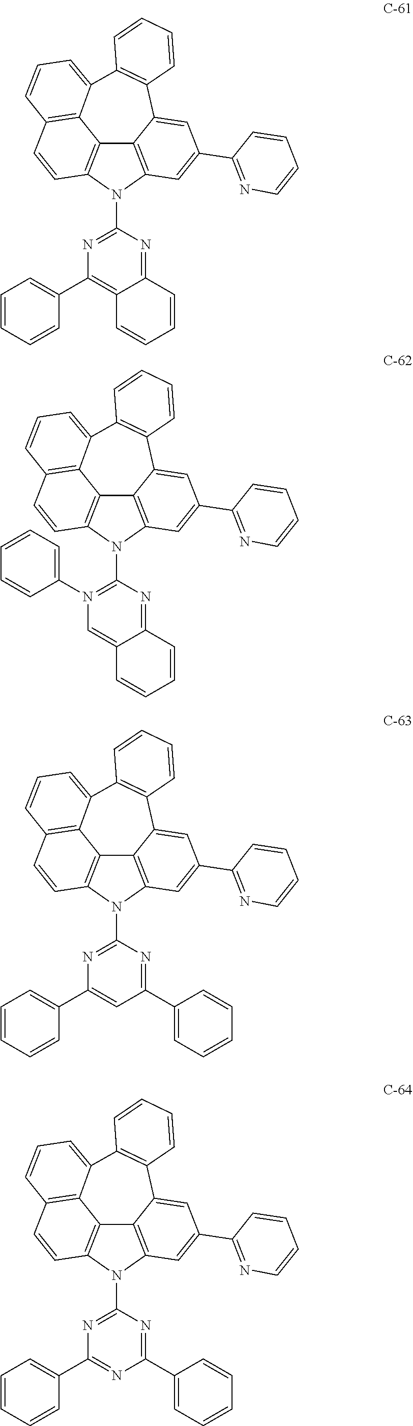

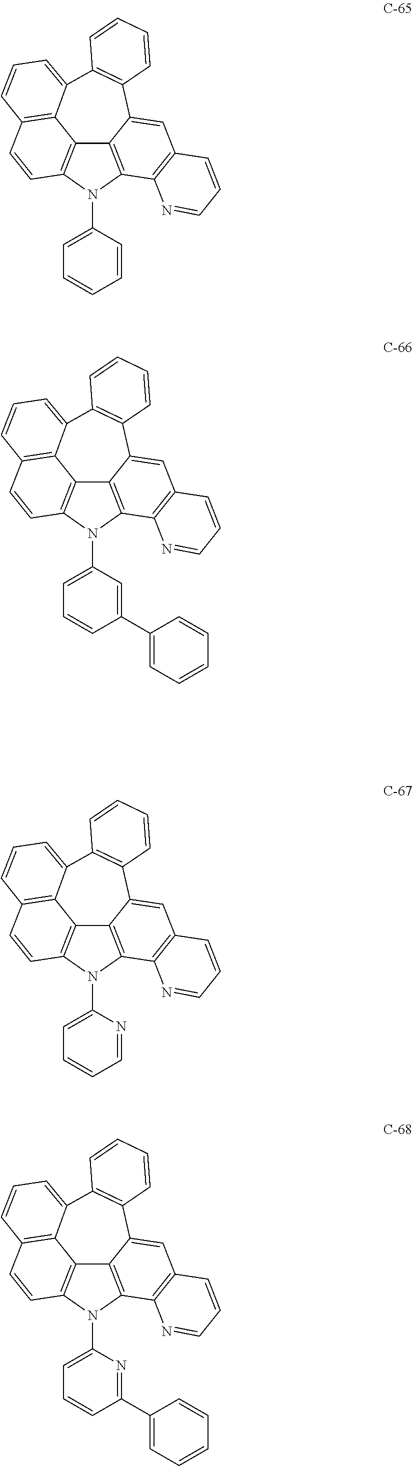 [SMILES: c1ccc(-n2c3ccc4cccc5c4c3c3c(cc4cccnc4c32)-c2ccccc2-5)cc1 ; c1ccc(-c2cccc(-n3c4ccc5cccc6c5c4c4c(cc5cccnc5c43)-c3ccccc3-6)c2)cc1 ; c1ccc(-n2c3ccc4cccc5c4c3c3c(cc4cccnc4c32)-c2ccccc2-5)nc1 ; c1ccc(-c2cccc(-n3c4ccc5cccc6c5c4c4c(cc5cccnc5c43)-c3ccccc3-6)n2)cc1]

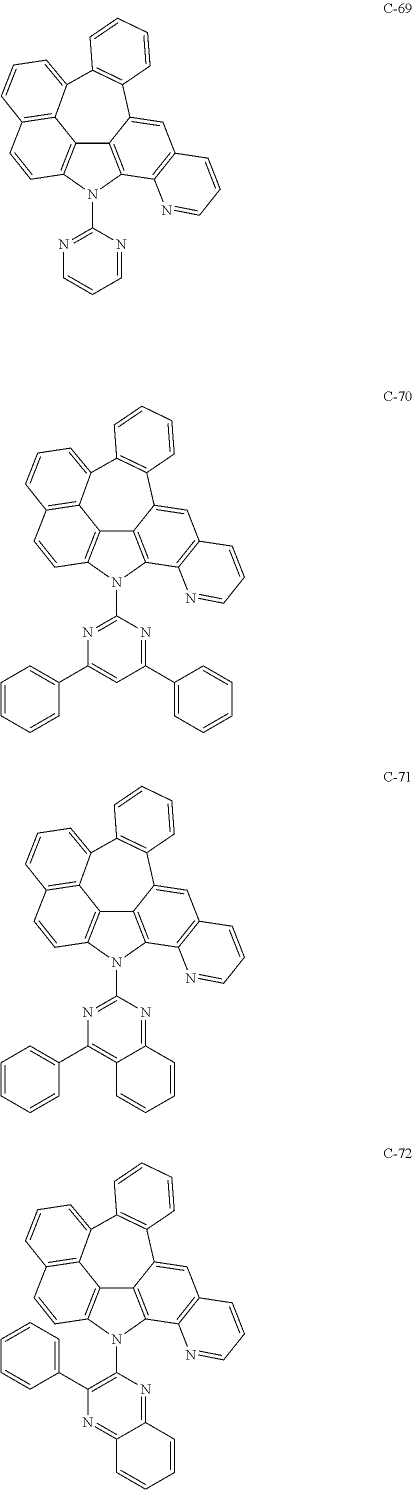 [SMILES: c1cnc(-n2c3ccc4cccc5c4c3c3c(cc4cccnc4c32)-c2ccccc2-5)nc1 ; c1ccc(-c2cc(-c3ccccc3)nc(-n3c4ccc5cccc6c5c4c4c(cc5cccnc5c43)-c3ccccc3-6)n2)cc1 ; c1ccc(-c2nc(-n3c4ccc5cccc6c5c4c4c(cc5cccnc5c43)-c3ccccc3-6)nc3ccccc23)cc1 ; c1ccc(-c2nc3ccccc3nc2-n2c3ccc4cccc5c4c3c3c(cc4cccnc4c32)-c2ccccc2-5)cc1]

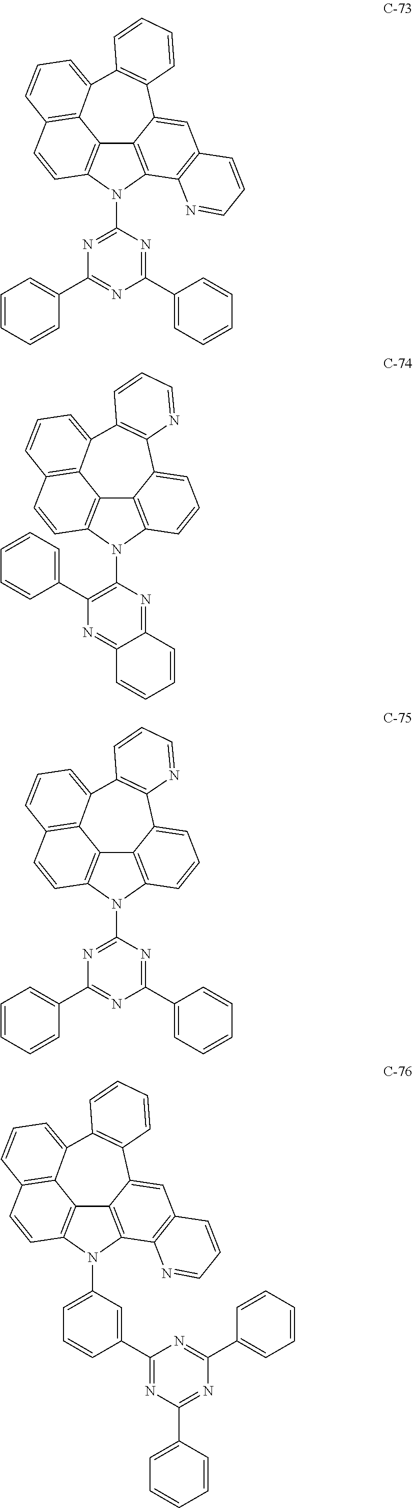

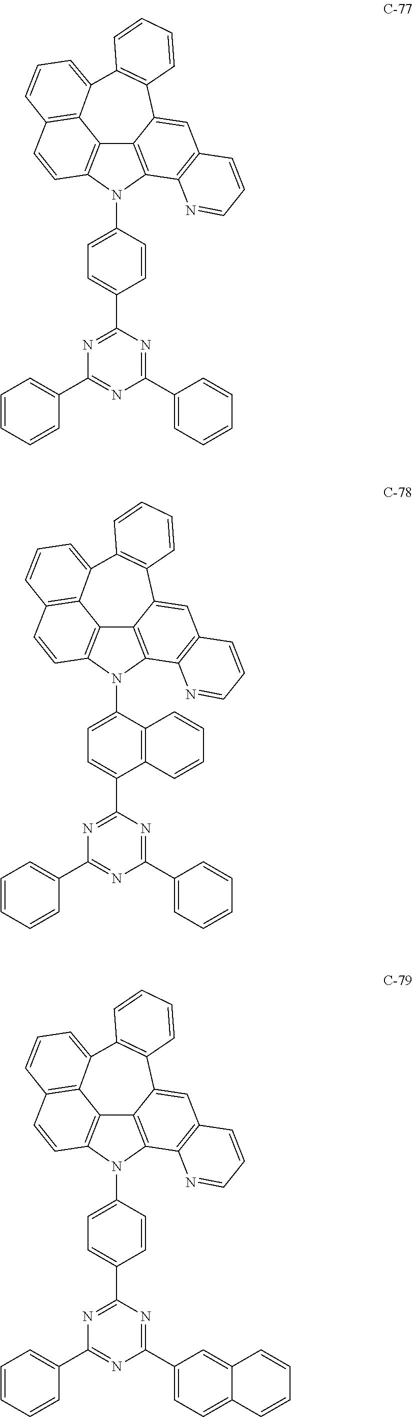 [SMILES: c1ccc(-c2nc(-c3ccccc3)nc(-c3ccc(-n4c5ccc6cccc7c6c5c5c(cc6cccnc6c54)-c4ccccc4-7)cc3)n2)cc1 ; c1ccc(-c2nc(-c3ccccc3)nc(-c3ccc(-n4c5ccc6cccc7c6c5c5c(cc6cccnc6c54)-c4ccccc4-7)c4ccccc34)n2)cc1 ; c1ccc(-c2nc(-c3ccc(-n4c5ccc6cccc7c6c5c5c(cc6cccnc6c54)-c4ccccc4-7)cc3)nc(-c3ccc4ccccc4c3)n2)cc1]

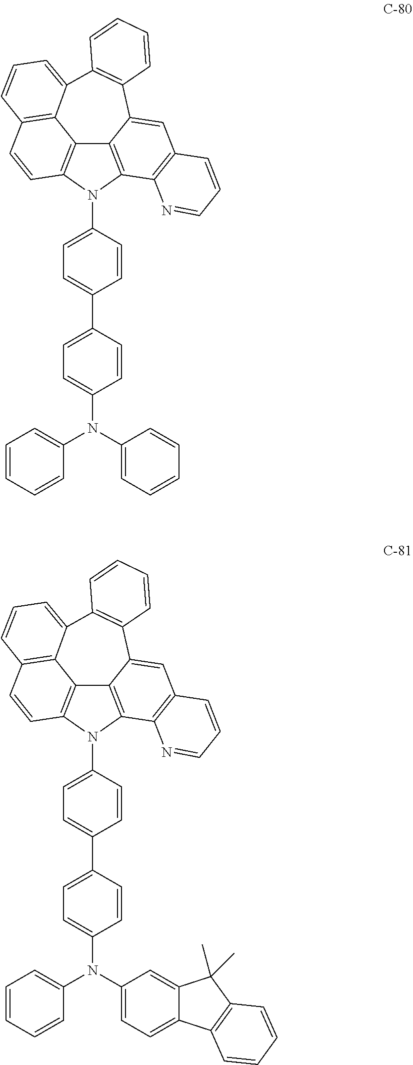 [SMILES: c1ccc(N(c2ccccc2)c2ccc(-c3ccc(-n4c5ccc6cccc7c6c5c5c(cc6cccnc6c54)-c4ccccc4-7)cc3)cc2)cc1 ; CC1(C)c2ccccc2-c2ccc(N(c3ccccc3)c3ccc(-c4ccc(-n5c6ccc7cccc8c7c6c6c(cc7cccnc7c65)-c5ccccc5-8)cc4)cc3)cc21]

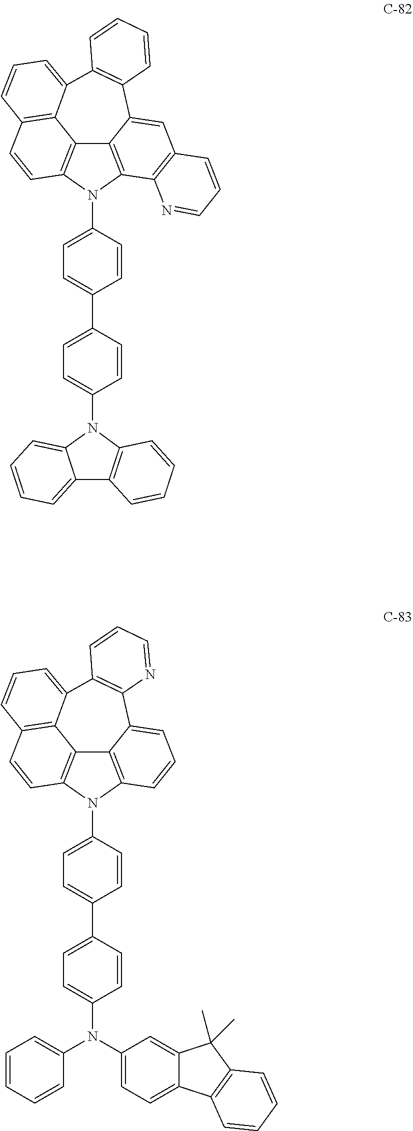 [SMILES: c1ccc2c(c1)-c1cccc3ccc4c(c13)c1c-2cc2cccnc2c1n4-c1ccc(-c2ccc(-n3c4ccccc4c4ccccc43)cc2)cc1 ; CC1(C)c2ccccc2-c2ccc(N(c3ccccc3)c3ccc(-c4ccc(-n5c6cccc7c6c6c8c(cccc8ccc65)-c5cccnc5-7)cc4)cc3)cc21]

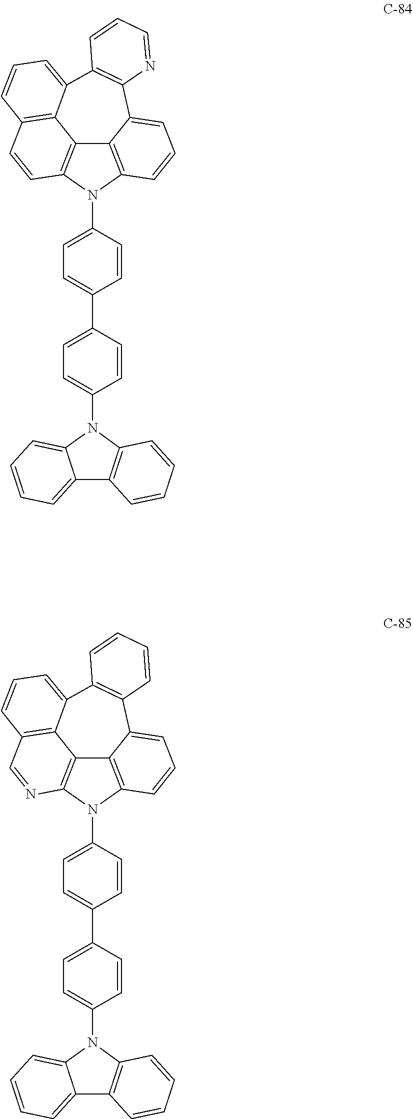 [SMILES: c1cnc2c(c1)-c1cccc3ccc4c(c13)c1c-2cccc1n4-c1ccc(-c2ccc(-n3c4ccccc4c4ccccc43)cc2)cc1 ; c1ccc2c(c1)-c1cccc3cnc4c(c13)c1c-2cccc1n4-c1ccc(-c2ccc(-n3c4ccccc4c4ccccc43)cc2)cc1]

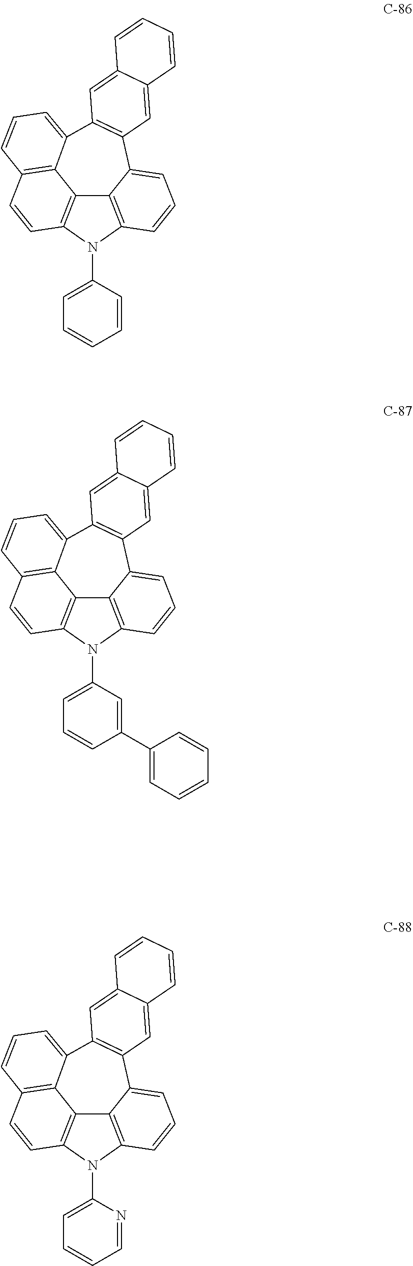 [SMILES: c1ccc(-n2c3cccc4c3c3c5c(cccc5ccc32)-c2cc3ccccc3cc2-4)cc1 ; c1ccc(-c2cccc(-n3c4cccc5c4c4c6c(cccc6ccc43)-c3cc4ccccc4cc3-5)c2)cc1 ; c1ccc(-n2c3cccc4c3c3c5c(cccc5ccc32)-c2cc3ccccc3cc2-4)nc1]

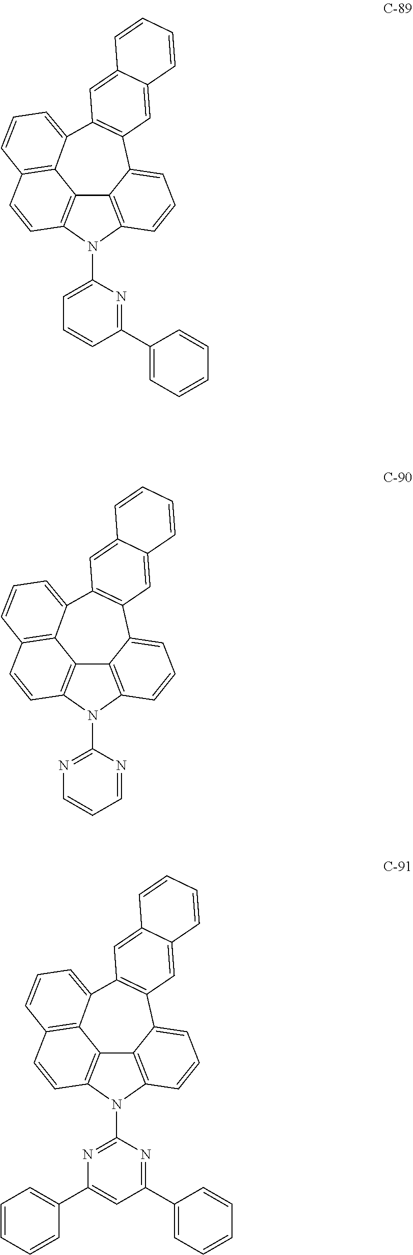 [SMILES: c1ccc(-c2cccc(-n3c4cccc5c4c4c6c(cccc6ccc43)-c3cc4ccccc4cc3-5)n2)cc1 ; c1cnc(-n2c3cccc4c3c3c5c(cccc5ccc32)-c2cc3ccccc3cc2-4)nc1 ; c1ccc(-c2cc(-c3ccccc3)nc(-n3c4cccc5c4c4c6c(cccc6ccc43)-c3cc4ccccc4cc3-5)n2)cc1]

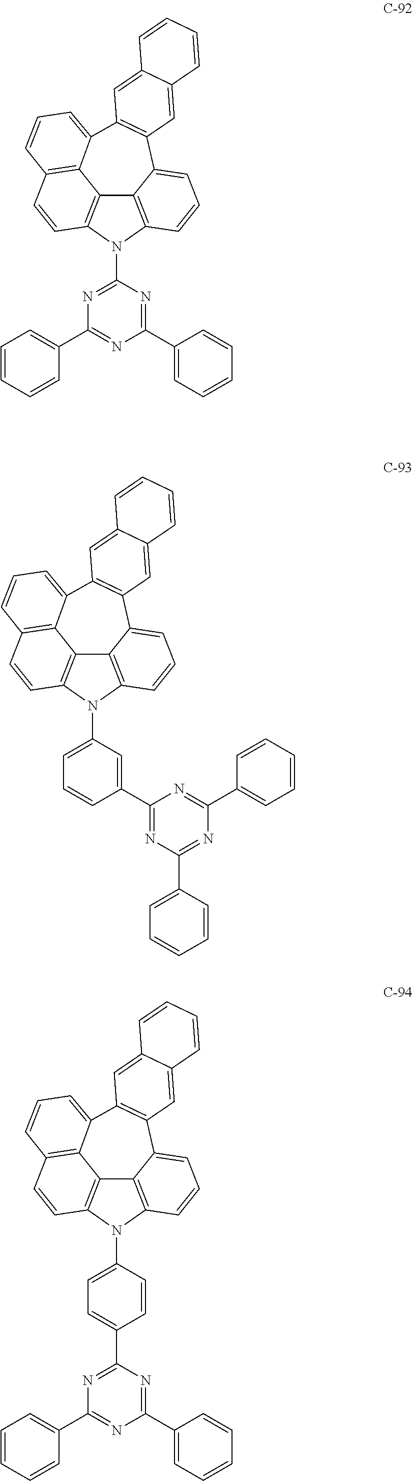 [SMILES: c1ccc(-c2nc(-c3ccccc3)nc(-n3c4cccc5c4c4c6c(cccc6ccc43)-c3cc4ccccc4cc3-5)n2)cc1 ; c1ccc(-c2nc(-c3ccccc3)nc(-c3cccc(-n4c5cccc6c5c5c7c(cccc7ccc54)-c4cc5ccccc5cc4-6)c3)n2)cc1 ; c1ccc(-c2nc(-c3ccccc3)nc(-c3ccc(-n4c5cccc6c5c5c7c(cccc7ccc54)-c4cc5ccccc5cc4-6)cc3)n2)cc1]

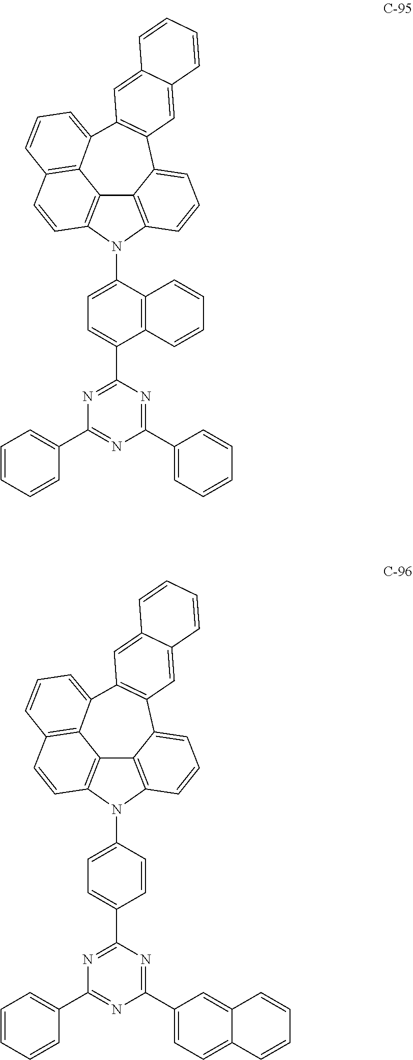 [SMILES: c1ccc(-c2nc(-c3ccccc3)nc(-c3ccc(-n4c5cccc6c5c5c7c(cccc7ccc54)-c4cc5ccccc5cc4-6)c4ccccc34)n2)cc1 ; c1ccc(-c2nc(-c3ccc(-n4c5cccc6c5c5c7c(cccc7ccc54)-c4cc5ccccc5cc4-6)cc3)nc(-c3ccc4ccccc4c3)n2)cc1]

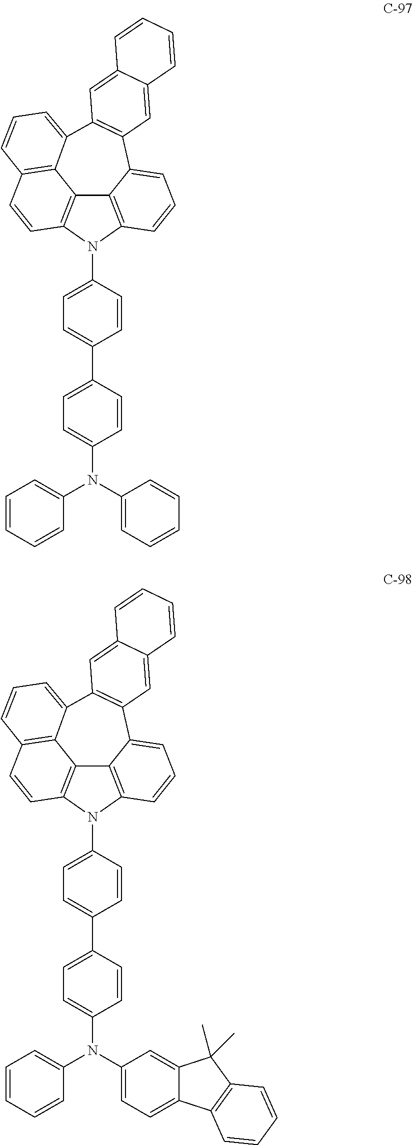

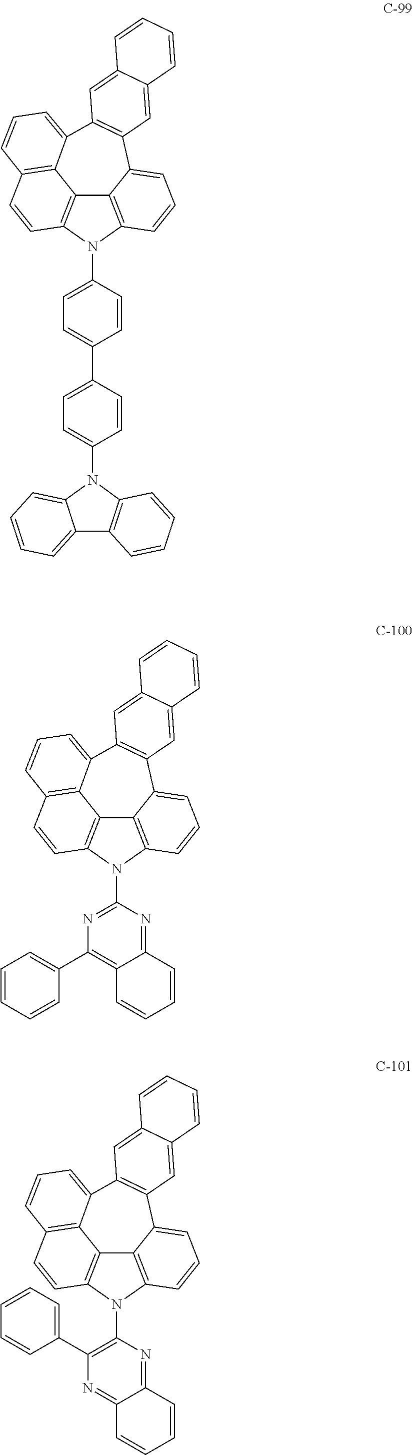 [SMILES: c1ccc2cc3c(cc2c1)-c1cccc2ccc4c(c12)c1c-3cccc1n4-c1ccc(-c2ccc(-n3c4ccccc4c4ccccc43)cc2)cc1 ; c1ccc(-c2nc(-n3c4cccc5c4c4c6c(cccc6ccc43)-c3cc4ccccc4cc3-5)nc3ccccc23)cc1 ; c1ccc(-c2nc3ccccc3nc2-n2c3cccc4c3c3c5c(cccc5ccc32)-c2cc3ccccc3cc2-4)cc1]

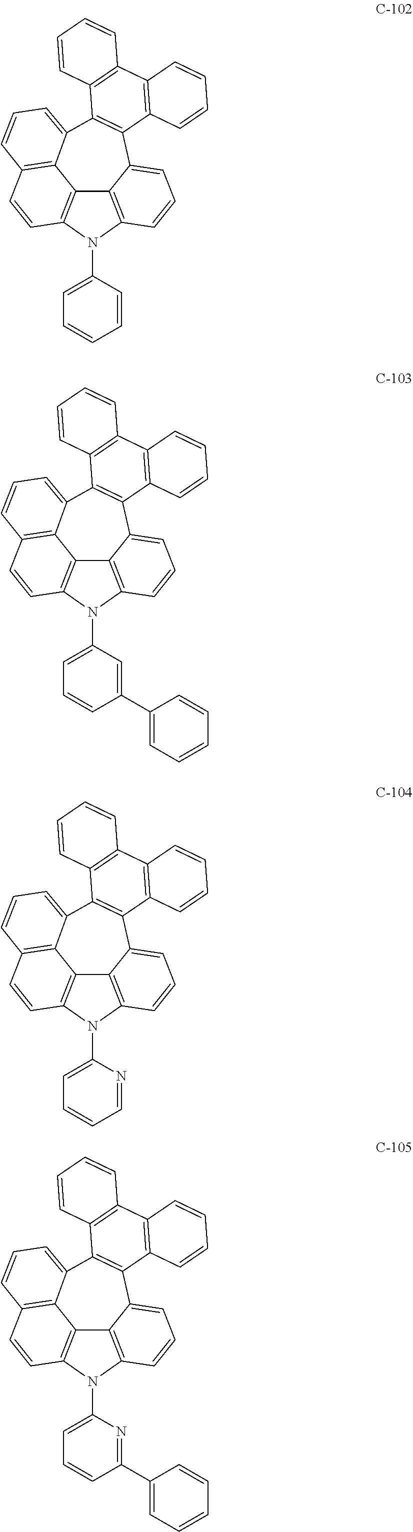

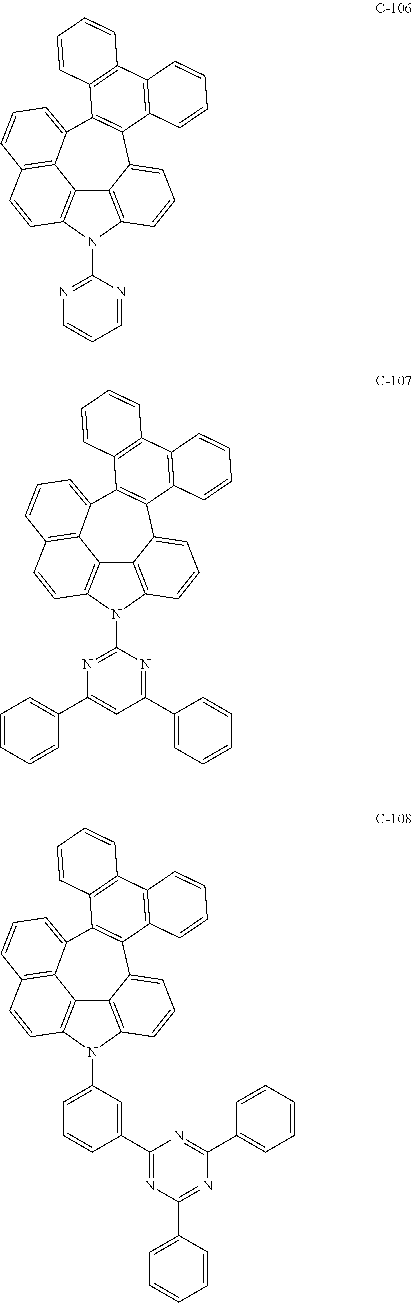 [SMILES: c1cnc(-n2c3cccc4c3c3c5c(cccc5ccc32)-c2c-4c3ccccc3c3ccccc23)nc1 ; c1ccc(-c2cc(-c3ccccc3)nc(-n3c4cccc5c4c4c6c(cccc6ccc43)-c3c-5c4ccccc4c4ccccc34)n2)cc1 ; c1ccc(-c2nc(-c3ccccc3)nc(-c3cccc(-n4c5cccc6c5c5c7c(cccc7ccc54)-c4c-6c5ccccc5c5ccccc45)c3)n2)cc1]

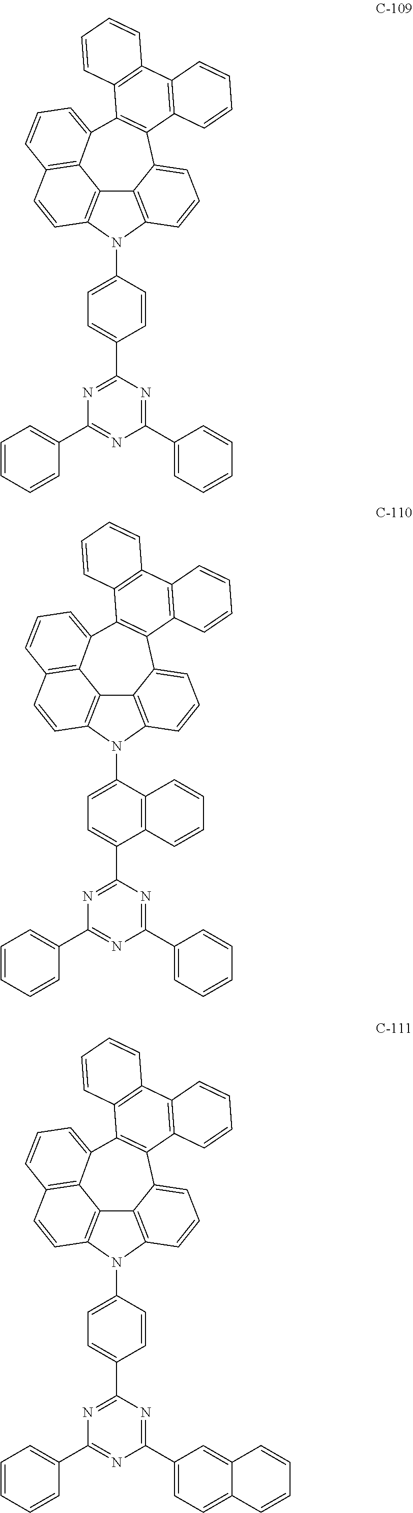 [SMILES: c1ccc(-c2nc(-c3ccccc3)nc(-c3ccc(-n4c5cccc6c5c5c7c(cccc7ccc54)-c4c-6c5ccccc5c5ccccc45)cc3)n2)cc1 ; c1ccc(-c2nc(-c3ccccc3)nc(-c3ccc(-n4c5cccc6c5c5c7c(cccc7ccc54)-c4c-6c5ccccc5c5ccccc45)c4ccccc34)n2)cc1 ; c1ccc(-c2nc(-c3ccc(-n4c5cccc6c5c5c7c(cccc7ccc54)-c4c-6c5ccccc5c5ccccc45)cc3)nc(-c3ccc4ccccc4c3)n2)cc1]

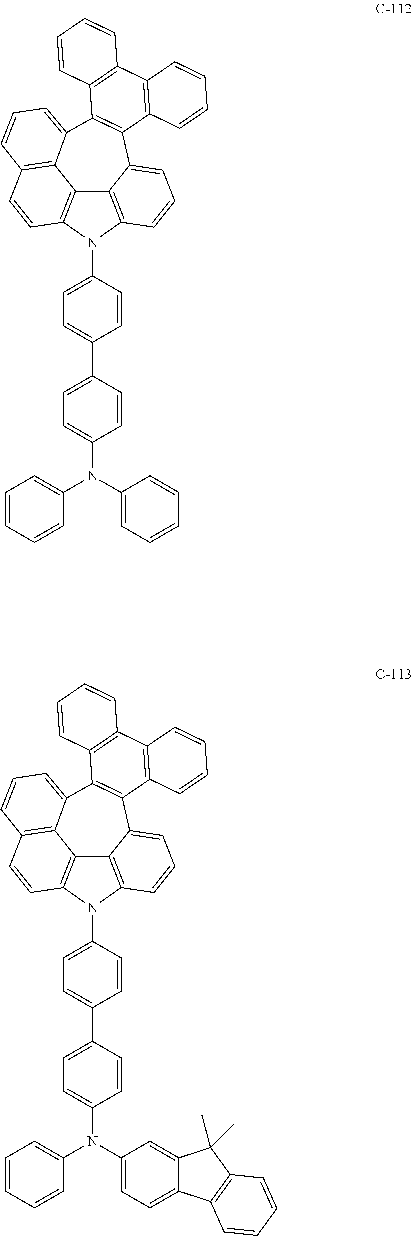 [SMILES: c1ccc(N(c2ccccc2)c2ccc(-c3ccc(-n4c5cccc6c5c5c7c(cccc7ccc54)-c4c-6c5ccccc5c5ccccc45)cc3)cc2)cc1 ; CC1(C)c2ccccc2-c2ccc(N(c3ccccc3)c3ccc(-c4ccc(-n5c6cccc7c6c6c8c(cccc8ccc65)-c5c-7c6ccccc6c6ccccc56)cc4)cc3)cc21]

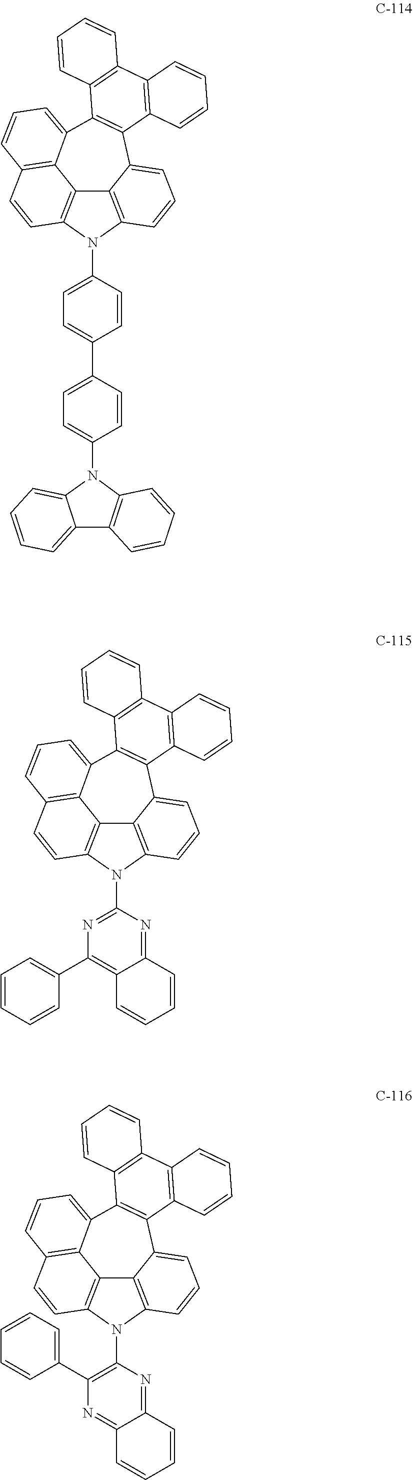 [SMILES: c1cc2c3c(c1)ccc1c3c3c(cccc3n1-c1ccc(-c3ccc(-n4c5ccccc5c5ccccc54)cc3)cc1)-c1c-2c2ccccc2c2ccccc12 ; c1ccc(-c2nc(-n3c4cccc5c4c4c6c(cccc6ccc43)-c3c-5c4ccccc4c4ccccc34)nc3ccccc23)cc1 ; c1ccc(-c2nc3ccccc3nc2-n2c3cccc4c3c3c5c(cccc5ccc32)-c2c-4c3ccccc3c3ccccc23)cc1]

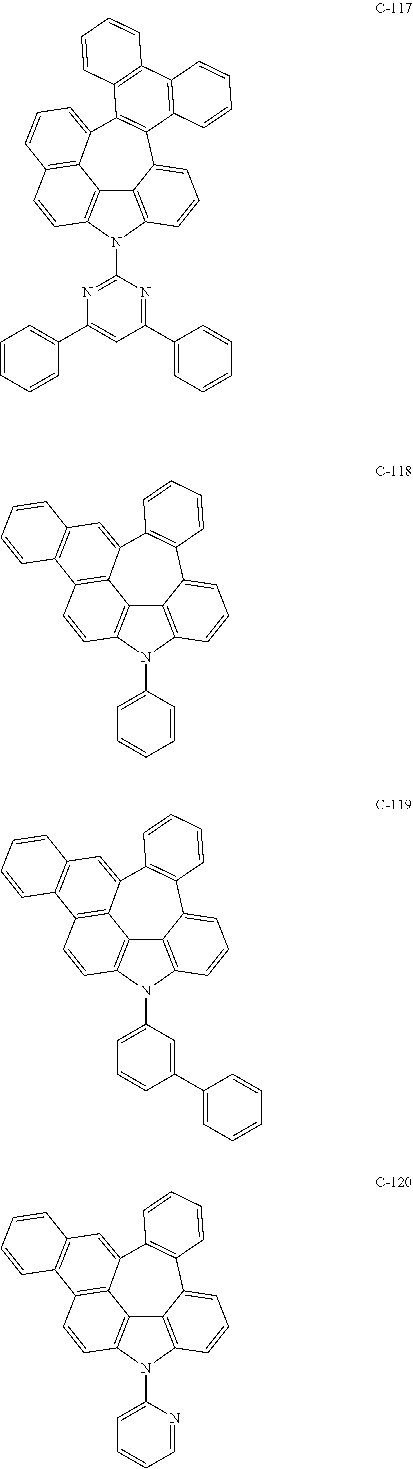 [SMILES: c1ccc(-c2cc(-c3ccccc3)nc(-n3c4cccc5c4c4c6c(cccc6ccc43)-c3c-5c4ccccc4c4ccccc34)n2)cc1 ; c1ccc(-n2c3cccc4c3c3c5c(cc6ccccc6c5ccc32)-c2ccccc2-4)cc1 ; c1ccc(-c2cccc(-n3c4cccc5c4c4c6c(cc7ccccc7c6ccc43)-c3ccccc3-5)c2)cc1 ; c1ccc(-n2c3cccc4c3c3c5c(cc6ccccc6c5ccc32)-c2ccccc2-4)nc1]

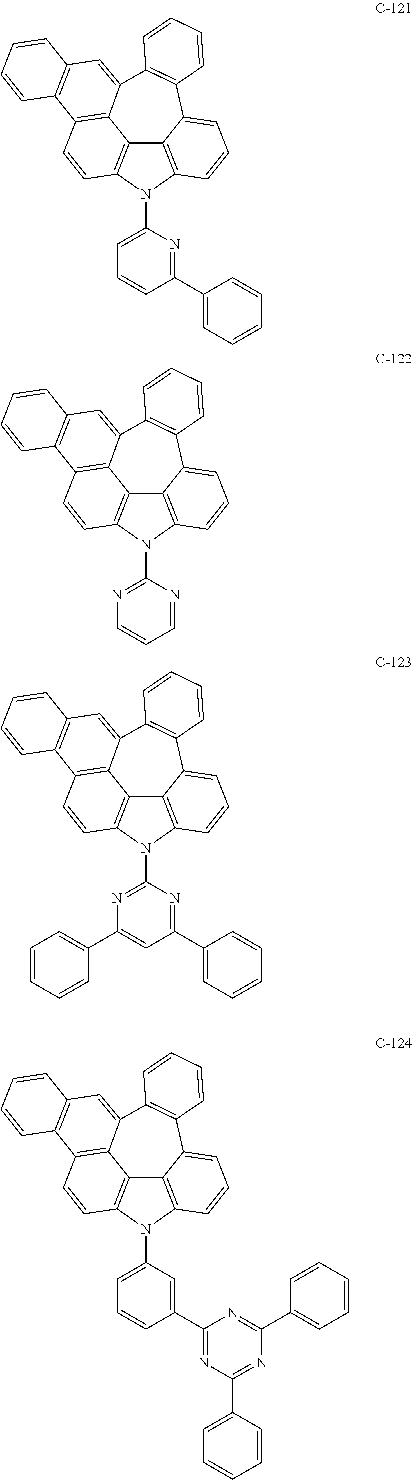

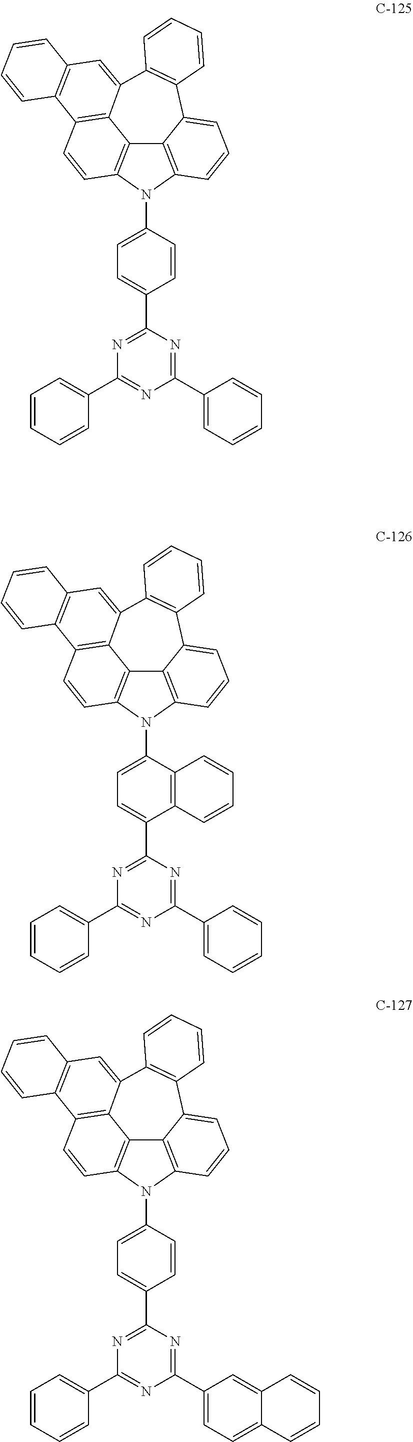 [SMILES: c1ccc(-c2nc(-c3ccccc3)nc(-c3ccc(-n4c5cccc6c5c5c7c(cc8ccccc8c7ccc54)-c4ccccc4-6)cc3)n2)cc1 ; c1ccc(-c2nc(-c3ccccc3)nc(-c3ccc(-n4c5cccc6c5c5c7c(cc8ccccc8c7ccc54)-c4ccccc4-6)c4ccccc34)n2)cc1 ; c1ccc(-c2nc(-c3ccc(-n4c5cccc6c5c5c7c(cc8ccccc8c7ccc54)-c4ccccc4-6)cc3)nc(-c3ccc4ccccc4c3)n2)cc1]

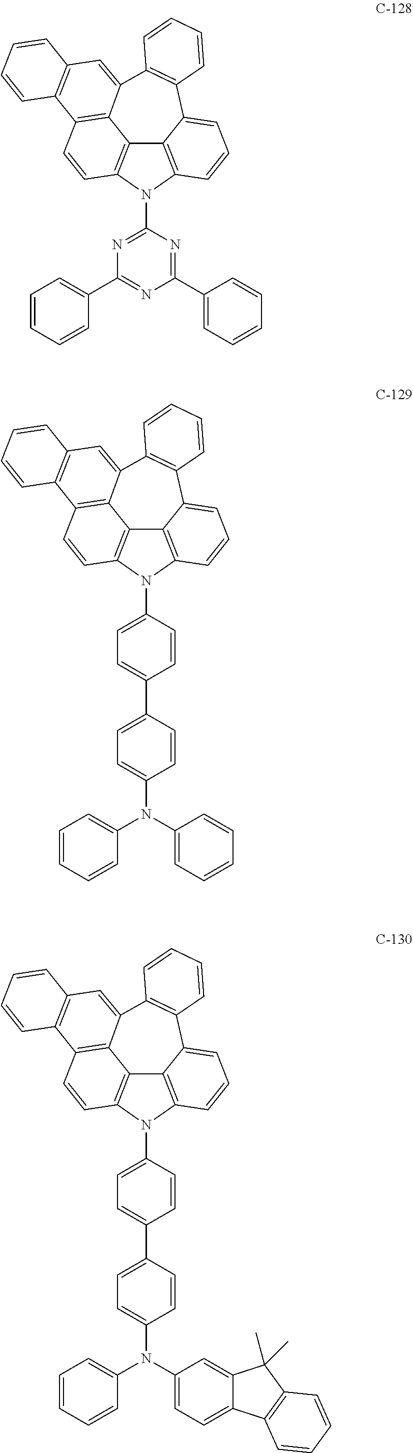 [SMILES: c1ccc(-c2nc(-c3ccccc3)nc(-n3c4cccc5c4c4c6c(cc7ccccc7c6ccc43)-c3ccccc3-5)n2)cc1 ; c1ccc(N(c2ccccc2)c2ccc(-c3ccc(-n4c5cccc6c5c5c7c(cc8ccccc8c7ccc54)-c4ccccc4-6)cc3)cc2)cc1 ; CC1(C)c2ccccc2-c2ccc(N(c3ccccc3)c3ccc(-c4ccc(-n5c6cccc7c6c6c8c(cc9ccccc9c8ccc65)-c5ccccc5-7)cc4)cc3)cc21]

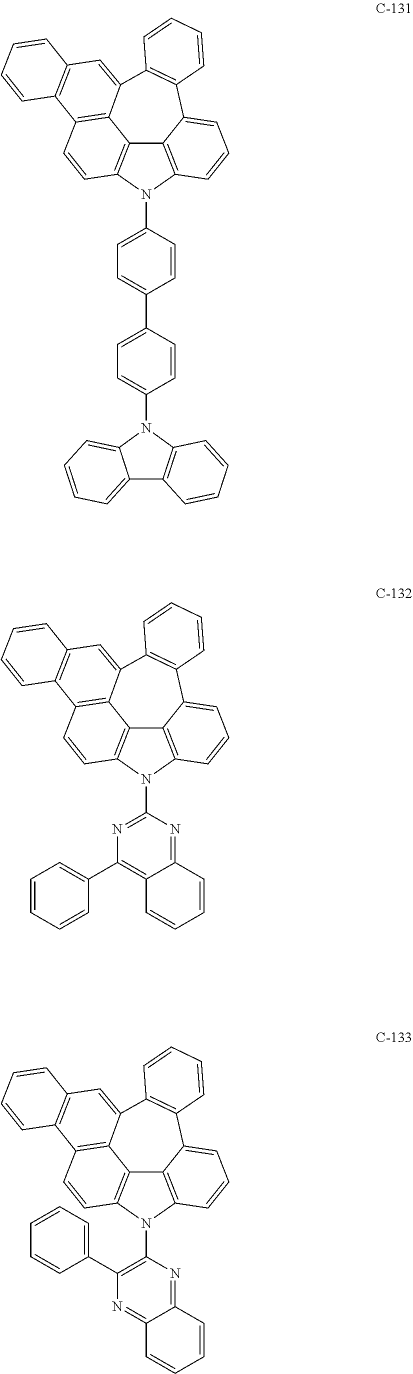 [SMILES: c1ccc2c(c1)-c1cc3ccccc3c3ccc4c(c13)c1c-2cccc1n4-c1ccc(-c2ccc(-n3c4ccccc4c4ccccc43)cc2)cc1 ; c1ccc(-c2nc(-n3c4cccc5c4c4c6c(cc7ccccc7c6ccc43)-c3ccccc3-5)nc3ccccc23)cc1 ; c1ccc(-c2nc3ccccc3nc2-n2c3cccc4c3c3c5c(cc6ccccc6c5ccc32)-c2ccccc2-4)cc1]

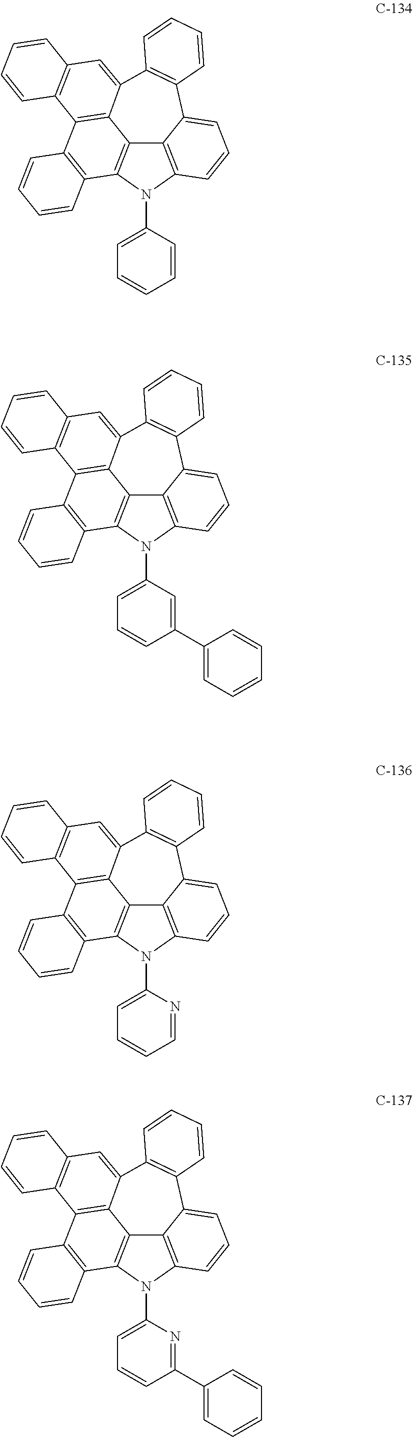 [SMILES: c1ccc(-n2c3cccc4c3c3c5c(cc6ccccc6c5c5ccccc5c32)-c2ccccc2-4)cc1 ; c1ccc(-c2cccc(-n3c4cccc5c4c4c6c(cc7ccccc7c6c6ccccc6c43)-c3ccccc3-5)c2)cc1 ; c1ccc(-n2c3cccc4c3c3c5c(cc6ccccc6c5c5ccccc5c32)-c2ccccc2-4)nc1 ; c1ccc(-c2cccc(-n3c4cccc5c4c4c6c(cc7ccccc7c6c6ccccc6c43)-c3ccccc3-5)n2)cc1]

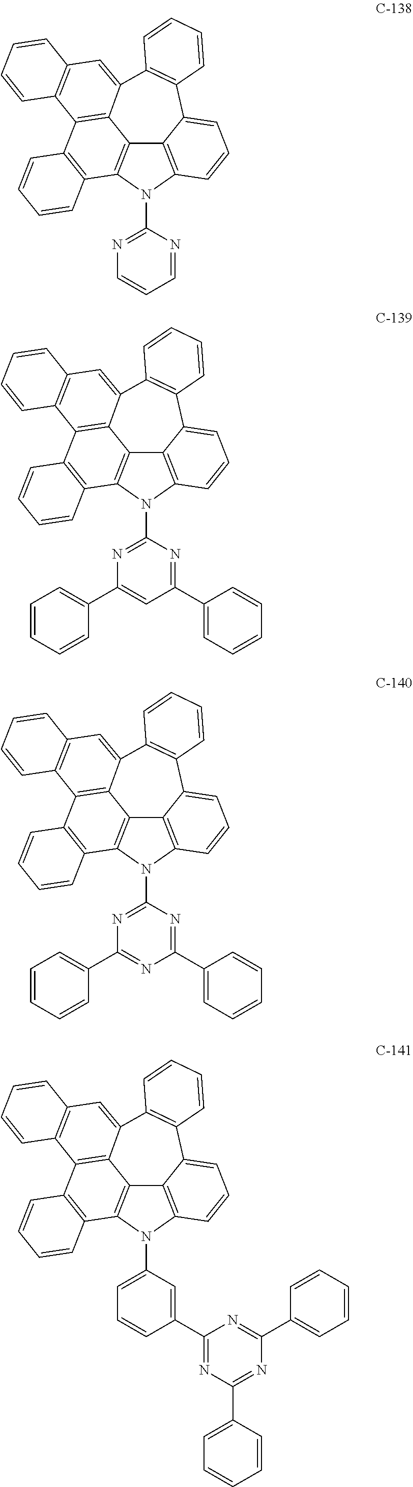

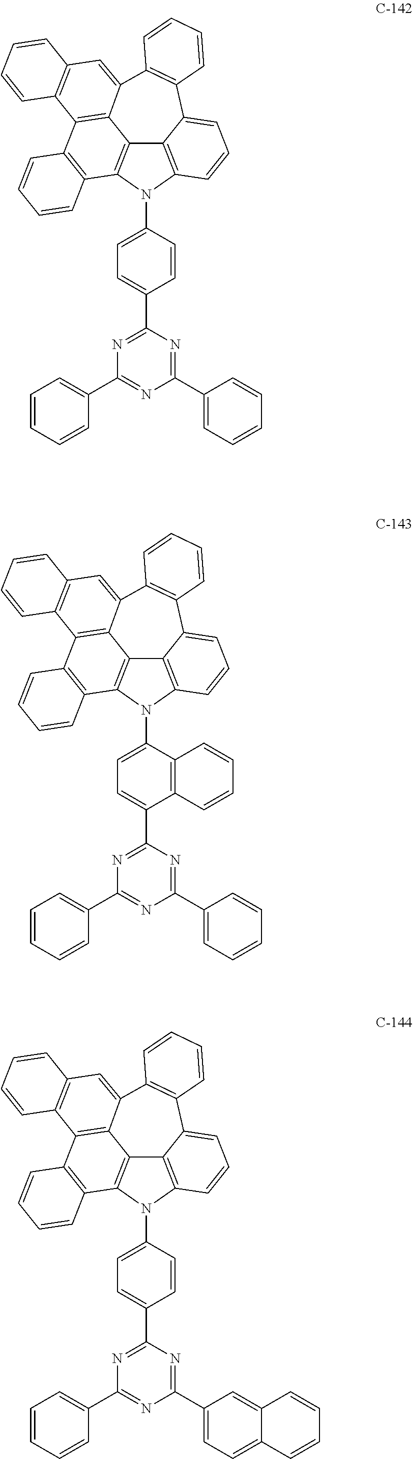 [SMILES: c1ccc(-c2nc(-c3ccccc3)nc(-c3ccc(-n4c5cccc6c5c5c7c(cc8ccccc8c7c7ccccc7c54)-c4ccccc4-6)cc3)n2)cc1 ; c1ccc(-c2nc(-c3ccccc3)nc(-c3ccc(-n4c5cccc6c5c5c7c(cc8ccccc8c7c7ccccc7c54)-c4ccccc4-6)c4ccccc34)n2)cc1 ; c1ccc(-c2nc(-c3ccc(-n4c5cccc6c5c5c7c(cc8ccccc8c7c7ccccc7c54)-c4ccccc4-6)cc3)nc(-c3ccc4ccccc4c3)n2)cc1]

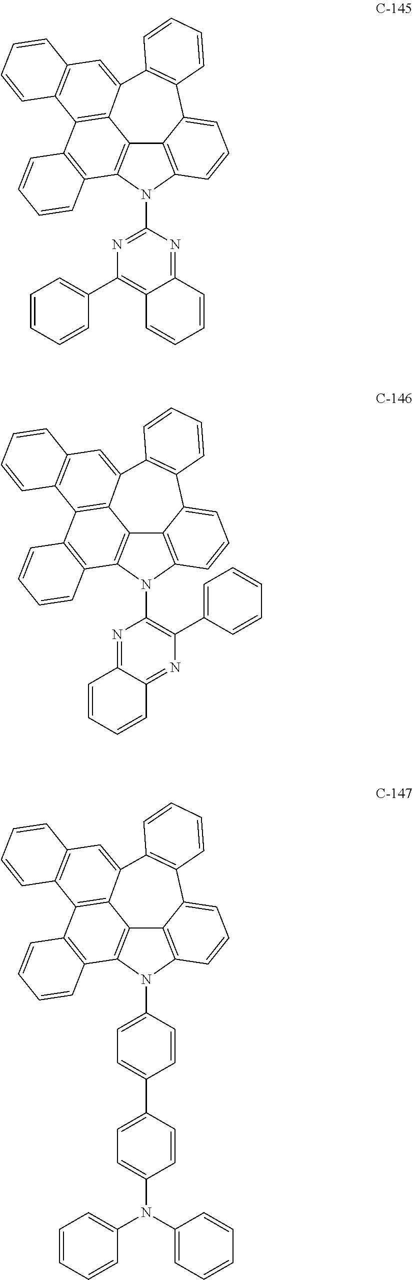 [SMILES: c1ccc(-c2nc(-n3c4cccc5c4c4c6c(cc7ccccc7c6c6ccccc6c43)-c3ccccc3-5)nc3ccccc23)cc1 ; c1ccc(-c2nc3ccccc3nc2-n2c3cccc4c3c3c5c(cc6ccccc6c5c5ccccc5c32)-c2ccccc2-4)cc1 ; c1ccc(N(c2ccccc2)c2ccc(-c3ccc(-n4c5cccc6c5c5c7c(cc8ccccc8c7c7ccccc7c54)-c4ccccc4-6)cc3)cc2)cc1]

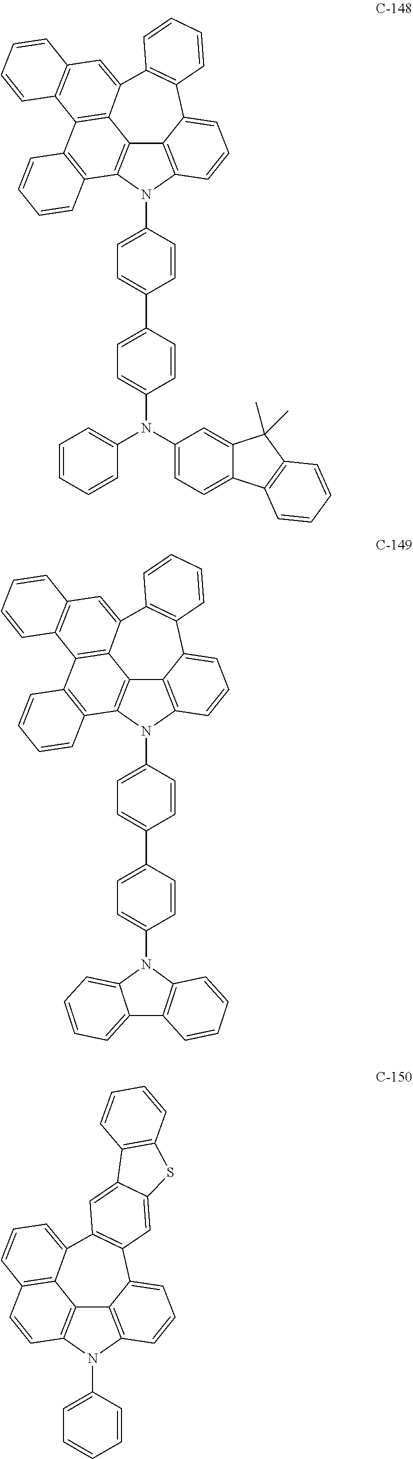 [SMILES: CC1(C)c2ccccc2-c2ccc(N(c3ccccc3)c3ccc(-c4ccc(-n5c6cccc7c6c6c8c(cc9ccccc9c8c8ccccc8c65)-c5ccccc5-7)cc4)cc3)cc21 ; c1ccc2c(c1)-c1cc3ccccc3c3c4ccccc4c4c(c13)c1c-2cccc1n4-c1ccc(-c2ccc(-n3c4ccccc4c4ccccc43)cc2)cc1 ; c1ccc(-n2c3cccc4c3c3c5c(cccc5ccc32)-c2cc3c(cc2-4)sc2ccccc23)cc1]

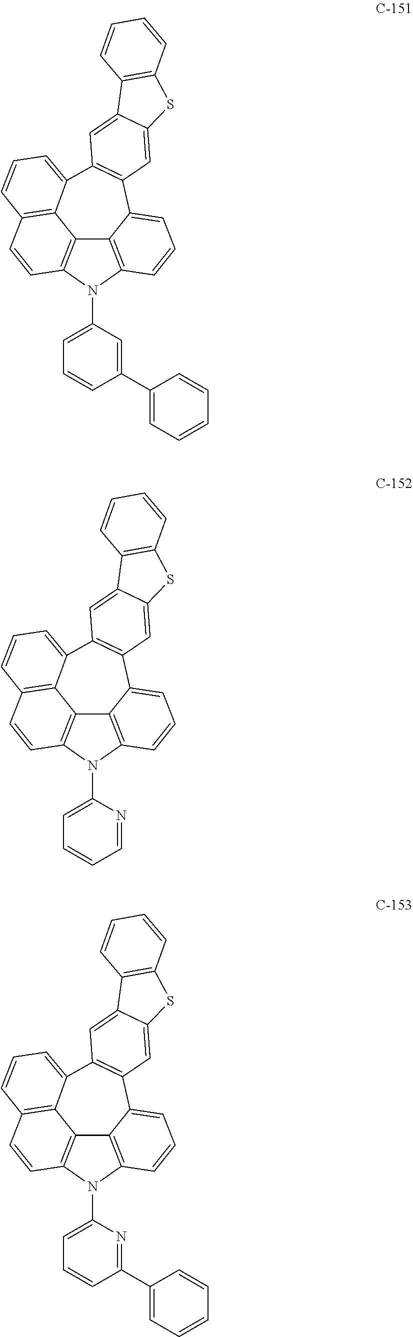 [SMILES: c1ccc(-c2cccc(-n3c4cccc5c4c4c6c(cccc6ccc43)-c3cc4c(cc3-5)sc3ccccc34)c2)cc1 ; c1ccc(-n2c3cccc4c3c3c5c(cccc5ccc32)-c2cc3c(cc2-4)sc2ccccc23)nc1 ; c1ccc(-c2cccc(-n3c4cccc5c4c4c6c(cccc6ccc43)-c3cc4c(cc3-5)sc3ccccc34)n2)cc1]

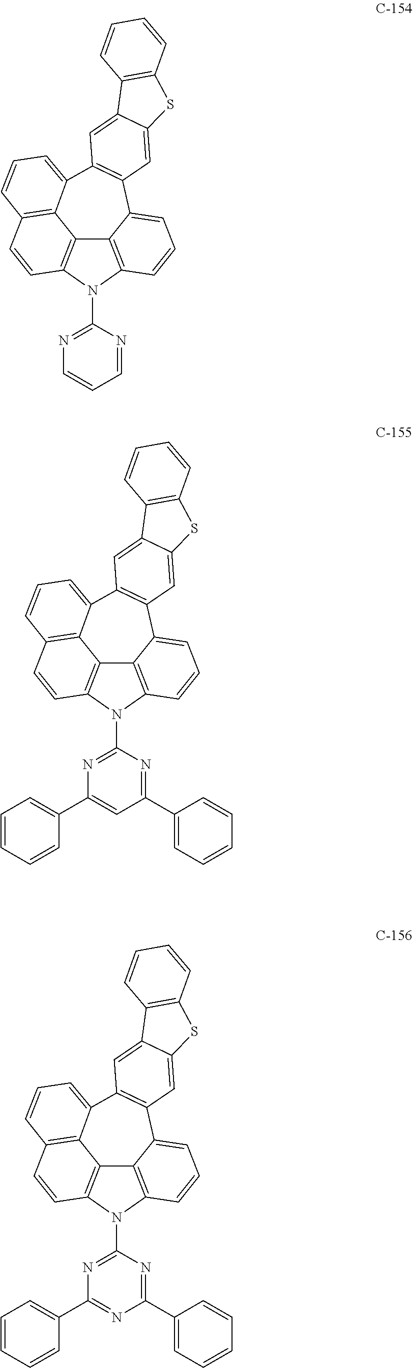 [SMILES: c1cnc(-n2c3cccc4c3c3c5c(cccc5ccc32)-c2cc3c(cc2-4)sc2ccccc23)nc1 ; c1ccc(-c2cc(-c3ccccc3)nc(-n3c4cccc5c4c4c6c(cccc6ccc43)-c3cc4c(cc3-5)sc3ccccc34)n2)cc1 ; c1ccc(-c2nc(-c3ccccc3)nc(-n3c4cccc5c4c4c6c(cccc6ccc43)-c3cc4c(cc3-5)sc3ccccc34)n2)cc1]

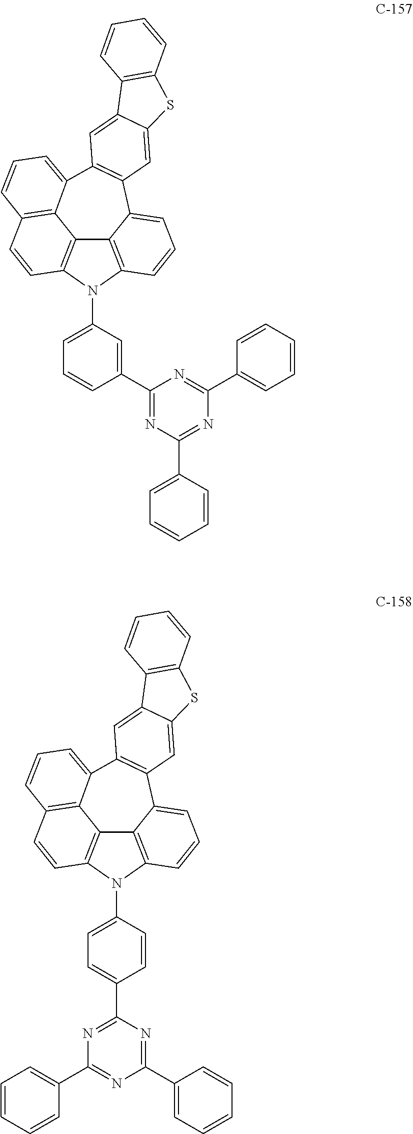 [SMILES: c1ccc(-c2nc(-c3ccccc3)nc(-c3cccc(-n4c5cccc6c5c5c7c(cccc7ccc54)-c4cc5c(cc4-6)sc4ccccc45)c3)n2)cc1 ; c1ccc(-c2nc(-c3ccccc3)nc(-c3ccc(-n4c5cccc6c5c5c7c(cccc7ccc54)-c4cc5c(cc4-6)sc4ccccc45)cc3)n2)cc1]

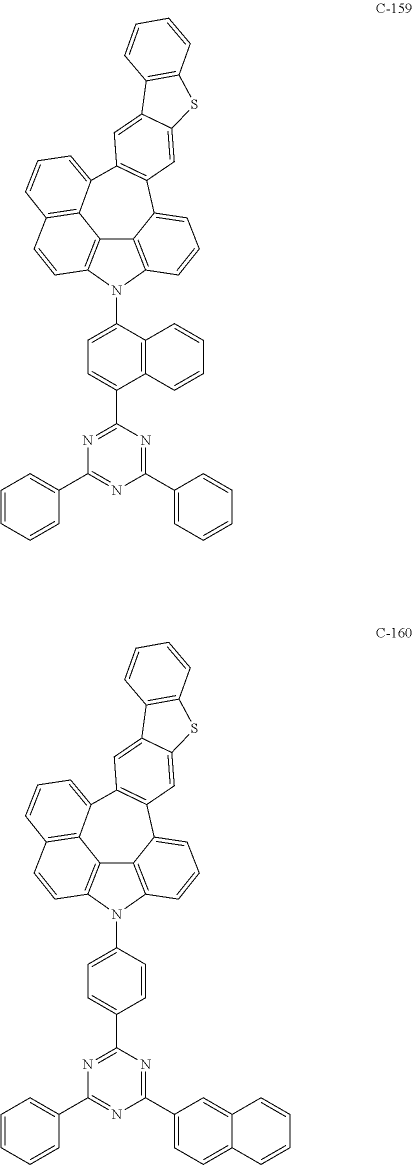 [SMILES: c1ccc(-c2nc(-c3ccccc3)nc(-c3ccc(-n4c5cccc6c5c5c7c(cccc7ccc54)-c4cc5c(cc4-6)sc4ccccc45)c4ccccc34)n2)cc1 ; c1ccc(-c2nc(-c3ccc(-n4c5cccc6c5c5c7c(cccc7ccc54)-c4cc5c(cc4-6)sc4ccccc45)cc3)nc(-c3ccc4ccccc4c3)n2)cc1]

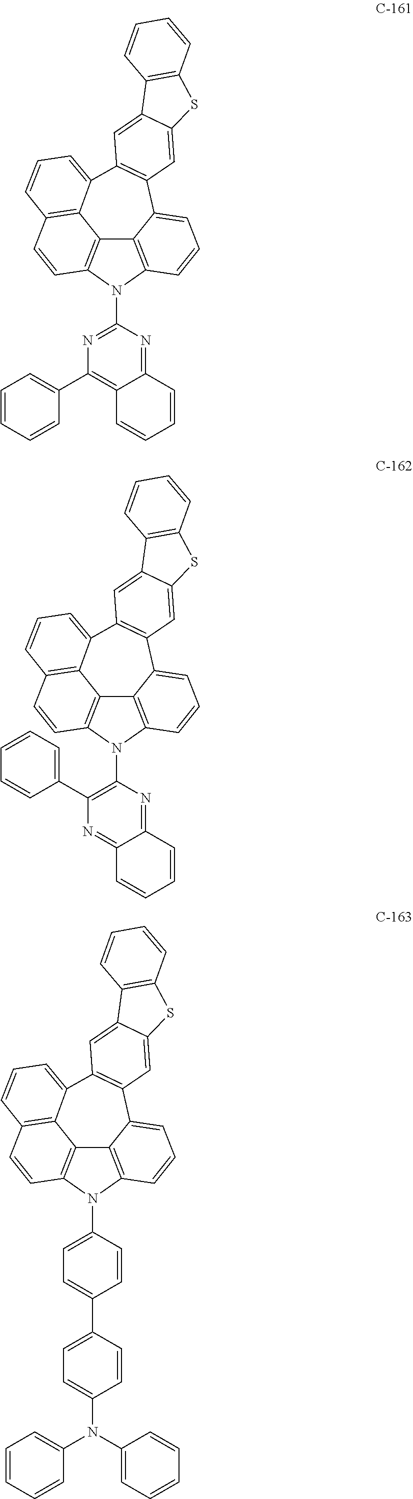

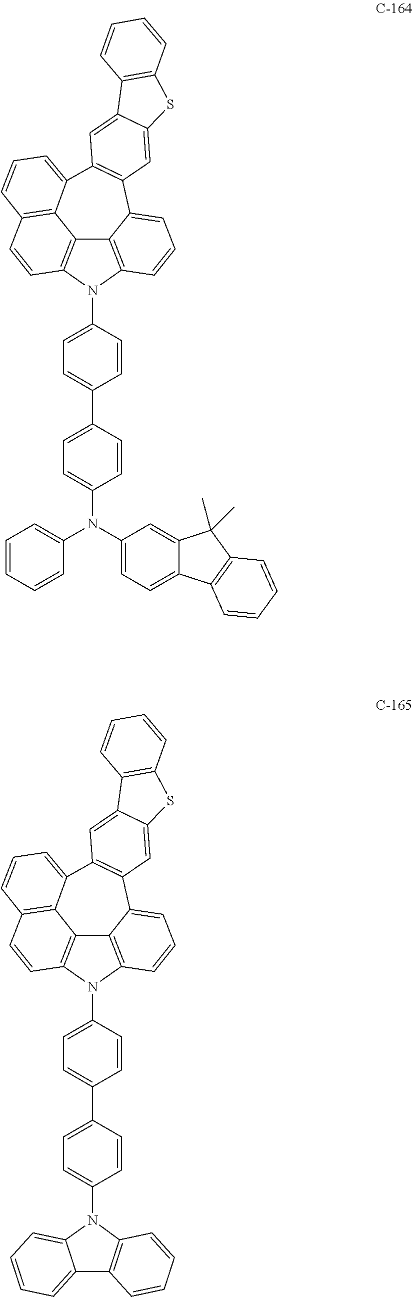 [SMILES: CC1(C)c2ccccc2-c2ccc(N(c3ccccc3)c3ccc(-c4ccc(-n5c6cccc7c6c6c8c(cccc8ccc65)-c5cc6c(cc5-7)sc5ccccc56)cc4)cc3)cc21 ; c1cc2c3c(c1)ccc1c3c3c(cccc3n1-c1ccc(-c3ccc(-n4c5ccccc5c5ccccc54)cc3)cc1)-c1cc3sc4ccccc4c3cc1-2]

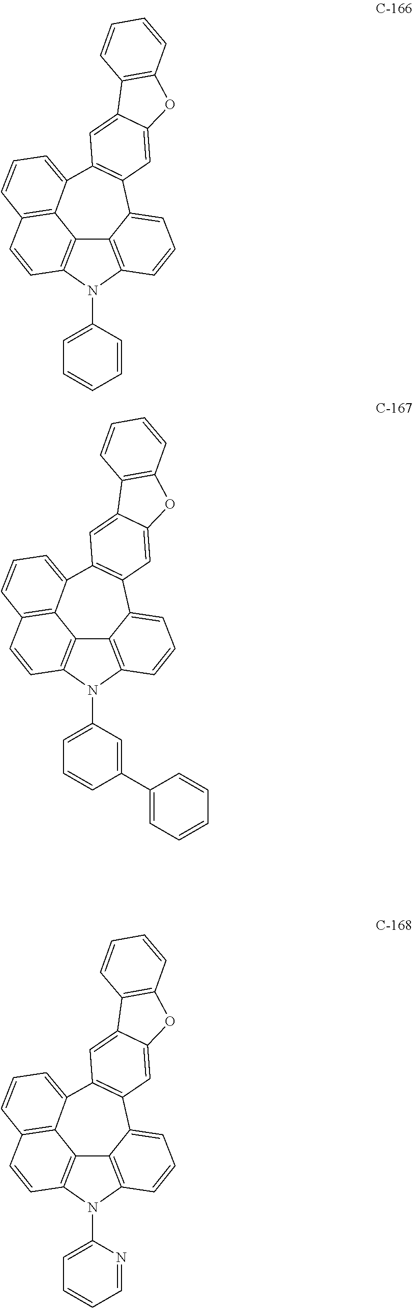

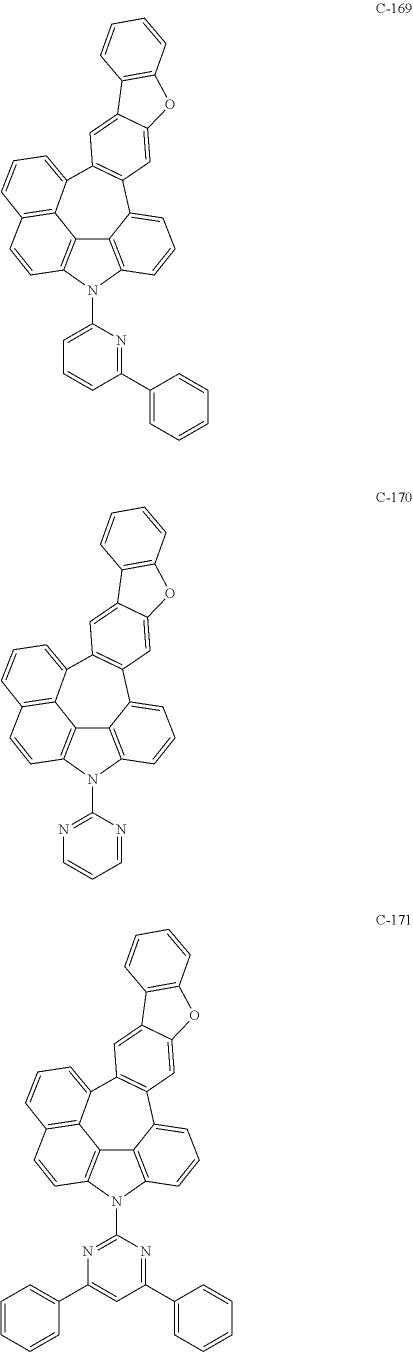 [SMILES: c1ccc(-c2cccc(-n3c4cccc5c4c4c6c(cccc6ccc43)-c3cc4c(cc3-5)oc3ccccc34)n2)cc1 ; c1cnc(-n2c3cccc4c3c3c5c(cccc5ccc32)-c2cc3c(cc2-4)oc2ccccc23)nc1 ; c1ccc(-c2cc(-c3ccccc3)nc(-n3c4cccc5c4c4c6c(cccc6ccc43)-c3cc4c(cc3-5)oc3ccccc34)n2)cc1]

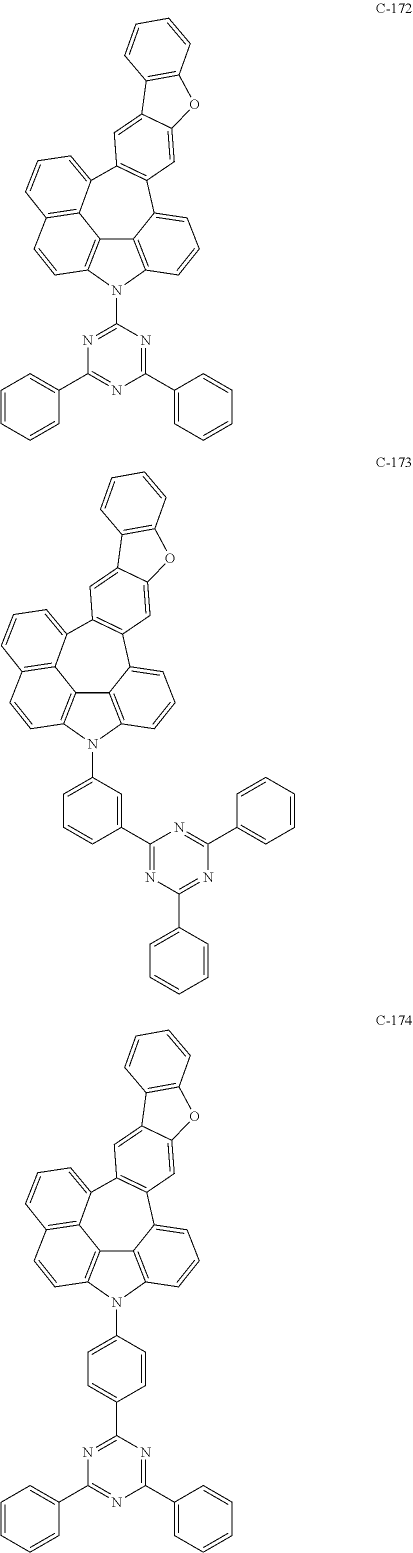

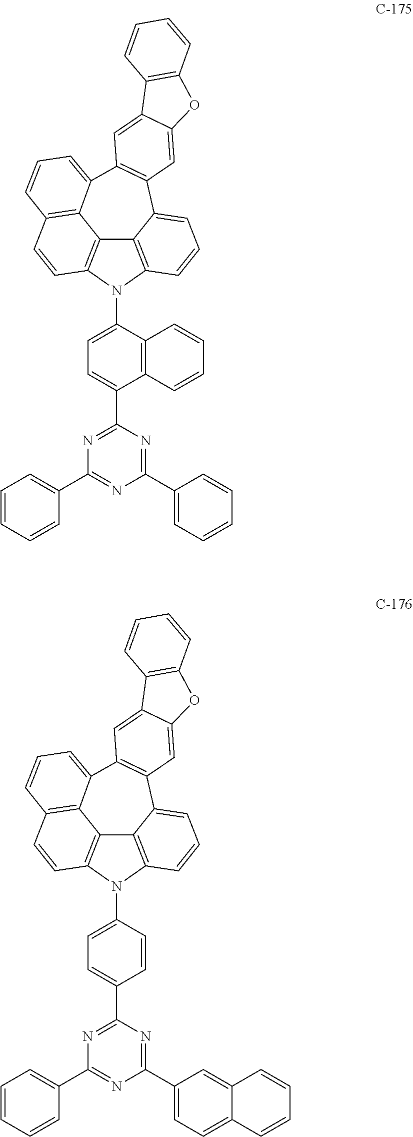 [SMILES: c1ccc(-c2nc(-c3ccccc3)nc(-c3ccc(-n4c5cccc6c5c5c7c(cccc7ccc54)-c4cc5c(cc4-6)oc4ccccc45)c4ccccc34)n2)cc1 ; c1ccc(-c2nc(-c3ccc(-n4c5cccc6c5c5c7c(cccc7ccc54)-c4cc5c(cc4-6)oc4ccccc45)cc3)nc(-c3ccc4ccccc4c3)n2)cc1]

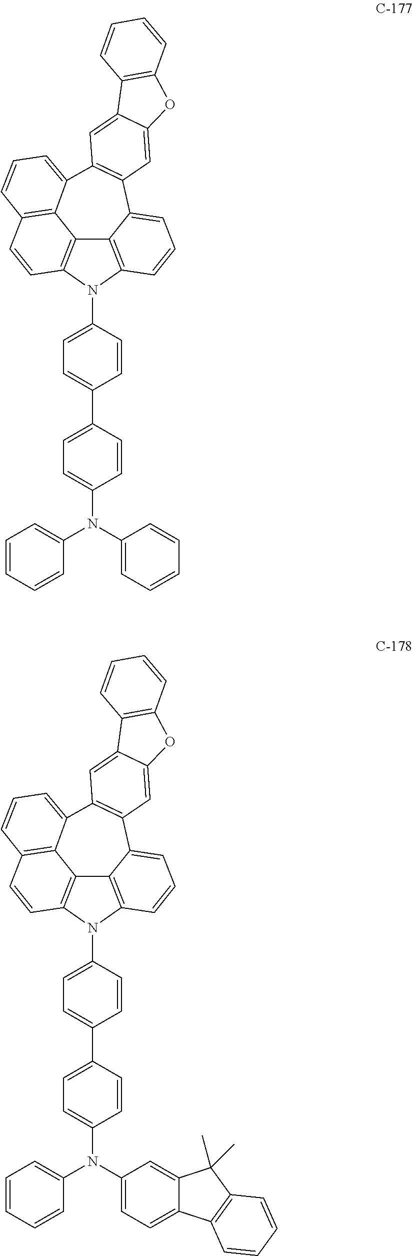 [SMILES: c1ccc(N(c2ccccc2)c2ccc(-c3ccc(-n4c5cccc6c5c5c7c(cccc7ccc54)-c4cc5c(cc4-6)oc4ccccc45)cc3)cc2)cc1 ; CC1(C)c2ccccc2-c2ccc(N(c3ccccc3)c3ccc(-c4ccc(-n5c6cccc7c6c6c8c(cccc8ccc65)-c5cc6c(cc5-7)oc5ccccc56)cc4)cc3)cc21]

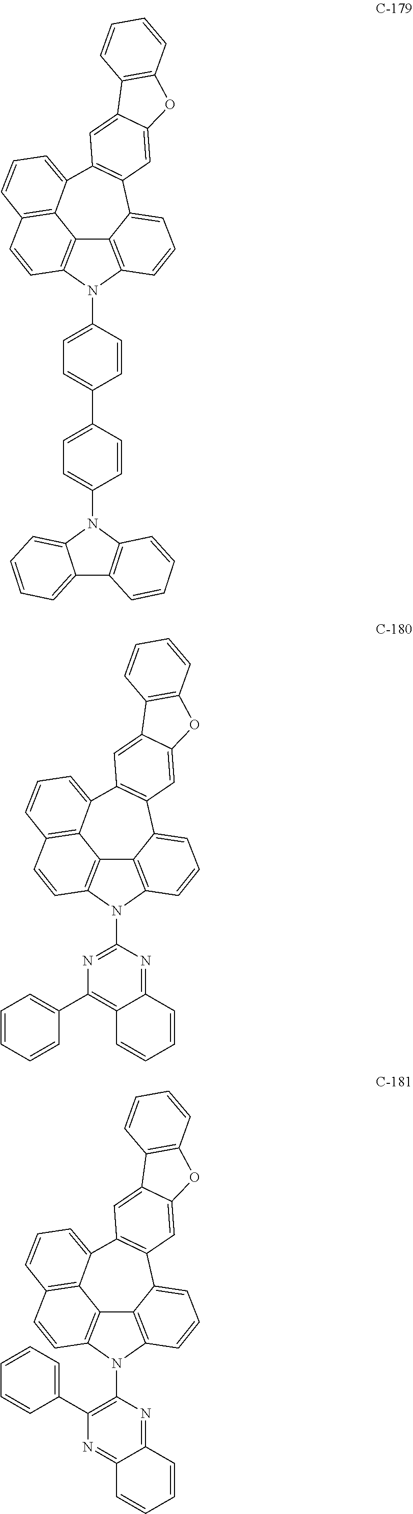

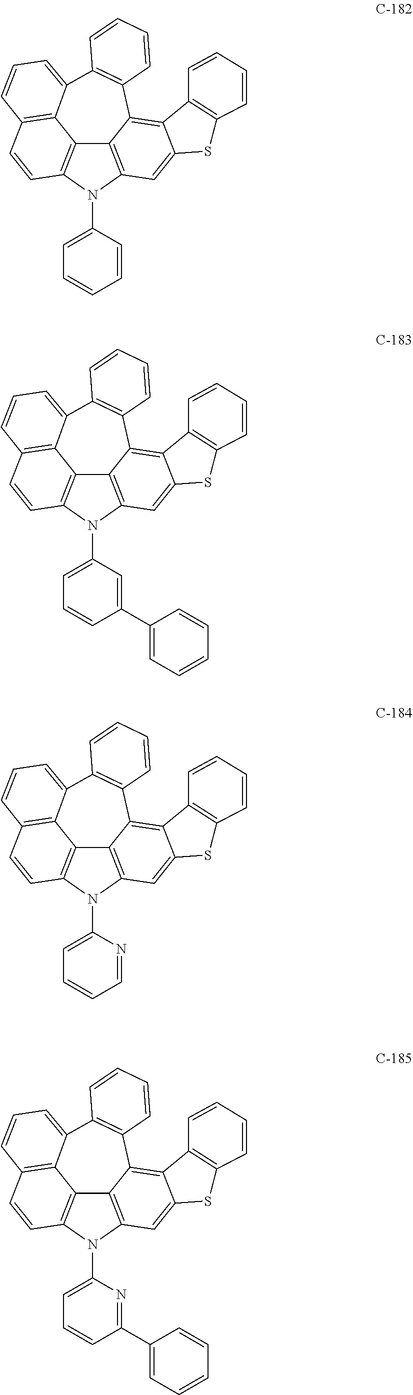 [SMILES: c1ccc(-n2c3cc4sc5ccccc5c4c4c3c3c5c(cccc5ccc32)-c2ccccc2-4)cc1 ; c1ccc(-c2cccc(-n3c4cc5sc6ccccc6c5c5c4c4c6c(cccc6ccc43)-c3ccccc3-5)c2)cc1 ; c1ccc(-n2c3cc4sc5ccccc5c4c4c3c3c5c(cccc5ccc32)-c2ccccc2-4)nc1 ; c1ccc(-c2cccc(-n3c4cc5sc6ccccc6c5c5c4c4c6c(cccc6ccc43)-c3ccccc3-5)n2)cc1]

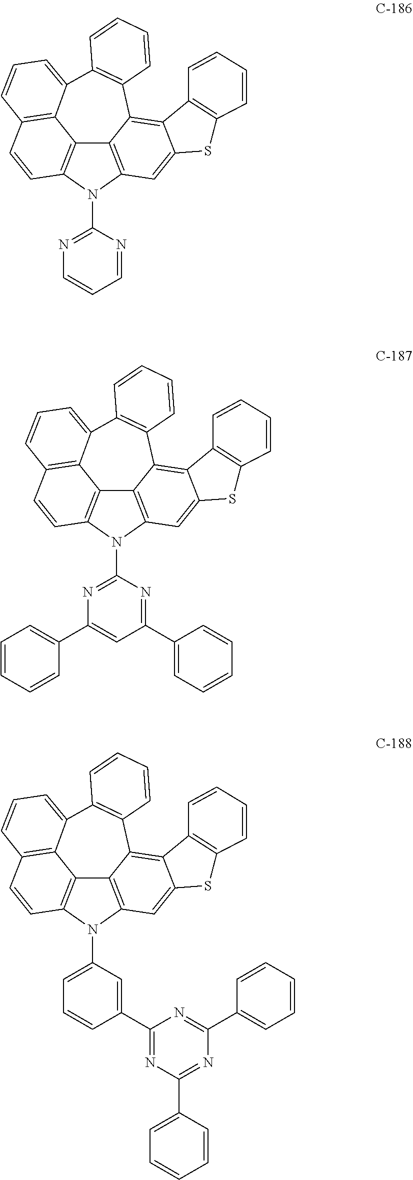 [SMILES: c1cnc(-n2c3cc4sc5ccccc5c4c4c3c3c5c(cccc5ccc32)-c2ccccc2-4)nc1 ; c1ccc(-c2cc(-c3ccccc3)nc(-n3c4cc5sc6ccccc6c5c5c4c4c6c(cccc6ccc43)-c3ccccc3-5)n2)cc1 ; c1ccc(-c2nc(-c3ccccc3)nc(-c3cccc(-n4c5cc6sc7ccccc7c6c6c5c5c7c(cccc7ccc54)-c4ccccc4-6)c3)n2)cc1]

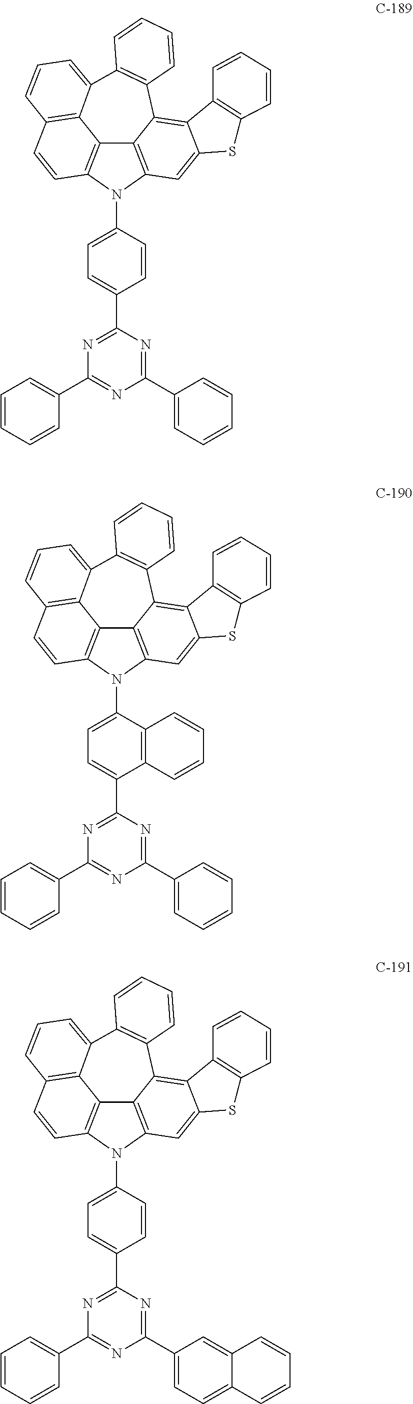 [SMILES: c1ccc(-c2nc(-c3ccccc3)nc(-c3ccc(-n4c5cc6sc7ccccc7c6c6c5c5c7c(cccc7ccc54)-c4ccccc4-6)cc3)n2)cc1 ; c1ccc(-c2nc(-c3ccccc3)nc(-c3ccc(-n4c5cc6sc7ccccc7c6c6c5c5c7c(cccc7ccc54)-c4ccccc4-6)c4ccccc34)n2)cc1 ; c1ccc(-c2nc(-c3ccc(-n4c5cc6sc7ccccc7c6c6c5c5c7c(cccc7ccc54)-c4ccccc4-6)cc3)nc(-c3ccc4ccccc4c3)n2)cc1]

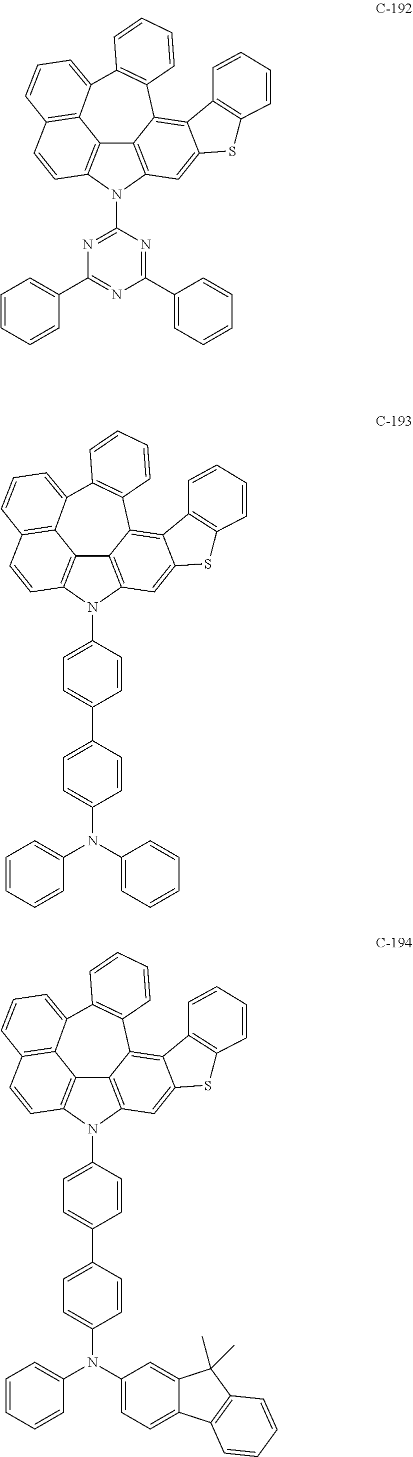 [SMILES: c1ccc(-c2nc(-c3ccccc3)nc(-n3c4cc5sc6ccccc6c5c5c4c4c6c(cccc6ccc43)-c3ccccc3-5)n2)cc1 ; c1ccc(N(c2ccccc2)c2ccc(-c3ccc(-n4c5cc6sc7ccccc7c6c6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cc7sc8ccccc8c7c7c6c6c8c(cccc8ccc65)-c5ccccc5-7)cc4)cc3)cc21]

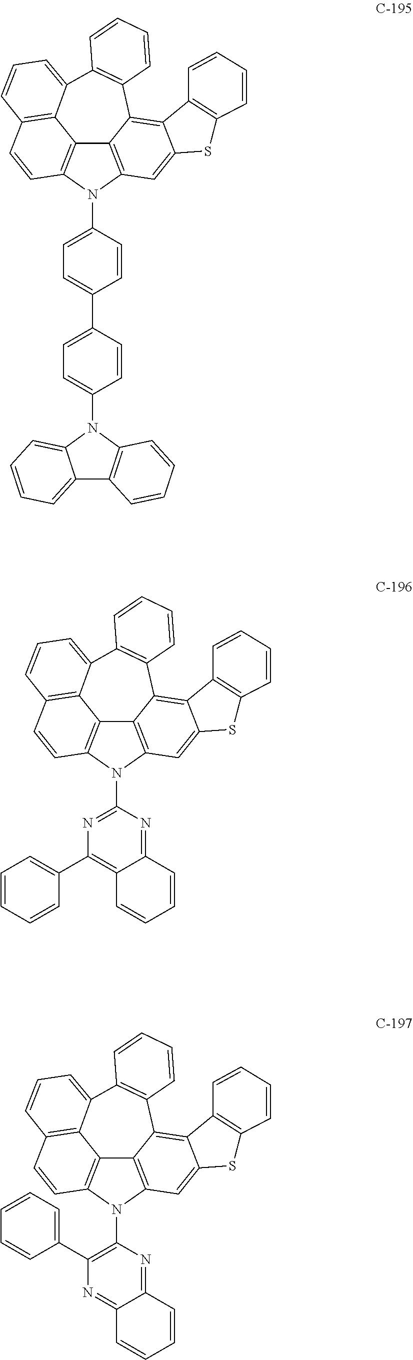

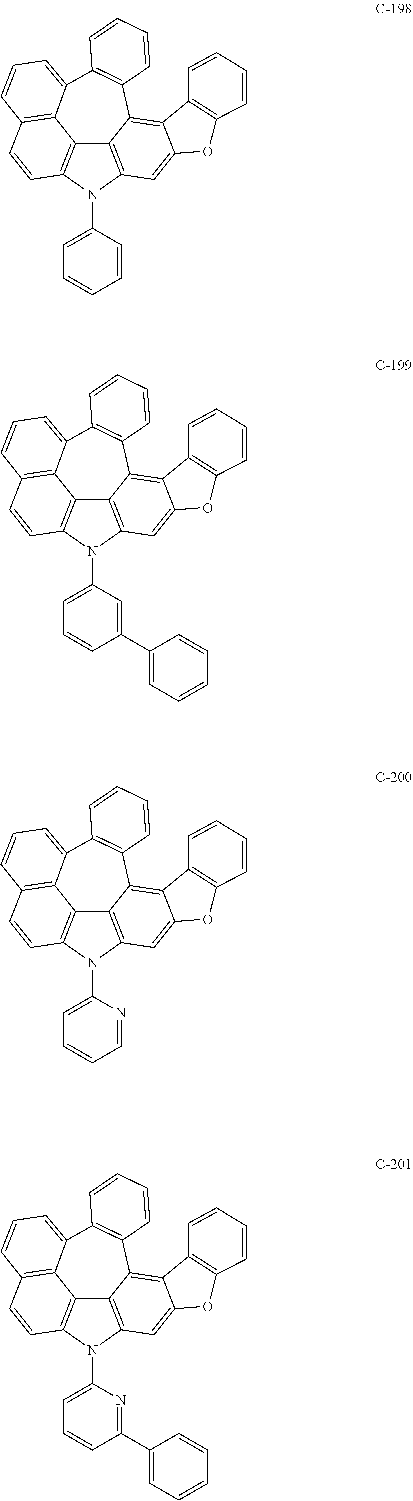 [SMILES: c1ccc(-n2c3cc4oc5ccccc5c4c4c3c3c5c(cccc5ccc32)-c2ccccc2-4)cc1 ; c1ccc(-c2cccc(-n3c4cc5oc6ccccc6c5c5c4c4c6c(cccc6ccc43)-c3ccccc3-5)c2)cc1 ; c1ccc(-n2c3cc4oc5ccccc5c4c4c3c3c5c(cccc5ccc32)-c2ccccc2-4)nc1 ; c1ccc(-c2cccc(-n3c4cc5oc6ccccc6c5c5c4c4c6c(cccc6ccc43)-c3ccccc3-5)n2)cc1]

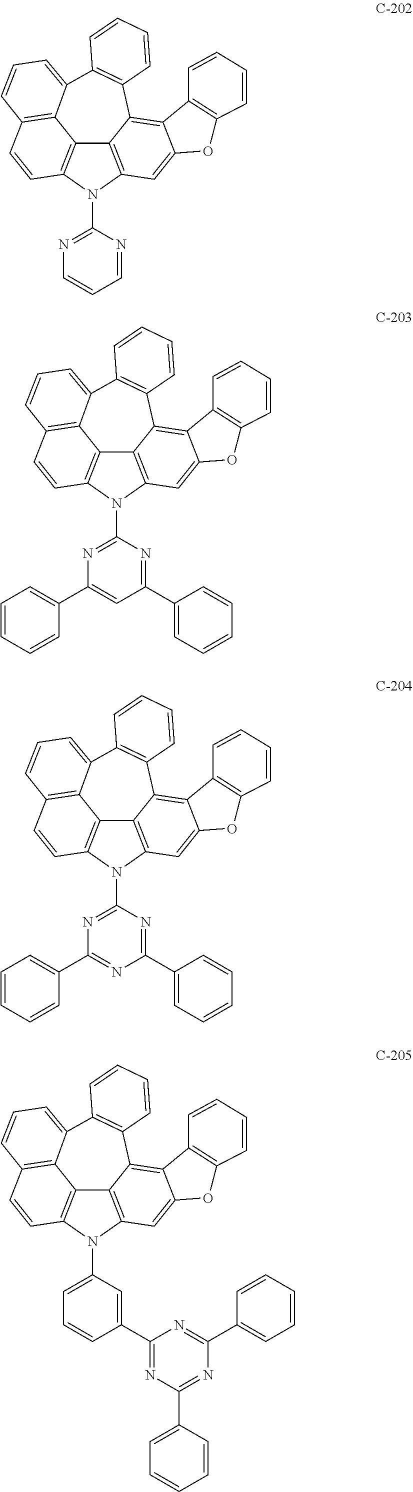 [SMILES: c1cnc(-n2c3cc4oc5ccccc5c4c4c3c3c5c(cccc5ccc32)-c2ccccc2-4)nc1 ; c1ccc(-c2cc(-c3ccccc3)nc(-n3c4cc5oc6ccccc6c5c5c4c4c6c(cccc6ccc43)-c3ccccc3-5)n2)cc1 ; c1ccc(-c2nc(-c3ccccc3)nc(-n3c4cc5oc6ccccc6c5c5c4c4c6c(cccc6ccc43)-c3ccccc3-5)n2)cc1 ; c1ccc(-c2nc(-c3ccccc3)nc(-c3cccc(-n4c5cc6oc7ccccc7c6c6c5c5c7c(cccc7ccc54)-c4ccccc4-6)c3)n2)cc1]

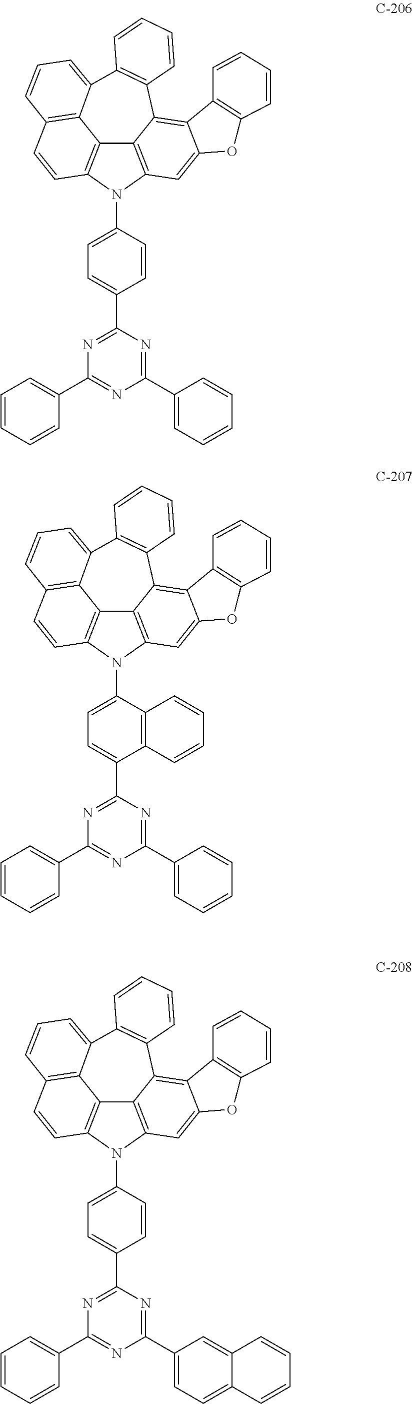 [SMILES: c1ccc(-c2nc(-c3ccccc3)nc(-c3ccc(-n4c5cc6oc7ccccc7c6c6c5c5c7c(cccc7ccc54)-c4ccccc4-6)cc3)n2)cc1 ; c1ccc(-c2nc(-c3ccccc3)nc(-c3ccc(-n4c5cc6oc7ccccc7c6c6c5c5c7c(cccc7ccc54)-c4ccccc4-6)c4ccccc34)n2)cc1 ; c1ccc(-c2nc(-c3ccc(-n4c5cc6oc7ccccc7c6c6c5c5c7c(cccc7ccc54)-c4ccccc4-6)cc3)nc(-c3ccc4ccccc4c3)n2)cc1]

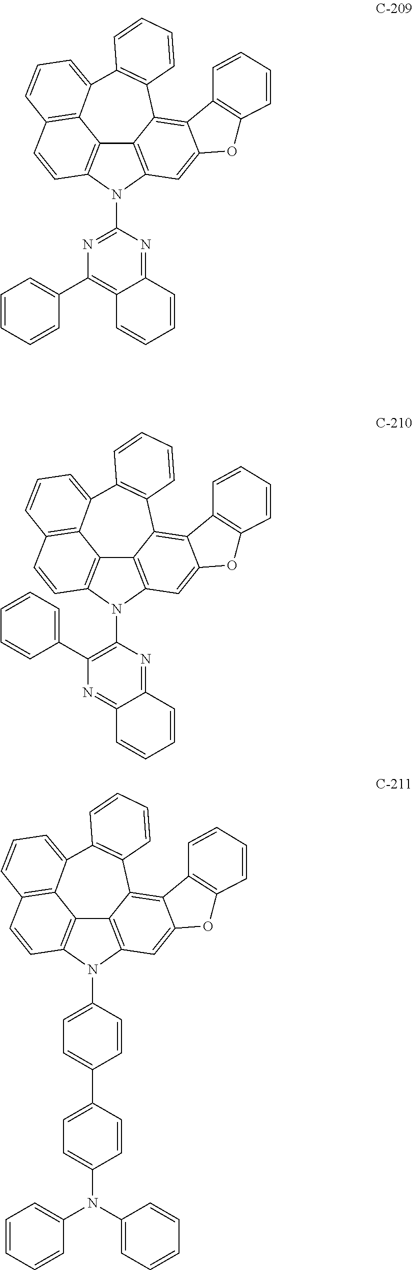

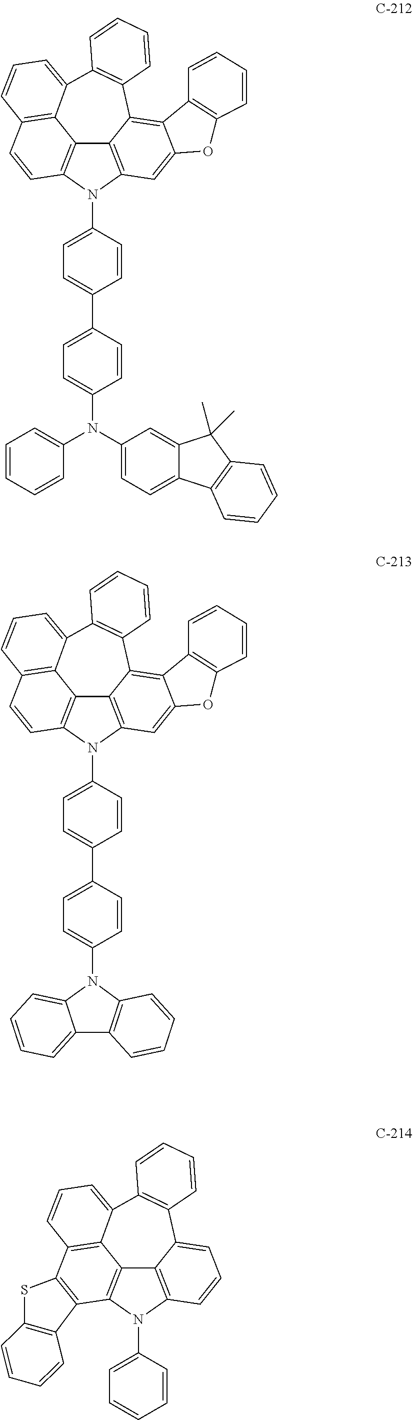 [SMILES: CC1(C)c2ccccc2-c2ccc(N(c3ccccc3)c3ccc(-c4ccc(-n5c6cc7oc8ccccc8c7c7c6c6c8c(cccc8ccc65)-c5ccccc5-7)cc4)cc3)cc21 ; c1ccc2c(c1)-c1cccc3ccc4c(c13)c1c-2c2c(cc1n4-c1ccc(-c3ccc(-n4c5ccccc5c5ccccc54)cc3)cc1)oc1ccccc12 ; c1ccc(-n2c3cccc4c3c3c5c(cccc5c5sc6ccccc6c5c32)-c2ccccc2-4)cc1]

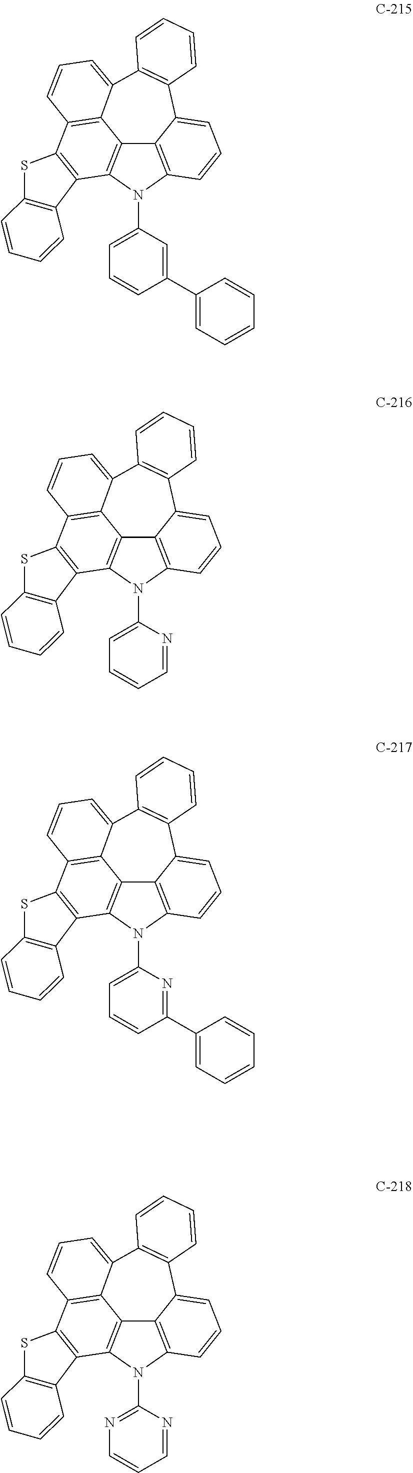 [SMILES: c1ccc(-c2cccc(-n3c4cccc5c4c4c6c(cccc6c6sc7ccccc7c6c43)-c3ccccc3-5)c2)cc1 ; c1ccc(-n2c3cccc4c3c3c5c(cccc5c5sc6ccccc6c5c32)-c2ccccc2-4)nc1 ; c1ccc(-c2cccc(-n3c4cccc5c4c4c6c(cccc6c6sc7ccccc7c6c43)-c3ccccc3-5)n2)cc1 ; c1cnc(-n2c3cccc4c3c3c5c(cccc5c5sc6ccccc6c5c32)-c2ccccc2-4)nc1]

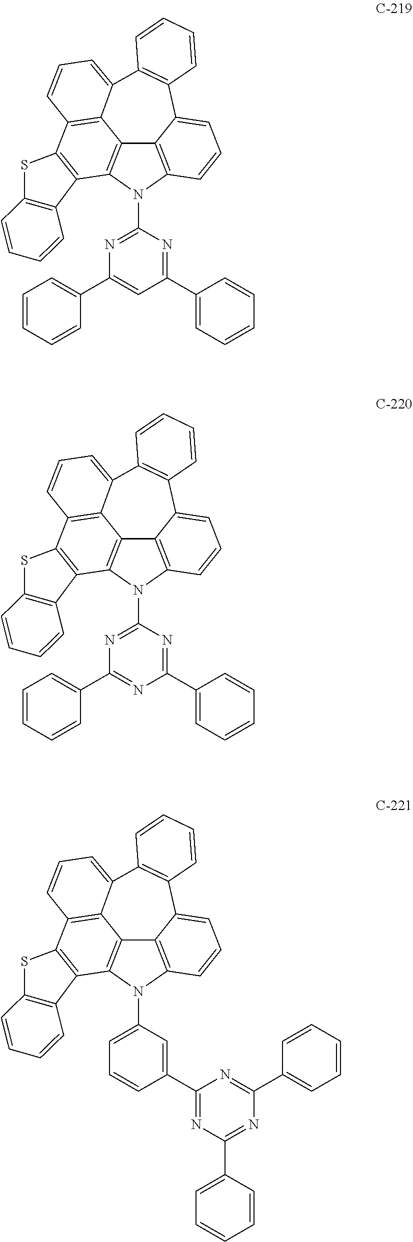 [SMILES: c1ccc(-c2cc(-c3ccccc3)nc(-n3c4cccc5c4c4c6c(cccc6c6sc7ccccc7c6c43)-c3ccccc3-5)n2)cc1 ; c1ccc(-c2nc(-c3ccccc3)nc(-n3c4cccc5c4c4c6c(cccc6c6sc7ccccc7c6c43)-c3ccccc3-5)n2)cc1 ; c1ccc(-c2nc(-c3ccccc3)nc(-c3cccc(-n4c5cccc6c5c5c7c(cccc7c7sc8ccccc8c7c54)-c4ccccc4-6)c3)n2)cc1]

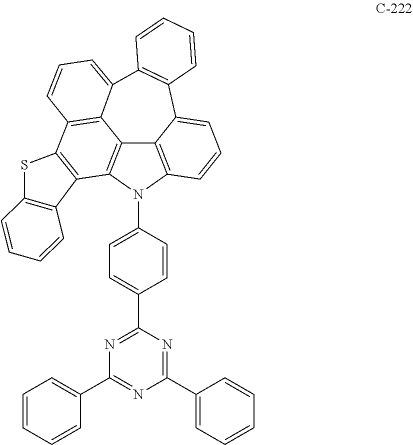 [SMILES: c1ccc(-c2nc(-c3ccccc3)nc(-c3ccc(-n4c5cccc6c5c5c7c(cccc7c7sc8ccccc8c7c54)-c4ccccc4-6)cc3)n2)cc1]

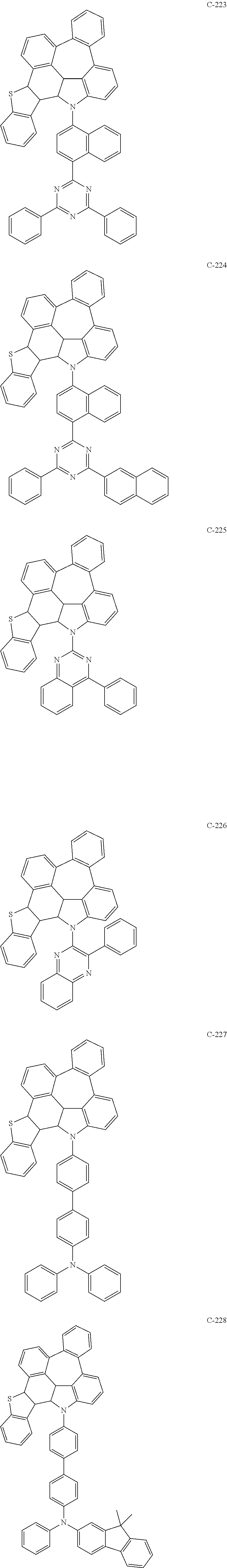

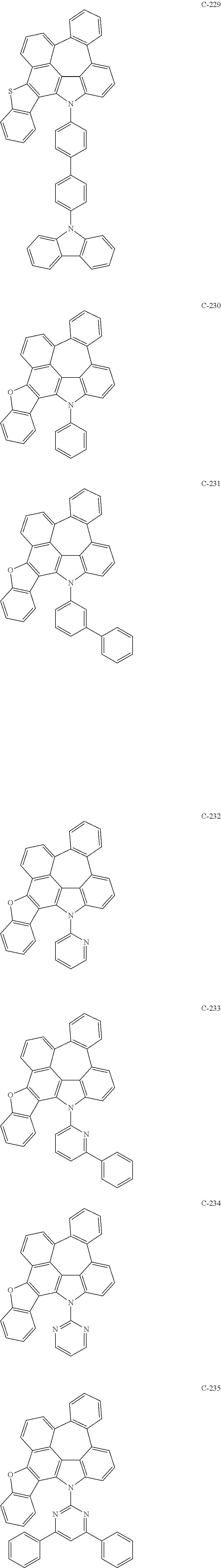

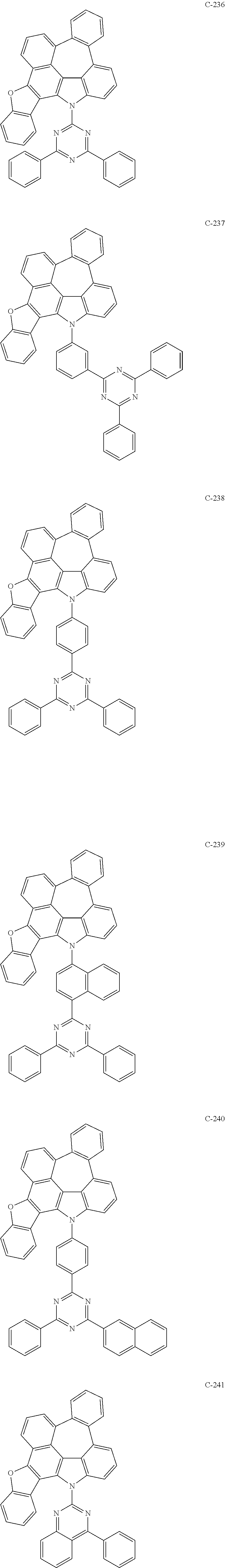

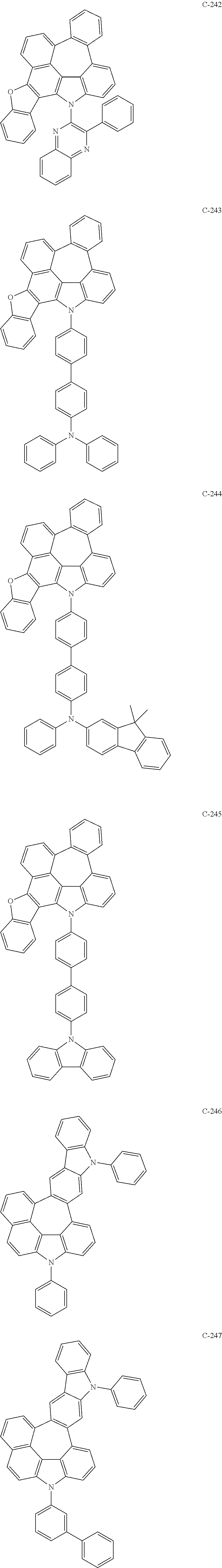

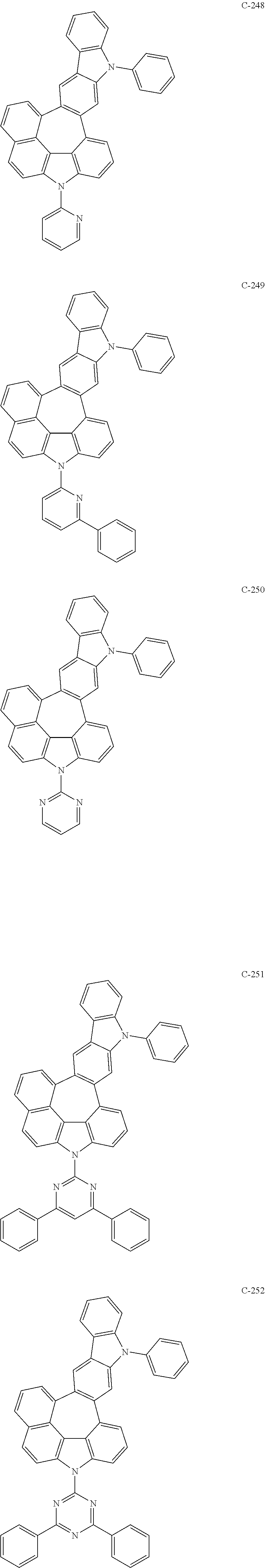 [SMILES: c1ccc(-n2c3ccccc3c3cc4c(cc32)-c2cccc3c2c2c5c-4cccc5ccc2n3-c2ccccn2)cc1 ; c1ccc(-c2cccc(-n3c4cccc5c4c4c6c(cccc6ccc43)-c3cc4c6ccccc6n(-c6ccccc6)c4cc3-5)n2)cc1 ; c1ccc(-n2c3ccccc3c3cc4c(cc32)-c2cccc3c2c2c5c-4cccc5ccc2n3-c2ncccn2)cc1 ; c1ccc(-c2cc(-c3ccccc3)nc(-n3c4cccc5c4c4c6c(cccc6ccc43)-c3cc4c6ccccc6n(-c6ccccc6)c4cc3-5)n2)cc1 ; c1ccc(-c2nc(-c3ccccc3)nc(-n3c4cccc5c4c4c6c(cccc6ccc43)-c3cc4c6ccccc6n(-c6ccccc6)c4cc3-5)n2)cc1]

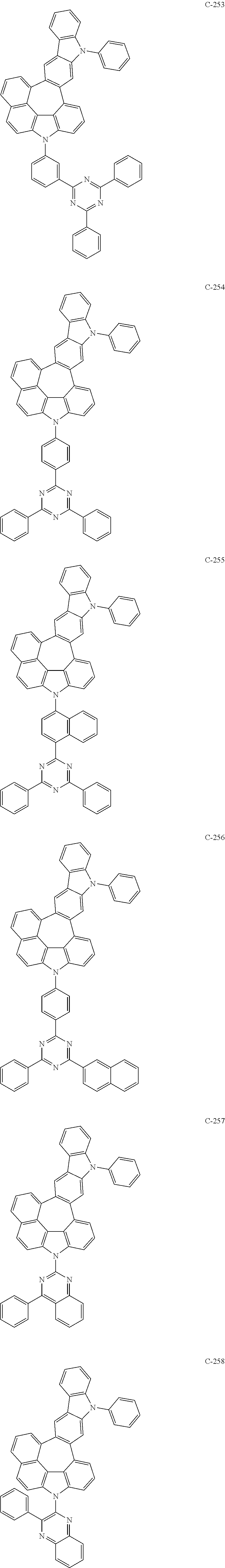

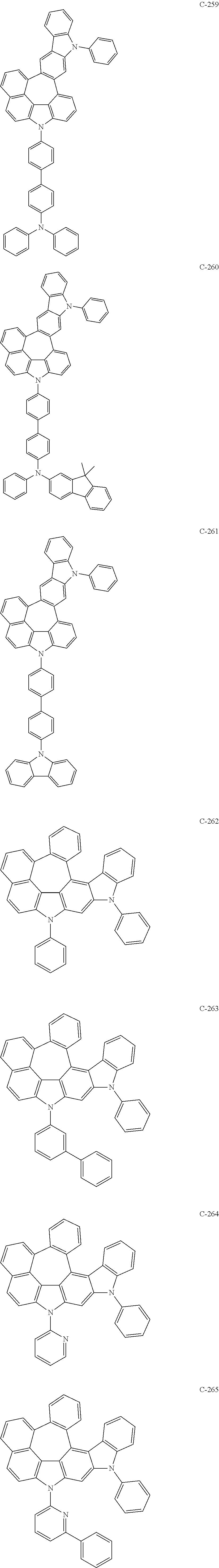

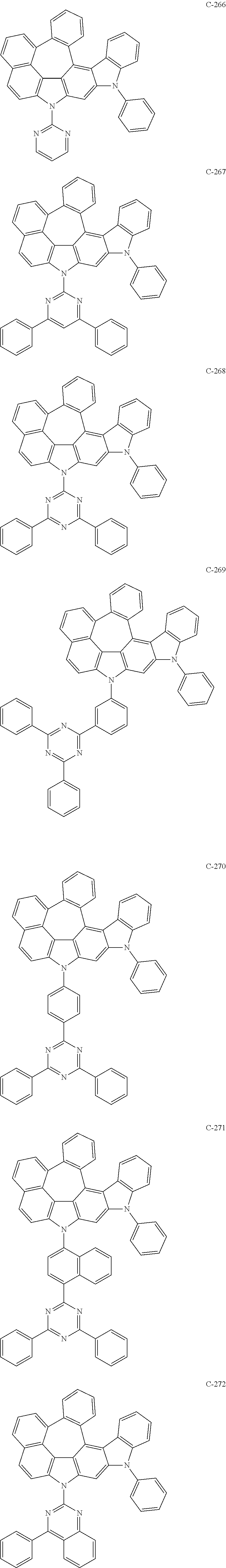

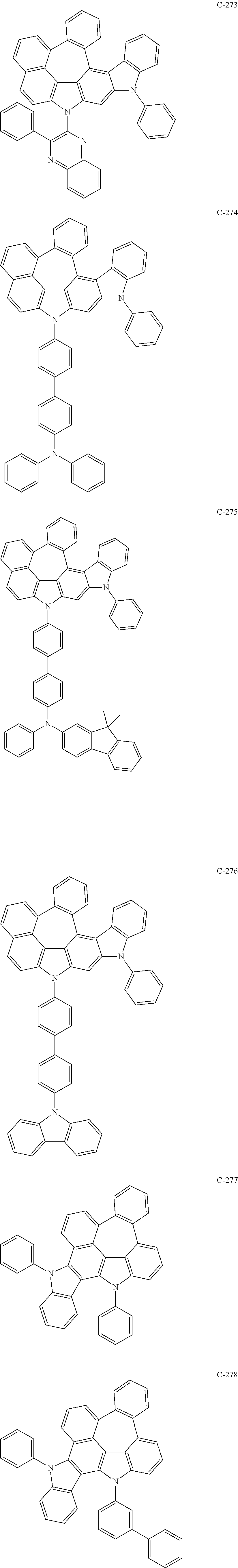

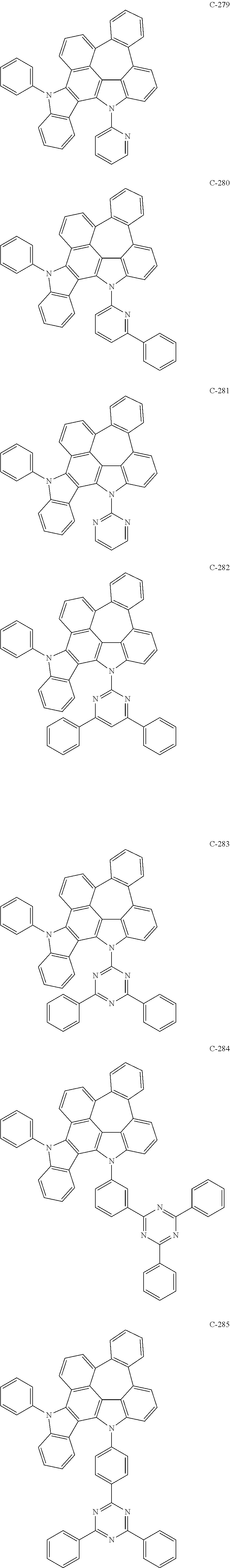

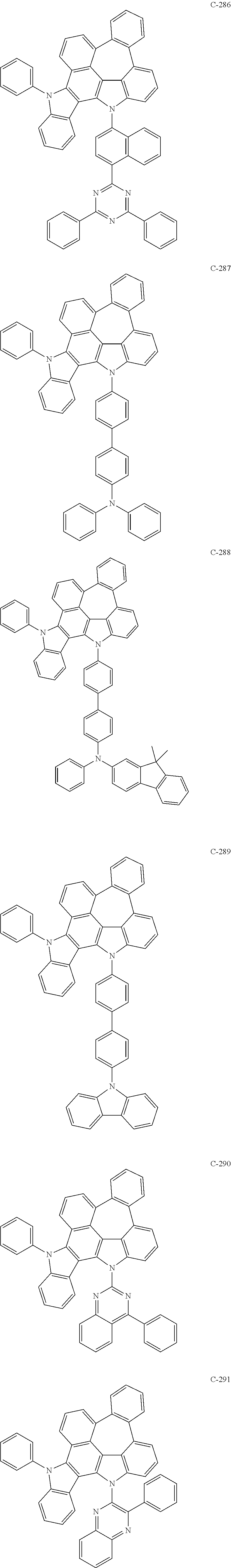

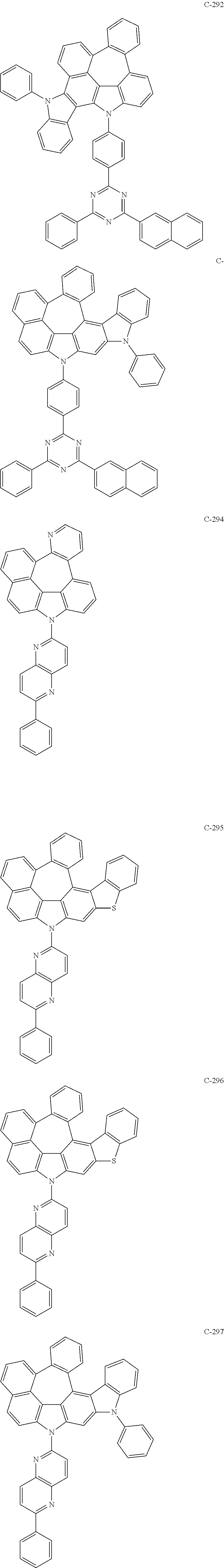

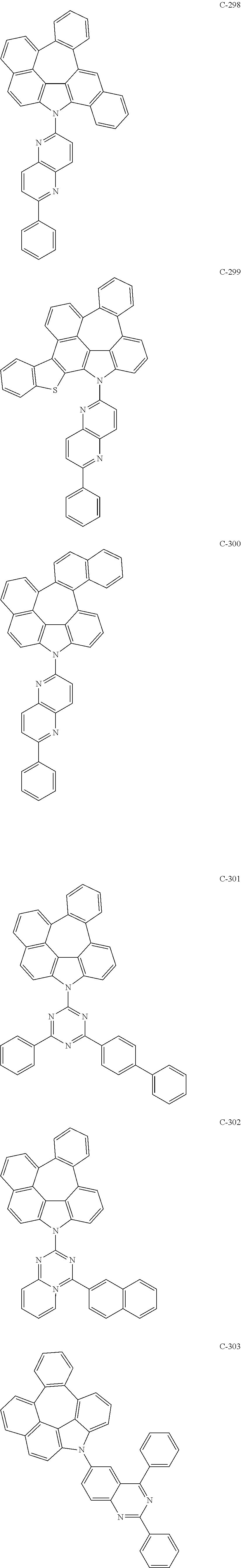

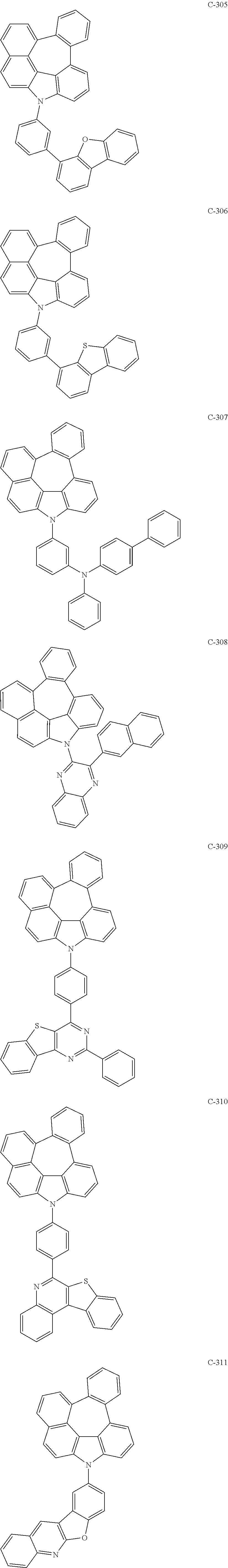

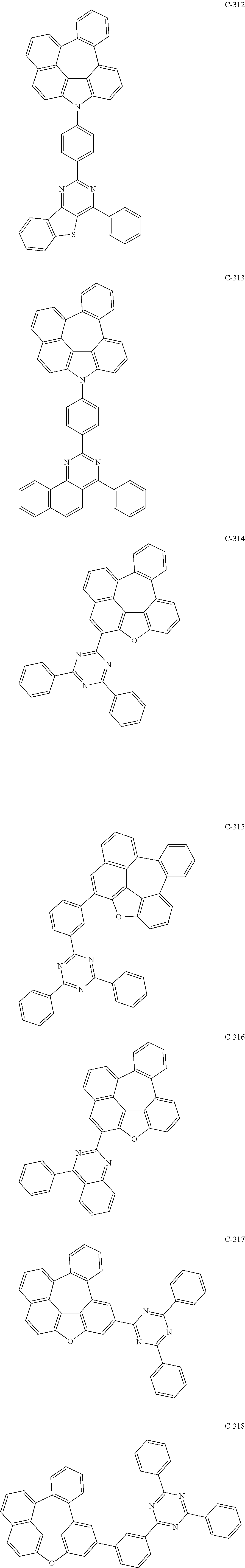

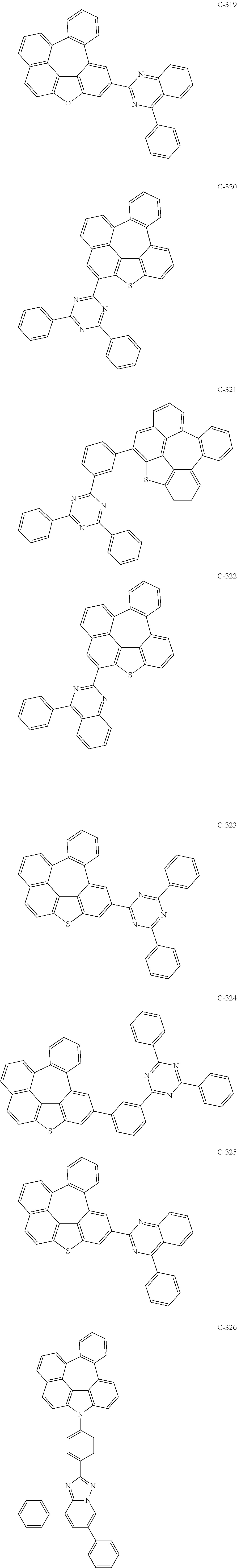

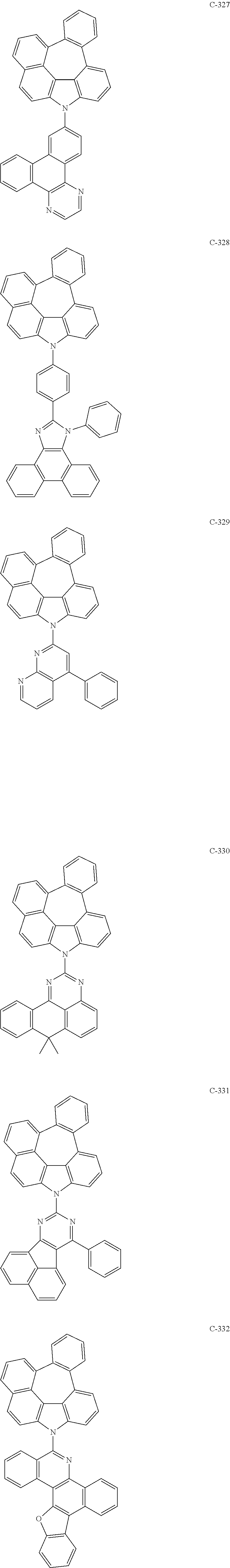 [SMILES: c1ccc2c(c1)-c1cccc3ccc4c(c13)c1c-2cccc1n4-c1ccc2c(c1)c1ccccc1c1nccnc21 ; c1ccc(-n2c(-c3ccc(-n4c5cccc6c5c5c7c(cccc7ccc54)-c4ccccc4-6)cc3)nc3c4ccccc4c4ccccc4c32)cc1 ; c1ccc(-c2cc(-n3c4cccc5c4c4c6c(cccc6ccc43)-c3ccccc3-5)nc3ncccc23)cc1 ; CC1(C)c2ccccc2-c2nc(-n3c4cccc5c4c4c6c(cccc6ccc43)-c3ccccc3-5)nc3cccc1c23 ; c1ccc(-c2nc(-n3c4cccc5c4c4c6c(cccc6ccc43)-c3ccccc3-5)nc3c2-c2cccc4cccc-3c24)cc1 ; c1ccc2c(c1)-c1cccc3ccc4c(c13)c1c-2cccc1n4-c1nc2c3ccccc3c3c4ccccc4oc3c2c2ccccc12]

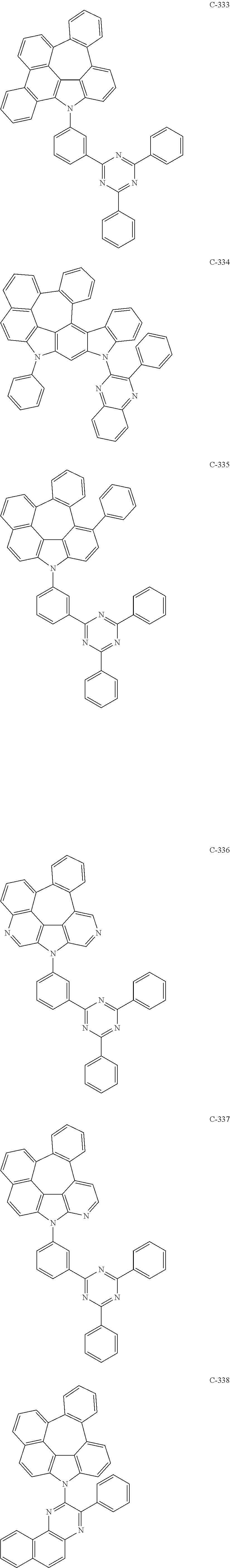

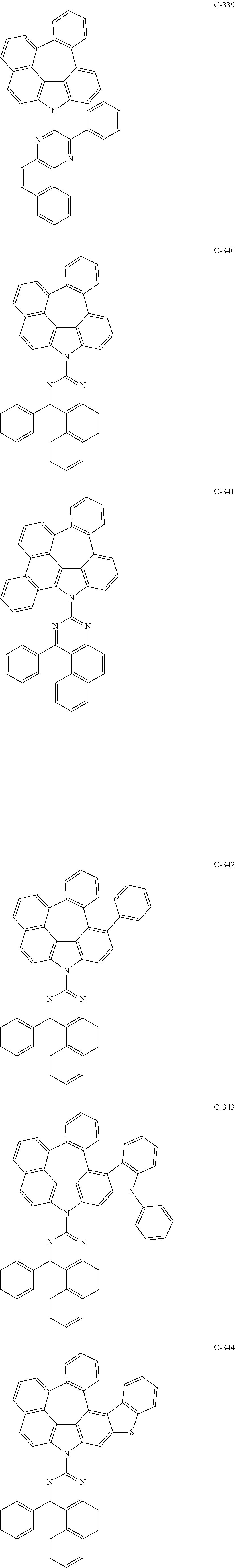

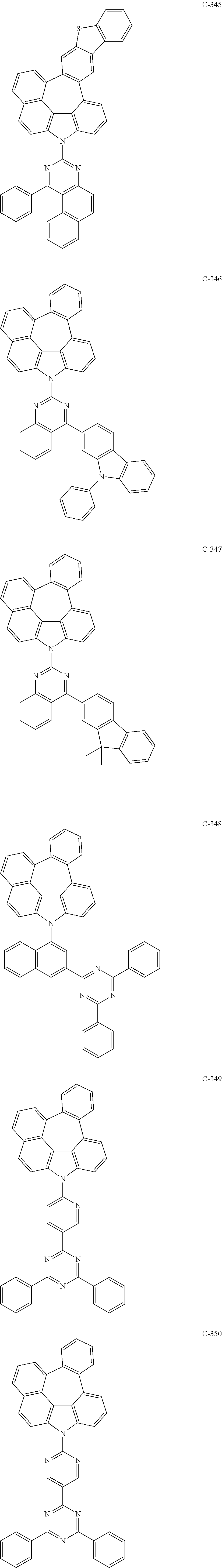

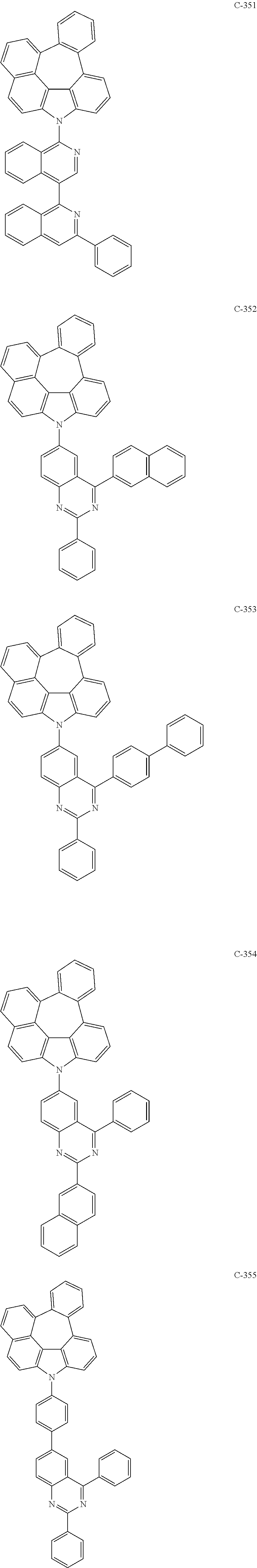

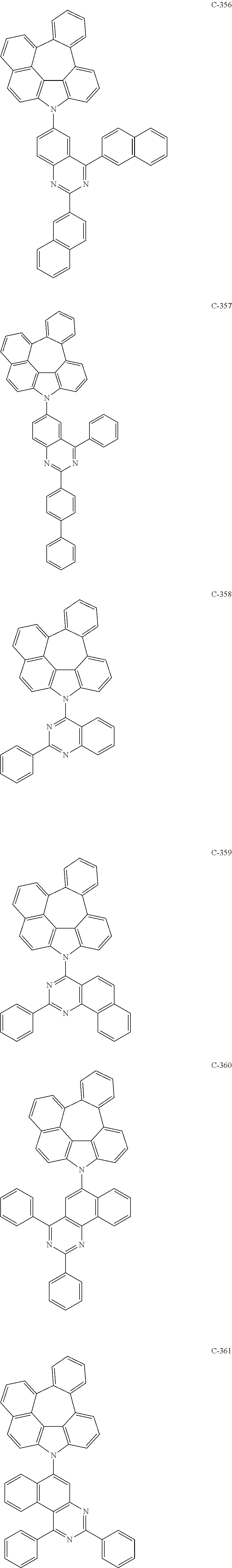

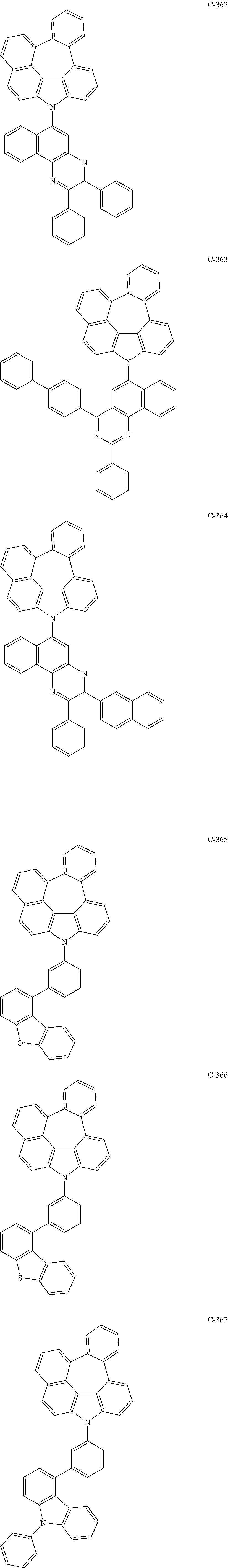

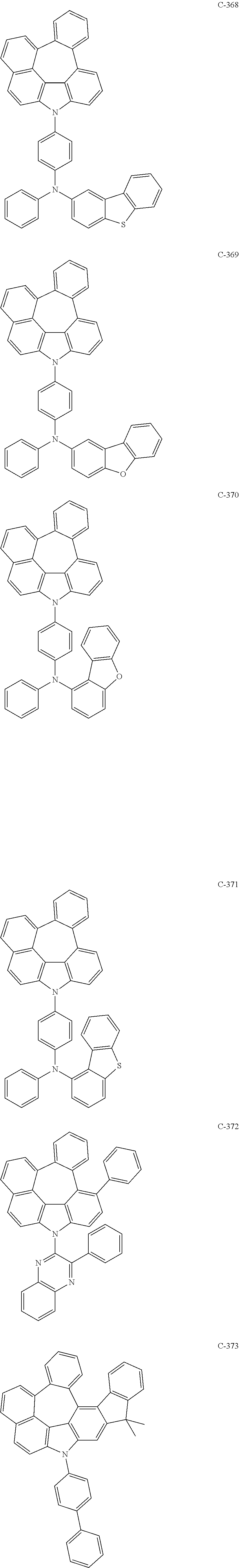 [SMILES: c1ccc(N(c2ccc(-n3c4cccc5c4c4c6c(cccc6ccc43)-c3ccccc3-5)cc2)c2ccc3sc4ccccc4c3c2)cc1 ; c1ccc(N(c2ccc(-n3c4cccc5c4c4c6c(cccc6ccc43)-c3ccccc3-5)cc2)c2ccc3oc4ccccc4c3c2)cc1 ; c1ccc(N(c2ccc(-n3c4cccc5c4c4c6c(cccc6ccc43)-c3ccccc3-5)cc2)c2cccc3oc4ccccc4c23)cc1 ; c1ccc(N(c2ccc(-n3c4cccc5c4c4c6c(cccc6ccc43)-c3ccccc3-5)cc2)c2cccc3sc4ccccc4c23)cc1 ; c1ccc(-c2ccc3c4c2-c2ccccc2-c2cccc5ccc(c4c25)n3-c2nc3ccccc3nc2-c2ccccc2)cc1 ; CC1(C)c2ccccc2-c2c1cc1c3c2-c2ccccc2-c2cccc4ccc(c3c24)n1-c1ccc(-c2ccccc2)cc1]

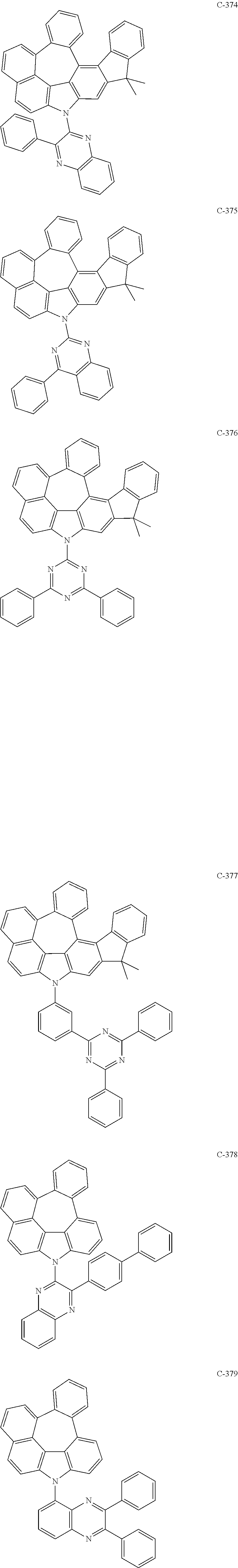

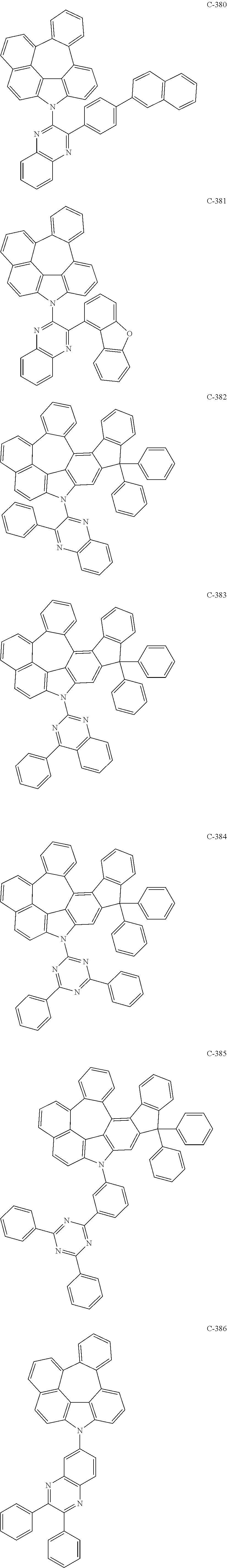

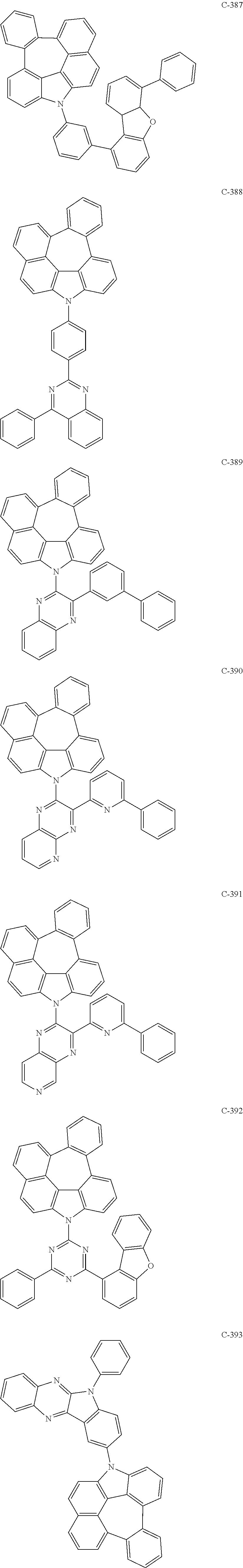

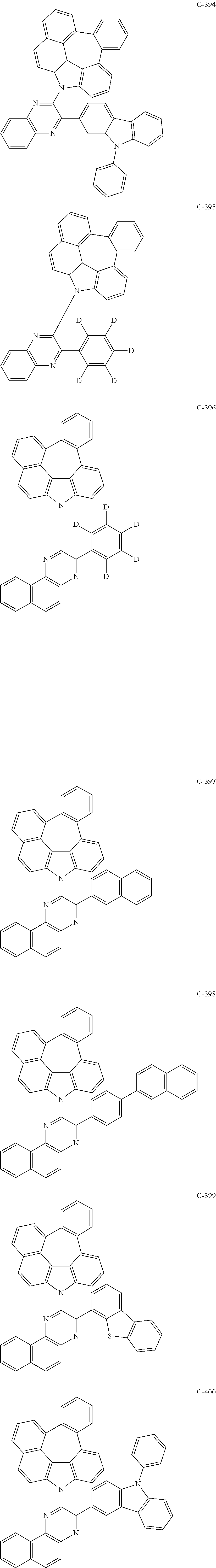

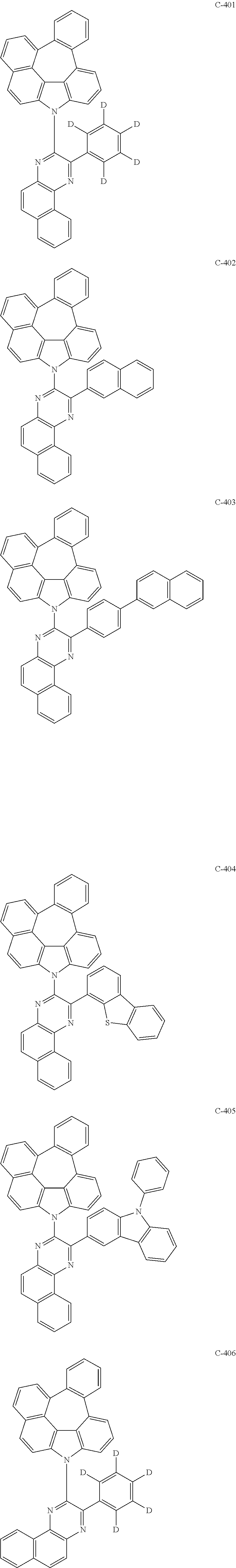

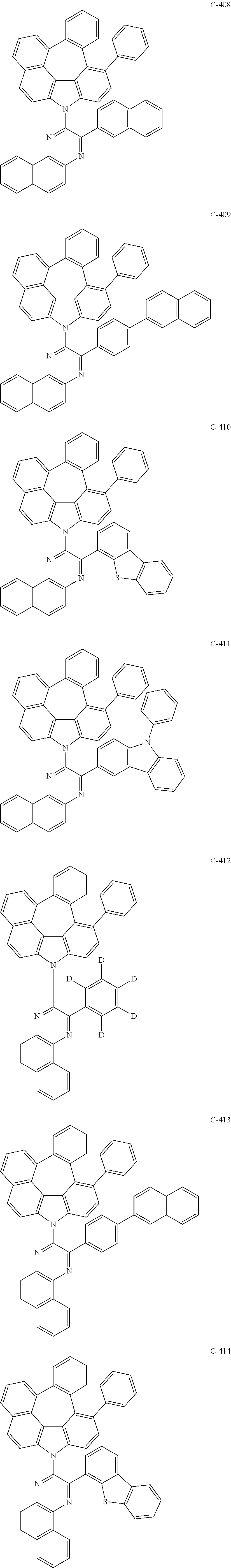

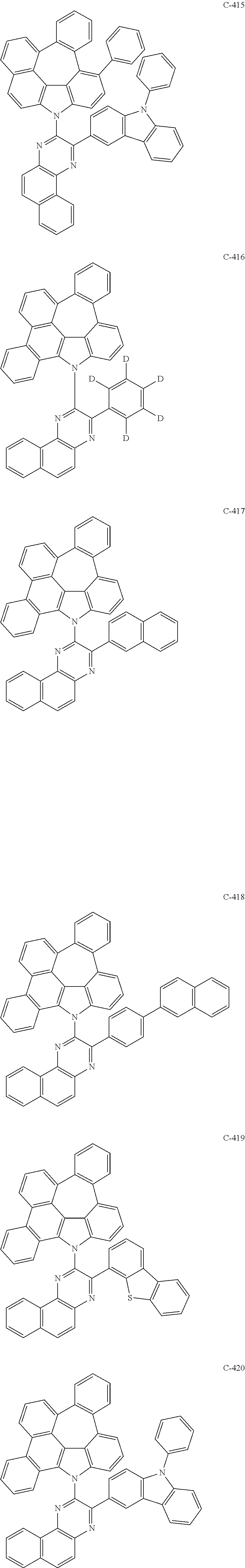

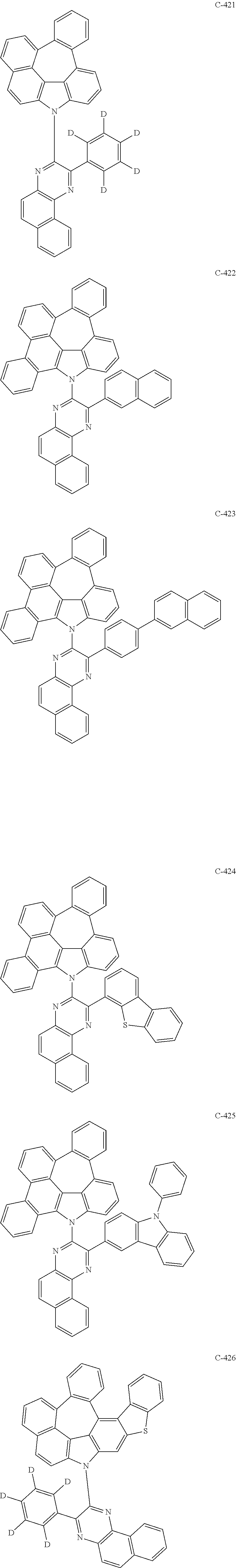

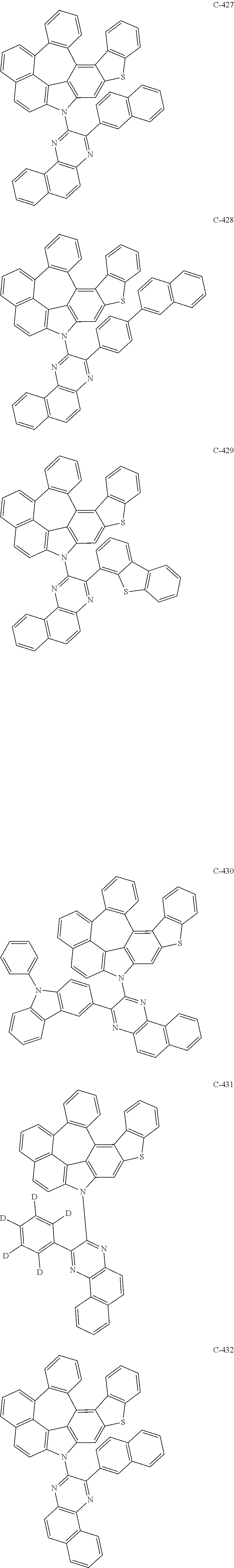

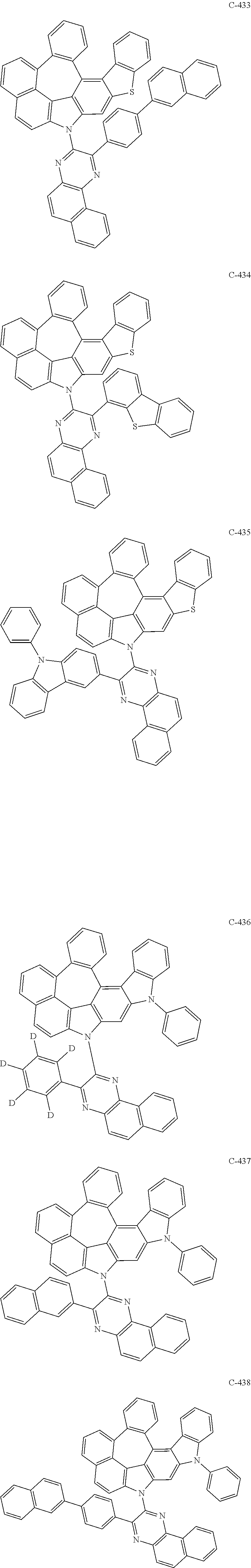

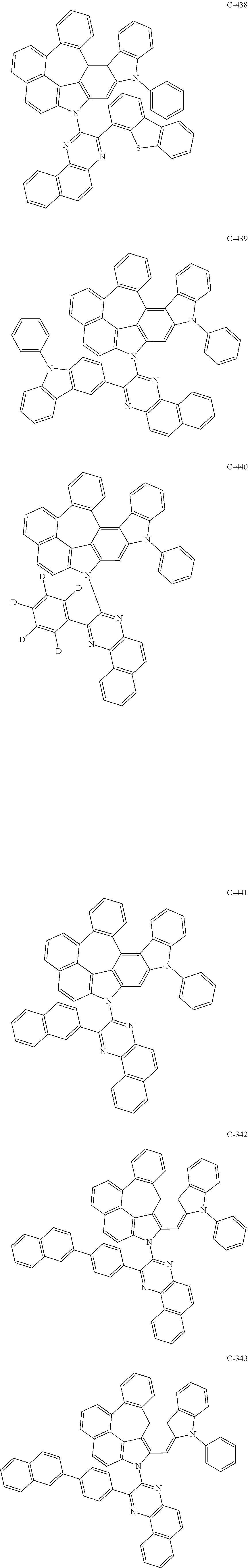

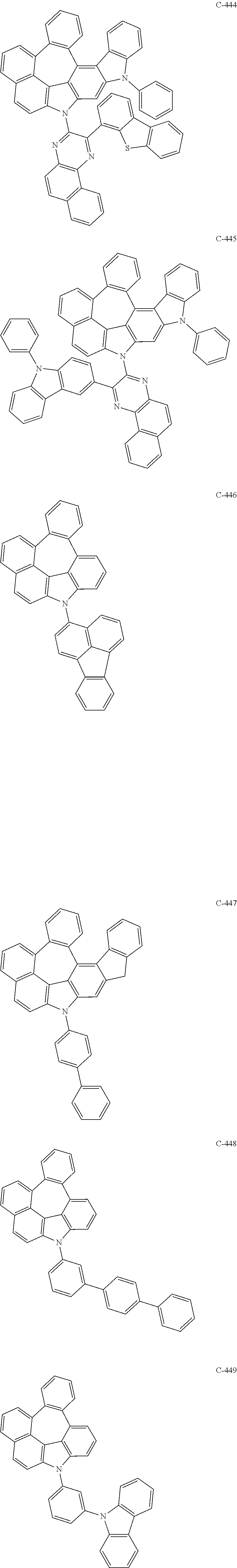

The compound represented by formula 1 according to the present disclosure may be prepared by a synthetic method known to one skilled in the art. For example, the compound represented by formula 1 can be prepared by referring to the following reaction schemes 1 to 9, but are not limited thereto.

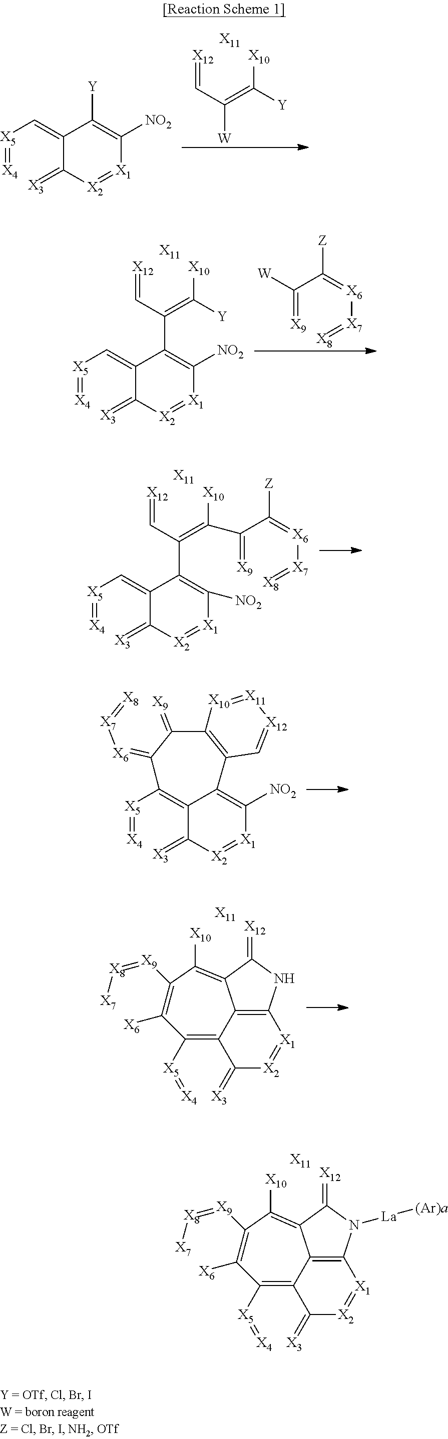

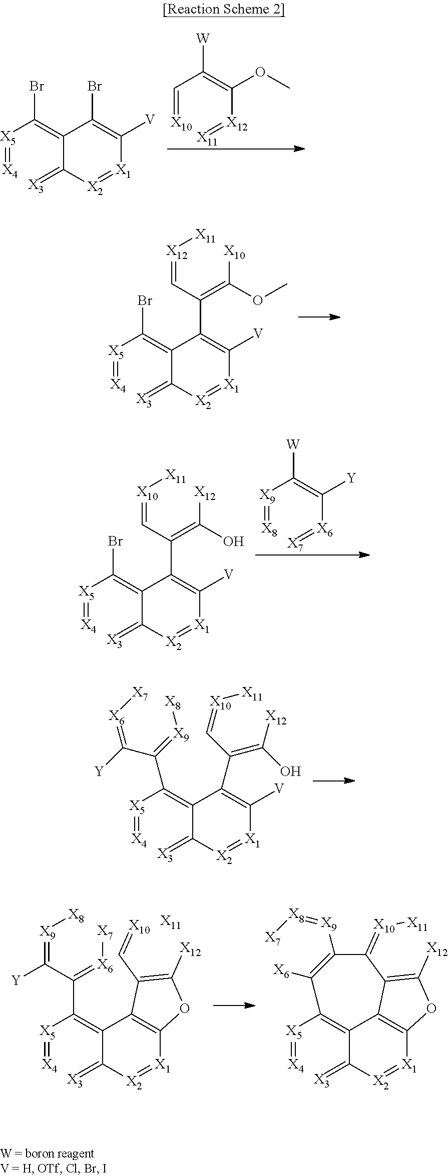

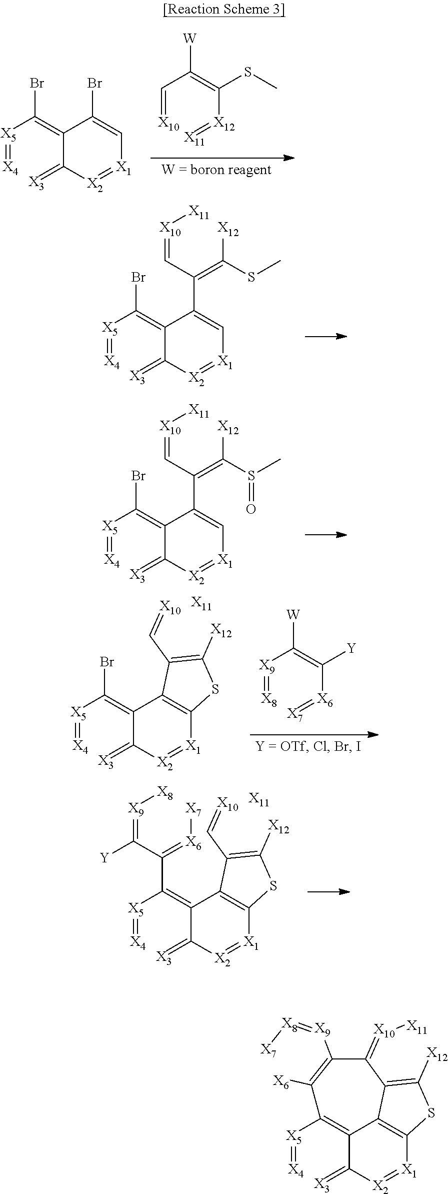

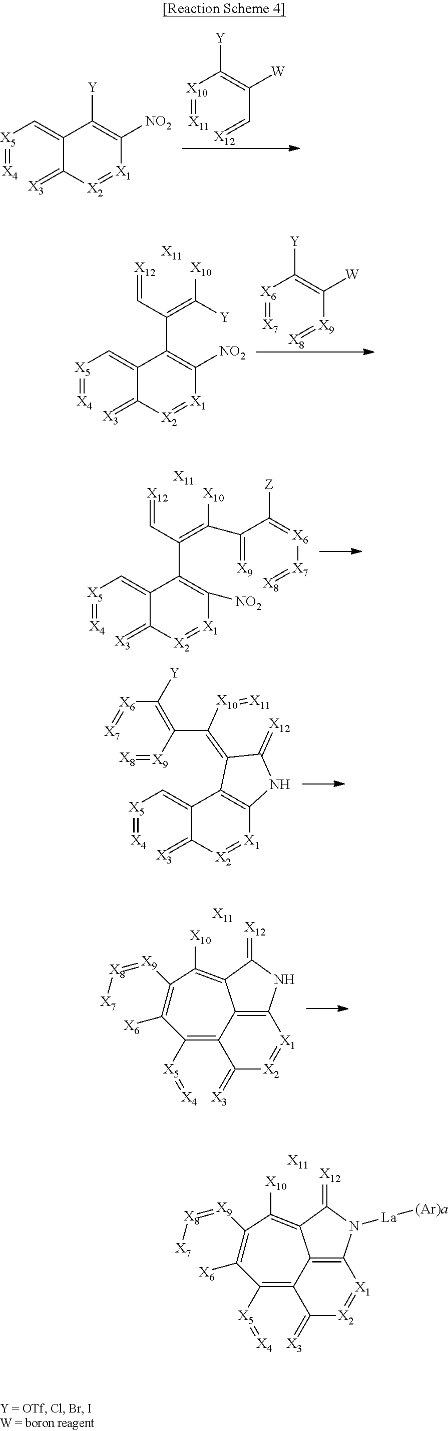

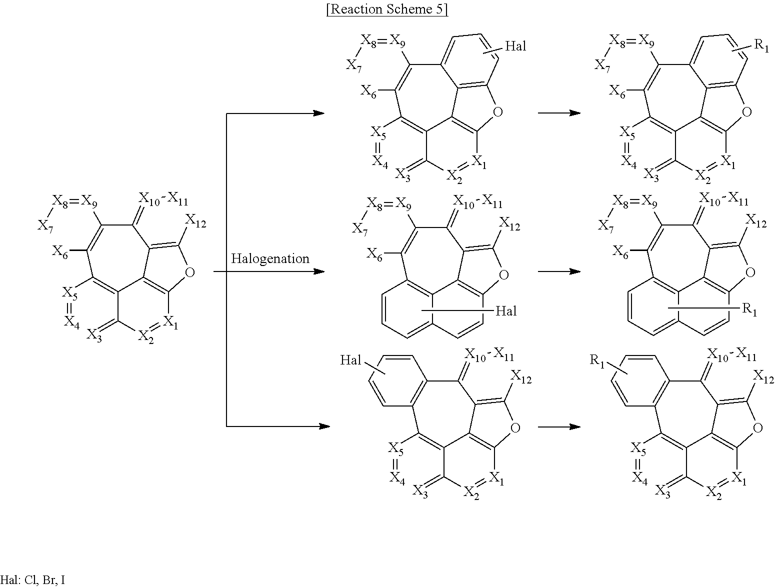

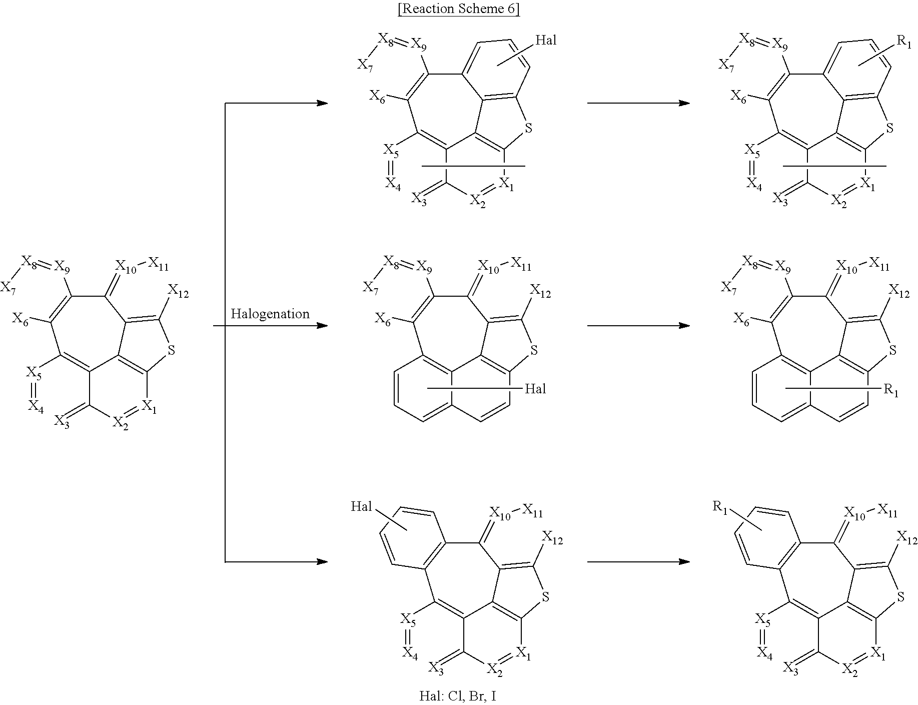

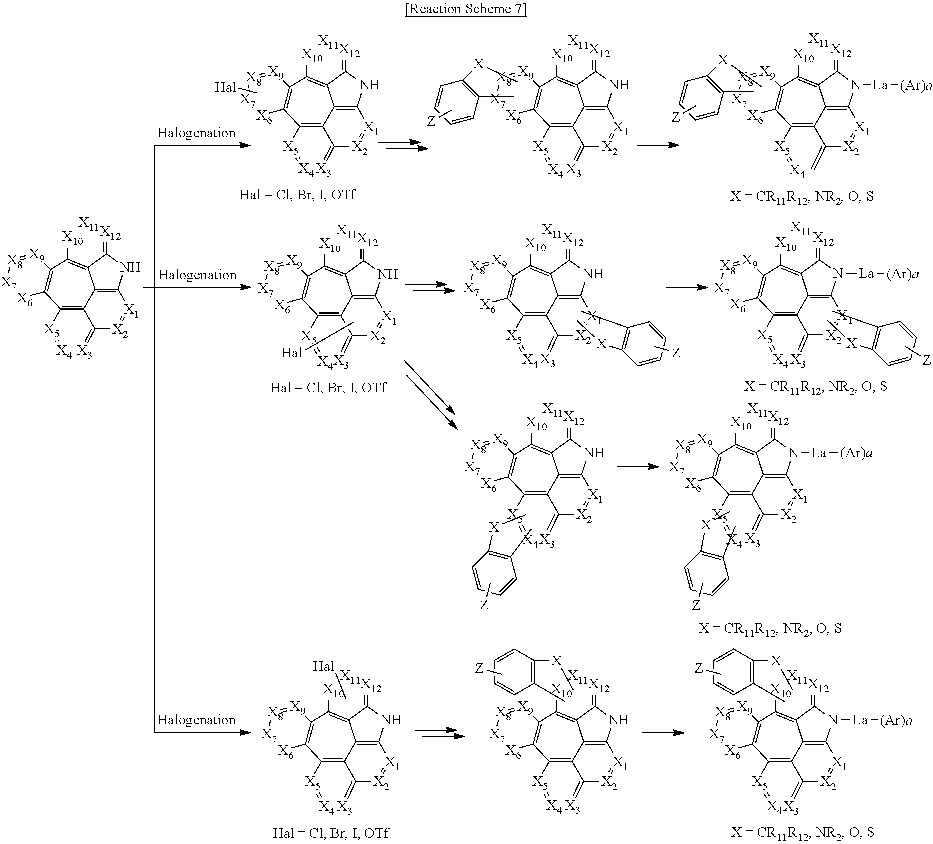

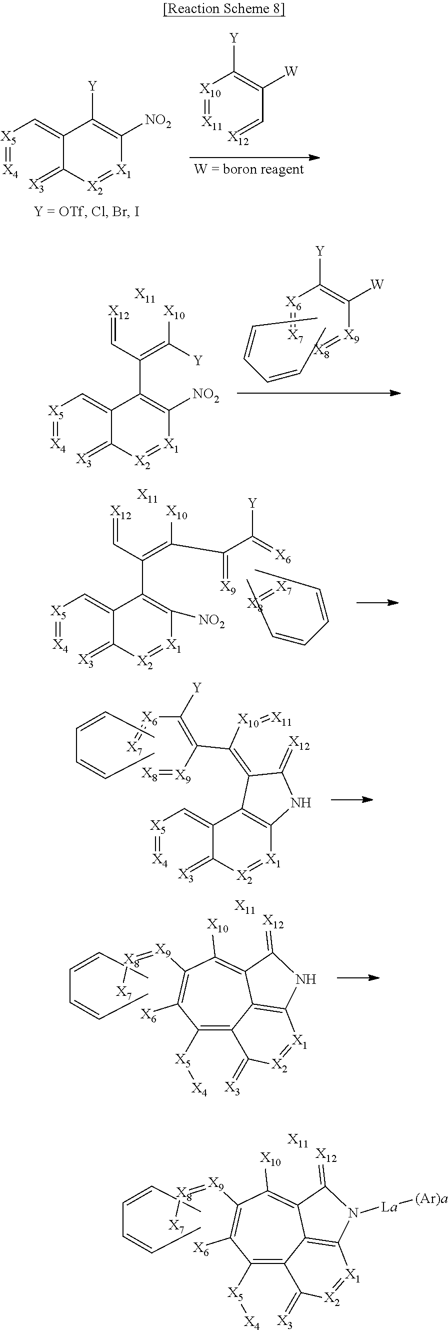

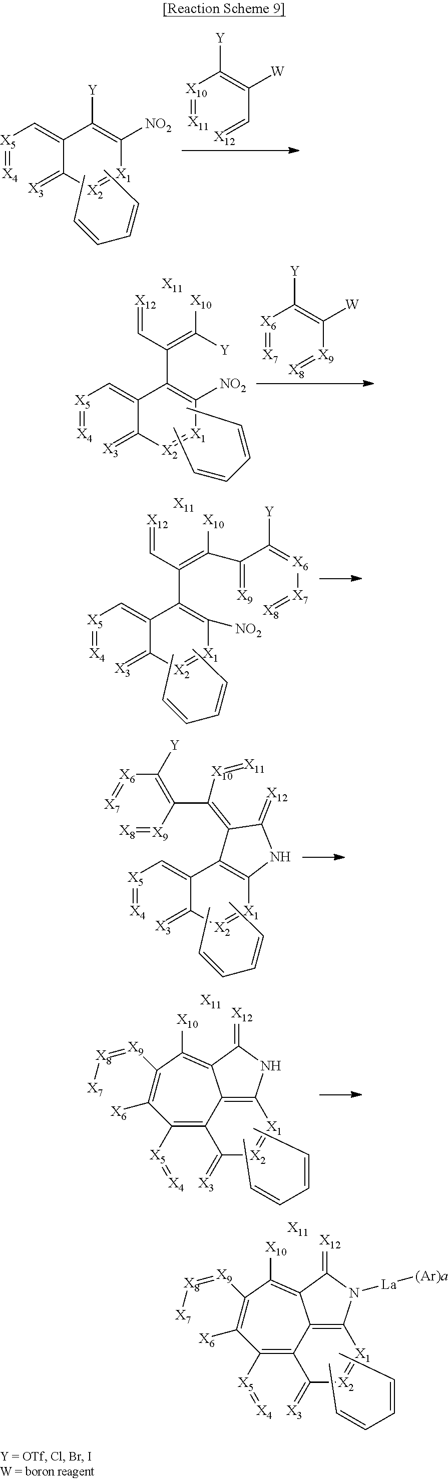

In reaction schemes 1 to 9, X₁ to X₁₂, R₁, La, Ar, and a are each as defined in formula 1; R₂, R₁₁, and R₁₂ are each as defined in formulas 5 and 6; Z is as defined in R₁; and OTf is trifluoromethanesulfonate.

Although illustrative synthesis examples of the compound represented by formula 1 were described above, one skilled in the art will be able to readily understand that all of the illustrative synthesis examples are based on a Buchwald-Hartwig cross-coupling reaction, an N-arylation reaction, a H-mont-mediated etherification reaction, a Miyaura borylation reaction, a Suzuki cross-coupling reaction, an Intramolecular acid-induced cyclization reaction, a Pd(II)-catalyzed oxidative cyclization reaction, a Grignard reaction, a Heck reaction, a Cyclic Dehydration reaction, an SN₁ substitution reaction, an SN₂ substitution reaction, a Phosphine-mediated reductive cyclization reaction, etc., and the above reactions proceed even when substituents, which are defined in formula 1 above but are not specified in the specific synthesis examples, are bonded.

Hereinafter, the preparation method of the compound according to the present disclosure and the properties thereof will be explained in detail. However, the present disclosure is not limited to the following examples.

### Example 1: Preparation of Compound C-8

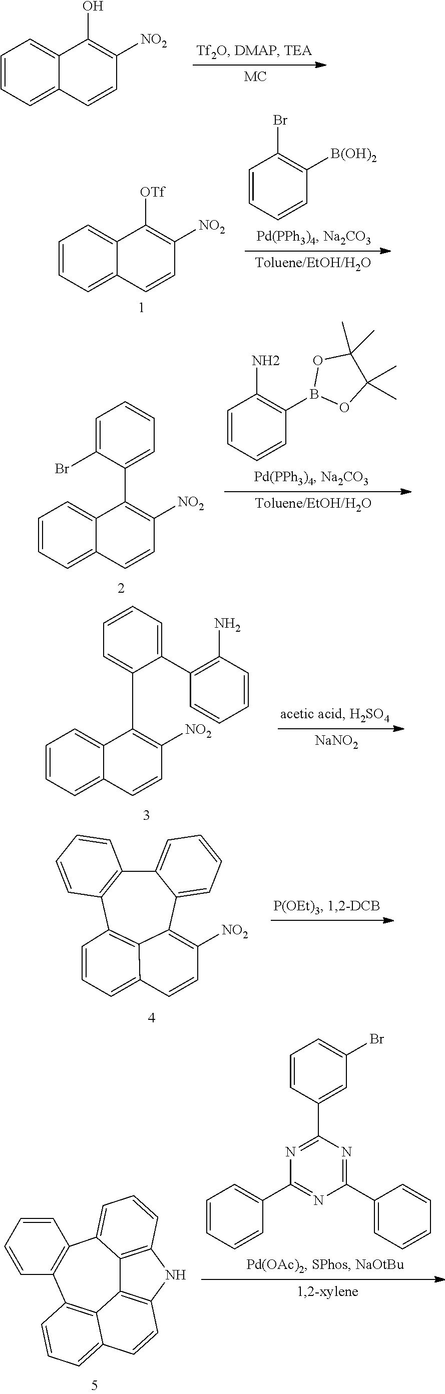

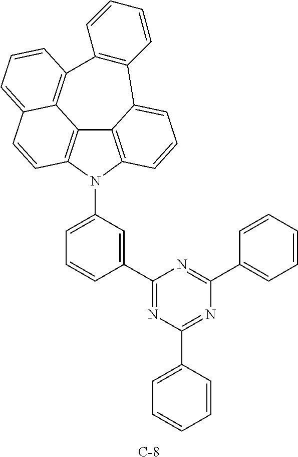

Synthesis of Compound 1

In a flask, 70 g of 2-nitro-1-naphthol (370 mmol), and 4.5 g of 4-dimethylaminopyridine (DMAP) (37 mmol) were dissolved in 1800 mL of methylene chloride (MC). 62 mL of triethylamine (TEA) (444 mmol) was added dropwise to the mixture at 0° C., and stirred for 20 minutes. 125.3 g of trifluoromethanesulfonic anhydride (Tf₂O) (444 mmol) was slowly added dropwise to the reaction mixture at the same temperature and stirred for 1 hour. After completion of the reaction, the organic layer was extracted with MC, and residual moisture was removed by using magnesium sulfate. Thereafter, the residue was dried and separated by column chromatography to obtain 96.2 g of compound 1 (yield: 81%).

Synthesis of Compound 2

In a flask, 96.2 g of compound 1 (299 mmol), 72.1 g of 2-bromophenylboronic acid (359 mmol), 17.3 g of tetrakis(triphenylphosphine)palladium(0) (15 mmol), and 79.3 g of sodium carbonate (749 mmol) were dissolved in 1400 mL of toluene, 350 mL of ethanol, and 350 mL of water, and the mixture was refluxed for 1 hour. After completion of the reaction, the organic layer was extracted with ethyl acetate, and residual moisture was removed by using magnesium sulfate. Thereafter, the residue was dried and separated by column chromatography to obtain 98 g of compound 2 (yield: 99%).

Synthesis of Compound 3

In a flask, 98 g of compound 2 (299 mmol), 78.5 g of 2-aminophenylboronic acid pinacolester (358 mmol), 17.2 g of tetrakis(triphenylphosphine)palladium(0) (15 mmol), and 103 g of potassium carbonate (747 mmol) were dissolved in 1300 mL of toluene, 350 mL of ethanol, and 350 mL of water, and the mixture was refluxed for 20 hours. After completion of the reaction, the organic layer was extracted with ethyl acetate, and residual moisture was removed by using magnesium sulfate. Thereafter, the residue was dried and separated by column chromatography to obtain 54 g of compound 3 (yield: 53%).

Synthesis of Compound 4

In a flask, 25 g of compound 3 (73 mmol) was dissolved in 250 mL of acetic acid and 25 mL of sulfuric acid. 6.5 g of sodium nitrite (95 mmol) was slowly added dropwise to the mixture at 0° C., and stirred for 40 minutes. After completion of the reaction, the reaction mixture was added dropwise into water and filtered to remove moisture. Thereafter, the residue was dried and separated by column chromatography to obtain 2 g of compound 4 (yield: 8.4%).

Synthesis of Compound 5

In a flask, 4.7 g of compound 4 (15 mmol) was dissolved in 48 mL of triethylphosphite and 48 mL of 1,2-dichlorobenzene, and the mixture was refluxed for 3 hours. After completion of the reaction, the organic layer was extracted with ethyl acetate after distillation under reduced pressure, and residual moisture was removed by using magnesium sulfate. Thereafter, the residue was dried and separated by column chromatography to obtain 2.7 g of compound 5 (yield: 63%).

Synthesis of Compound C-8

In a flask, 2.1 g of compound 5 (7 mmol), 3.1 g of 2-(3-bromophenyl)-4,6-diphenyl-1,3,5-triazine (8 mmol), 0.81 g of palladium(II) acetate (0.36 mmol), 0.3 g of 2-dicyclohexylphosphino-2′,6′-dimethoxybiphenyl (SPhos) (0.7 mmol), and 1.7 g of sodium tert-butoxide (NaOtBu) (18 mmol) were dissolved in 72 mL of 1,2-xylene, and the mixture was refluxed for 4 hours. After completion of the reaction, the organic layer was extracted with ethyl acetate after distillation under reduced pressure, and residual moisture was removed by using magnesium sulfate. Thereafter, the residue was dried and separated by column chromatography to obtain 2.5 g of compound C-8 (yield: 58%).

| Compound | MW | UV | PL | M.P. | Tg |
|---|---|---|---|---|---|
| C-8 | 598.71 | 308 nm | 495 nm | 285° C. | 132.37° C. |

### Example 2: Preparation of Compound C-301

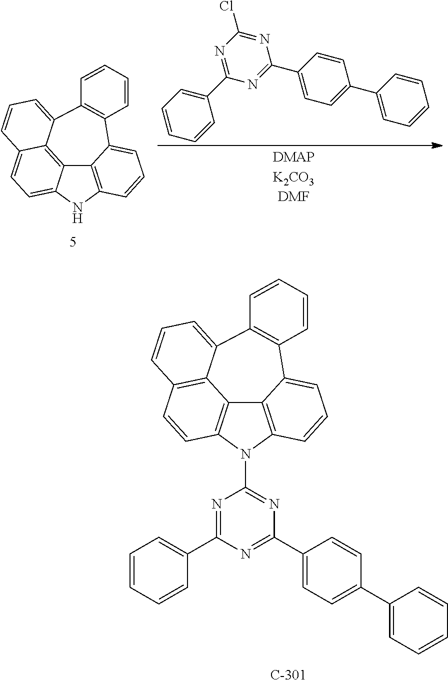

In a flask, 5.0 g of compound 5 (17 mmol), 7.08 g of 2-([1,1′-biphenyl]-4-yl)-4-chloro-6-phenyl-1,3,5-triazine (21 mmol), 105 mg of DMAP (0.858 mmol), and 7.1 g of potassium carbonate (51 mmol) were dissolved in 85 mL of dimethylformamide (DMF), and the mixture was refluxed for 3 hours. After completion of the reaction, the organic layer was extracted with ethyl acetate after distillation under reduced pressure, and residual moisture was removed by using magnesium sulfate. Thereafter, the residue was dried and separated by column chromatography to obtain 4.8 g of compound C-301 (yield: 47%).

¹H NMR (600 MHz, CDCl3) 9.09-9.07 (d, J=12 Hz, 1H), 8.93-8.91 (d, J=12 Hz, 1H), 8.74-8.73 (d, J=6 Hz, 2H), 8.71-8.69 (d, J=12 Hz, 2H), 7.80-7.75 (m, 6H), 7.73-7.69 (m, 3H), 7.64-7.57 (m, 3H), 7.52-7.38 (m, 8H)

| Compound | MW | Tg | M.P. |
|---|---|---|---|
| C-301 | 598.71 | 124.4° C. | 236° C. |

### Example 3: Preparation of Compound C-10

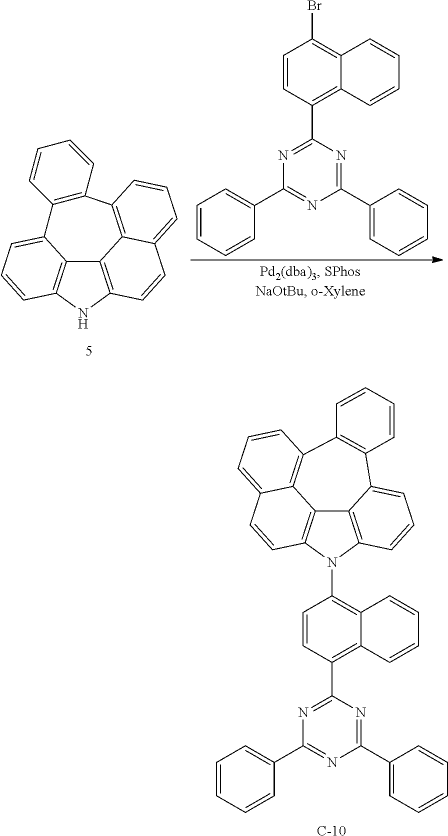

In a flask, 5.0 g of compound 5 (17 mmol), 11.28 g of 2-(4-bromonaphthalene-1-yl)-4,6-diphenyl-1,3,5-triazine) (21 mmol), 625 mg of tris(dibenzylideneacetone)dipalladium(0) (Pd₂(dba)₃) (0.686 mmol), 565 mg of SPhos (1 mmol), and 4.9 g of sodium tert-butoxide (51 mmol) were dissolved in 100 mL of o-xylene, and the mixture was refluxed for 3 hours. After completion of the reaction, the organic layer was extracted with ethyl acetate after distillation under reduced pressure, and residual moisture was removed by using magnesium sulfate. Thereafter, the residue was dried and separated by column chromatography to obtain 3.6 g of compound C-10 (yield: 32%).

¹H NMR (600 MHz, CDCl3) 9.25-9.24 (d, J=6 Hz, 1H), 8.85-8.83 (sd, J=12 Hz, 4H), 8.68-8.67 (d, J=6 Hz, 1H), 7.94-7.92 (m, 1H), 7.82-7.79 (m, 3H), 7.74-7.61 (m, 10H), 7.49-7.42 (m, 5H), 7.31-7.29 (t, J=6 Hz, 1H), 7.16-7.15 (d, J=6 Hz, 1H), 6.96-6.94 (d, J=12 Hz, 1H)

| Compound | MW | Tg | M.P. |
|---|---|---|---|
| C-10 | 648.7 | 159.5° C. | 176° C. |

### Example 4: Preparation of Compound C-7

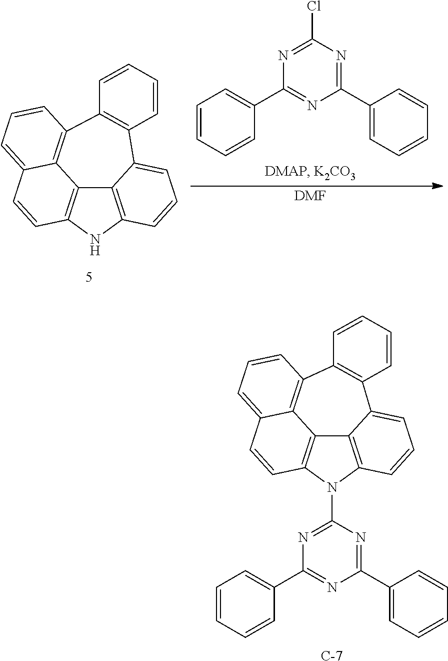

In a flask, 5 g of compound 5 (17.1 mmol), 5.5 g of 2-chloro-4,6-diphenyl-1,3,5-triazine (20.5 mmol), 0.1 g of DMAP (0.85 mmol), and 7.1 g of potassium carbonate (51.4 mmol) were dissolved in 85 mL of DMF, and the mixture was refluxed for 3 hours. After completion of the reaction, the reaction mixture was cooled, and methanol and water were added thereto and filtered. Thereafter, the residue was dried and separated by column chromatography to obtain 4.4 g of compound C-7 (yield: 49%).

¹H NMR (600 MHz, CDCl3) 9.13-9.11 (d, J=12 Hz, 1H), 8.97-8.95 (d, J=12 Hz, 1H), 8.75-8.73 (d, J=12 Hz, 4H), 7.83-7.75 (m, 5H), 7.64-7.59 (m, 6H), 7.54-7.51 (m, 3H), 7.48-7.45 (t, J=12 Hz, 3H), 7.40-7.39 (m, 2H)

| Compound | MW | Tg | M.P. |
|---|---|---|---|
| C-7 | 522.6 | 105° C. | 209° C. |

### Example 5: Preparation of Compound C-302

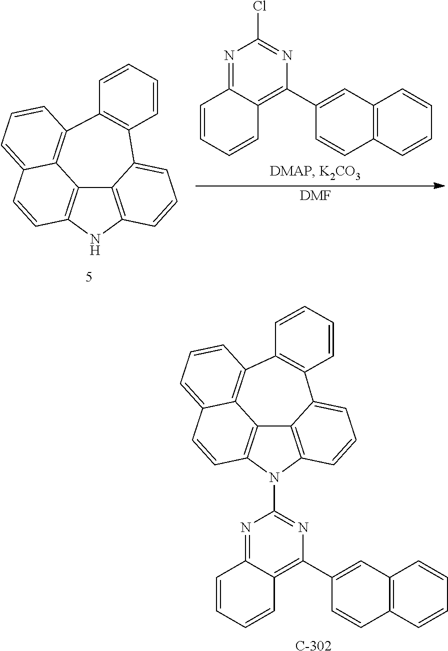

In a flask, 4.5 g of compound 5 (15.4 mmol), 5.4 g of 2-chloro-4-(naphthalene-2-yl)quinazoline (18.5 mmol), 0.09 g of DMAP (0.7 mmol), and 6.4 g of potassium carbonate (46.3 mmol) were dissolved in 77 mL of DMF, and the mixture was refluxed for 1.5 hours. After completion of the reaction, the residue was filtered, dried, and separated by column chromatography to obtain 7.5 g of compound C-302 (yield: 80%).

¹H NMR (600 MHz, CDCl3) 9.03-9.02 (d, J=6 Hz, 1H), 8.88-8.86 (d, J=12 Hz, 1H), 8.39 (s, 1H), 8.22-8.21 (d, J=6 Hz, 1H), 8.20-8.17 (d, J=18 Hz, 1H), 8.15-8.05 (m, 2H), 8.00-7.98 (t, J=6 Hz, 2H), 7.91-7.89 (m, 1H), 7.76-7.72 (m, 5H), 7.63-7.61 (m, 2H), 7.54-7.52 (m, 2H), 7.43-7.36 (m, 4H)

| Compound | MW | Tg | M.P. |
|---|---|---|---|
| C-302 | 545.65 | 120.6° C. | 257° C. |

### Example 6: Preparation of Compound C-9

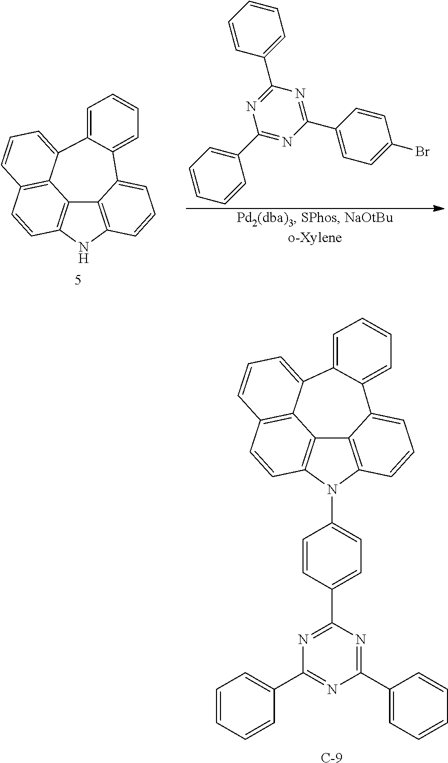

In a flask, 5.0 g of compound 5 (17.16 mmol), 6.6 g of 2-(4-bromophenyl)-4,6-diphenyl-1,3,5-triazine (17.16 mmol), 0.6 g of tris(dibenzylideneacetone)dipalladium(0) (0.686 mmol), 0.7 g of SPhos (1.176 mmol), and 4.0 g of sodium tert-butoxide (42.9 mmol) were dissolved in 90 mL of o-xylene, and the mixture was refluxed for 4 hours. After completion of the reaction, the organic layer was extracted with ethyl acetate after distillation under reduced pressure, and residual moisture was removed by using magnesium sulfate. Thereafter, the residue was dried and separated by column chromatography to obtain 6.2 g of compound C-9 (yield: 62%).

¹H NMR (600 MHz, CDCl3, δ) 9.06-9.05 (d, J=6.0 Hz, 2H), 8.85-8.83 (d, J=12 Hz, 4H), 7.90-7.89 (m, 1H), 7.82-7.78 (m, 4H), 7.74-7.72 (m, 2H), 7.66-7.58 (m, 8H), 7.45-7.43 (m, 3H), 7.42-7.39 (m, 2H)

| Compound | MW | Tg | M.P. |
|---|---|---|---|
| C-9 | 598.71 | 140.59° C. | 260° C. |

### Example 7: Preparation of Compound C-303

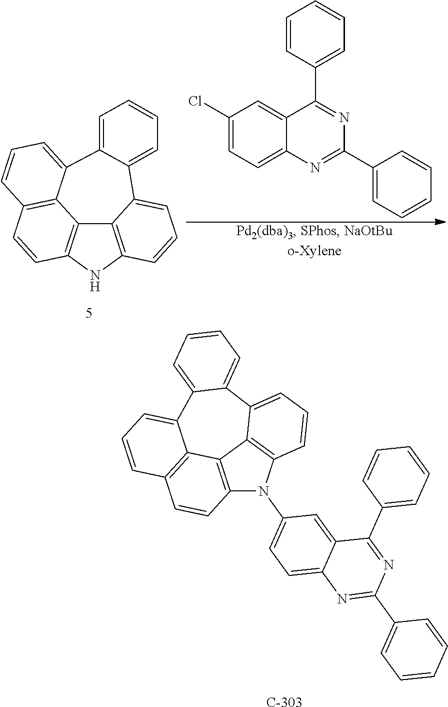

In a flask, 4.3 g of compound 5 (14.83 mmol), 4.7 g of 6-chloro-2,4-diphenylquinazoline (14.83 mmol), 0.5 g of Pd₂(dba)₃ (0.593 mmol), 0.6 g of SPhos (1.483 mmol), and 3.6 g of sodium ter-butoxide (37.07 mmol) were dissolved in 80 mL of o-xylene, and the mixture was refluxed for 4 hours. After completion of the reaction, the organic layer was extracted with ethyl acetate after distillation under reduced pressure, and residual moisture was removed by using magnesium sulfate. Thereafter, the residue was dried and separated by column chromatography to obtain 1.8 g of compound C-303 (yield: 21%).

¹H NMR (600 MHz, CDCl3, δ) 8.74-8.73 (d, J=6.0 Hz, 2H), 8.37-8.36 (d, J=6.0 Hz, 1H), 8.28-8.27 (d, J=6.0 Hz, 1H), 8.05-8.04 (d, J=6.0 Hz, 1H), 7.89-7.88 (d, J=6.0 Hz, 2H), 7.85-7.83 (m, 1H), 7.75-7.73 (d, J=12 Hz, 2H), 7.69-7.67 (m, 2H), 7.57-7.50 (m, 7H), 7.42-7.37 (m, 4H), 7.34-7.31 (m, 1H), 7.22-7.21 (m, 1H)

| Compound | MW | Tg | M.P. |
|---|---|---|---|
| C-303 | 571.67 | 140.16° C. | 189.3° C. |

### Example 8: Preparation of Compound C-307

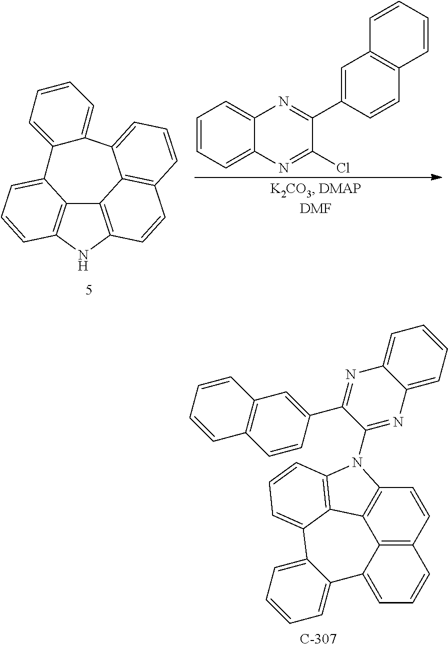

In a flask, 5.4 g of compound 5 (18.53 mmol), 4.5 g of 2-chloro-3-naphthylquinoxaline (15.44 mmol), 2.1 g of potassium carbonate (15.44 mmol), and 0.9 g of DMAP (7.72 mmol) were dissolved in 80 mL of DMF, and the mixture was refluxed for 4 hours. After completion of the reaction, the reaction mixture was cooled to room temperature, and distilled water was added thereto. The organic layer was extracted with MC, and the extracted organic layer dried with magnesium sulfate. Thereafter, the residue was distilled under reduced pressure and separated by column chromatography to obtain 2.3 g of compound C-307 (yield: 47%).

¹H NMR (600 MHz, CDCl3, δ) 8.36-8.34 (d, J=6.0 Hz, 1H), 8.23 (s, 1H), 8.17-8.16 (d, J=6.0 HZ, 1H), 7.90-7.86 (m, 3H), 7.73-7.71 (d, J=12 Hz, 1H), 7.68-7.63 (m, 4H), 7.50-7.48 (m, 2H), 7.40-7.35 (m, 6H), 7.32-7.24 (m, 2H)

| Compound | MW | Tg | M.P. |
|---|---|---|---|
| C-307 | 545.65 | 133° C. | 152° C. |

### Example 9: Preparation of Compound C-13

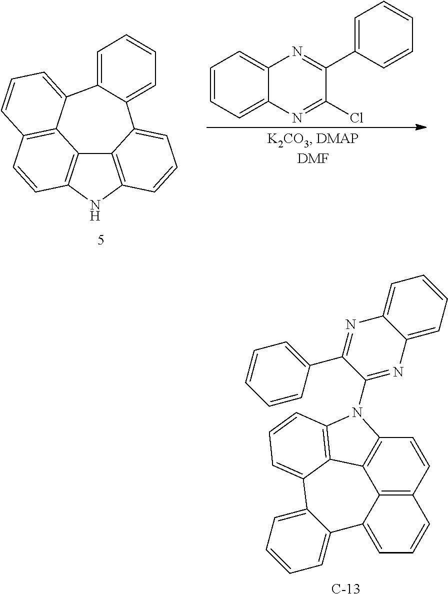

In a flask, 4.0 g of compound 5 (13.73 mmol), 4.0 g of 2-chloro-3-phenylquinoxaline (16.47 mmol), 3.8 g of potassium carbonate (27.46 mmol), and 0.84 g of DMAP (6.87 mmol), were dissolved in 68 mL of DMF, and the mixture was refluxed for 18 hours. After completion of the reaction, the reaction mixture was cooled to room temperature, and distilled water was added thereto. The organic layer was extracted with MC, and the extracted organic layer dried with magnesium sulfate. Thereafter, the residue was distilled under reduced pressure and separated by column chromatography to obtain 2.3 g of compound C-13 (yield: 33.8%).

¹H NMR (600 MHz, CDCl3, δ) 8.32-8.30 (m, 1H), 8.16-8.15 (m, 1H), 7.89-7.83 (m, 3H), 7.73 (d, J=7.38 Hz, 1H), 7.69-7.68 (m, 2H), 7.60-7.54 (m, 2H), 7.50 (d, J=9.00 Hz, 1H), 7.42-7.37 (m, 3H), 7.29-7.27 (m, 3H), 7.21-7.15 (m, 4H)

| Compound | MW | Tg | M.P. |
|---|---|---|---|
| C-13 | 495.59 | 124.88° C. | 154-164° C. |

### Example 10: Preparation of Compound C-304

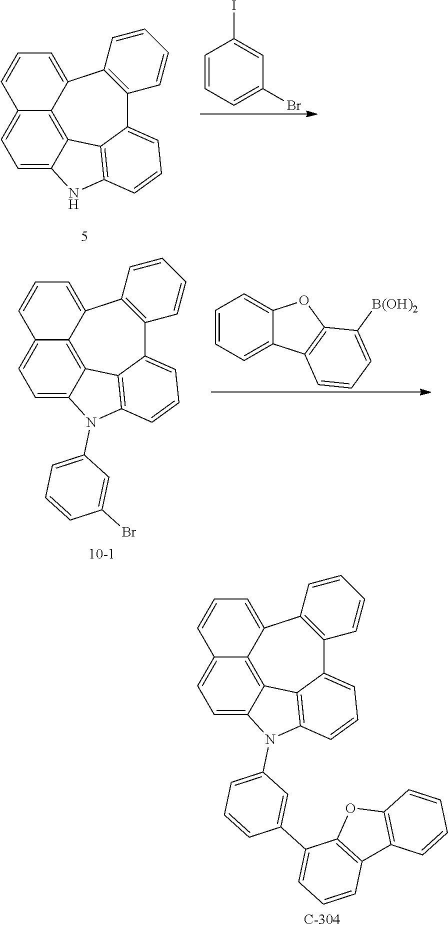

Synthesis of Compound 10-1

9 g of compound 5 (30.89 mmol), 10.6 g of 1-bromo-3-iodobenzene (61.78 mmol), 3 g of CuI (15.44 mmol), 1.8 g of EDA (30.89 mmol), and 16.4 g of K₃PO₄ (77.22 mmol) were added to 155 mL of toluene, and the mixture was stirred under reflux for 1 day. After completion of the reaction, the reaction mixture was cooled to room temperature, and then the resultant solid was filtered under reduced pressure. The solid was dissolved in CHCl₃, and the mixture was separated by column chromatography with MC/Hex to obtain 10 g of compound 10-1 (yield: 75%).

Synthesis of Compound C-304

5.7 g of compound 10-1 (12.77 mmol), 2.98 g of 4-dibenzofuranboronic acid (14.05 mmol), 0.73 g of Pd(PPh₃)₄ (0.638 mmol), and 3.5 g of K₂CO₃ (25.54 mmol) were added to 50 mL of toluene, 13 mL of EtOH, and 13 mL of purified water, and the mixture was stirred under reflux for 2 hours. After completion of the reaction, the reaction mixture was cooled to room temperature, and then the resultant solid was filtered under reduced pressure. The solid was dissolved in CHCl₃, and the mixture was separated by column chromatography with MC/Hex to obtain 2.9 g of compound C-304 (yield: 43%).

¹H NMR (600 MHz, DMSO-d6, δ) 8.232-8.206 (m, 3H), 8.111-8.098 (d, 1H), 7.962-7.946 (m, 1H), 7.929-7.903 (m, 3H), 7.896-7.882 (d, 1H), 7.806-7.802 (d, 2H), 7.783-7.759 (t, 2H), 7.738-7.723 (d, 1H), 7.635-7.620 (m, 1H), 7.581-7.548 (m, 2H), 7.513-7.440 (m, 6H)

| Compound | MW | Tg | M.P. |
|---|---|---|---|
| C-304 | 533.6 | 119° C. | 208° C. |

### Example 11: Preparation of Compound C-306

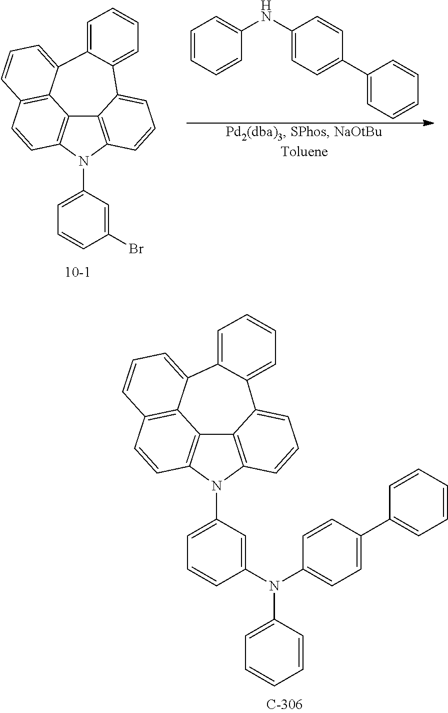 [SMILES: Brc1cccc(-n2c3cccc4c3c3c5c(cccc5ccc32)-c2ccccc2-4)c1 ; c1ccc(Nc2ccc(-c3ccccc3)cc2)cc1 ; "Pd2(dba)3, SPhos, NaOtBuToluene" ; c1ccc(-c2ccc(N(c3ccccc3)c3cccc(-n4c5cccc6c5c5c7c(cccc7ccc54)-c4ccccc4-6)c3)cc2)cc1]

In a flask, 5.0 g of compound 10-1 (11.2 mmol), 3.0 g of N-phenyl-[1,1′-biphenyl]-4-amine (12.3 mmol), 0.51 g of Pd₂(dba)₃ (0.56 mmol), 0.46 g of SPhos (1.12 mmol), and 2.7 g of sodium tert-butoxide (28 mmol) were added to 60 mL of toluene, and the mixture was refluxed for 4 hours. After completion of the reaction, the organic layer was extracted with ethyl acetate after distillation under reduced pressure, and residual moisture was removed by using magnesium sulfate. Thereafter, the residue was dried and separated by column chromatography to obtain 2.3 g of compound C-306 (yield: 34%).

¹H NMR (600 MHz, DMSO-d6, δ) 7.896-7.880 (m, 1H), 7.863-7.850 (d, 1H), 7.805-7.790 (d, 1H), 7.758-7.745 (d, 1H), 7.733-7.720 (d, 1H), 7.669-7.650 (m, 2H), 7.640-7.627 (d, 1H), 7.604-7.566 (m, 2H), 7.522-7.507 (d, 1H), 7.447-7.384 (m, 7H), 7.373-7.347 (t, 1H), 7.335-7.311 (t, 1H), 7.269-7.237 (m, 6H), 7.175-7.156 (d, 1H) 7.147-7.122 (t, 1H), 7.069-7.062 (t, 1H)

| Compound | MW | Tg | M.P. |
|---|---|---|---|
| C-306 | 610.8 | 114° C. | 132° C. |

### Example 12: Preparation of Compound C-333

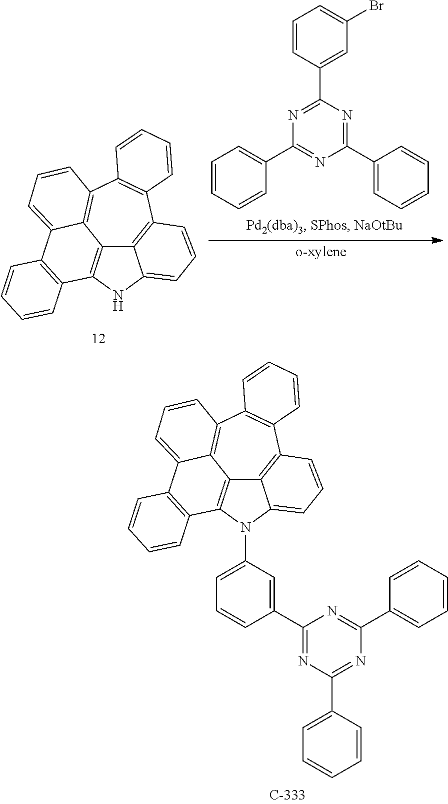

In a flask, 2.6 g of compound 12 (7.6 mmol), 2.95 g of 2-(3-bromophenyl)-4,6-diphenyl-1,3,5-triazine (7.6 mmol), 0.27 g of tris(dibenzylideneacetone)dipalladium(0) (0.3 mmol), 0.3 g of 2-dicyclohexylphosphino-2′,6′-dimethoxybiphenyl (0.7 mmol), and 1.8 g of sodium tert-butoxide (19 mmol) were dissolved in 50 mL of o-xylene, and the mixture was refluxed for 12 hours. After completion of the reaction, the organic layer was extracted with ethyl acetate after distillation under reduced pressure, and residual moisture was removed by using magnesium sulfate. Thereafter, the residue was dried and separated by column chromatography to obtain 1.9 g of compound C-333 (yield: 38%).

¹H NMR (600 MHz, DMSO-d6, δ) 9.086-9.072 (d, 1H), 8.887-8.882 (t, 1H), 8.821-8.807 (d, 1H), 8.714-8.699 (d, 4H), 8.676-8.663 (d, 1H), 8.014-7.988 (t, 1H), 7.883-7.833 (m, 3H), 7.781-7.768 (d, 1H), 7.691-7.665 (t, 2H), 7.640-7.575 (m, 6H), 7.540-7.485 (m, 3H), 7.399-7.343 (m, 3H), 6.982-6.968 (d, 1H)

| Compound | MW | M.P. | Tg |
|---|---|---|---|
| C-333 | 648.77 | 195° C. | 165° C. |

### Example 13: Preparation of Compound C-372

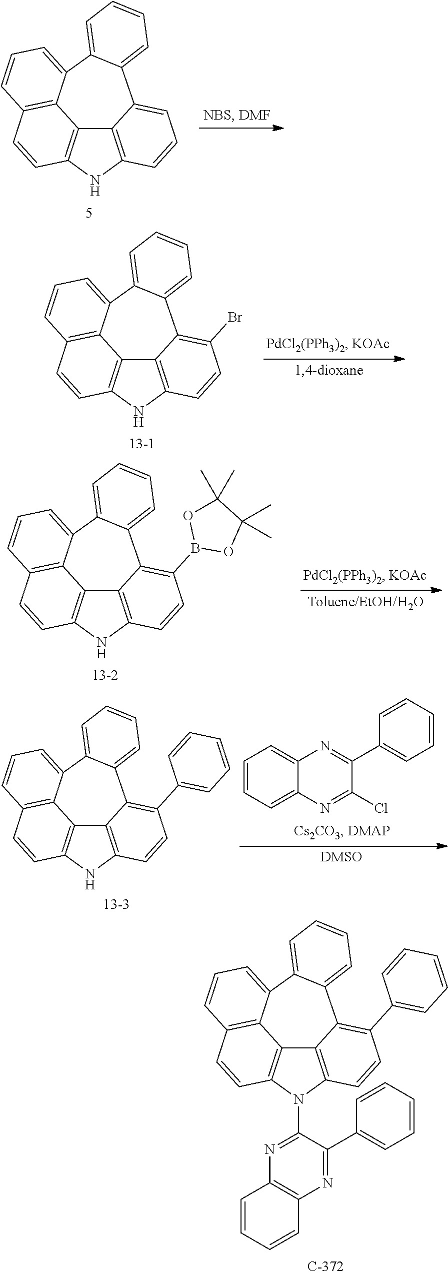

Synthesis of Compound 13-1

In a flask, 70 g of compound 5 (240 mol) and 40.6 g of N-bromosuccinimide (NBS) (255 mmol) were dissolved in 1200 mL of dimethylformamide, and the mixture was stirred at 0° C. for 3 hours. After completion of the reaction, the organic layer was extracted with ethyl acetate, and residual moisture was removed by using magnesium sulfate. Thereafter, the residue was dried and separated by column chromatography to obtain 68 g of compound 13-1 (yield: 76%).

Synthesis of Compound 13-2

In a flask, 47.3 g of compound 13-1 (127 mmol). 42 g of bis(pinacolato)diboron (166 mmol), 4.5 g of bis(triphenylphosphine)palladium(II) dichloride (PdCl₂(PPh₃)₂) (6.4 mmol), and 25 g of potassium acetate (255 mmol) were dissolved in 635 mL of 1,4-dioxane, and the mixture was refluxed for 4 hours. After completion of the reaction, the organic layer was extracted with ethyl acetate after distillation under reduced pressure, and residual moisture was removed by using magnesium sulfate. Thereafter, the residue was dried and separated by column chromatography to obtain 31.5 g of compound 13-2 (yield: 59%).

Synthesis of Compound 13-3

In a flask, 4.5 g of compound 13-2 (10.7 mmol), 1.9 g of 1-bromobenzene (11.85 mmol), 0.63 g of tetrakis(triphenylphosphine)palladium(0) (0.54 mmol), and 3.7 g of potassium carbonate (26.95 mmol) were dissolved in 54 mL of toluene, 13 mL of ethanol, and 13 mL of water, and the mixture was refluxed for 12 hours. After completion of the reaction, the organic layer was extracted with ethyl acetate, and residual moisture was removed by using magnesium sulfate. Thereafter, the residue was dried and separated by column chromatography to obtain 2.2 g of compound 13-3 (yield: 56%).

Synthesis of Compound C-372

In a flask, 2.2 g of compound 13-3 (5.9 mmol), 1.58 g of 2-chloro-3-phenylquinoxaline (6.57 mmol), 3.89 g of cesium carbonate (11.96 mmol), and 0.36 g of 4-dimethylaminopyridine (2.99 mmol) were dissolved in 30 mL of dimethyl sulfoxide (DMSO), and the mixture was stirred at 100° C. for 4 hours. After completion of the reaction, the reaction mixture was cooled to room temperature, and distilled water was added thereto. The organic layer was extracted with ethyl acetate, and residual moisture was removed by using magnesium sulfate. Thereafter, the residue was dried and separated by column chromatography to obtain 2.9 g of compound C-372 (yield: 85%).

| Compound | MW | M.P. | Tg |
|---|---|---|---|
| C-372 | 571.68 | 210° C. | 167° C. |

### Example 14: Preparation of Compound C-334

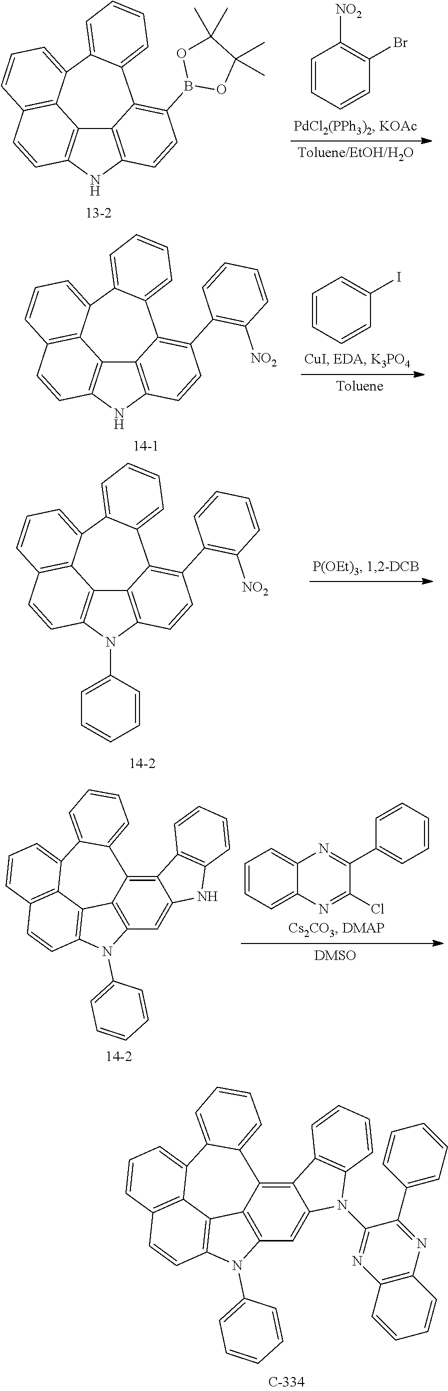

Synthesis of Compound 14-1

In a flask, 27 g of compound 13-2 (64.7 mmol), 14.4 g of 1-bromo-2-nitrobenzene (71.2 mmol), 3.7 g of tetrakis(triphenylphosphine)palladium(0) (3.2 mmol), and 22.4 g of potassium carbonate (162 mmol) were dissolved in 320 mL of toluene, 80 mL of ethanol, and 80 mL of water, and the mixture was refluxed for 12 hours. After completion of the reaction, the organic layer was extracted with ethyl acetate, and residual moisture was removed by using magnesium sulfate. Thereafter, the residue was dried and separated by column chromatography to obtain 26.7 g of compound 14-1 (yield: 100%).

Synthesis of Compound 14-2

In a flask, 26.7 g of compound 14-1 (64.7 mmol), 18.5 g of copper(I) iodide (97 mmol), and 27.4 g of tripotassium phosphate (129 mmol) were dissolved in 18 mL of 1-iodobenzene (162 mmol), 13 mL of ethylenediamine (EDA) (194 mmol), and 325 mL of toluene, and the mixture was refluxed for 2 hours. After completion of the reaction, the organic layer was extracted with ethyl acetate, and residual moisture was removed by using magnesium sulfate. Thereafter, the residue was dried and separated by column chromatography to obtain 15.7 g of compound 14-2 (yield: 49%).

Synthesis of Compound 14-3

In a flask, 13.1 g of compound 14-2 (26.8 mmol) was added to 180 mL of triethyl phosphite and 180 mL of 1,2-dichlorobenzene, and the mixture was stirred at 200° C. for 2 hours. After completion of the reaction, the solvent was removed by distillation under reduced pressure, and the reaction mixture was cooled to room temperature, and then hexane was added to obtain a solid. After removing solvent from the resultant solid through a filter, the residue was separated by column chromatography to obtain 0.71 g of compound 14-3 (yield: 5.8%).

Synthesis of Compound C-334

In a flask, 0.71 g of compound 14-3 (1.56 mmol). 0.45 g of 2-chloro-3-phenylquinoxaline (1.87 mmol), 1.01 g of cesium carbonate (3.12 mmol), and 0.095 g of 4-dimethylaminopyridine (0.78 mmol) were dissolved in 30 mL of dimethyl sulfoxide, and the mixture was stirred at 100° C. for 4 hours. After completion of the reaction, the reaction mixture was cooled to room temperature, and distilled water and methanol were added thereto. After removing solvent from the resultant solid through a filter, the residue was separated by column chromatography to obtain 0.50 g of compound C-334 (yield: 49%).

¹H NMR (600 MHz, CDCl₃, δ) 8.333-8.248 (m, 3H), 8.192-8.099 (m, 1H), 7.911-7.820 (m, 3H), 7.767-7.754 (d, 1H), 7.613-7.526 (m, 5H), 7.488-7.410 (m, 4H), 7.395-7.347 (m, 3H), 7.329-7.296 (m, 2H), 7.230-7.205 (m, 2H), 7.179-7.153 (m, 1H), 7.130-7.075 (m, 1H), 7.056-7.030 (m, 1H), 3.874-6.688 (m, 1H)

| Compound | MW | M.P. |
|---|---|---|
| C-334 | 660.78 | 290° C. |

### Example 15: Preparation of Compound C-197

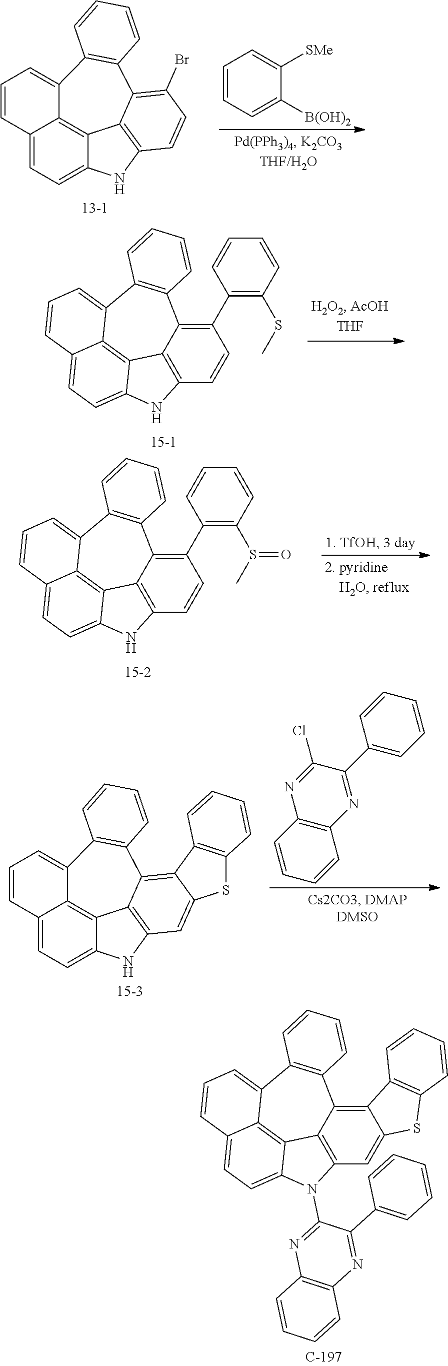

Synthesis of Compound 15-1

In a flask, 40 g of compound 13-1 (108 mmol), 25.4 g of (2-methylthio)phenylboronic acid (153.5 mmol), 6.26 g of tetrakis(triphenylphosphine)palladium(0) (5.40 mmol), and 26.3 g of potassium carbonate (272.0 mmol) were dissolved in 536 mL of tetrahydrofuran and 134 mL of distilled water, and the mixture was refluxed at 100° C. for 18 hours. After completion of the reaction, the organic layer was extracted with ethyl acetate, and residual moisture was removed by using magnesium sulfate. Thereafter, the residue was dried and separated by column chromatography to obtain 40 g of compound 15-1 (89%).

Synthesis of Compound 15-2

In a flask, 40 g of compound 15-1 (96.8 mmol) was dissolved in 400 mL of tetrahydrofuran, 200 mL of acetic acid, and 12.6 mL of 34.5% hydrogen peroxide (145.2 mmol), and the mixture was stirred at room temperature for 20 hours. After completion of the reaction, the mixture is concentrated, and the organic layer was extracted with methylene chloride and aqueous sodium hydrogen carbonate solution, and then residual moisture was removed by using magnesium sulfate. Thereafter, the residue was dried to obtain 42 g of compound 15-2 (yield: 100%).

Synthesis of Compound 15-3

In a flask, 42 g of compound 15-2 (96.4 mmol) was dissolved in 190 mL of trifluoromethanesulfonic acid, and the mixture was stirred at room temperature for 3 days. After completion of the reaction, 50 mL of pyridine and 1M NaOH aqueous solution were added to the mixture at 0° C. to adjust the pH to 7 to 8, and the mixture was refluxed at 100° C. for 1 hour. After removing solvent through a filter, the resultant solid was separated by column chromatography to obtain 9.1 g of compound 15-3 (yield: 24%).

Synthesis of Compound C-197

In a flask, 4 g of compound 15-3 (10.1 mmol), 3 g of 2-chloro-3-phenylquinoxaline (12.1 mmol), 6.6 g of cesium carbonate (20.2 mmol), and 0.62 g of 4-dimethylaminopyridine (5.1 mmol) were dissolved in 50 mL of dimethyl sulfoxide, and the mixture was stirred at 100° C. for 4 hours. After completion of the reaction, the reaction mixture was cooled to room temperature, and distilled water and methanol were added thereto. After removing solvent from the resultant solid through a filter, the residue was separated by column chromatography to obtain 4.8 g of compound C-197 (yield: 79%).

¹H NMR (600 MHz, CDCl₃, δ) 8.337-8.310 (m, 1H), 8.247-8.202 (m, 1H), 8.196-8.151 (m, 1H), 7.957-7.945 (m, 1H), 7.928 (s. 1H), 7.912-7.837 (m, 3H), 7.794-7.728 (m, 3H), 7.685-7.672 (d, 1H), 7.531-7.498 (m, 1H), 7.469-7.414 (m, 2H), 7.348-7.300 (m, 2H), 7.262-7.173 (m, 4H), 7.102-7.087 (d, 1H), 7.036-6.955 (m, 1H)

| Compound | MW | M.P. | Tg |
|---|---|---|---|
| C-197 | 601.73 | 317° C. | 194° C. |

### Example 16: Preparation of Compound C-339

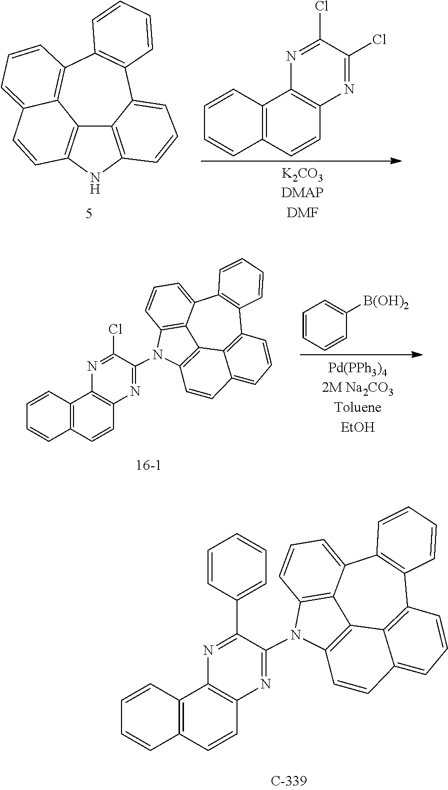

Synthesis of Compound 16-1

15.6 g of compound 5 (53.5 mmol), 20 g of 2,3-dichlorobenzo[f]quinoxaline (80.3 mmol), 15 g of potassium carbonate (107.0 mmol), and 3.3 g of DMAP (26.7 mmol) were added to 270 mL of N,N-dimethylformamide, and the mixture was stirred at 150° C. for 4 hours. After completion of the reaction, the reaction mixture was cooled to room temperature, and the solvent was removed by a rotary evaporator. The residue was separated by column chromatography to obtain 2.2 g of compound 16-1 (yield: 8%).

Synthesis of Compound C-339

In a reaction vessel, 2.2 g of compound 16-1 (4.4 mmol), 800 mg of phenylboronic acid (6.6 mmol), 250 mg of tetrakis(triphenylphosphine)palladium(0) (0.2 mmol), and 1.2 g of sodium carbonate (10.9 mmol) were added to 20 mL of toluene. 5.5 mL of distilled water, and 5 mL of ethanol, and the mixture was refluxed at 130° C. for 3 hours. After completion of the reaction, the reaction mixture was cooled to room temperature, and the solvent was removed by a rotary evaporator. The residue was separated by column chromatography to obtain 1.8 g of compound C-339 (yield: 76%).

¹H NMR (600 MHz, CDCl₃, δ) 9.403-9.390 (d, 1H), 8.119-8.105 (d, 1H), 8.012-7.997 (d, 1H), 7.994-7.979 (d, 1H), 7.867-7.851 (m, 1H), 7.847-7.822 (td, 1H), 7.815-7.788 (td, 1H), 7.734-7.722 (d, 1H), 7.686-7.656 (m, 4H), 7.600-7.585 (m, 1H), 7.509-7.494 (d, 1H), 7.404-7.389 (m, 2H), 7.385-7.359 (t, 1H), 7.295-7.264 (m, 2H), 7.250-7.219 (t, 1H), 7.208-7.182 (m, 3H).

| Compound | MW | M.P. | Tg |
|---|---|---|---|
| C-339 | 545.65 | 247° C. | 148° C. |

### Example 17: Preparation of Compound C-338

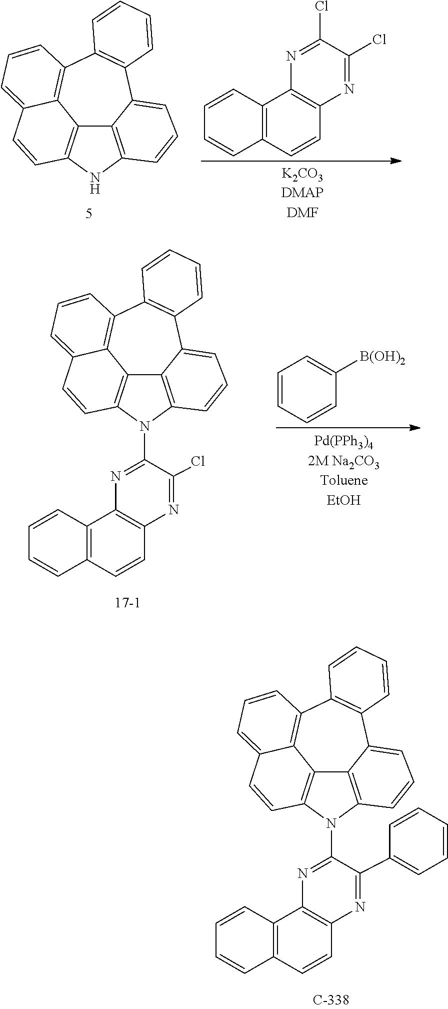

Synthesis of Compound 17-1

15.6 g of compound 5 (53.5 mmol), 20 g of 2,3-dichlorobenzo[f]quinoxaline (80.3 mmol), 15 g of potassium carbonate (107.0 mmol), and 3.3 g of DMAP (26.7 mmol) were added to 270 mL of N,N-dimethylformamide, and the mixture was stirred at 150° C. for 4 hours. After completion of the reaction, the reaction mixture was cooled to room temperature, and the solvent was removed by a rotary evaporator. The residue was separated by column chromatography to obtain 2.8 g of compound 17-1 (yield: 10%).

Synthesis of Compound C-338

In a reaction vessel, 2.7 g of compound 17-1 (5.4 mmol), 1 g of phenylboronic acid (8.0 mmol), 310 mg of tetrakis(triphenylphosphine)palladium(0) (0.3 mmol), and 1.4 g of sodium carbonate (13.4 mmol) were added to 28 mL of toluene, 6.7 mL of distilled water, and 7 mL of ethanol, and the mixture was stirred at 130° C. for 3 hours. After completion of the reaction, the reaction mixture was cooled to room temperature, and the solvent was removed by a rotary evaporator. The residue was separated by column chromatography to obtain 2.5 g of compound C-338 (yield: 86%).

¹H NMR (600 MHz, CDCl₃, δ) 9.119-9.106 (d, 1H), 8.160-8.125 (dd, 2H), 8.001-7.988 (d, 1H), 7.878-7.862 (m, 1H), 7.782-7.755 (td, 1H), 7.748-7.726 (m, 2H), 7.709-7.685 (t, 2H), 7.623-7.594 (m, 3H), 7.518-7.503 (d, 1H), 7.418-7.371 (m, 4H), 7.305-7.271 (m, 2H), 7.200-7.182 (m, 3H).

| Compound | MW | M.P. | Tg |
|---|---|---|---|
| C-338 | 545.65 | 299° C. | 149° C. |

### Example 18: Preparation of Compound C-379

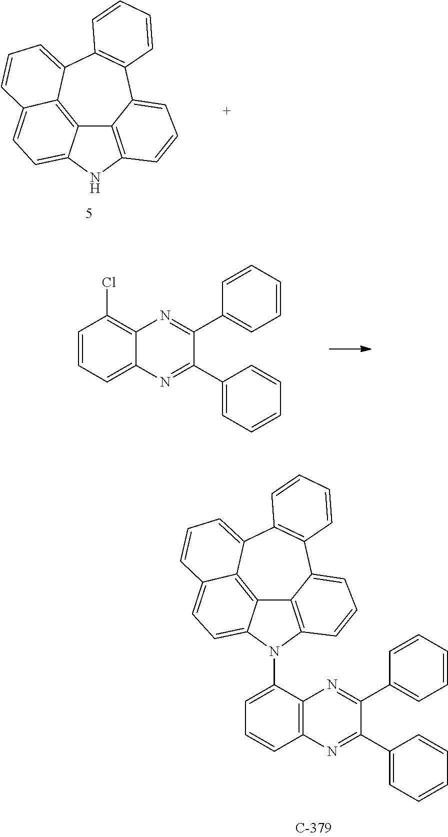 [SMILES: c1ccc2c(c1)-c1cccc3ccc4[nH]c5cccc-2c5c4c13 ; Clc1cccc2nc(-c3ccccc3)c(-c3ccccc3)nc12 ; c1ccc(-c2nc3cccc(-n4c5cccc6c5c5c7c(cccc7ccc54)-c4ccccc4-6)c3nc2-c2ccccc2)cc1]

In a flask, 4.0 g of compound 5 (13.73 mmol), 5.2 g of 5-chloro-2,3-diphenylquinoxaline (16.47 mmol). 0.629 g of tris(dibenzylideneacetone)dipalladium(0) (0.686 mmol), 0.564 mg of 2-dicyclohexylphosphino-2′,6′-dimethoxybiphenyl (1.0 mmol), and 3.9 g of sodium tert-butoxide (41 mmol) were dissolved in 80 mL of 1,2-dimethylbenzene, and the mixture was refluxed for 4 hours. After completion of the reaction, the reaction mixture was cooled to room temperature, and distilled water was added thereto. The organic layer was extracted with MC, and residual moisture was removed by using magnesium sulfate. Thereafter, the residue was distilled under reduced pressure and separated by column chromatography to obtain 2.8 g of compound C-379 (yield: 35.67%).

¹H NMR (600 MHz, CDCl3, δ) 8.323-8.307 (d, J=7.2 Hz, 1H), 7.947-7.935 (m, 2H), 7.883-7.867 (m, 1H), 7.762-7.749 (d, J=7.2 Hz, 2H), 7.686-7.673 (d, J=7.8 Hz, 1H), 7.633-7.603 (m, 2H), 7.568-7.556 (d, J=7.2 Hz, 2H), 7.404-7.337 (m, 6H), 7.307-7.281 (t, J=7.8 Hz, 1H), 7.195-7.281 (m, 3H), 7.144-7.110 (t, J=7.2 HZ, 1H), 7.087-7.074 (d, J=7.8 HZ, 1H), 7.010-6.990 (m, 2H)

| Compound | MW | Tg | M.P. |
|---|---|---|---|
| C-379 | 571.67 | 135.60° C. | 142° C. |

### Example 19: Preparation of Compound C-389

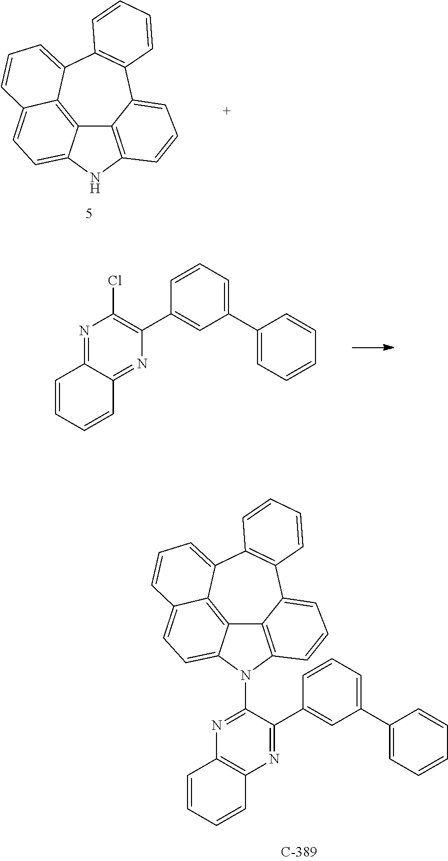 [SMILES: c1ccc2c(c1)-c1cccc3ccc4[nH]c5cccc-2c5c4c13 ; Clc1nc2ccccc2nc1-c1cccc(-c2ccccc2)c1 ; c1ccc(-c2cccc(-c3nc4ccccc4nc3-n3c4cccc5c4c4c6c(cccc6ccc43)-c3ccccc3-5)c2)cc1]

In a flask, 6.0 g of compound 5 (21 mmol), 7.8 g of 2-([1,1′-biphenyl]-3-yl)-3-chloroquinoxaline (25 mmol), 8.5 g of potassium carbonate (62 mmol), and 0.126 g of 4-dimethylaminopyridine (1 mmol) were dissolved in 100 mL of dimethylformamide, and the mixture was refluxed for 4 hours. After completion of the reaction, the reaction mixture was cooled to room temperature, and distilled water was added thereto. The organic layer was extracted with MC, and dried with magnesium sulfate. Thereafter, the residue was distilled under reduced pressure and separated by column chromatography to obtain 8.8 g of compound C-389 (yield: 74%).

¹H NMR (600 MHz, CDCl3, δ) 8.338-8.325 (d, J=7.8 HZ, 1H), 8.228-8.212 (d, J=8.7 HZ, 1H), 7.907-7.877 (m, 3H), 7.783-7.758 (m, 2H), 7.686-7.683 (d, J=7.8 Hz, 2H), 7.630-7.590 (m, 1H), 7.523-7.508 (d, J=9 Hz, 2H), 7.447-7.390 (m, 3H), 7.341-7.332 (m, 2H), 7.284-7.236 (m, 3H), 7.205 (s, 1H), 7.088-7.066 (m, 1H), 7.016-7.002 (d, J=7.8 Hz, 2H), 6.903-6.877 (m, 2H

| Compound | MW | Tg | M.P. |
|---|---|---|---|
| C-389 | 571.67 | 120.06° C. | 202° C. |

### Example 20: Preparation of Compound C-395

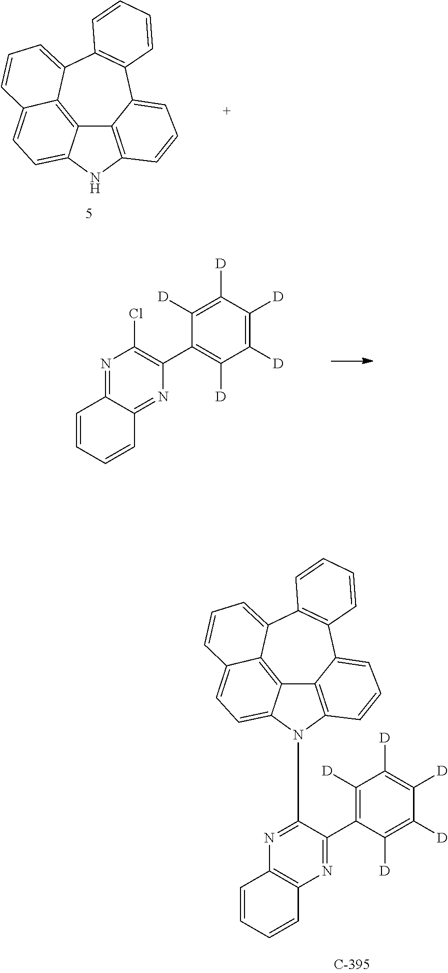 [SMILES: c1ccc2c(c1)-c1cccc3ccc4[nH]c5cccc-2c5c4c13 ; [2H]c1c([2H])c([2H])c(-c2nc3ccccc3nc2Cl)c([2H])c1[2H] ; [2H]c1c([2H])c([2H])c(-c2nc3ccccc3nc2-n2c3cccc4c3c3c5c(cccc5ccc32)-c2ccccc2-4)c([2H])c1[2H]]

In a flask, 7.9 g of compound 5 (27 mmol), 7.9 g of 2-chloro-3-(phenyl-D5)quinoxaline (33 mmol), 11.24 g of potassium carbonate (81 mmol), and 0.166 g of 4-dimethylaminopyridine (1 mmol) were dissolved in 135 mL of dimethylformamide, and the mixture was refluxed for 4 hours. After completion of the reaction, the reaction mixture was cooled to room temperature, and distilled water was added thereto. The organic layer was extracted with MC, and dried with magnesium sulfate. Thereafter, the residue was distilled under reduced pressure and separated by column chromatography to obtain 3.2 g of compound C-395 (yield: 23.7%).

¹H NMR (600 MHz, CDCl3, δ) 8.318-8.305 (d, J=7.8 Hz, 1H), 8.164-8.151 (d, J=7.8 Hz, 1H), 7.892-7.834 (m, 3H), 7.740-7.728 (d, J=7.2 Hz, 1H), 7.691-7.679 (d, J=7.2 Hz, 2H), 7.603-7.587 (m, 1H), 7.508-7.493 (d, J=9 Hz, 1H), 7.413-7.370 (m, 3H), 7.291-7.250 (m, 2H), 7.212-7.197 (d, J=9 Hz 1H)

| Compound | MW | Tg | M.P. |
|---|---|---|---|
| C-395 | 500.62 | 127° C. | 158° C. |

### Example 21: Preparation of Compound C-380

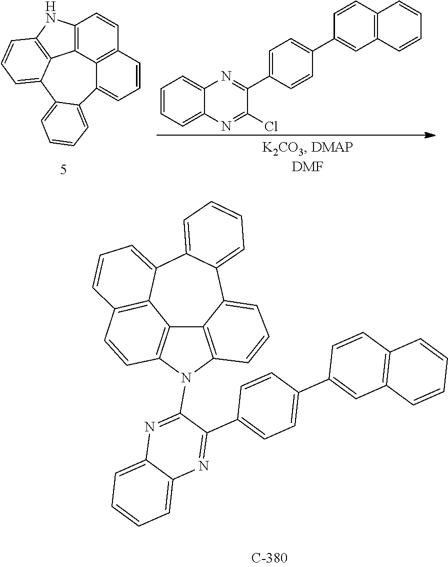

In a flask, 10 g of compound 5 (28.82 mmol), 7.0 g of 2-chloro-3-(4-(naphthalene-2-yl)phenyl)quinoxaline (24.02 mmol), 1.5 g of 4-dimethylaminopyridine (12.01 mmol), and 3.3 g of potassium carbonate (24.02 mmol) were dissolved in 130 mL of dimethylformamide, and the mixture was refluxed for 3 hours. After completion of the reaction, the organic layer was extracted with ethyl acetate after distillation under reduced pressure, and residual moisture was removed by using magnesium sulfate. Thereafter, the residue was dried and separated by column chromatography to obtain 8.8 g of compound C-380 (yield: 59%).

¹H NMR (600 MHz, CDCl3, δ) 8.33-8.32 (d, J=6.0 Hz, 1H), 8.16-8.15 (d, J=6.0 Hz, 1H), 7.88-7.84 (m, 4H), 7.80-7.77 (m, 3H), 7.74-7.73 (d, J=6.0 Hz, 1H), 7.69-7.66 (m, 4H), 7.57-7.56 (m, 2H), 7.53-7.50 (m, 3H), 7.43-7.37 (m, 5H), 7.32-7.23 (m, 3H)

| Compound | MW | Tg | M.P. |
|---|---|---|---|
| C-380 | 621.74 | 145.6° C. | 262.7° C. |

### Example 22: Preparation of Compound C-394

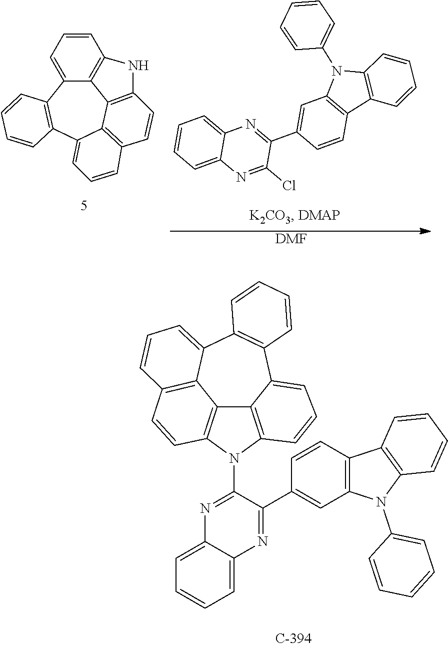

In a flask, 6 g of compound 5 (20.59 mmol), 9.1 g of 2-(3-chloroquinoxalin-2-yl)-9-phenyl-9H-carbazole (22.65 mmol), 1.2 g of 4-dimethylaminopyridine (10.29 mmol), and 2.8 g of potassium carbonate (20.59 mmol) were dissolved in 100 mL of dimethylformamide, and the mixture was refluxed for 3 hours. After completion of the reaction, the organic layer was extracted with ethyl acetate after distillation under reduced pressure, and residual moisture was removed by using magnesium sulfate. Thereafter, the residue was dried and separated by column chromatography to obtain 9.6 g of compound C-394 (yield: 70%).

¹H NMR (600 MHz, CDCl3, δ) 8.31-8.30 (d, J=6.0 Hz, 1H), 8.13-8.11 (d, J=12.0 Hz, 1H), 8.04-8.03 (d, J=6.0 Hz, 1H), 7.94-7.93 (d, J=6.0 Hz, 1H), 7.86-7.81 (m, 3H), 7.74-7.73 (d, J=6.0 Hz, 1H), 7.65-7.63 (d, J=12.0 Hz, 2H), 7.61-7.60 (m, 1H), 7.44-7.36 (m, 4H), 7.30-7.28 (m, 1H), 7.23-7.15 (m, 6H), 6.98-6.93 (m, 3H), 6.88-6.87 (m, 2H).

| Compound | MW | Tg | M.P. |
|---|---|---|---|
| C-394 | 660.78 | 154.09° C. | 290.5° C. |

### Example 23: Preparation of Compound C-346

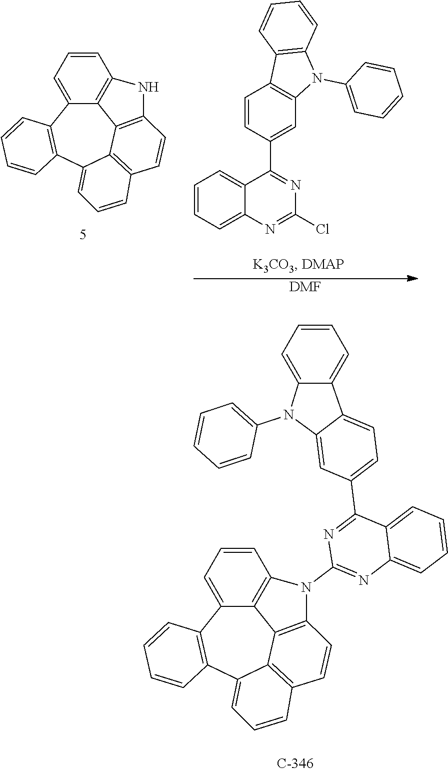

In a flask, 6.0 g of compound 5 (20.59 mmol), 9.1 g of 2-(2-chloroquinazolin-4-yl)-9-phenyl-9H-carbazole (22.65 mmol), and 1.2 g of 4-dimethylaminopyridine (10.29 mmol), and 2.8 g of potassium carbonate (20.59 mmol) were dissolved in 100 mL of dimethylformamide, and the mixture was refluxed for 3 hours. After completion of the reaction, the organic layer was extracted with ethyl acetate after distillation under reduced pressure, and residual moisture was removed by using magnesium sulfate. Thereafter, the residue was dried and separated by column chromatography to obtain 10 g of compound C-346 (yield: 77%).

¹H NMR (600 MHz, CDCl3, δ) 9.01-9.00 (d, J=6.0 Hz, 1H), 8.85-8.84 (d, J=6.0 Hz, 1H), 8.34-8.33 (d, J=6.0 Hz, 1H), 8.23-8.22 (d, J=6.0 Hz, 2H), 8.11-8.10 (d, J=6.0 Hz, 1H), 8.05 (s, 1H), 7.86-7.82 (m, 2H), 7.79-7.77 (m, 1H), 7.75-7.71 (m, 3H), 7.67-7.64 (m, 3H), 7.59-7.57 (m, 2H), 7.53-7.52 (m, 1H), 7.50-7.47 (m, 3H), 7.43-7.37 (m, 2H), 7.36-7.35 (m, 4H)

| Compound | MW | Tg | M.P. |
|---|---|---|---|
| C-346 | 660.78 | 158° C. | 189.9° C. |

### Example 24: Preparation of Compound C-388

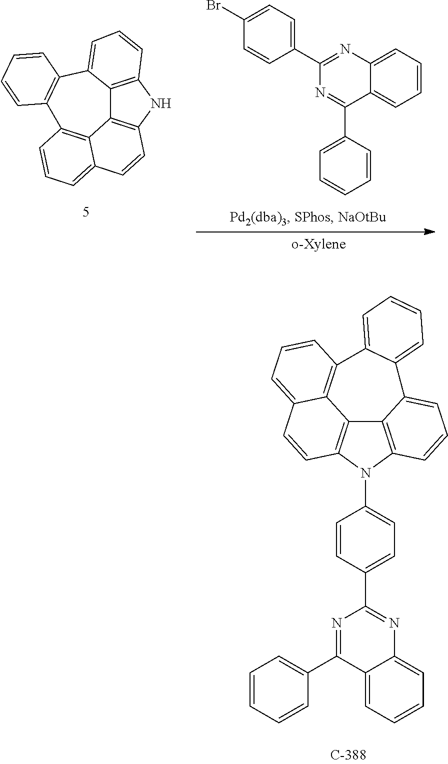 [SMILES: c1ccc2c(c1)-c1cccc3ccc4[nH]c5cccc-2c5c4c13 ; Brc1ccc(-c2nc(-c3ccccc3)c3ccccc3n2)cc1 ; c1ccc(-c2nc(-c3ccc(-n4c5cccc6c5c5c7c(cccc7ccc54)-c4ccccc4-6)cc3)nc3ccccc23)cc1]

In a flask, 12 g of compound 5 (41.1 mmol), 14.8 g of 2-(4-bromophenyl)-4-phenylquinazoline (41.1 mmol), 1.5 g of tris(dibenzylideneacetone)dipalladium(0) (1.6 mmol), 1.7 g of 2-dicyclohexylphosphino-2′,6′-dimethoxybiphenyl (4.1 mmol), and 9.8 g of sodium tert-butoxide (102.9 mmol) were dissolved in 274 mL of o-xylene, and the mixture was refluxed for 4 hours. After completion of the reaction, the reaction mixture was cooled to room temperature and separated by column chromatography to obtain 1.1 g of compound C-388 (yield: 4.7%).

¹H NMR (600 MHz, CDCl3, δ) 8.927-8.912 (d, J=7.8 Hz, 2H), 8.199-8.160 (m, 2H), 7.925-7.910 (m, 3H), 7.865-7.855 (m, 1H), 7.759-7.672 (m, 6H), 7.620-7.587 (m, 5H), 7.540-7.525 (d, J=9 Hz, 1H), 7.401-7.375 (m, 3H), 7.339-7.328 (m, 2H).

| Compound | MW | Tg | M.P. |
|---|---|---|---|
| C-388 | 571.6 | 133° C. | 241° C. |

### Example 25: Preparation of Compound C-381

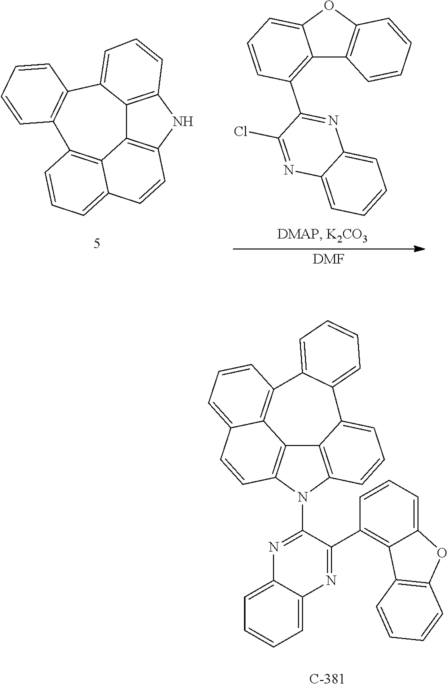

In a flask, 5.7 g of compound 5 (19.5 mmol), 7.7 g of 2-chloro-3-(dibenzo[b,d]furan-1-yl)quinoxaline (23.2 mmol), 0.1 g of 4-dimethylaminopyridine (0.9 mmol), and 8.1 g of potassium carbonate (58.5 mmol) were dissolved in 99 mL of dimethylformamide, and the mixture was refluxed for 3.5 hours. After completion of the reaction, the reaction mixture was cooled, and methanol and water were added thereto, and filtered. Thereafter, the residue was dried and separated by column chromatography to obtain 6 g of compound C-381 (yield: 52%).

¹H NMR (600 MHz, CDCl3, δ) 8.324-8.271 (m, 2H), 7.962-7.942 (m, 2H), 7.867-7.855 (d, J=7.2 Hz, 1H), 7.821-7.805 (m, 1H), 7.705-7.693 (d, J=7.2 Hz, 1H), 7.655-7.595 (m, 3H), 7.567-7.537 (m, 2H), 7.394-7.272 (m, 8H), 7.124-7.155 (m, 1H), 6.984-6.958 (t, J=7.2 Hz, 1H), 6.830-6.817 (d J=7.8 Hz, 1H)

| Compound | MW | Tg | M.P. |
|---|---|---|---|
| C-381 | 585.6 | 154.79° C. | 233° C. |

### Example 26: Preparation of Compound C-378

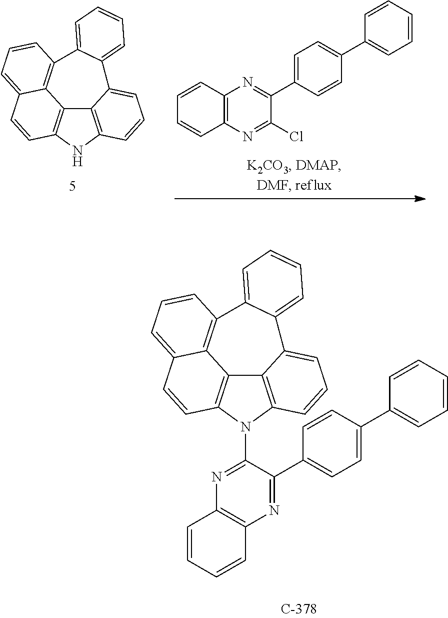

In a flask, 3.8 g of compound 5 (13 mmol), 5.0 g of 2-([1,1′-biphenyl]-4-yl)-3-chloroquinoxaline (16 mmol), 800 mg of DMAP (7 mmol), and 3.6 g of potassium carbonate (26 mmol) were dissolved in 55 mL of dimethylformamide, and the mixture was refluxed for 18 hours. After completion of the reaction, the organic layer was extracted with ethyl acetate after distillation under reduced pressure, and residual moisture was removed by using magnesium sulfate. Thereafter, the residue was dried and separated by column chromatography to obtain 1.4 g of compound C-378 (yield: 19%).

¹H NMR (600 MHz, CDCl3, δ) 8.33-8.32 (m, 1H), 8.17-8.16 (m, 1H), 7.90-7.84 (m, 3H), 7.74 (d, J=7.50 Hz, 1H), 7.69 (t, J=6.72 Hz, 2H), 7.63 (d, J=8.4 Hz, 2H), 7.61-7.59 (m, 1H), 7.51 (d, J=9.00 Hz, 1H), 7.45-7.37 (m, 7H), 7.35-7.27 (m, 5H), 7.23 (d, J=8.79 Hz, 1H)

| Compound | MW | Tg | M.P. |
|---|---|---|---|
| C-378 | 571.68 | 137.6° C. | 189° C. |

### Example 27: Preparation of Compound C-386

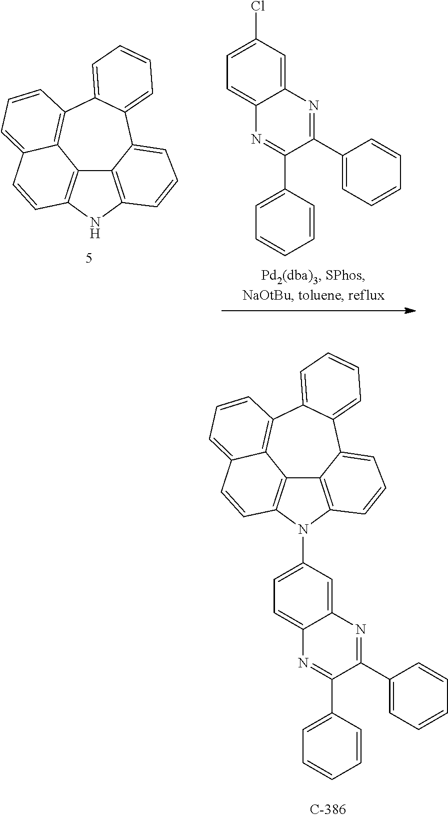 [SMILES: c1ccc2c(c1)-c1cccc3ccc4[nH]c5cccc-2c5c4c13 ; Clc1ccc2nc(-c3ccccc3)c(-c3ccccc3)nc2c1 ; c1ccc(-c2nc3ccc(-n4c5cccc6c5c5c7c(cccc7ccc54)-c4ccccc4-6)cc3nc2-c2ccccc2)cc1]

In a flask, 5.1 g of compound 5 (17 mmol), 5.0 g of 6-chloro-2,3-diphenylquinoxaline (16 mmol), 578 mg of tris(dibenzylideneacetone)dipalladium(0) (0.631 mmol), 648 mg of 2-dicyclohexylphosphino-2′,6′-dimethoxybiphenyl (2 mmol), and 3.8 g of sodium tert-butoxide (39 mmol) were dissolved in 100 mL of toluene, and the mixture was refluxed for 16 hours. After completion of the reaction, the organic layer was extracted with ethyl acetate after distillation under reduced pressure, and residual moisture was removed by using magnesium sulfate. Thereafter, the residue was dried and separated by column chromatography to obtain 7.6 g of compound C-386 (yield: 84%).

¹H NMR (600 MHz, CDCl3, δ) 8.01 (s, 1H), 8.40 (d, J=5.4 Hz, 1H), 7.99 (dd, J=5.4 Hz; 2.22 Hz, 1H), 7.89-7.87 (m, 1H), 7.79-7.77 (m, 2H), 7.74-7.70 (m, 2H), 7.63-7.60 (m, 2H), 7.59-7.56 (m, 4H), 7.44-7.34 (m, 11H)

| Compound | MW | Tg | M.P. |
|---|---|---|---|
| C-386 | 571.68 | 138.80° C. | 295° C. |

### Example 28: Preparation of Compound C-387

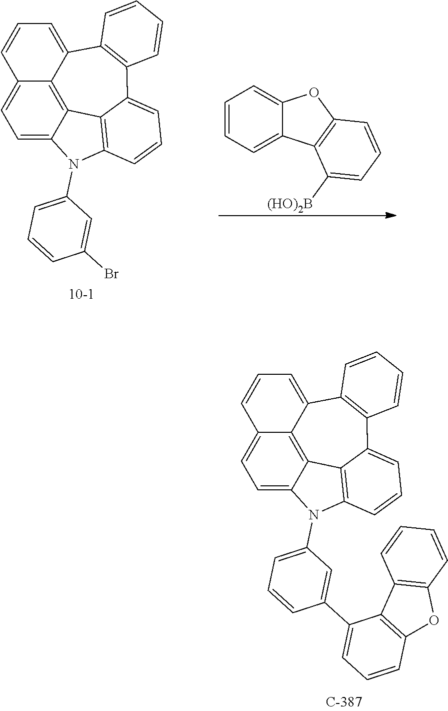 [SMILES: Brc1cccc(-n2c3cccc4c3c3c5c(cccc5ccc32)-c2ccccc2-4)c1 ; OB(O)c1cccc2oc3ccccc3c12 ; c1cc(-c2cccc3oc4ccccc4c23)cc(-n2c3cccc4c3c3c5c(cccc5ccc32)-c2ccccc2-4)c1]

6.6 g of compound 10-1 (14.78 mmol), 3.4 g of dibenzo[b,d]furan-1-yl-boronic acid (16.24 mmol), 0.85 g of tetrakis(triphenylphosphine)palladium(0) (0.739 mmol), and 4 g of potassium carbonate (29.57 mmol) were added to 60 mL of toluene, 15 mL of ethanol, and 15 mL of purified water, and the mixture was stirred under reflux for 1 day. After completion of the reaction, the reaction mixture was cooled to room temperature, and then the resultant solid was filtered under reduced pressure. The solid was dissolved in CHCl₃, and the mixture was separated by column chromatography with MC/Hex to obtain 3.5 g of compound C-387 (yield: 45%).

¹H NMR (600 MHz, DMSO, δ) 7.953-7.927 (m, 2H), 7.896-7.872 (t, 2H), 7.848-7.810 (m, 3H), 7.793-7.746 (m, 4H), 7.656-7.601 (m, 4H), 7.539-7.511 (t, 1H), 7.485-7.443 (m, 4H), 7.419-7.393 (t, 1H), 7.369-7.356 (d, 1H), 7.294-7.269 (t, 1H)

| Compound | MW | M.P. | Tg |
|---|---|---|---|
| C-387 | 533.6 | 224° C. | 117° C. |

### Example 29: Preparation of Compound C-393

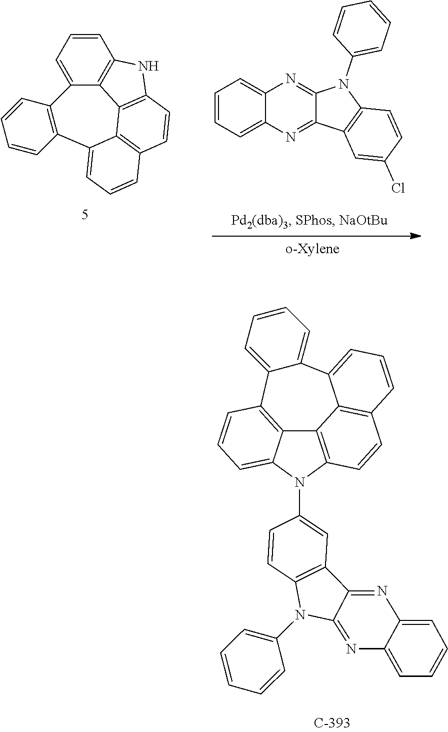 [SMILES: c1ccc2c(c1)-c1cccc3ccc4[nH]c5cccc-2c5c4c13 ; Clc1ccc2c(c1)c1nc3ccccc3nc1n2-c1ccccc1 ; c1ccc(-n2c3ccc(-n4c5cccc6c5c5c7c(cccc7ccc54)-c4ccccc4-6)cc3c3nc4ccccc4nc32)cc1]

In a flask, 4.4 g of compound 5 (15.16 mmol), 5.0 g of 9-chloro-6-phenyl-6H-indolo[2,3,b]quinoxaline (15.16 mmol), 0.5 g of tris(dibenzylideneacetone)dipalladium(0) (0.606 mmol), 0.6 g of 2-dicyclohexylphosphino-2′,6′-dimethoxybiphenyl (1.516 mmol), and 12 g of sodium tert-butoxide (37.90 mmol) were added to 100 mL of o-xylene, and the mixture was refluxed for 4 hours. After completion of the reaction, the organic layer was extracted with ethyl acetate after distillation under reduced pressure, and residual moisture was removed by using magnesium sulfate. Thereafter, the residue was dried and separated by column chromatography to obtain 1.9 g of compound C-393 (yield: 21%).

¹H NMR (600 MHz, CDCl3, δ) 8.74 (s, 1H), 8.33-8.32 (d, J=6.0 Hz, 1H), 8.15-8.14 (d, J=6.0 Hz, 1H), 7.91-7.90 (m, 1H), 7.84-8.73 (m, 2H), 7.80-7.78 (m, 5H), 7.77-7.69 (m, 5H), 7.64-7.63 (m, 1H), 7.60-7.59 (m, 1H), 7.50-7.49 (d, J=6.0 Hz, 1H), 7.43-7.41 (m, 3H), 7.36-7.34 (t, J=6.0 Hz, 1H), 7.28-7.27 (m, 1H)

| Compound | MW | Tg | M.P. |
|---|---|---|---|
| C-393 | 584.67 | 129.07° C. | 294° C. |

### Example 30: Preparation of Compound C-447

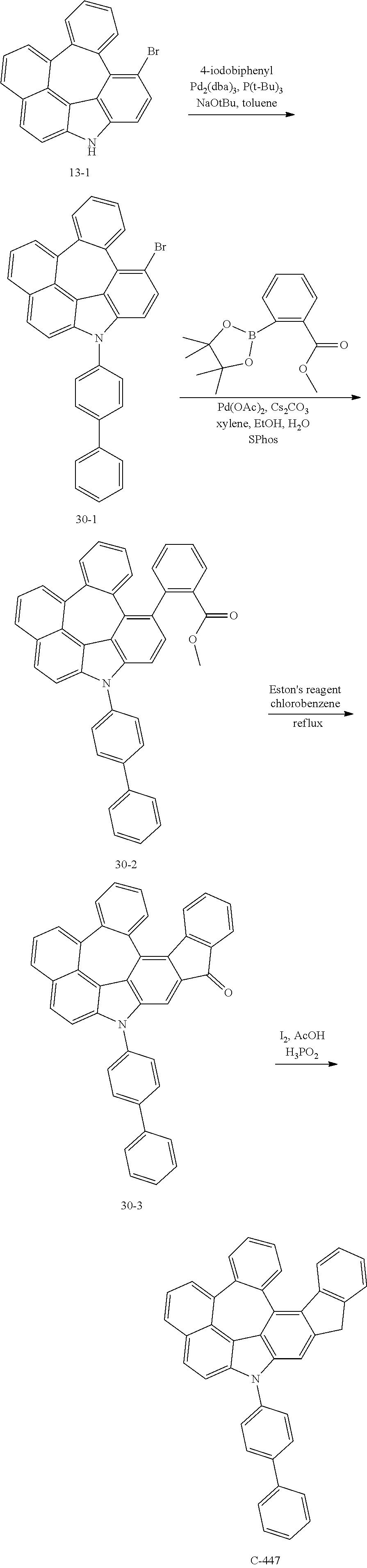 [SMILES: Brc1ccc2[nH]c3ccc4cccc5c4c3c2c1-c1ccccc1-5 ; Brc1ccc2c3c1-c1ccccc1-c1cccc4ccc(c3c14)n2-c1ccc(-c2ccccc2)cc1 ; COC(=O)c1ccccc1B1OC(C)(C)C(C)(C)O1 ; COC(=O)c1ccccc1-c1ccc2c3c1-c1ccccc1-c1cccc4ccc(c3c14)n2-c1ccc(-c2ccccc2)cc1 ; O=C1c2ccccc2-c2c1cc1c3c2-c2ccccc2-c2cccc4ccc(c3c24)n1-c1ccc(-c2ccccc2)cc1 ; c1ccc(-c2ccc(-n3c4cc5c(c6c4c4c7c(cccc7ccc43)-c3ccccc3-6)-c3ccccc3C5)cc2)cc1]

Synthesis of Compound 30-1

In a flask, 8.0 g of compound 13-1 (21.6 mmol), 12.1 g of 4-iodobiphenyl (43.2 mmol), 1.0 g of tris(dibenzylideneacetone)dipalladium(0) (1.08 mmol), 0.87 mL of tri-tert-butylphosphine (2.16 mmol 50% toluene solution), 5.2 g of sodium tert-butoxide (54.0 mmol), and 216 mL of toluene were added, and the mixture was refluxed for 18 hours. After completion of the reaction, the reaction mixture was cooled to room temperature, and the solvent was removed by a rotary evaporator. The residue was separated by column chromatography to obtain 7.5 g of compound 30-1 (yield: 66%)

Synthesis of Compound 30-2

In a flask, 7.5 g of compound 30-1 (14.4 mmol), 4.5 g of methyl 2-(4,4,5,5-tetramethyl-1,3,2-dioxylboren-2-yl)benzoate (17.3 mmol), 323 mg of palladium acetate (Pd(OAc)₂) (1.44 mmol), 1.2 g of Ligand (2-dicyclohexylphosphonium-2′,6′-dimethoxybiphenyl) (2.88 mmol), and 14 g of cesium carbonate (43.2 mmol) were added to 80 mL of xylene, 40 mL of ethanol, and 40 mL of distilled water, and the mixture was stirred under reflux for 18 hours. The reaction mixture was cooled to room temperature and distilled water was added thereto. The organic layer was extracted with MC and dried with magnesium sulfate. Thereafter, the residue was distilled under reduced pressure and separated by column chromatography to obtain 2.2 g of compound 30-2 (yield: 27%).

Synthesis of Compound 30-3

In a flask, 2.2 g of compound 30-2 (3.8 mmol), 2 mL of Eaton's reagent, and 13 mL of benzene chloride were added, and the mixture was stirred under reflux for 18 hours. The reaction mixture was cooled to room temperature and aqueous sodium hydrogen carbonate solution was added thereto. The organic layer was extracted with ethyl acetate (EA) and dried with magnesium sulfate. Thereafter, the residue was distilled under reduced pressure and separated by column chromatography to obtain 1.5 g of compound 30-3 (yield: 71%).

Synthesis of Compound C-447

In a flask, 244 mg of iodine (0.96 mmol), 0.48 mL of hypophosphorous acid (4.4 mmol, 50% aqueous solution), and 14 mL of acetic acid were added, and the mixture was stirred at 80° C. for 30 minutes. 1.5 g of compound 30-3 (2.75 mmol) was slowly added dropwise to the reaction mixture and stirred under reflux for 4 hours. The reaction solution was cooled to room temperature, and the precipitated solid was filtered and washed with a large amount of water and ethanol. After removing solvent from the resultant solid through a filter, the residue was separated by column chromatography to obtain 270 mg of compound C-447 (yield: 18%).

¹H NMR (600 MHz, CDCl₃, δ) 8.051-8.036 (dd, 1H), 7.967-7.953 (m, 1H), 7.920-7.909 (d, 1H), 7.857-7.843 (d, 2H), 7.797-7.784 (d, 1H), 7.720-7.698 (m, 2H), 7.669-7.643 (m, 3H), 7.562-7.500 (m, 5H), 7.463-7.416 (m, 5H), 7.217-7.190 (m, 2H), 4.153-4.188 (d, 1H), 3.949-3.913 (d, 1H).

FIG. 1 schematically illustrates a structure of an organic electroluminescent device according to one embodiment of the present disclosure. Hereinafter, an organic electroluminescent device according to one embodiment of the present disclosure will be described referring to FIG. 1.

Referring to FIG. 1, an organic electroluminescent device of the present disclosure comprises a substrate, an anode formed on the substrate, a first unit formed on the anode, a charge generation layer formed on the first unit, a second unit formed on the charge generation layer, and a cathode formed on the second unit. The first unit may comprise one or more light-emitting layers, and may comprise a compound represented by formula 1 of the present disclosure. The first unit may comprise a first hole injection layer formed on the anode, a first hole transport layer formed on the first hole injection layer, a first light-emitting layer formed on the first hole transport layer, and a first electron transport layer formed on the first light-emitting layer, and a first electron injection layer formed on the first electron transport layer. The first hole injection layer, the first hole transport layer, the first light-emitting layer, the first electron transport layer, and the first electron injection layer may each be a single layer or a plurality of layers. Also, the second unit may comprise one or more light-emitting layers, and may comprise a compound represented by formula 1 of the present disclosure. The second unit may comprise a second hole injection layer formed on the charge generation layer, a second hole transport layer formed on the second hole injection layer, a second light-emitting layer formed on the second hole transport layer, and a second electron transport layer formed on the second light-emitting layer, and a second electron injection layer formed on the second electron transport layer. The second hole injection layer, the second hole transport layer, the second light-emitting layer, the second electron transport layer, and the second electron injection layer may each be a single layer or a plurality of layers. In addition, the organic electroluminescent device of the present disclosure may further comprise a third unit including one or more light-emitting layers between the second unit and the cathode. One or more charge generation layers may be comprised between the second unit and the third unit. The third unit may comprise a third hole injection layer formed on the charge generation layer, a third hole transport layer formed on the third hole injection layer, a third light-emitting layer formed on the third hole transport layer, and a third electron transport layer formed on the third light-emitting layer, and a third electron injection layer formed on the third electron transport layer. The third hole injection layer, the third hole transport layer, the third light-emitting layer, the third electron transport layer, and the third electron injection layer may each be a single layer or a plurality of layers.

According to one embodiment of the present disclosure, an organic electroluminescent device of the present disclosure comprises an anode, a cathode, and a plurality of light-emitting layers between the anode and the cathode, and at least one charge generation layer between the plurality of light-emitting layers. At least one of the plurality of light-emitting layers comprises a compound represented by formula 1 of the present disclosure. According to one embodiment of the present disclosure, an organic electroluminescent device of the present disclosure may be a white organic electroluminescent device. In the case of a white organic electroluminescent device, color may be implemented using a color filter or other known color implementing means.

The charge generation layer (CGL) is generally composed of a junction structure of an electron transport layer doped with alkali metal and a material having a very low LUMO energy level, which greatly affects the overall characteristics of the device. According to one embodiment of the present disclosure, the charge generation layer refers to pCGL (e.g., HATCN, V₂O₅, WO₃, MoO₃, etc.), which generates and moves charges, and it is used together with nCGL (e.g., Li, Mg, Ca, etc.) to effectively transfer generated electrons to the electron transport layer.

The structure of the organic electroluminescent device of the present disclosure is not limited to the above examples, and a plurality of light-emitting materials emitting different colors may be disposed in a stacking direction of layers constituting the device, or a plurality of light-emitting materials may be mixed to generate white light.

In order to form each layer of the organic electroluminescent device of the present disclosure, dry film-forming methods such as vacuum evaporation, sputtering, plasma and ion plating methods, or wet film-forming methods such as ink jet printing, nozzle printing, slot coating, spin coating, dip coating, and flow coating methods may be used. The compounds of the present disclosure may be co-evaporated or mixture-evaporated.

When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

In addition, it is possible to produce a display system or a lighting system by using the organic electroluminescent device of the present disclosure. Specifically, it is possible to produce a display system, e.g., a display system for smartphones, tablets, notebooks, PCs, TVs, or cars, or a lighting system, e.g., an outdoor or indoor lighting system, by using the organic electroluminescent device of the present disclosure.

Hereinafter, the properties of an OLED comprising the compound according to the present disclosure will be explained in detail.

### Device Example 1: Producing an OLED by Depositing the Host Compound According to the Present Disclosure

An OLED was produced using an organic electroluminescent compound according to the present disclosure, as follows: A transparent electrode indium tin oxide (ITO) thin film (10 Ω/sq) on a glass substrate for an OLED (Samsung-Corning GEOMATEC CO., LTD.) was subjected to an ultrasonic washing with acetone, ethanol and distilled water, sequentially, and then was stored in isopropanol. The ITO substrate was mounted on a substrate holder of a vacuum vapor deposition apparatus. Compound HI-1 was introduced into a cell of the vacuum vapor deposition apparatus, and the pressure in the chamber of the apparatus was then controlled to 10⁻⁶ torr. Thereafter, an electric current was applied to the cell to evaporate the above-introduced material, thereby forming a first hole injection layer having a thickness of 5 nm on the ITO substrate. Next, compound HI-2 was introduced into another cell of the vacuum vapor deposition apparatus and was evaporated by applying an electric current to the cell, thereby forming a second hole injection layer having a thickness of 75 nm on the first hole injection layer. Compound HT-1 was then introduced into another cell of the vacuum vapor deposition apparatus and was evaporated by applying an electric current to the cell, thereby forming a first hole transport layer having a thickness of 5 nm on the second hole injection layer. After forming the hole injection layers and the hole transport layer, a light-emitting layer was formed thereon as follows: Compound BH-1 was introduced into one cell of the vacuum vapor deposition apparatus as a host, and compound BD-1 was introduced into another cell as a dopant. The two materials were evaporated at different rates, so that the dopant was deposited in a doping amount of 2 wt % based on the total amount of the host and dopant to form a first light-emitting layer (a blue light-emitting layer) having a thickness of 10 nm on the first hole transport layer. As a second light-emitting layer, compound C-8 of the present disclosure was introduced into one cell of the vacuum vapor deposition apparatus as a host, and compound RD-1 was introduced into another cell as a dopant. The two materials were evaporated at different rates, so that the dopant was deposited in a doping amount of 3 wt % based on the total amount of the host and dopant to form a second light-emitting layer (a red light-emitting layer) having a thickness of 5 nm on the first light-emitting layer. Next, as a third light-emitting layer, compound GH-1 and compound GH-2 were introduced at a ratio of 1:1 into two cells of the vacuum vapor deposition apparatus as hosts, and compound GD-1 was introduced into another cell as a dopant. The materials were evaporated at different rates, so that the dopant was deposited in a doping amount of 12 wt % based on the total amount of the host and dopant to form a third light-emitting layer (a green light-emitting layer) having a thickness of 22.5 nm on the second light-emitting layer. Compound ET-1 was introduced into another cell of the vapor deposition apparatus and was deposited as an electron transport layer having a thickness of 35 nm on the third light-emitting layer. After depositing compound EI-1 as an electron injection layer having a thickness of 2 nm on the electron transport layer, an Al cathode having a thickness of 100 nm was deposited on the electron injection layer by another vacuum vapor deposition apparatus. Thus, an OLED was produced.

The driving voltage, the luminous efficiency, the power efficiency, the external quantum efficiency (EQE), and the CIE color coordinates at a current density of 10 mA/cm² of the OLED produced in the Device Example, are shown in Table 1 below.

TABLE 1

| | | Driv- | | | | | |
|---|---|---|---|---|---|---|---|
| | Second | ing | Luminous | Power | | CIE Color | |
| | Light- | Volt- | Effi- | Effi- | | Coor- | |
| | Emitting | age | ciency | ciency | EQE | dinates | |
| | Layer | [V] | [cd/A] | [lm/W] | [%] | x | y |
| Device | C-8 | 4.6 | 25.9 | 17.7 | 11.4 | 0.436 | 0.467 |
| Example 1 | | | | | | | |

### Comparative Example: Producing an OLED by Depositing Conventional Compounds

An OLED not according to the present disclosure was produced, as follows: A transparent electrode indium tin oxide (ITO) thin film (10 Ω/sq) on a glass substrate for an OLED (Samsung-Corning GEOMATEC CO., LTD.) was subjected to an ultrasonic washing with acetone, ethanol and distilled water, sequentially, and then was stored in isopropanol. The ITO substrate was mounted on a substrate holder of a vacuum vapor deposition apparatus. Compound HI-1 was introduced into a cell of the vacuum vapor deposition apparatus, and the pressure in the chamber of the apparatus was then controlled to 10⁻⁶ torr. Thereafter, an electric current was applied to the cell to evaporate the above-introduced material, thereby forming a hole injection layer 1-1 having a thickness of 5 nm on the ITO substrate. Next, compound HI-2 was introduced into another cell of the vacuum vapor deposition apparatus and was evaporated by applying an electric current to the cell, thereby forming a hole injection layer 1-2 having a thickness of 75 nm on the hole injection layer 1-1. Compound HT-1 was then introduced into another cell of the vacuum vapor deposition apparatus and was evaporated by applying an electric current to the cell, thereby forming a first hole transport layer having a thickness of 5 nm on the hole injection layer 1-2. After forming the hole injection layers and the hole transport layer, a light-emitting layer was formed thereon as follows: Compound BH-1 was introduced into one cell of the vacuum vapor deposition apparatus as a host, and compound BD-1 was introduced into another cell as a dopant. The two materials were evaporated at different rates, so that the dopant was deposited in a doping amount of 2 wt % based on the total amount of the host and dopant to form a first light-emitting layer (a blue light-emitting layer) having a thickness of 20 nm on the first hole transport layer. Compound ET-2 was introduced into another cell of the vapor deposition apparatus and was deposited as a first electron transport layer having a thickness of 30 nm. Next, compound CGL was doped with lithium in an amount of 2 wt % as the first charge generation layer. Compound HI-1 was deposited as a second charge generation layer having a thickness of 5 nm on the first charge generation layer. Next, compound HI-2 was deposited as a second hole injection layer having a thickness of 25 nm on the second charge generation layer. Compound HT-2 was introduced into a cell of the vacuum vapor deposition apparatus and was evaporated by applying an electric current to the cell, thereby forming a second hole transport layer having a thickness of 5 nm on the second hole injection layer. As a second light-emitting layer, compound RH and dopant compound RD-1 were simultaneously evaporated at different rates, so that the dopant was deposited in a doping amount of 3 wt % based on the total amount of the host and dopant to form a second light-emitting layer (a red light-emitting layer) having a thickness of 10 nm on the second hole transport layer. Next, as a third light-emitting layer, compound GH-1 and compound GH-2 were introduced at a ratio of 1:1 into two cells of the vacuum vapor deposition apparatus as hosts, and compound GD-1 was introduced into another cell as a dopant. The materials were evaporated at different rates, so that the dopant was deposited in a doping amount of 12 wt % based on the total amount of the host and dopant to form a third light-emitting layer (a green light-emitting layer) having a thickness of 45 nm on the second light-emitting layer, wherein each host was deposited at a ratio of 1:1. Compound ET-1 was deposited as a second electron transport layer having a thickness of 35 nm. After depositing compound EI-1 as a second electron injection layer having a thickness of 2 nm, an Al cathode having a thickness of 100 nm was deposited by another vacuum vapor deposition apparatus. Thus, an OLED was produced.

### Device Examples 2 to 7: Producing an OLED by Depositing the Compound According to the Present Disclosure as a Host of the Second Light-Emitting Layer

An OLED was produced in the same manner as in the Comparative Example, except that the host compound described as a host material in Table 2 was used instead of compound RH.

The driving voltage, the luminous efficiency, the power efficiency, the external quantum efficiency (EQE), and the CIE color coordinates at a current density of 10 mA/cm² of the OLEDs produced in the above, are shown in Table 2 below.

TABLE 2

| | | Driv- | Luminous | Power | | CIE Color | |
|---|---|---|---|---|---|---|---|
| | | ing | Effi- | Effi- | | Coor- | |
| | | Volt- | ciency | ciency | EQE | dinates | |
| | Host | age | [cd/A] | [lm/W] | [%] | x | y |
| Comparative | RH | 8.2 | 47.2 | 18.1 | 23.9 | 0.309 | 0.350 |
| Example | | | | | | | |
| Device | C-8 | 7.4 | 53.5 | 22.8 | 26.1 | 0.330 | 0.345 |
| Example 2 | | | | | | | |
| Device | C-13 | 7.6 | 47.9 | 19.9 | 26.6 | 0.345 | 0.322 |
| Example 3 | | | | | | | |
| Device | C-303 | 7.5 | 55.0 | 23.0 | 26.6 | 0.333 | 0.352 |
| Example 4 | | | | | | | |
| Device | C-25 | 7.8 | 46.4 | 18.6 | 27.7 | 0.345 | 0.330 |
| Example 5 | | | | | | | |
| Device | C-12 | 7.7 | 37.7 | 15.4 | 24.4 | 0.334 | 0.300 |
| Example 6 | | | | | | | |
| Device | C-338 | 7.6 | 40.8 | 17.0 | 26.0 | 0.353 | 0.317 |
| Example 7 | | | | | | | |

From Table 2 above, it can be confirmed that the OLED comprising the compound according to the present disclosure as a second host material is superior in driving voltage, luminous efficiency, external quantum efficiency, and CIE color coordinate characteristics as compared to an OLED comprising a conventional compound as a second host.

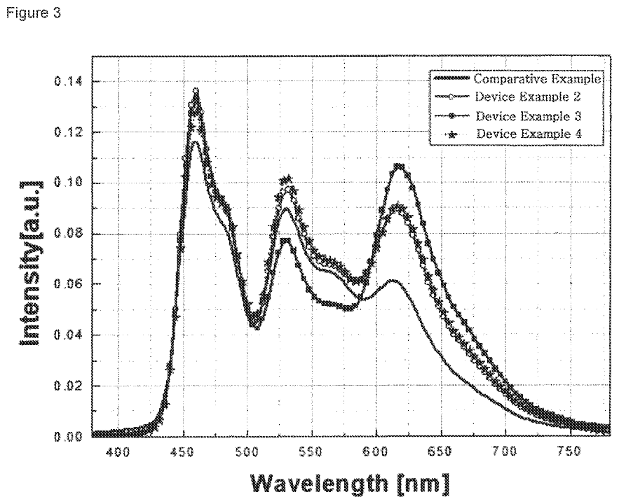

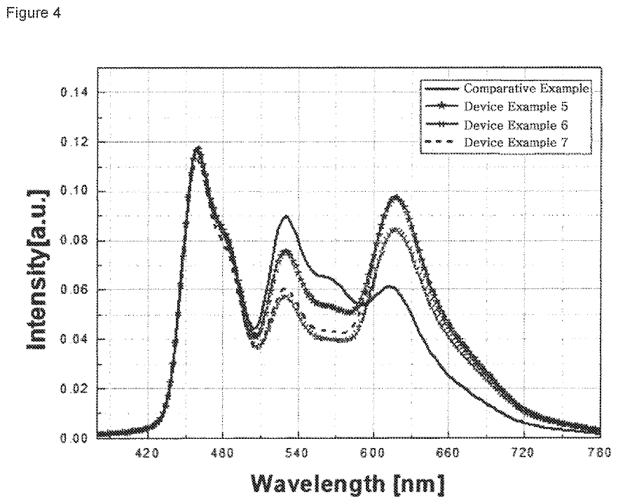

In addition, FIGS. 3 and 4 show the intensity according to the wavelength of the OLED produced in Comparative Example and Device Examples 2 to 7 of the present disclosure. The OLED produced in Comparative Example and Device Examples 2 to 7 includes fluorescent blue light emission, and has a light emission wavelength of 3-peak using phosphorescent red and phosphorescent green light-emitting layers. By using the compound represented by formula 1 of the present disclosure as a red light-emitting host, the red light-emitting host and the hole transport layer can be configured to be adjacent. This is considered to improve the charge recombination efficiency, since the holes and electrons of the red light-emitting layer can be balanced. The increase in red light emission can improve the external quantum efficiency of the OLED.

The compounds used in the Device Examples and the Comparative Example are shown as follows.

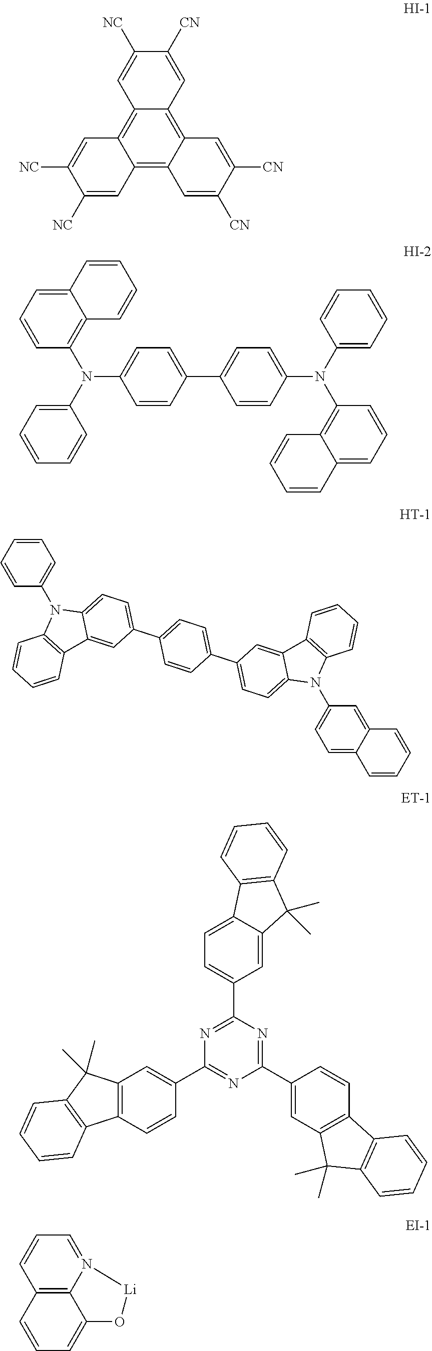

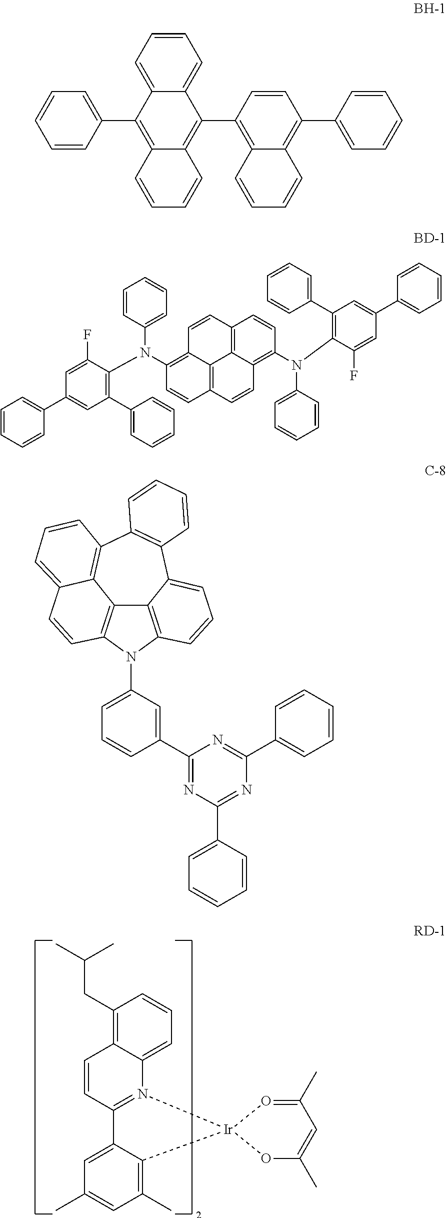

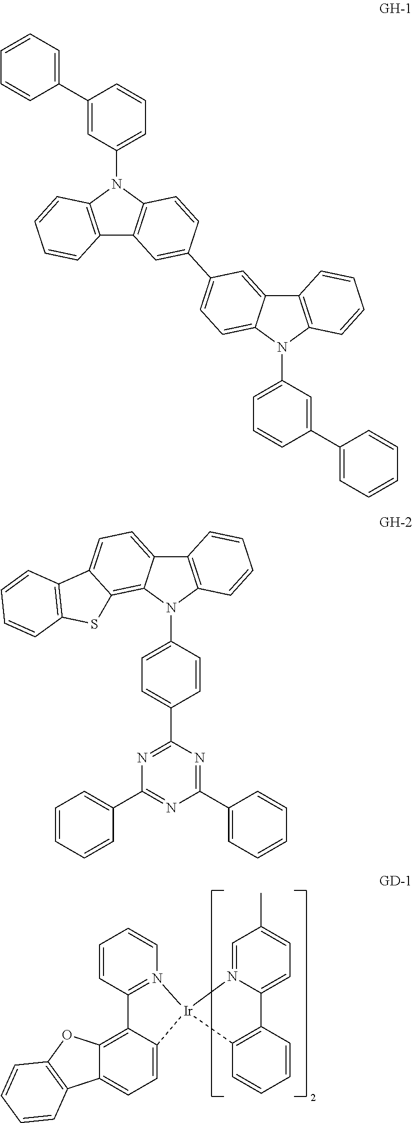

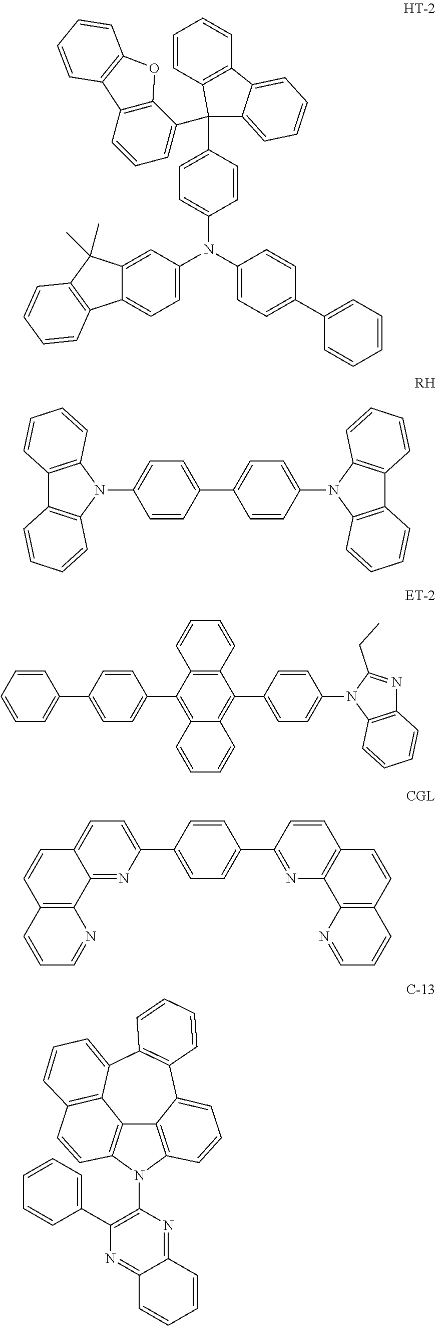

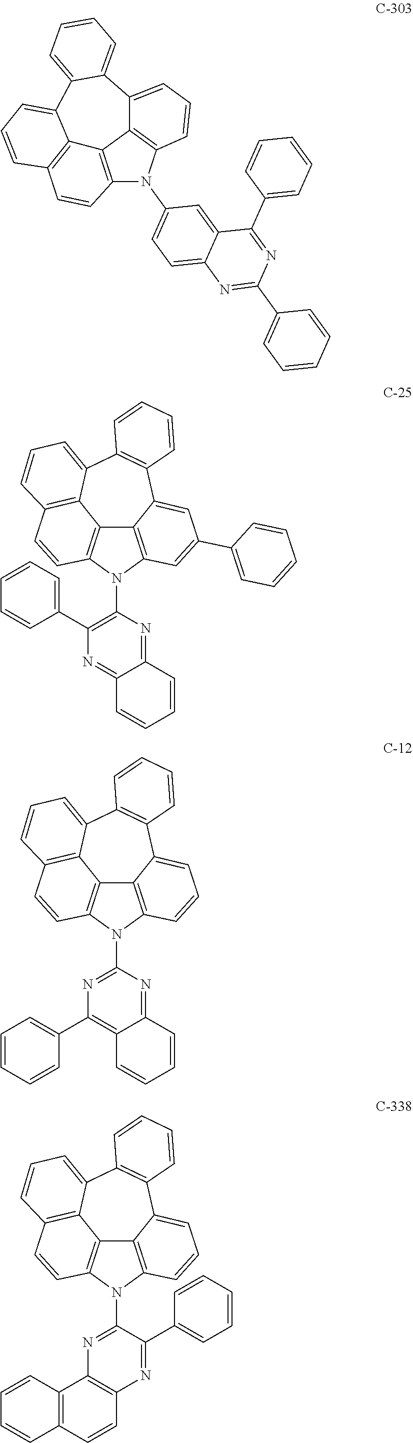

1. An organic electroluminescent device comprising an anode, a cathode, and a plurality of light-emitting layers between the anode and the cathode, wherein at least one of the plurality of light-emitting layers comprises a compound represented by the following formula 1: 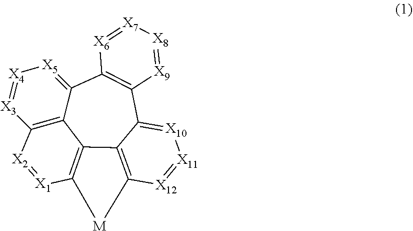
wherein
M represents 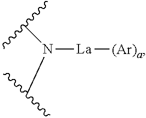
O or S;
X₁ to X₁₂, each independently, represent N or CR₁;
La represents a single bond, a substituted or unsubstituted (C1-C30)alkylene, a substituted or unsubstituted (C6-C30)arylene, a substituted or unsubstituted (3- to 30-membered)heteroarylene, or a substituted or unsubstituted (C3-C30)cycloalkylene;
Ar and R₁, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, a substituted or unsubstituted (C1-C30)alkyl(C6-C30)arylamino, or a substituted or unsubstituted (C6-C30)aryl(3- to 30-membered)heteroarylamino; or two or more adjacent Ar's may be linked to each other to form a ring(s), and two or more adjacent R₁'s may be linked to each other to form a ring(s); where if a plurality of R₁'s is present, each of R₁ may be the same or different; and
a represents an integer of 1 or 2, in which if a is an integer of 2, each of Ar may be the same or different.

2. The organic electroluminescent device according to claim 1, wherein the substituents of the substituted (C1-C30)alkyl(ene), the substituted (C6-C30)aryl(ene), the substituted (3-to 30-membered)heteroaryl(ene), the substituted (C3-C30)cycloalkyl(ene), the substituted (C1-C30)alkoxy, the substituted tri(C1-C30)alkylsilyl, the substituted di(C1-C30)alkyl(C6-C30)arylsilyl, the substituted (C1-C30)alkyldi(C6-C30)arylsilyl, the substituted tri(C6-C30)arylsilyl, the substituted mono- or di-(C1-C30)alkylamino, the substituted mono- or di-(C6-C30)arylamino, the substituted (C1-C30)alkyl(C6-C30)arylamino, and the substituted (C6-C30)aryl(3- to 30-membered)heteroarylamino, each independently, are at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (3- to 30-membered)heteroaryl unsubstituted or substituted with a (C6-C30)aryl(s); a (C6-C30)aryl unsubstituted or substituted with a (3- to 30-membered)heteroaryl(s); a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di-(C1-C30)alkylamino; a mono- or di-(C6-C30)arylamino unsubstituted or substituted with a (C1-C30)alkyl(s); a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl.

3. The organic electroluminescent device according to claim 1, wherein Ar represents a substituted or unsubstituted phenyl, a substituted or unsubstituted naphthyl, a substituted or unsubstituted biphenyl, a substituted or unsubstituted terphenyl, a substituted or unsubstituted fluorenyl, a substituted or unsubstituted fluoranthenyl, a substituted or unsubstituted triazinyl, a substituted or unsubstituted pyridyl, a substituted or unsubstituted triazolopyridyl, a substituted or unsubstituted pyrimidinyl, a substituted or unsubstituted benzothienopyrimidinyl, a substituted or unsubstituted acenaphthopyrimidinyl, a substituted or unsubstituted quinazolinyl, a substituted or unsubstituted benzoquinazolinyl, a substituted or unsubstituted quinoxalinyl, a substituted or unsubstituted benzoquinoxalinyl, a substituted or unsubstituted dibenzoquinoxalinyl, a substituted or unsubstituted indoloquinoxalinyl, a substituted or unsubstituted quinolyl, a substituted or unsubstituted benzoquinolyl, a substituted or unsubstituted isoquinolyl, a substituted or unsubstituted benzoisoquinolyl, a substituted or unsubstituted benzothienoquinolyl, a substituted or unsubstituted benzofuroquinolyl, a substituted or unsubstituted triazolyl, a substituted or unsubstituted pyrazolyl, a substituted or unsubstituted carbazolyl, a substituted or unsubstituted dibenzothiophenyl, a substituted or unsubstituted benzothiophenyl, a substituted or unsubstituted dibenzofuranyl, a substituted or unsubstituted benzofuranyl, a substituted or unsubstituted naphthyridinyl, a substituted or unsubstituted benzothiazolinyl, a substituted or unsubstituted phenanthroimidazolyl, a substituted or unsubstituted diphenylamino, a substituted or unsubstituted phenylbiphenylamino, a substituted or unsubstituted fluorenylphenylamino, a substituted or unsubstituted dibenzothiophenylphenylamino, or a substituted or unsubstituted dibenzofuranylphenylamino.

4. The organic electroluminescent device according to claim 1, wherein at least two adjacent ones of X₁ to X₁₂ are CR₁, and two adjacent R₁'s are linked to each other to form any one of the following formulas 2 to 6, wherein at least one ring is formed in one compound represented by the formula 1: 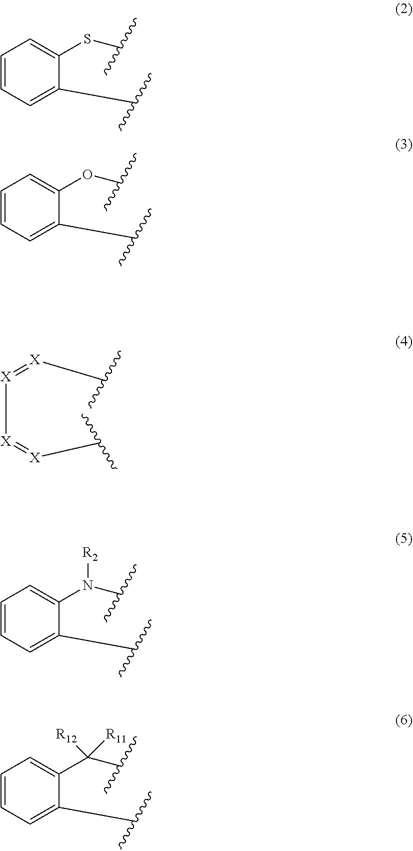
wherein
R₂ represents hydrogen, deuterium, a halogen, a cyano, a substituted or unsubstituted (C1-C30)alkyl, a substituted or unsubstituted (C6-C30)aryl, a substituted or unsubstituted (3-to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino;
X represents N or CH;
R₁₁ and R₁₂, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, or a substituted or unsubstituted (C3-C30)cycloalkyl; or R₁₁ and R₁₂ may be linked to each other to form a ring(s); and [symbol]
represents a linking site of C and R₁ in CR₁.

5. The organic electroluminescent device according to claim 1, wherein the formula 1 is represented by any one of the following formulas 7 to 10: 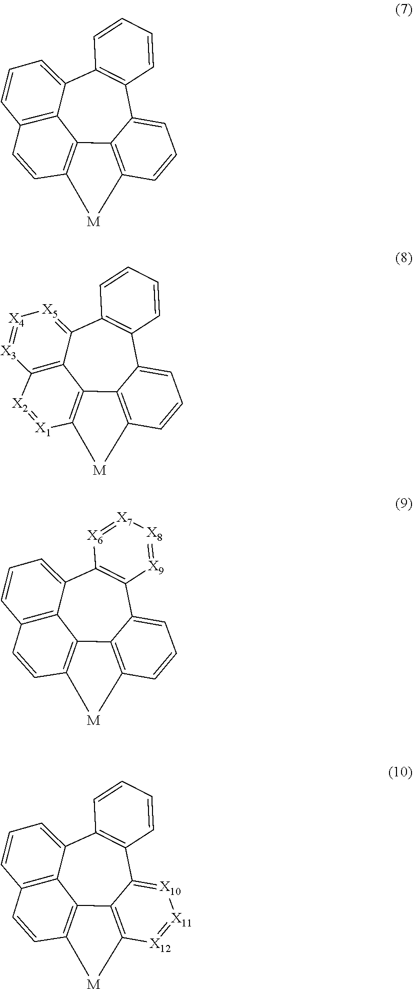
wherein, X₁ to X₁₂, and M are as defined in claim 1.

6. The organic electroluminescent device according to claim 1, wherein the compound represented by the formula 1 is at least one selected from the following compounds:

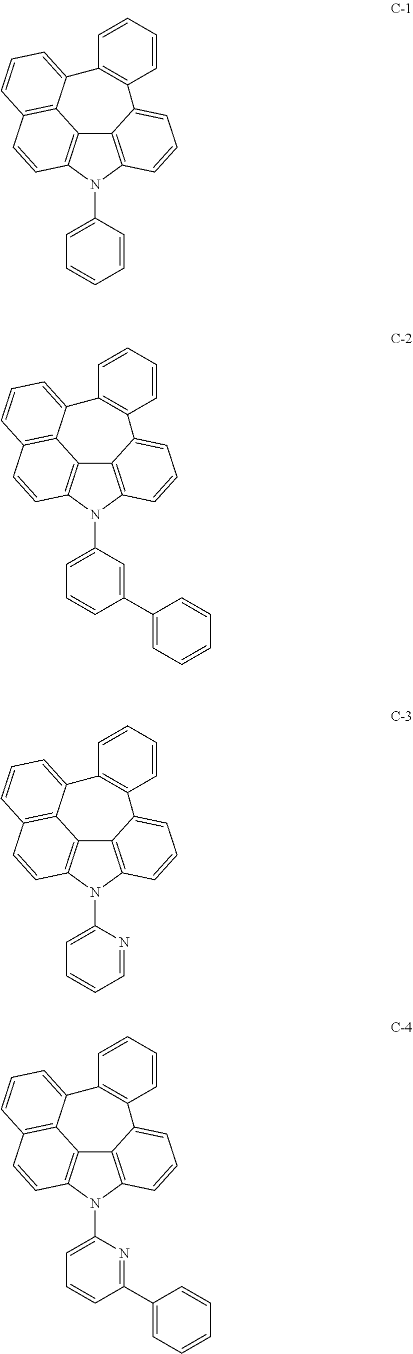 [SMILES: c1ccc(-n2c3cccc4c3c3c5c(cccc5ccc32)-c2ccccc2-4)cc1 ; c1ccc(-c2cccc(-n3c4cccc5c4c4c6c(cccc6ccc43)-c3ccccc3-5)c2)cc1 ; c1ccc(-n2c3cccc4c3c3c5c(cccc5ccc32)-c2ccccc2-4)nc1 ; c1ccc(-c2cccc(-n3c4cccc5c4c4c6c(cccc6ccc43)-c3ccccc3-5)n2)cc1]

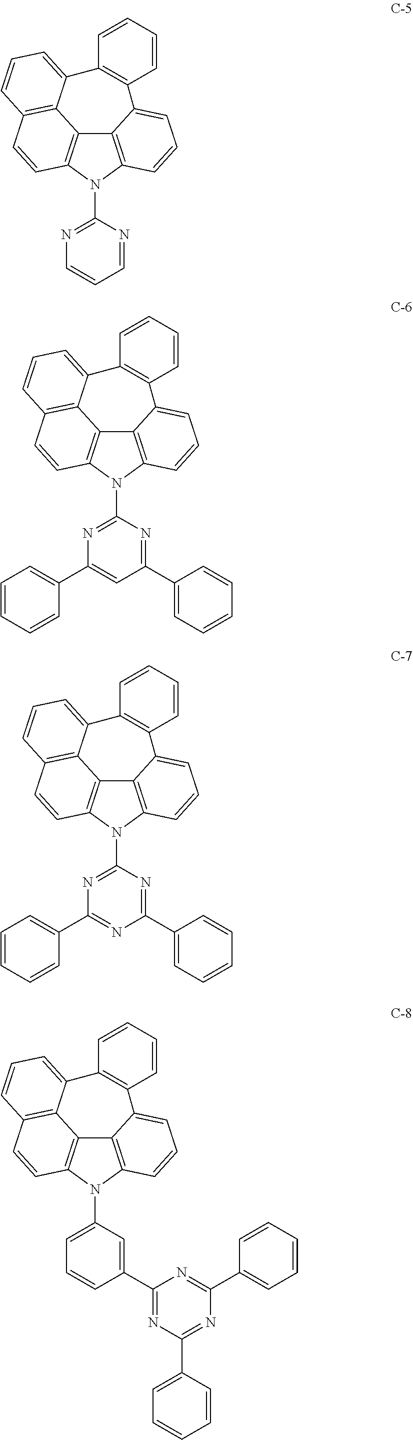 [SMILES: c1cnc(-n2c3cccc4c3c3c5c(cccc5ccc32)-c2ccccc2-4)nc1 ; c1ccc(-c2cc(-c3ccccc3)nc(-n3c4cccc5c4c4c6c(cccc6ccc43)-c3ccccc3-5)n2)cc1 ; c1ccc(-c2nc(-c3ccccc3)nc(-n3c4cccc5c4c4c6c(cccc6ccc43)-c3ccccc3-5)n2)cc1 ; c1ccc(-c2nc(-c3ccccc3)nc(-c3cccc(-n4c5cccc6c5c5c7c(cccc7ccc54)-c4ccccc4-6)c3)n2)cc1]

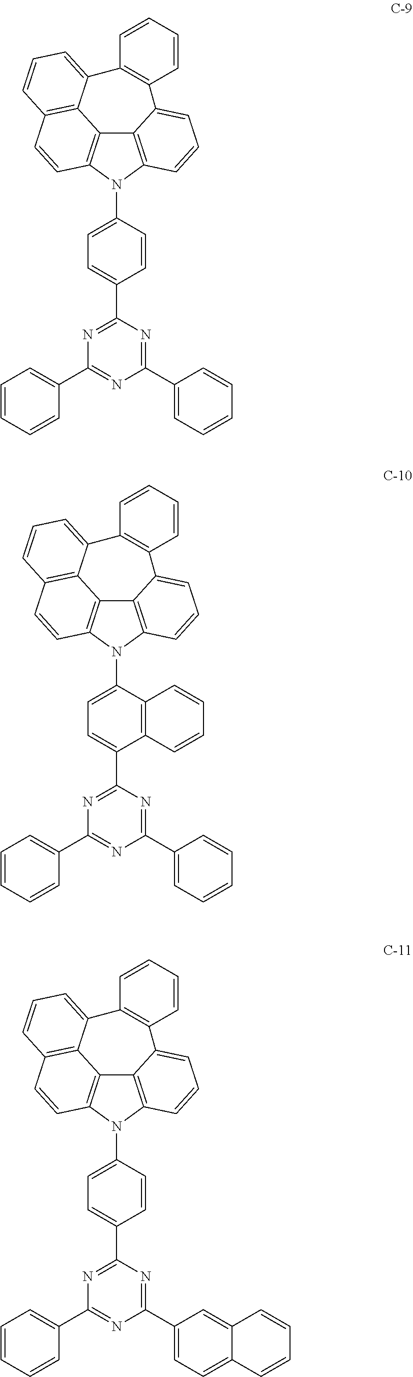 [SMILES: c1ccc(-c2nc(-c3ccccc3)nc(-c3ccc(-n4c5cccc6c5c5c7c(cccc7ccc54)-c4ccccc4-6)cc3)n2)cc1 ; c1ccc(-c2nc(-c3ccccc3)nc(-c3ccc(-n4c5cccc6c5c5c7c(cccc7ccc54)-c4ccccc4-6)c4ccccc34)n2)cc1 ; c1ccc(-c2nc(-c3ccc(-n4c5cccc6c5c5c7c(cccc7ccc54)-c4ccccc4-6)cc3)nc(-c3ccc4ccccc4c3)n2)cc1]

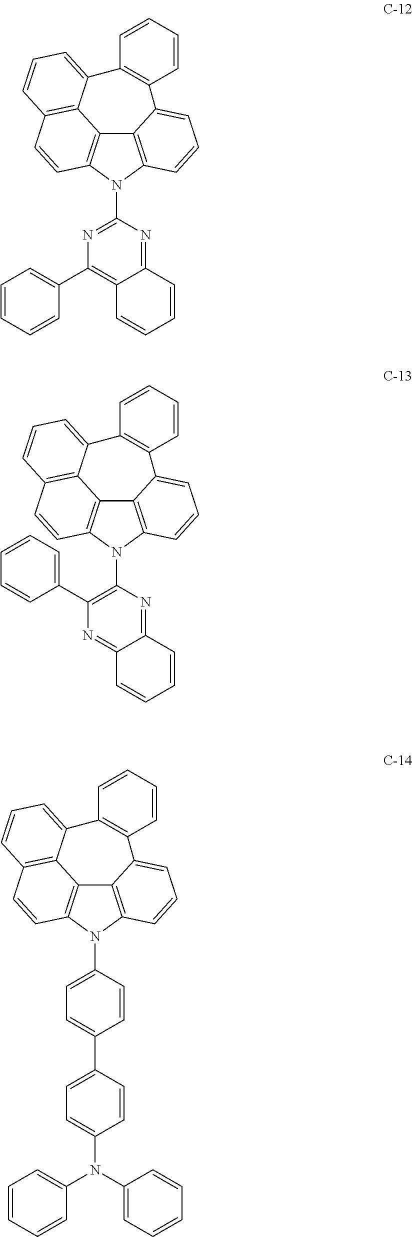 [SMILES: c1ccc(-c2nc(-n3c4cccc5c4c4c6c(cccc6ccc43)-c3ccccc3-5)nc3ccccc23)cc1 ; c1ccc(-c2nc3ccccc3nc2-n2c3cccc4c3c3c5c(cccc5ccc32)-c2ccccc2-4)cc1 ; c1ccc(N(c2ccccc2)c2ccc(-c3ccc(-n4c5cccc6c5c5c7c(cccc7ccc54)-c4ccccc4-6)cc3)cc2)cc1]

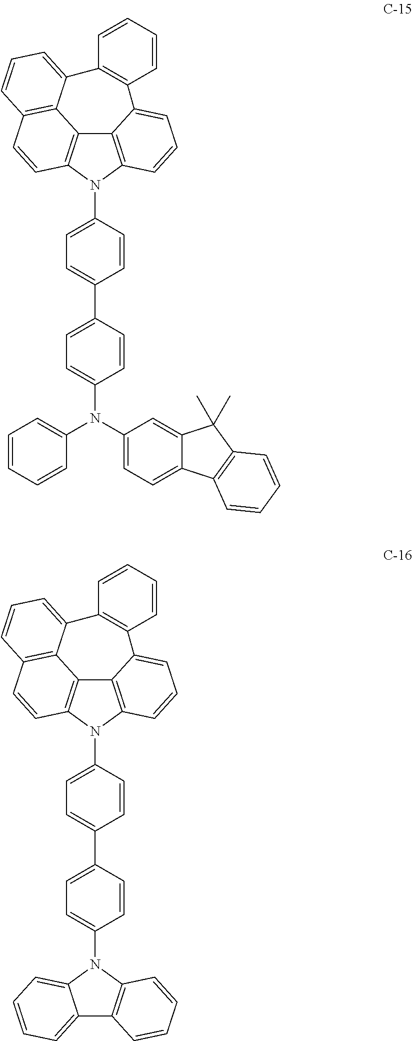 [SMILES: CC1(C)c2ccccc2-c2ccc(N(c3ccccc3)c3ccc(-c4ccc(-n5c6cccc7c6c6c8c(cccc8ccc65)-c5ccccc5-7)cc4)cc3)cc21 ; c1ccc2c(c1)-c1cccc3ccc4c(c13)c1c-2cccc1n4-c1ccc(-c2ccc(-n3c4ccccc4c4ccccc43)cc2)cc1]

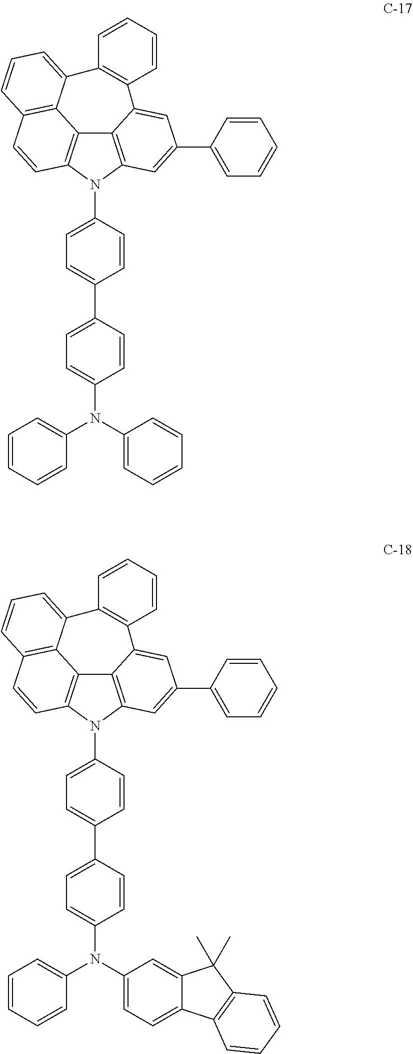 [SMILES: c1ccc(-c2cc3c4c5c6c(cccc6ccc5n(-c5ccc(-c6ccc(N(c7ccccc7)c7ccccc7)cc6)cc5)c4c2)-c2ccccc2-3)cc1 ; CC1(C)c2ccccc2-c2ccc(N(c3ccccc3)c3ccc(-c4ccc(-n5c6cc(-c7ccccc7)cc7c6c6c8c(cccc8ccc65)-c5ccccc5-7)cc4)cc3)cc21]

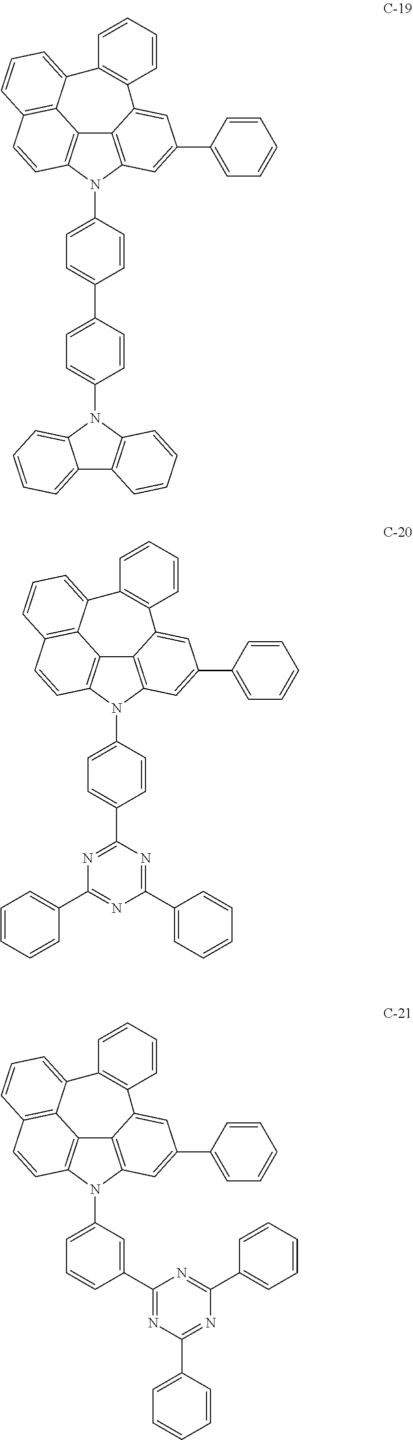 [SMILES: c1ccc(-c2cc3c4c5c6c(cccc6ccc5n(-c5ccc(-c6ccc(-n7c8ccccc8c8ccccc87)cc6)cc5)c4c2)-c2ccccc2-3)cc1 ; c1ccc(-c2cc3c4c5c6c(cccc6ccc5n(-c5ccc(-c6nc(-c7ccccc7)nc(-c7ccccc7)n6)cc5)c4c2)-c2ccccc2-3)cc1 ; c1ccc(-c2cc3c4c5c6c(cccc6ccc5n(-c5cccc(-c6nc(-c7ccccc7)nc(-c7ccccc7)n6)c5)c4c2)-c2ccccc2-3)cc1]

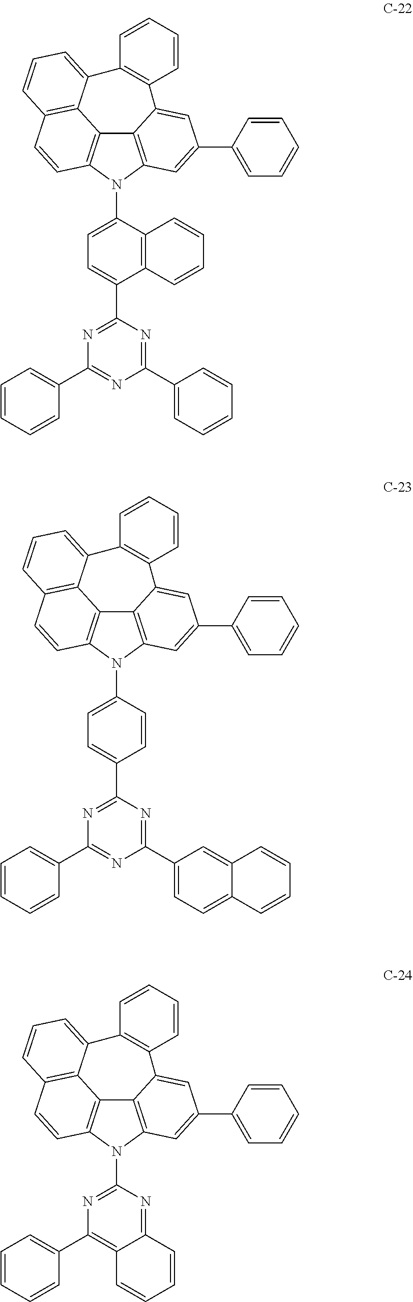 [SMILES: c1ccc(-c2cc3c4c5c6c(cccc6ccc5n(-c5ccc(-c6nc(-c7ccccc7)nc(-c7ccccc7)n6)c6ccccc56)c4c2)-c2ccccc2-3)cc1 ; c1ccc(-c2cc3c4c5c6c(cccc6ccc5n(-c5ccc(-c6nc(-c7ccccc7)nc(-c7ccc8ccccc8c7)n6)cc5)c4c2)-c2ccccc2-3)cc1 ; c1ccc(-c2cc3c4c5c6c(cccc6ccc5n(-c5nc(-c6ccccc6)c6ccccc6n5)c4c2)-c2ccccc2-3)cc1]

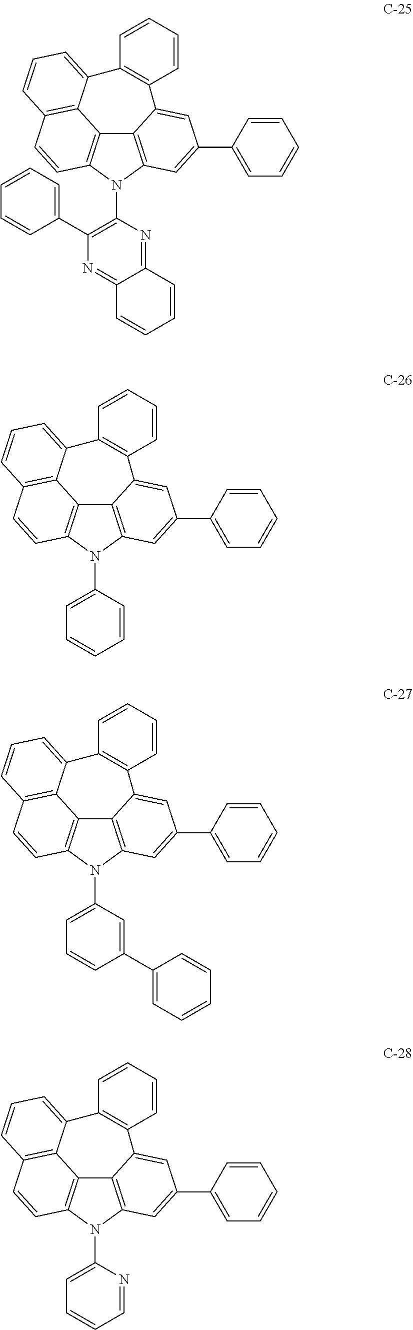 [SMILES: c1ccc(-c2cc3c4c5c6c(cccc6ccc5n(-c5nc6ccccc6nc5-c5ccccc5)c4c2)-c2ccccc2-3)cc1 ; c1ccc(-c2cc3c4c5c6c(cccc6ccc5n(-c5ccccc5)c4c2)-c2ccccc2-3)cc1 ; c1ccc(-c2cccc(-n3c4cc(-c5ccccc5)cc5c4c4c6c(cccc6ccc43)-c3ccccc3-5)c2)cc1 ; c1ccc(-c2cc3c4c5c6c(cccc6ccc5n(-c5ccccn5)c4c2)-c2ccccc2-3)cc1]

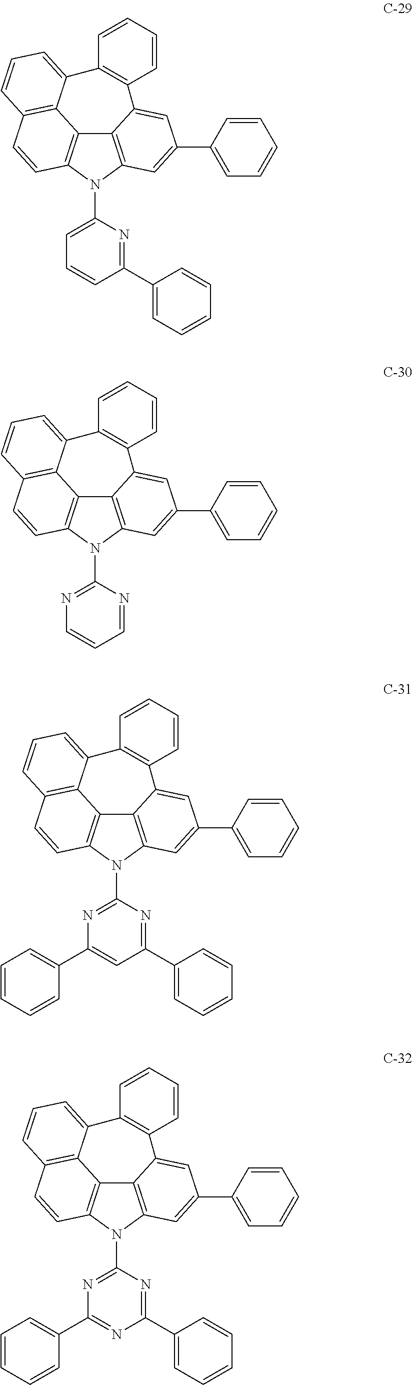 [SMILES: c1ccc(-c2cc3c4c5c6c(cccc6ccc5n(-c5cccc(-c6ccccc6)n5)c4c2)-c2ccccc2-3)cc1 ; c1ccc(-c2cc3c4c5c6c(cccc6ccc5n(-c5ncccn5)c4c2)-c2ccccc2-3)cc1 ; c1ccc(-c2cc3c4c5c6c(cccc6ccc5n(-c5nc(-c6ccccc6)cc(-c6ccccc6)n5)c4c2)-c2ccccc2-3)cc1 ; c1ccc(-c2cc3c4c5c6c(cccc6ccc5n(-c5nc(-c6ccccc6)nc(-c6ccccc6)n5)c4c2)-c2ccccc2-3)cc1]

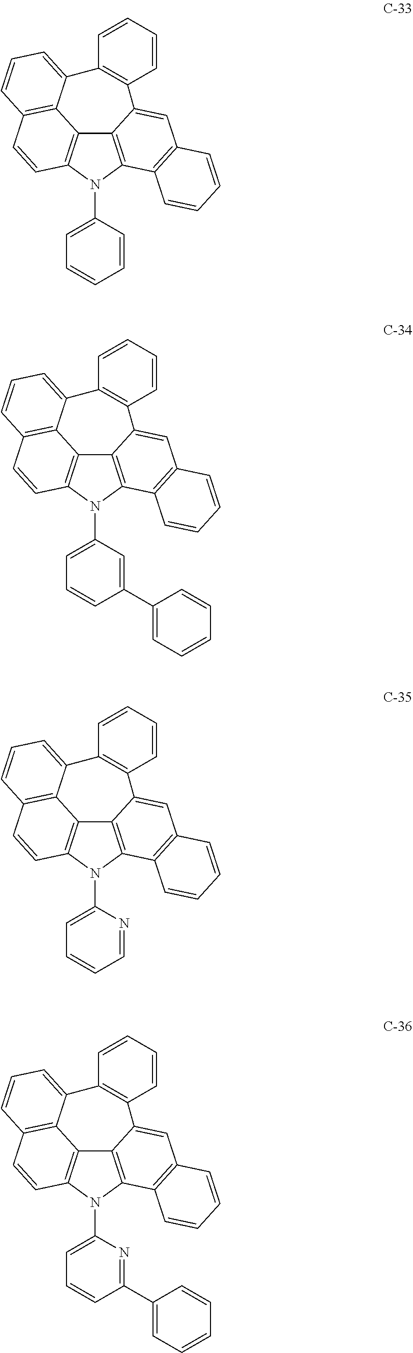 [SMILES: c1ccc(-n2c3ccc4cccc5c4c3c3c(cc4ccccc4c32)-c2ccccc2-5)cc1 ; c1ccc(-c2cccc(-n3c4ccc5cccc6c5c4c4c(cc5ccccc5c43)-c3ccccc3-6)c2)cc1 ; c1ccc(-n2c3ccc4cccc5c4c3c3c(cc4ccccc4c32)-c2ccccc2-5)nc1 ; c1ccc(-c2cccc(-n3c4ccc5cccc6c5c4c4c(cc5ccccc5c43)-c3ccccc3-6)n2)cc1]

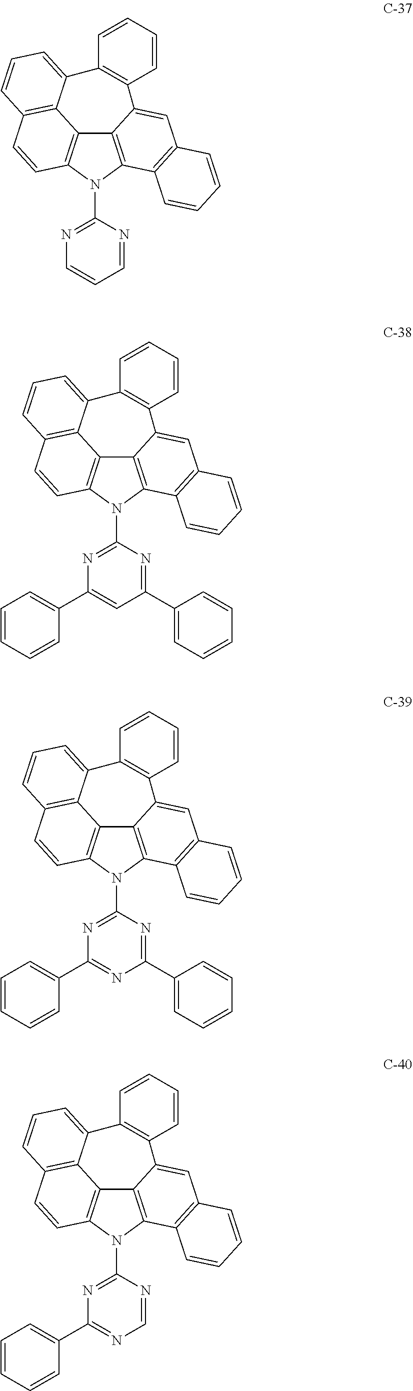 [SMILES: c1cnc(-n2c3ccc4cccc5c4c3c3c(cc4ccccc4c32)-c2ccccc2-5)nc1 ; c1ccc(-c2cc(-c3ccccc3)nc(-n3c4ccc5cccc6c5c4c4c(cc5ccccc5c43)-c3ccccc3-6)n2)cc1 ; c1ccc(-c2nc(-c3ccccc3)nc(-n3c4ccc5cccc6c5c4c4c(cc5ccccc5c43)-c3ccccc3-6)n2)cc1 ; c1ccc(-c2ncnc(-n3c4ccc5cccc6c5c4c4c(cc5ccccc5c43)-c3ccccc3-6)n2)cc1]

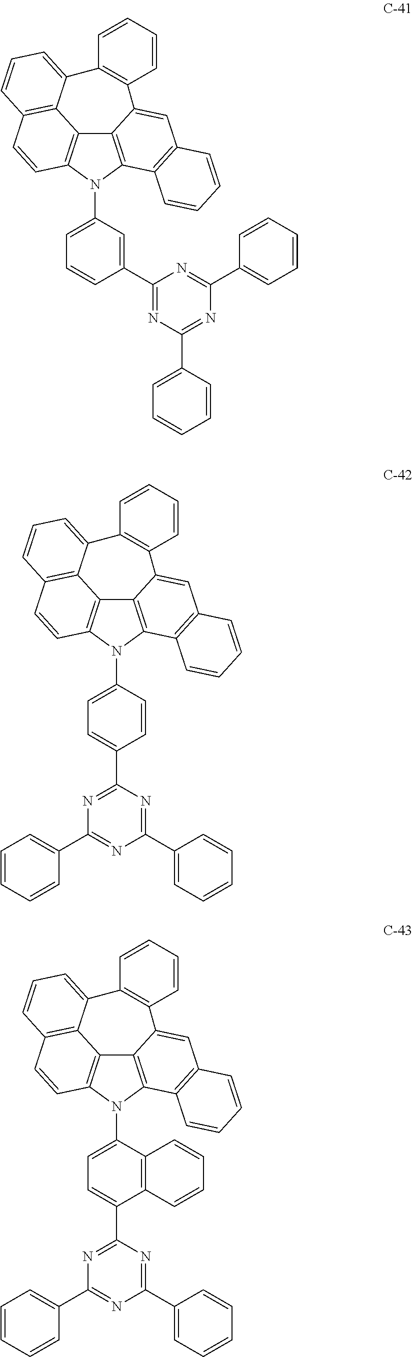 [SMILES: c1ccc(-c2nc(-c3ccccc3)nc(-c3cccc(-n4c5ccc6cccc7c6c5c5c(cc6ccccc6c54)-c4ccccc4-7)c3)n2)cc1 ; c1ccc(-c2nc(-c3ccccc3)nc(-c3ccc(-n4c5ccc6cccc7c6c5c5c(cc6ccccc6c54)-c4ccccc4-7)cc3)n2)cc1 ; c1ccc(-c2nc(-c3ccccc3)nc(-c3ccc(-n4c5ccc6cccc7c6c5c5c(cc6ccccc6c54)-c4ccccc4-7)c4ccccc34)n2)cc1]

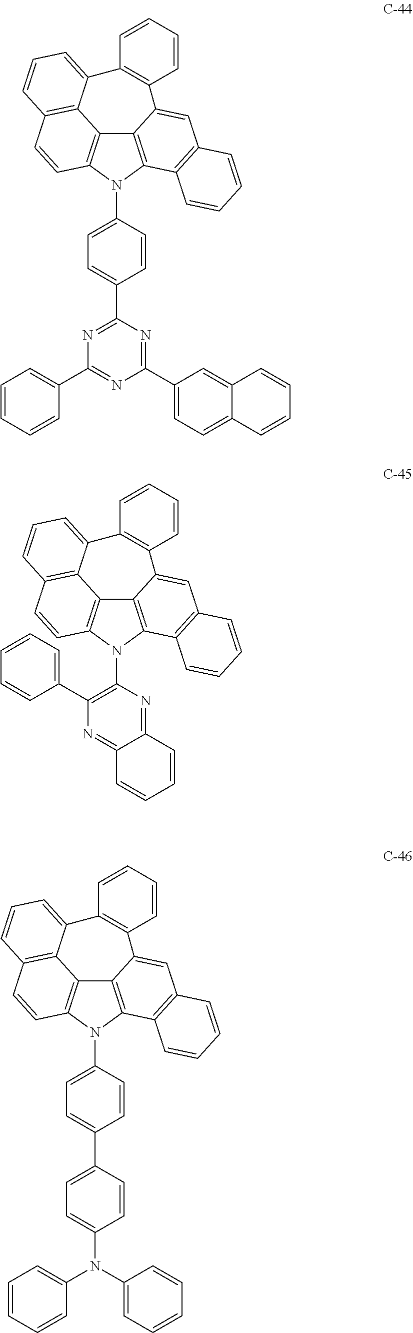 [SMILES: c1ccc(-c2nc(-c3ccc(-n4c5ccc6cccc7c6c5c5c(cc6ccccc6c54)-c4ccccc4-7)cc3)nc(-c3ccc4ccccc4c3)n2)cc1 ; c1ccc(-c2nc3ccccc3nc2-n2c3ccc4cccc5c4c3c3c(cc4ccccc4c32)-c2ccccc2-5)cc1 ; c1ccc(N(c2ccccc2)c2ccc(-c3ccc(-n4c5ccc6cccc7c6c5c5c(cc6ccccc6c54)-c4ccccc4-7)cc3)cc2)cc1]

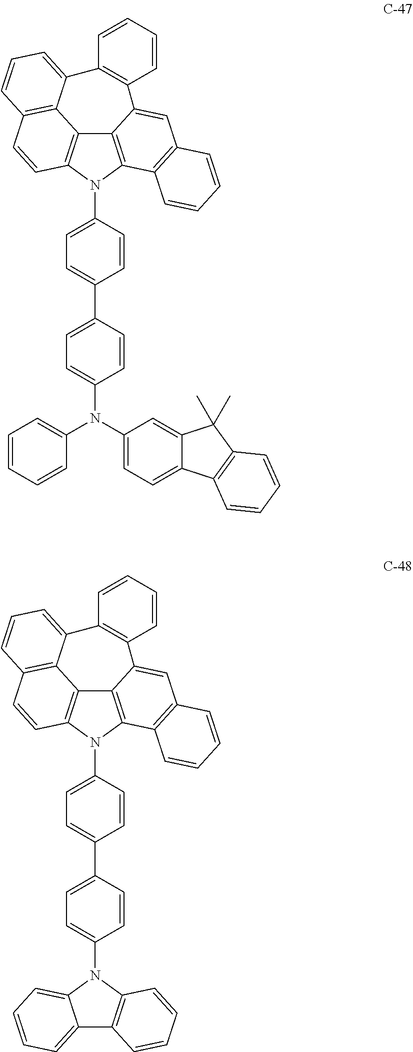 [SMILES: CC1(C)c2ccccc2-c2ccc(N(c3ccccc3)c3ccc(-c4ccc(-n5c6ccc7cccc8c7c6c6c(cc7ccccc7c65)-c5ccccc5-8)cc4)cc3)cc21 ; c1ccc2c(c1)-c1cccc3ccc4c(c13)c1c-2cc2ccccc2c1n4-c1ccc(-c2ccc(-n3c4ccccc4c4ccccc43)cc2)cc1]

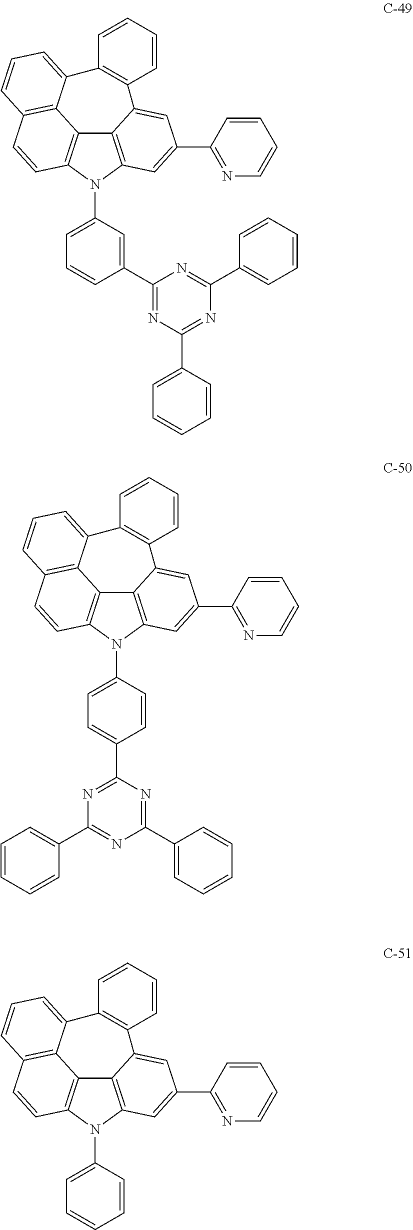 [SMILES: c1ccc(-c2nc(-c3ccccc3)nc(-c3cccc(-n4c5cc(-c6ccccn6)cc6c5c5c7c(cccc7ccc54)-c4ccccc4-6)c3)n2)cc1 ; c1ccc(-c2nc(-c3ccccc3)nc(-c3ccc(-n4c5cc(-c6ccccn6)cc6c5c5c7c(cccc7ccc54)-c4ccccc4-6)cc3)n2)cc1 ; c1ccc(-n2c3cc(-c4ccccn4)cc4c3c3c5c(cccc5ccc32)-c2ccccc2-4)cc1]

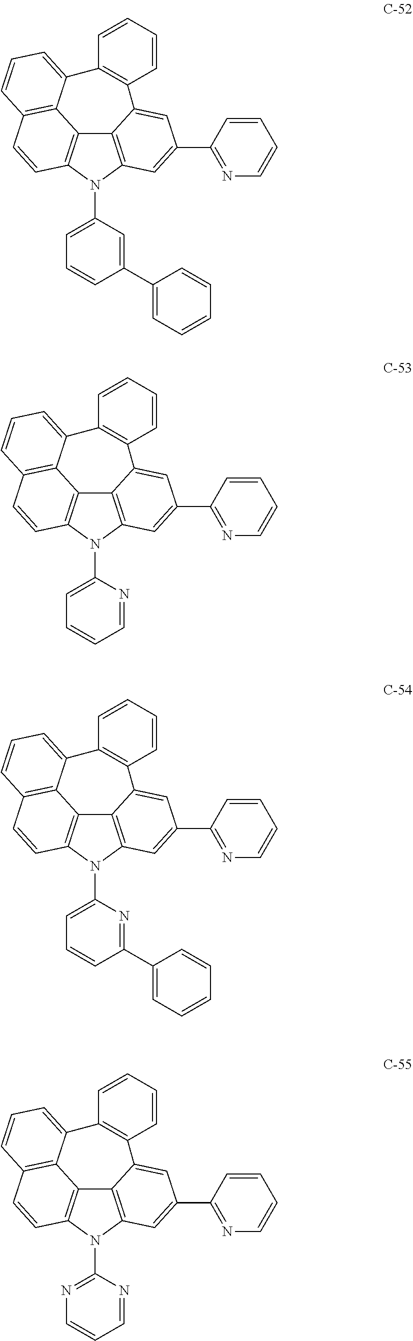 [SMILES: c1ccc(-c2cccc(-n3c4cc(-c5ccccn5)cc5c4c4c6c(cccc6ccc43)-c3ccccc3-5)c2)cc1 ; c1ccc(-c2cc3c4c5c6c(cccc6ccc5n(-c5ccccn5)c4c2)-c2ccccc2-3)nc1 ; c1ccc(-c2cccc(-n3c4cc(-c5ccccn5)cc5c4c4c6c(cccc6ccc43)-c3ccccc3-5)n2)cc1 ; c1ccc(-c2cc3c4c5c6c(cccc6ccc5n(-c5ncccn5)c4c2)-c2ccccc2-3)nc1]

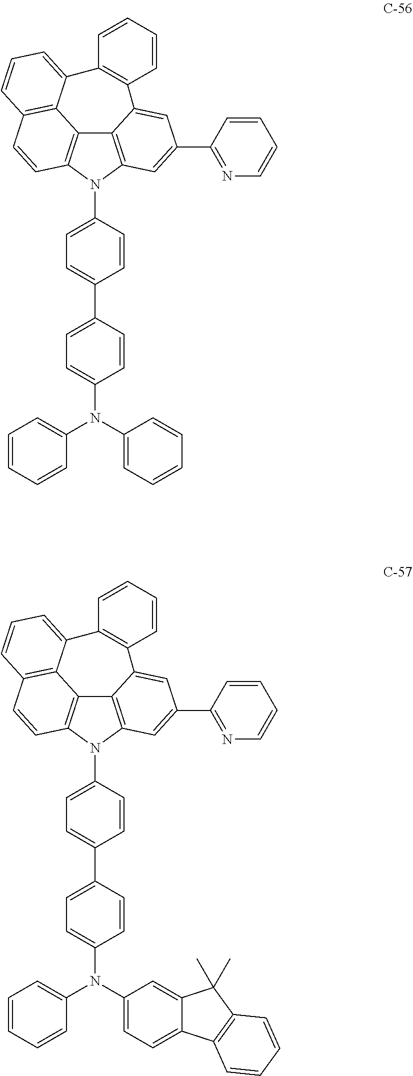 [SMILES: c1ccc(N(c2ccccc2)c2ccc(-c3ccc(-n4c5cc(-c6ccccn6)cc6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cc(-c7ccccn7)cc7c6c6c8c(cccc8ccc65)-c5ccccc5-7)cc4)cc3)cc21]

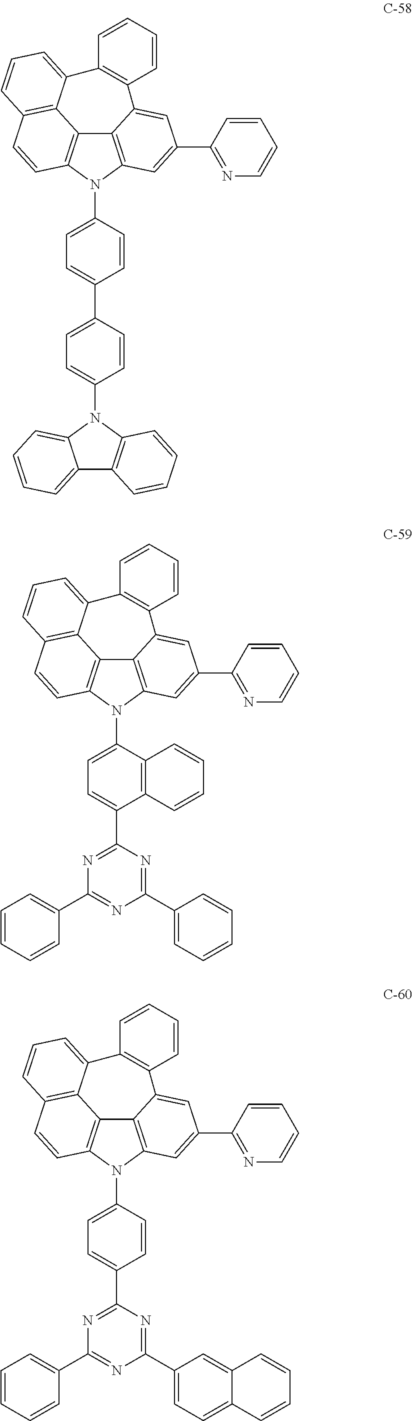 [SMILES: c1ccc(-c2cc3c4c5c6c(cccc6ccc5n(-c5ccc(-c6ccc(-n7c8ccccc8c8ccccc87)cc6)cc5)c4c2)-c2ccccc2-3)nc1 ; c1ccc(-c2nc(-c3ccccc3)nc(-c3ccc(-n4c5cc(-c6ccccn6)cc6c5c5c7c(cccc7ccc54)-c4ccccc4-6)c4ccccc34)n2)cc1 ; c1ccc(-c2nc(-c3ccc(-n4c5cc(-c6ccccn6)cc6c5c5c7c(cccc7ccc54)-c4ccccc4-6)cc3)nc(-c3ccc4ccccc4c3)n2)cc1]

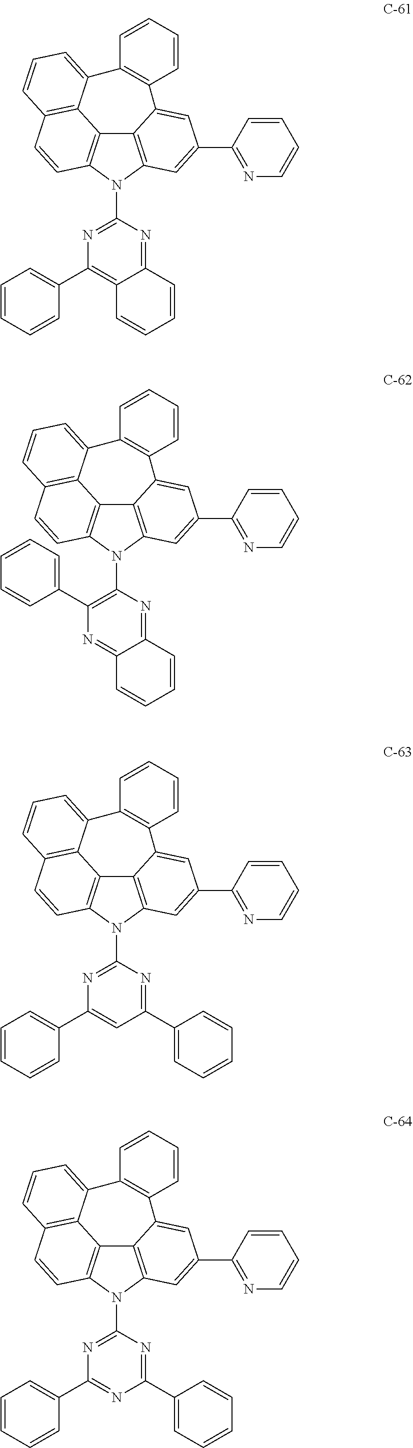 [SMILES: c1ccc(-c2nc(-n3c4cc(-c5ccccn5)cc5c4c4c6c(cccc6ccc43)-c3ccccc3-5)nc3ccccc23)cc1 ; c1ccc(-c2nc3ccccc3nc2-n2c3cc(-c4ccccn4)cc4c3c3c5c(cccc5ccc32)-c2ccccc2-4)cc1 ; c1ccc(-c2cc(-c3ccccc3)nc(-n3c4cc(-c5ccccn5)cc5c4c4c6c(cccc6ccc43)-c3ccccc3-5)n2)cc1 ; c1ccc(-c2nc(-c3ccccc3)nc(-n3c4cc(-c5ccccn5)cc5c4c4c6c(cccc6ccc43)-c3ccccc3-5)n2)cc1]

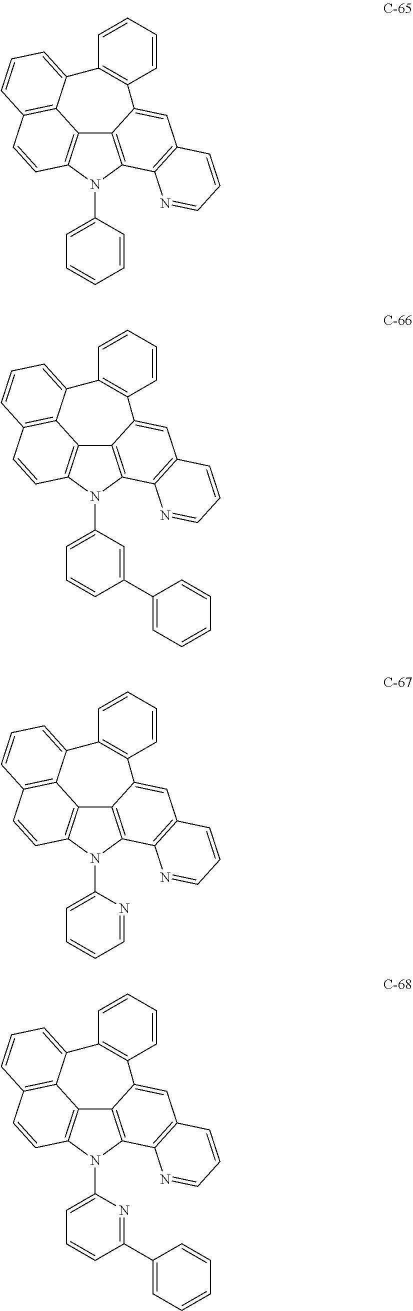 [SMILES: c1ccc(-n2c3ccc4cccc5c4c3c3c(cc4cccnc4c32)-c2ccccc2-5)cc1 ; c1ccc(-c2cccc(-n3c4ccc5cccc6c5c4c4c(cc5cccnc5c43)-c3ccccc3-6)c2)cc1 ; c1ccc(-n2c3ccc4cccc5c4c3c3c(cc4cccnc4c32)-c2ccccc2-5)nc1 ; c1ccc(-c2cccc(-n3c4ccc5cccc6c5c4c4c(cc5cccnc5c43)-c3ccccc3-6)n2)cc1]

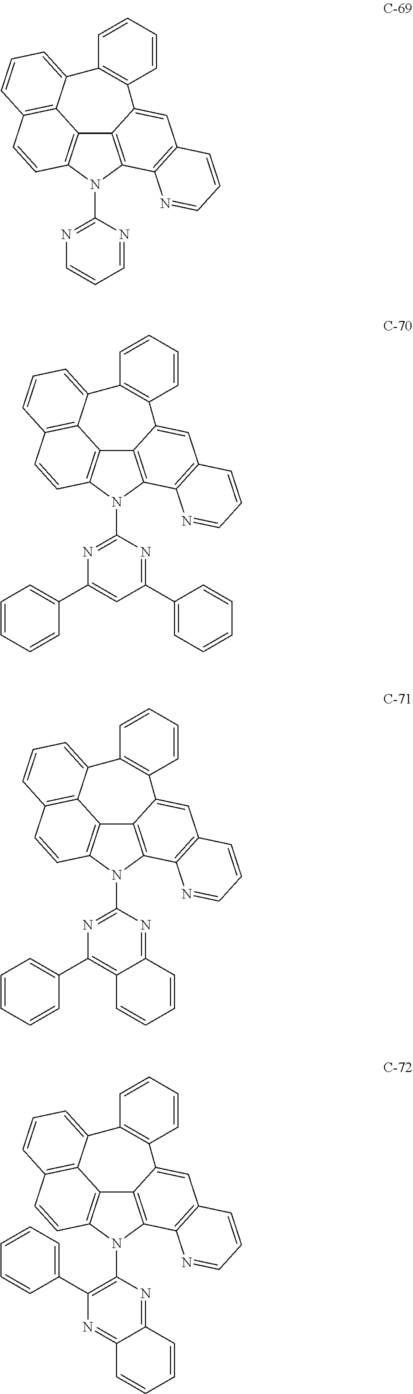 [SMILES: c1cnc(-n2c3ccc4cccc5c4c3c3c(cc4cccnc4c32)-c2ccccc2-5)nc1 ; c1ccc(-c2cc(-c3ccccc3)nc(-n3c4ccc5cccc6c5c4c4c(cc5cccnc5c43)-c3ccccc3-6)n2)cc1 ; c1ccc(-c2nc(-n3c4ccc5cccc6c5c4c4c(cc5cccnc5c43)-c3ccccc3-6)nc3ccccc23)cc1 ; c1ccc(-c2nc3ccccc3nc2-n2c3ccc4cccc5c4c3c3c(cc4cccnc4c32)-c2ccccc2-5)cc1]

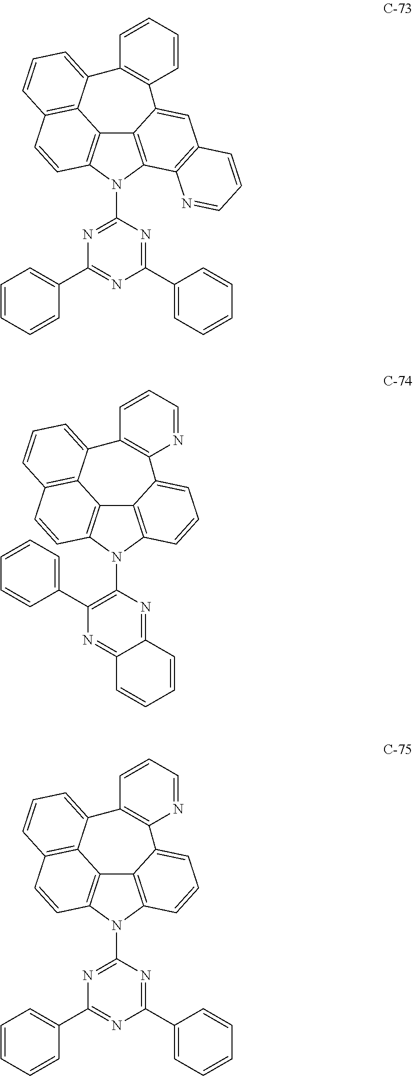 [SMILES: c1ccc(-c2nc(-c3ccccc3)nc(-n3c4ccc5cccc6c5c4c4c(cc5cccnc5c43)-c3ccccc3-6)n2)cc1 ; c1ccc(-c2nc3ccccc3nc2-n2c3cccc4c3c3c5c(cccc5ccc32)-c2cccnc2-4)cc1 ; c1ccc(-c2nc(-c3ccccc3)nc(-n3c4cccc5c4c4c6c(cccc6ccc43)-c3cccnc3-5)n2)cc1]

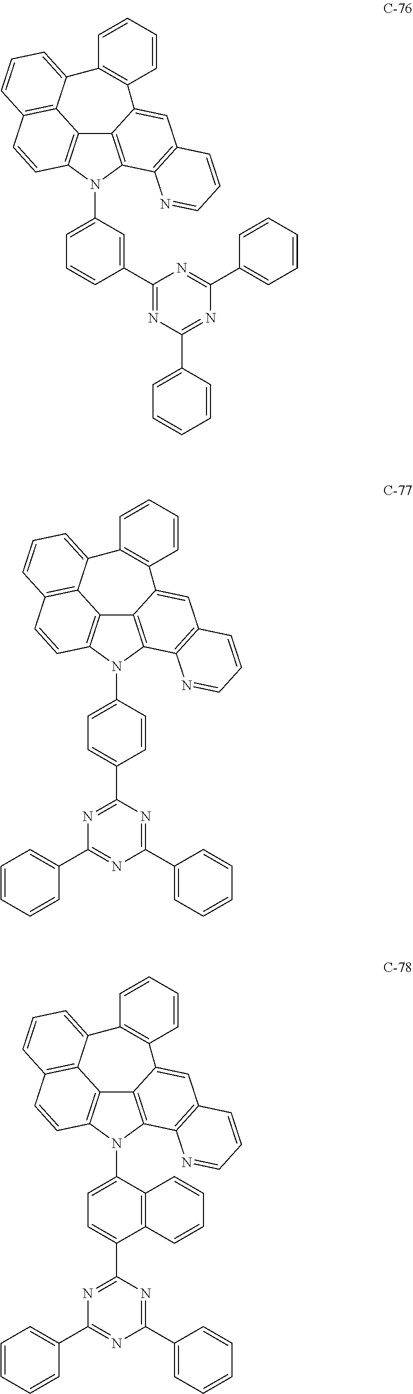 [SMILES: c1ccc(-c2nc(-c3ccccc3)nc(-c3cccc(-n4c5ccc6cccc7c6c5c5c(cc6cccnc6c54)-c4ccccc4-7)c3)n2)cc1 ; c1ccc(-c2nc(-c3ccccc3)nc(-c3ccc(-n4c5ccc6cccc7c6c5c5c(cc6cccnc6c54)-c4ccccc4-7)cc3)n2)cc1 ; c1ccc(-c2nc(-c3ccccc3)nc(-c3ccc(-n4c5ccc6cccc7c6c5c5c(cc6cccnc6c54)-c4ccccc4-7)c4ccccc34)n2)cc1]

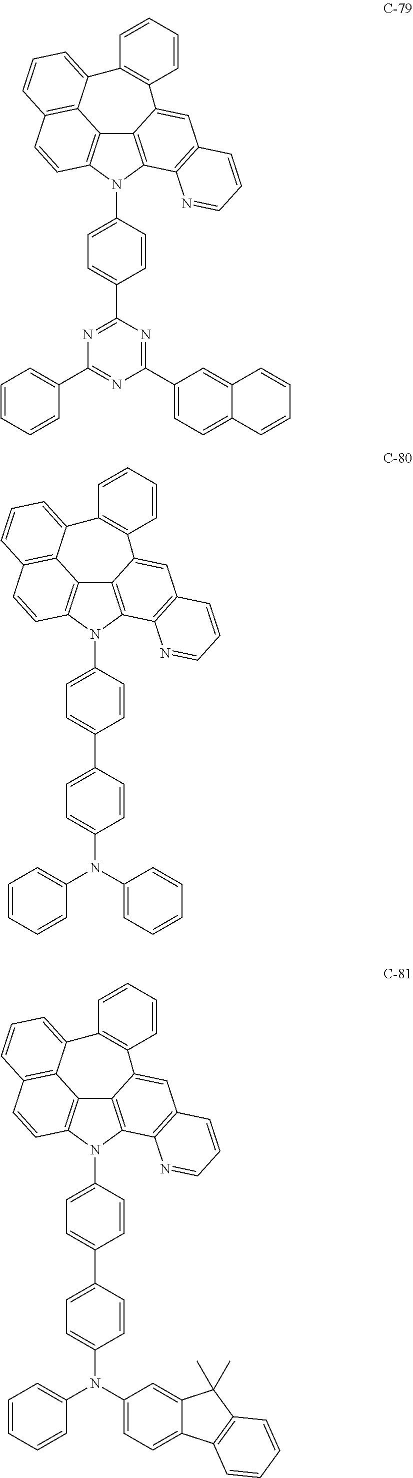 [SMILES: c1ccc(-c2nc(-c3ccc(-n4c5ccc6cccc7c6c5c5c(cc6cccnc6c54)-c4ccccc4-7)cc3)nc(-c3ccc4ccccc4c3)n2)cc1 ; c1ccc(N(c2ccccc2)c2ccc(-c3ccc(-n4c5ccc6cccc7c6c5c5c(cc6cccnc6c54)-c4ccccc4-7)cc3)cc2)cc1 ; CC1(C)c2ccccc2-c2ccc(N(c3ccccc3)c3ccc(-c4ccc(-n5c6ccc7cccc8c7c6c6c(cc7cccnc7c65)-c5ccccc5-8)cc4)cc3)cc21]

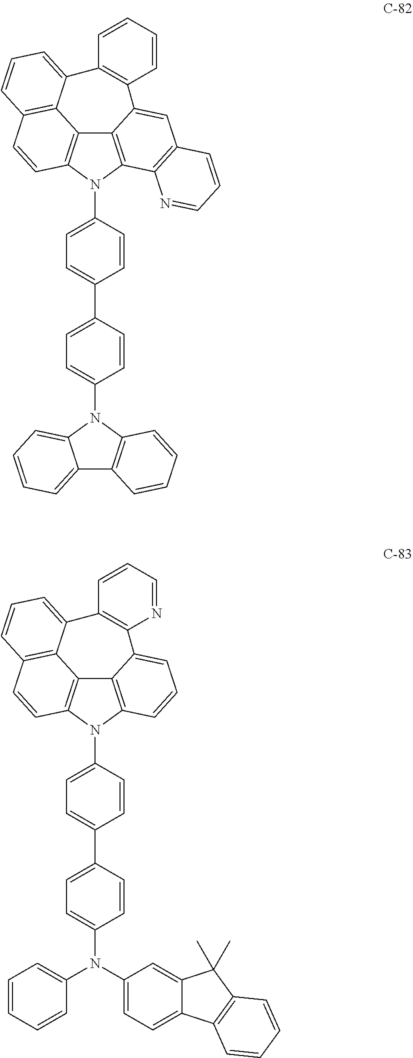 [SMILES: c1ccc2c(c1)-c1cccc3ccc4c(c13)c1c-2cc2cccnc2c1n4-c1ccc(-c2ccc(-n3c4ccccc4c4ccccc43)cc2)cc1 ; CC1(C)c2ccccc2-c2ccc(N(c3ccccc3)c3ccc(-c4ccc(-n5c6cccc7c6c6c8c(cccc8ccc65)-c5cccnc5-7)cc4)cc3)cc21]

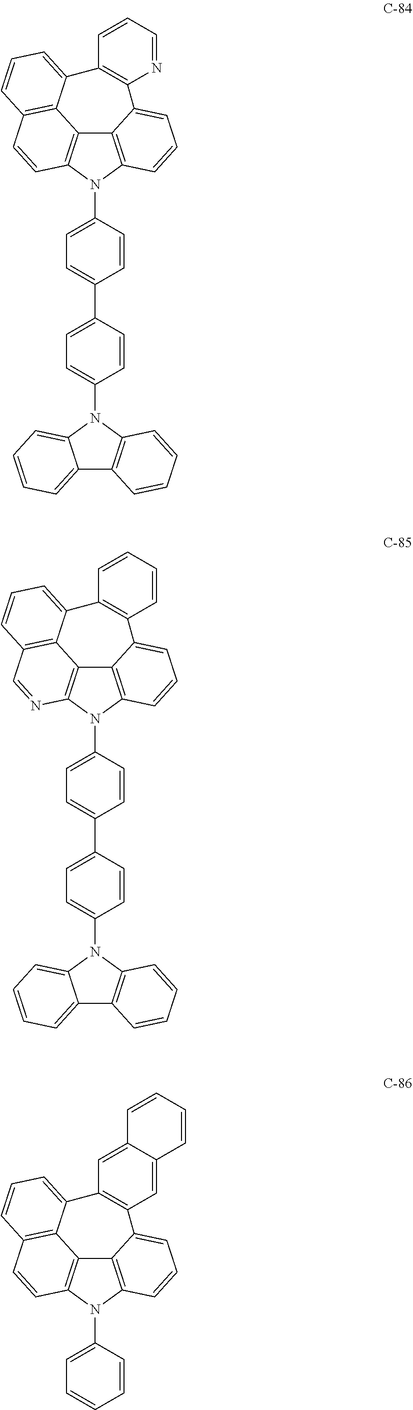 [SMILES: c1cnc2c(c1)-c1cccc3ccc4c(c13)c1c-2cccc1n4-c1ccc(-c2ccc(-n3c4ccccc4c4ccccc43)cc2)cc1 ; c1ccc2c(c1)-c1cccc3cnc4c(c13)c1c-2cccc1n4-c1ccc(-c2ccc(-n3c4ccccc4c4ccccc43)cc2)cc1 ; c1ccc(-n2c3cccc4c3c3c5c(cccc5ccc32)-c2cc3ccccc3cc2-4)cc1]

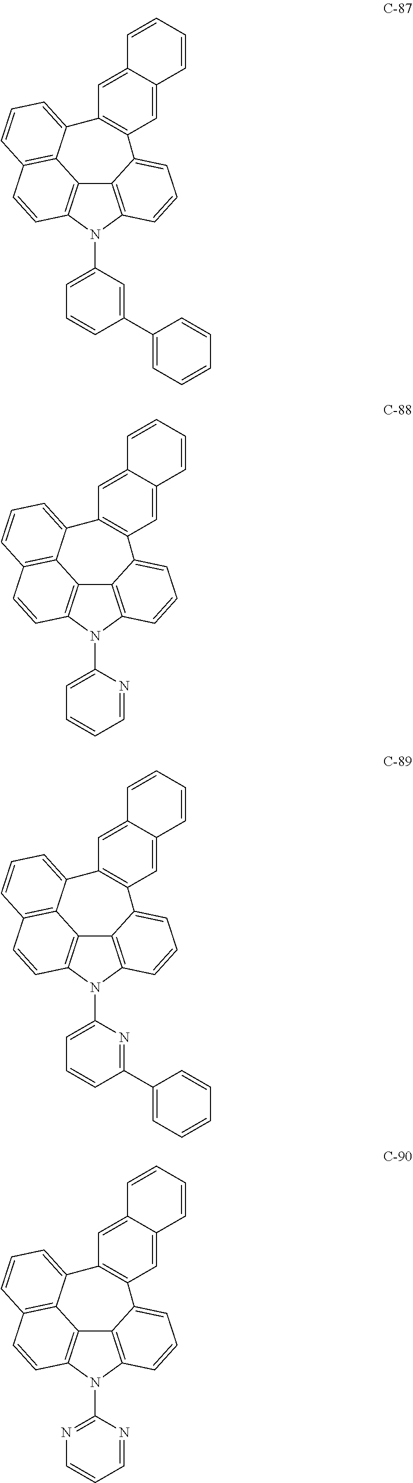

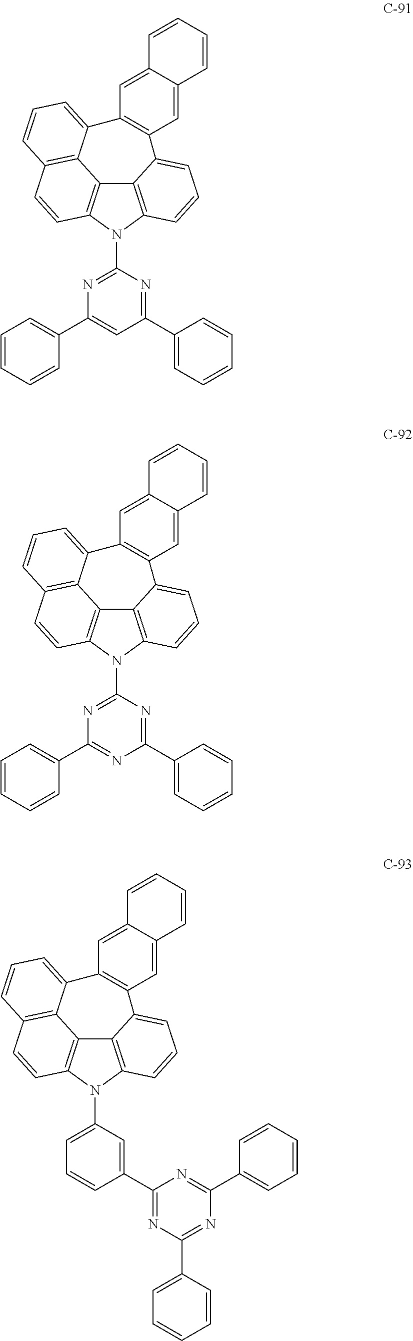 [SMILES: c1ccc(-c2cc(-c3ccccc3)nc(-n3c4cccc5c4c4c6c(cccc6ccc43)-c3cc4ccccc4cc3-5)n2)cc1 ; c1ccc(-c2nc(-c3ccccc3)nc(-n3c4cccc5c4c4c6c(cccc6ccc43)-c3cc4ccccc4cc3-5)n2)cc1 ; c1ccc(-c2nc(-c3ccccc3)nc(-c3cccc(-n4c5cccc6c5c5c7c(cccc7ccc54)-c4cc5ccccc5cc4-6)c3)n2)cc1]

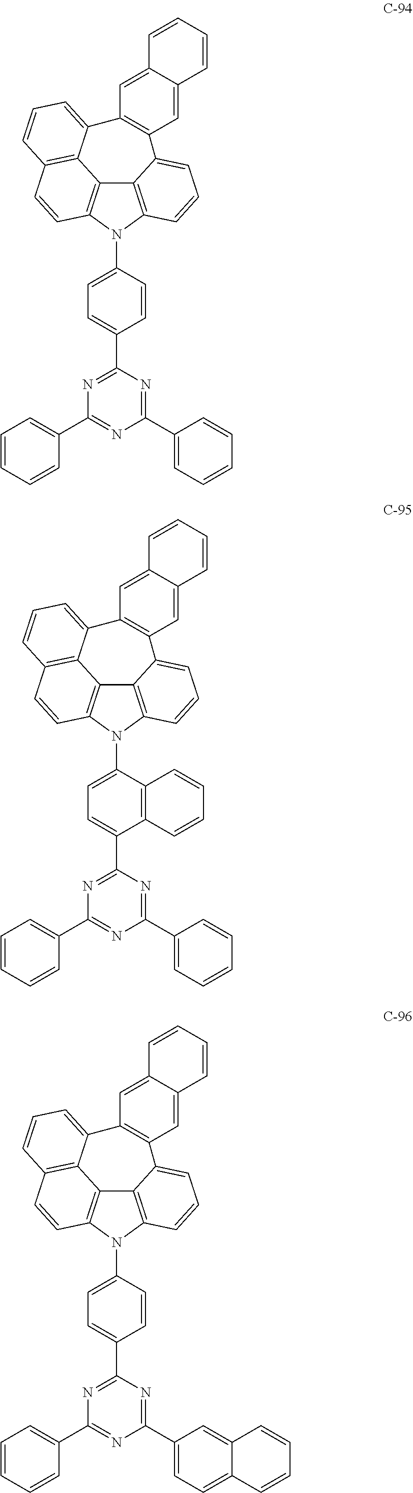

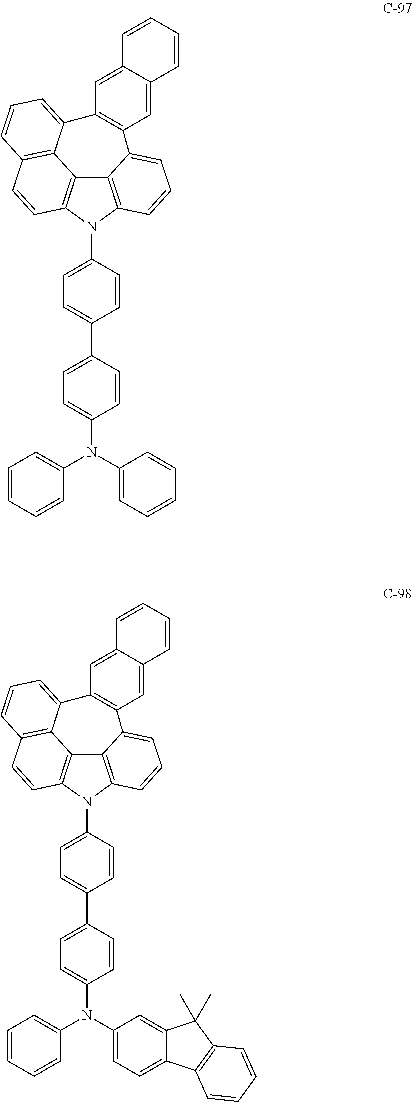 [SMILES: c1ccc(N(c2ccccc2)c2ccc(-c3ccc(-n4c5cccc6c5c5c7c(cccc7ccc54)-c4cc5ccccc5cc4-6)cc3)cc2)cc1 ; CC1(C)c2ccccc2-c2ccc(N(c3ccccc3)c3ccc(-c4ccc(-n5c6cccc7c6c6c8c(cccc8ccc65)-c5cc6ccccc6cc5-7)cc4)cc3)cc21]

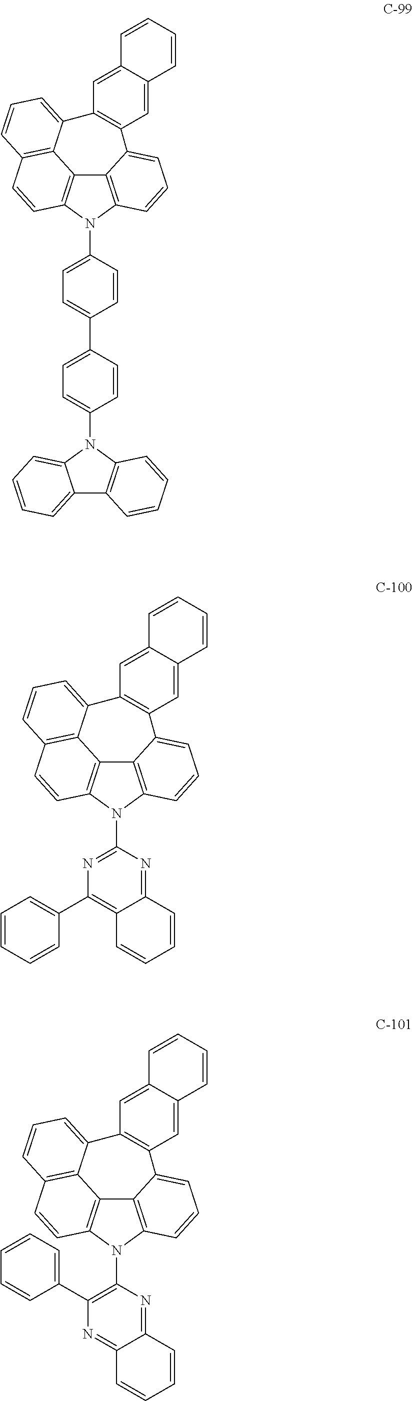 [SMILES: c1ccc2cc3c(cc2c1)-c1cccc2ccc4c(c12)c1c-3cccc1n4-c1ccc(-c2ccc(-n3c4ccccc4c4ccccc43)cc2)cc1 ; c1ccc(-c2nc(-n3c4cccc5c4c4c6c(cccc6ccc43)-c3cc4ccccc4cc3-5)nc3ccccc23)cc1 ; c1ccc(-c2nc3ccccc3nc2-n2c3cccc4c3c3c5c(cccc5ccc32)-c2cc3ccccc3cc2-4)cc1]

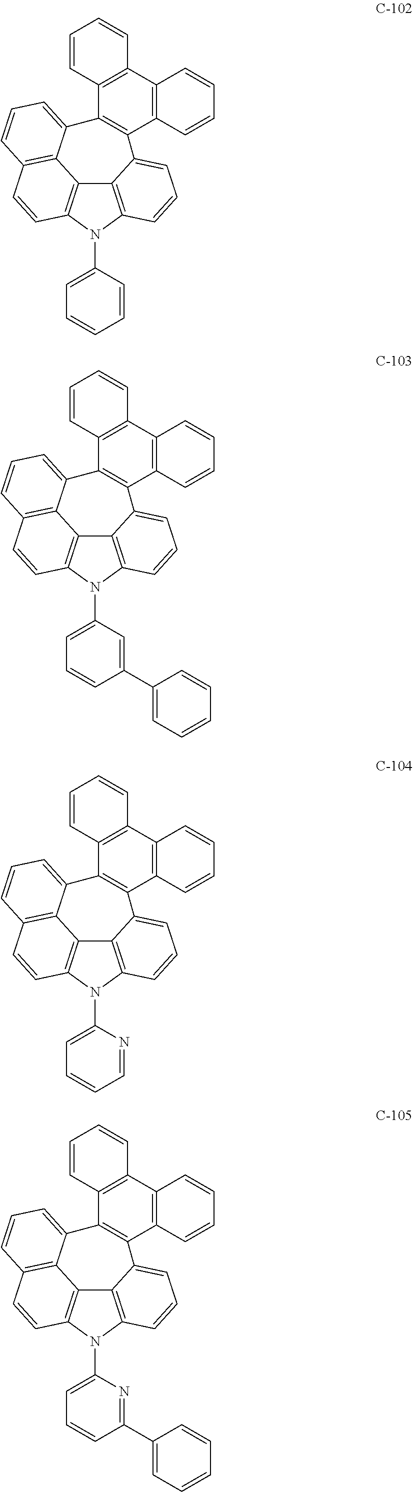

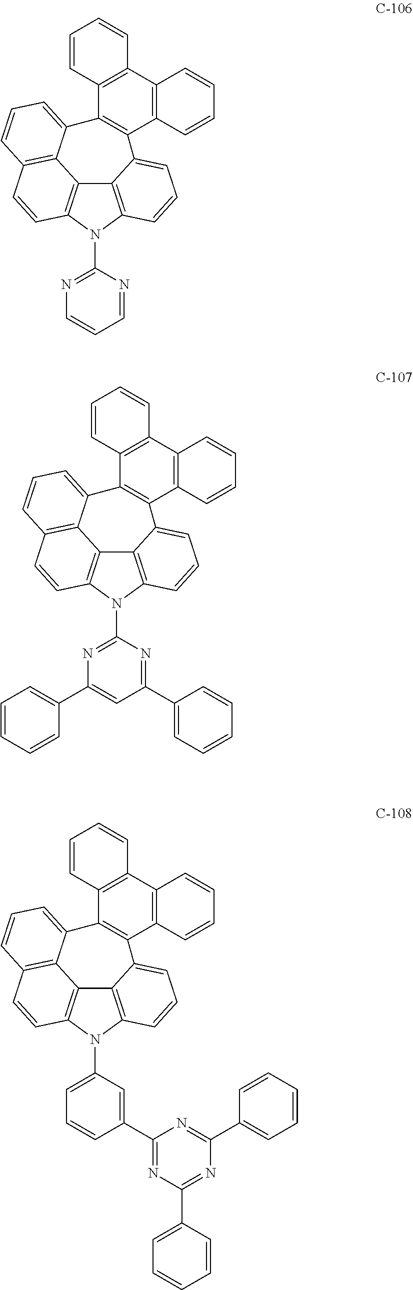 [SMILES: c1cnc(-n2c3cccc4c3c3c5c(cccc5ccc32)-c2c-4c3ccccc3c3ccccc23)nc1 ; c1ccc(-c2cc(-c3ccccc3)nc(-n3c4cccc5c4c4c6c(cccc6ccc43)-c3c-5c4ccccc4c4ccccc34)n2)cc1 ; c1ccc(-c2nc(-c3ccccc3)nc(-c3cccc(-n4c5cccc6c5c5c7c(cccc7ccc54)-c4c-6c5ccccc5c5ccccc45)c3)n2)cc1]

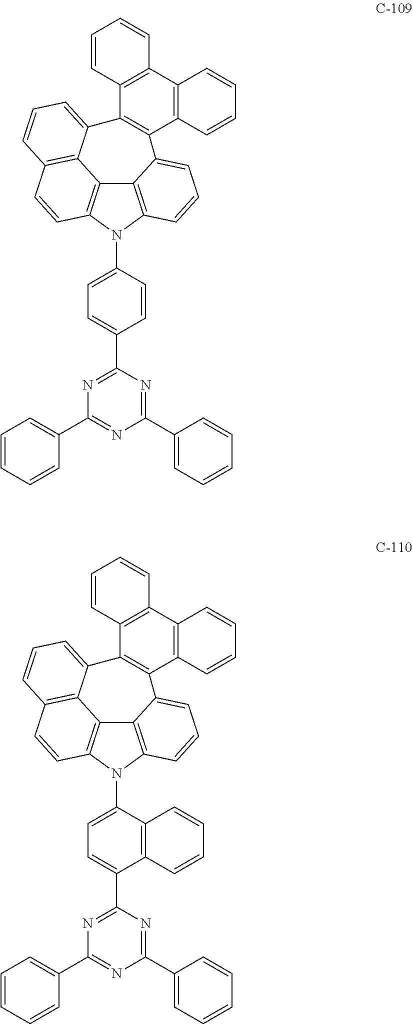 [SMILES: c1ccc(-c2nc(-c3ccccc3)nc(-c3ccc(-n4c5cccc6c5c5c7c(cccc7ccc54)-c4c-6c5ccccc5c5ccccc45)cc3)n2)cc1 ; c1ccc(-c2nc(-c3ccccc3)nc(-c3ccc(-n4c5cccc6c5c5c7c(cccc7ccc54)-c4c-6c5ccccc5c5ccccc45)c4ccccc34)n2)cc1]

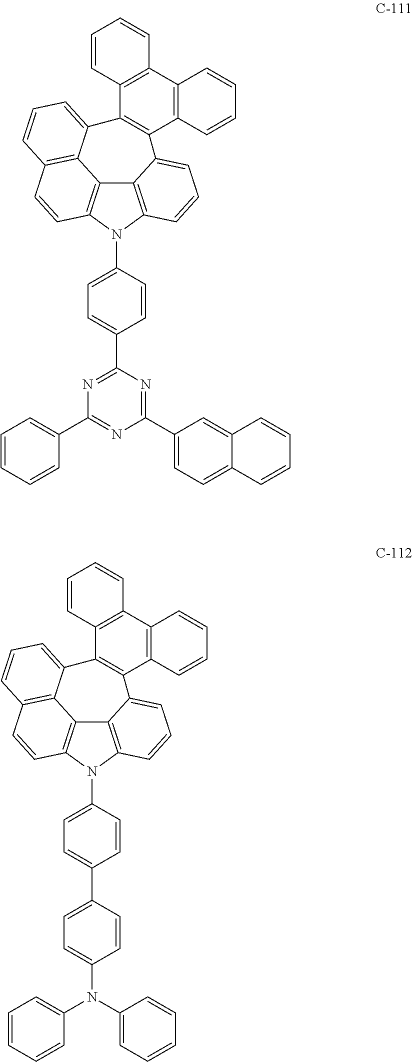 [SMILES: c1ccc(-c2nc(-c3ccc(-n4c5cccc6c5c5c7c(cccc7ccc54)-c4c-6c5ccccc5c5ccccc45)cc3)nc(-c3ccc4ccccc4c3)n2)cc1 ; c1ccc(N(c2ccccc2)c2ccc(-c3ccc(-n4c5cccc6c5c5c7c(cccc7ccc54)-c4c-6c5ccccc5c5ccccc45)cc3)cc2)cc1]

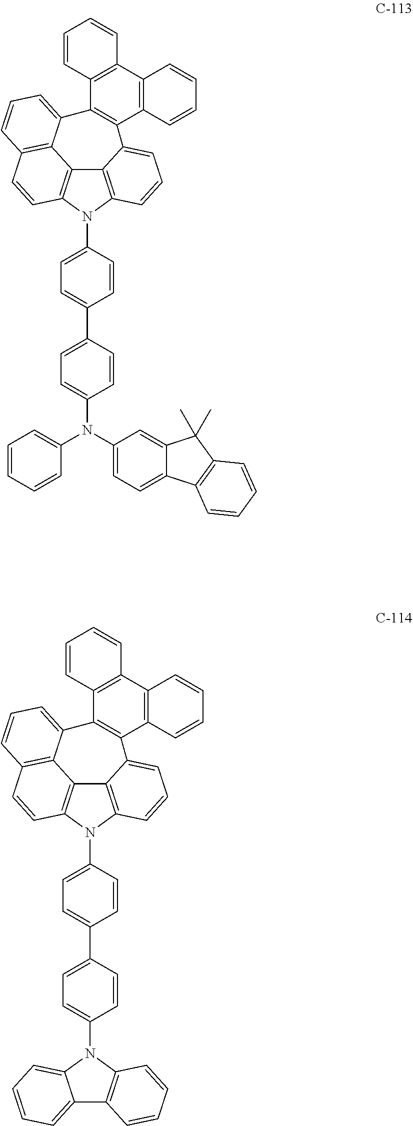 [SMILES: CC1(C)c2ccccc2-c2ccc(N(c3ccccc3)c3ccc(-c4ccc(-n5c6cccc7c6c6c8c(cccc8ccc65)-c5c-7c6ccccc6c6ccccc56)cc4)cc3)cc21 ; c1cc2c3c(c1)ccc1c3c3c(cccc3n1-c1ccc(-c3ccc(-n4c5ccccc5c5ccccc54)cc3)cc1)-c1c-2c2ccccc2c2ccccc12]

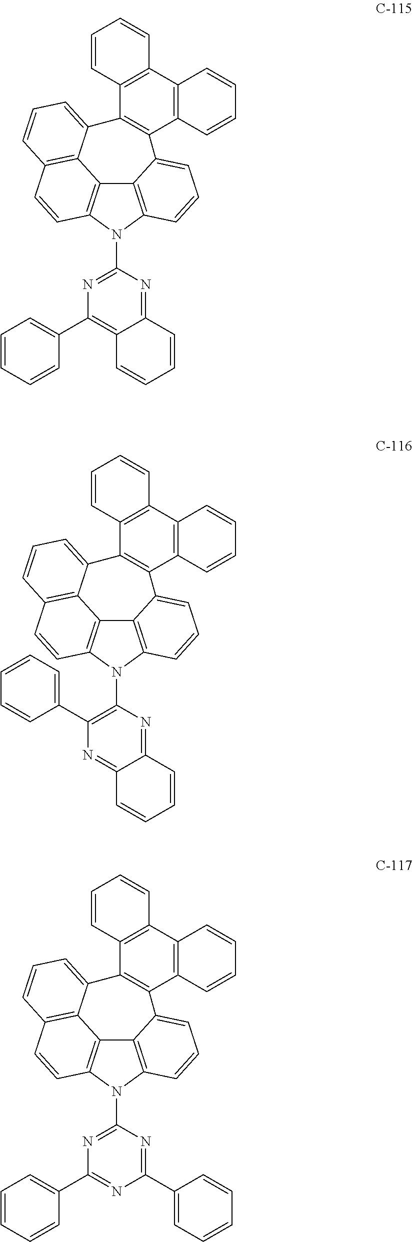 [SMILES: c1ccc(-c2nc(-n3c4cccc5c4c4c6c(cccc6ccc43)-c3c-5c4ccccc4c4ccccc34)nc3ccccc23)cc1 ; c1ccc(-c2nc3ccccc3nc2-n2c3cccc4c3c3c5c(cccc5ccc32)-c2c-4c3ccccc3c3ccccc23)cc1 ; c1ccc(-c2nc(-c3ccccc3)nc(-n3c4cccc5c4c4c6c(cccc6ccc43)-c3c-5c4ccccc4c4ccccc34)n2)cc1]

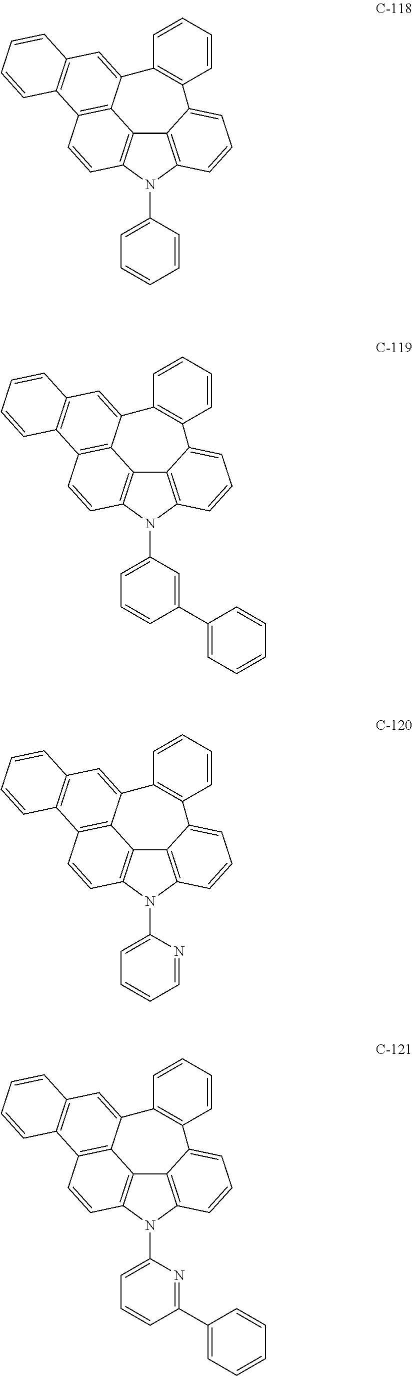 [SMILES: c1ccc(-n2c3cccc4c3c3c5c(cc6ccccc6c5ccc32)-c2ccccc2-4)cc1 ; c1ccc(-c2cccc(-n3c4cccc5c4c4c6c(cc7ccccc7c6ccc43)-c3ccccc3-5)c2)cc1 ; c1ccc(-n2c3cccc4c3c3c5c(cc6ccccc6c5ccc32)-c2ccccc2-4)nc1 ; c1ccc(-c2cccc(-n3c4cccc5c4c4c6c(cc7ccccc7c6ccc43)-c3ccccc3-5)n2)cc1]

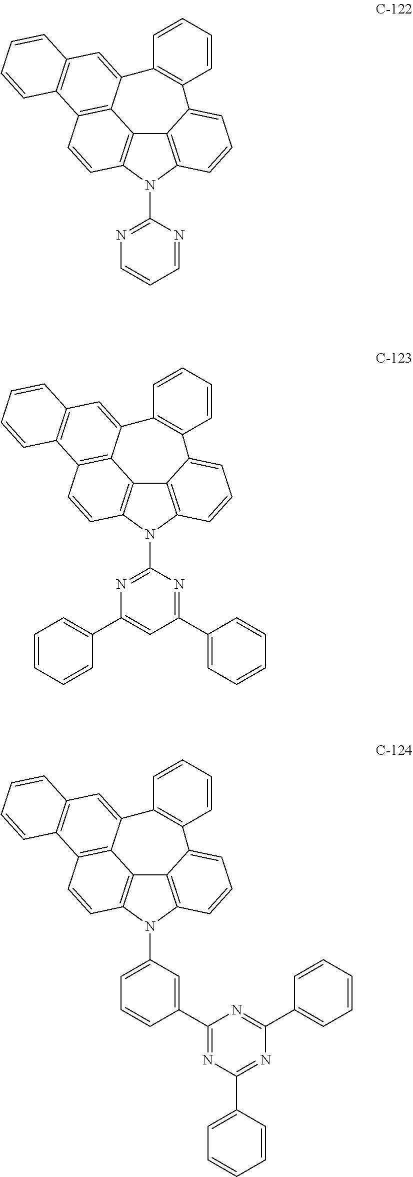 [SMILES: c1cnc(-n2c3cccc4c3c3c5c(cc6ccccc6c5ccc32)-c2ccccc2-4)nc1 ; c1ccc(-c2cc(-c3ccccc3)nc(-n3c4cccc5c4c4c6c(cc7ccccc7c6ccc43)-c3ccccc3-5)n2)cc1 ; c1ccc(-c2nc(-c3ccccc3)nc(-c3cccc(-n4c5cccc6c5c5c7c(cc8ccccc8c7ccc54)-c4ccccc4-6)c3)n2)cc1]

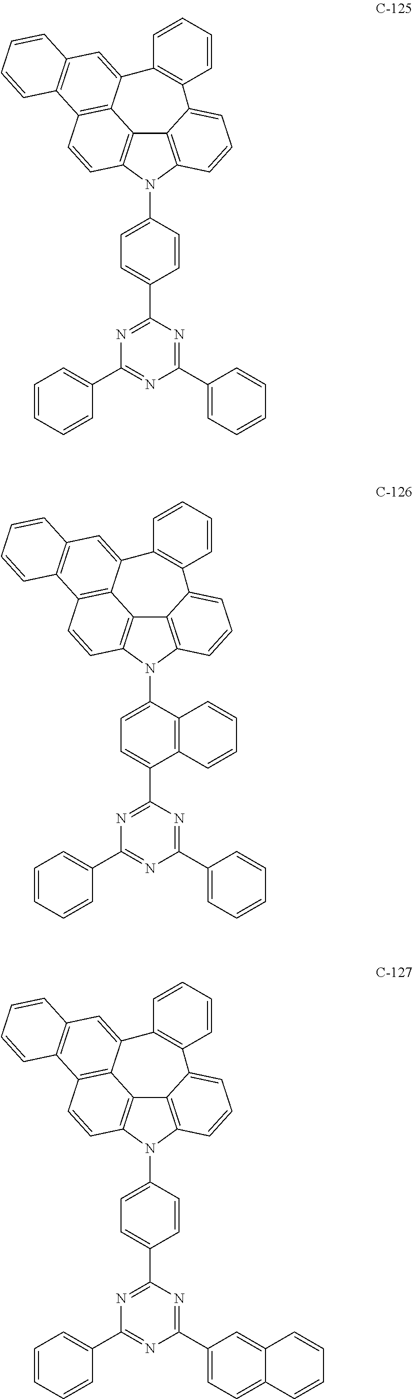 [SMILES: c1ccc(-c2nc(-c3ccccc3)nc(-c3ccc(-n4c5cccc6c5c5c7c(cc8ccccc8c7ccc54)-c4ccccc4-6)cc3)n2)cc1 ; c1ccc(-c2nc(-c3ccccc3)nc(-c3ccc(-n4c5cccc6c5c5c7c(cc8ccccc8c7ccc54)-c4ccccc4-6)c4ccccc34)n2)cc1 ; c1ccc(-c2nc(-c3ccc(-n4c5cccc6c5c5c7c(cc8ccccc8c7ccc54)-c4ccccc4-6)cc3)nc(-c3ccc4ccccc4c3)n2)cc1]

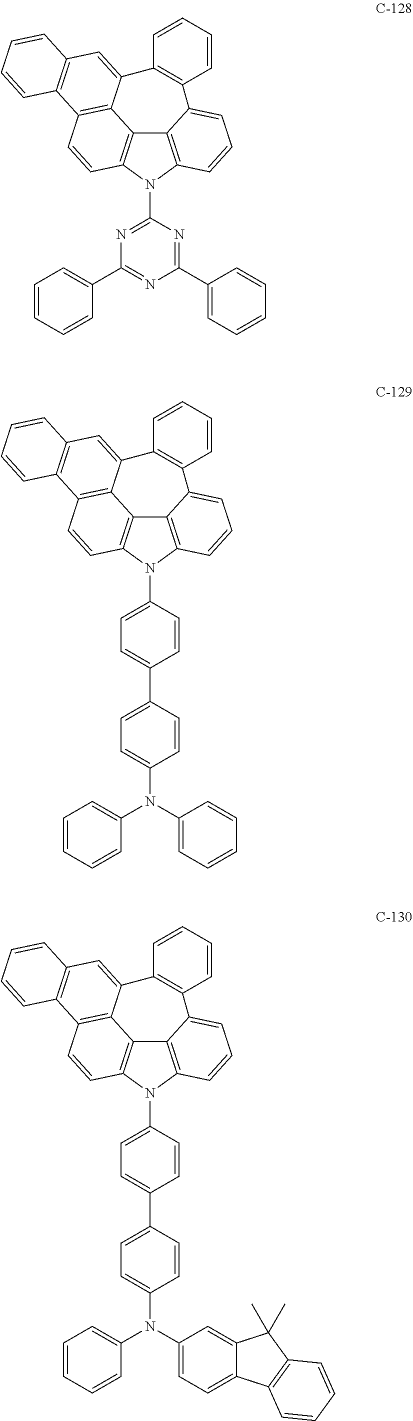 [SMILES: c1ccc(-c2nc(-c3ccccc3)nc(-n3c4cccc5c4c4c6c(cc7ccccc7c6ccc43)-c3ccccc3-5)n2)cc1 ; c1ccc(N(c2ccccc2)c2ccc(-c3ccc(-n4c5cccc6c5c5c7c(cc8ccccc8c7ccc54)-c4ccccc4-6)cc3)cc2)cc1 ; CC1(C)c2ccccc2-c2ccc(N(c3ccccc3)c3ccc(-c4ccc(-n5c6cccc7c6c6c8c(cc9ccccc9c8ccc65)-c5ccccc5-7)cc4)cc3)cc21]

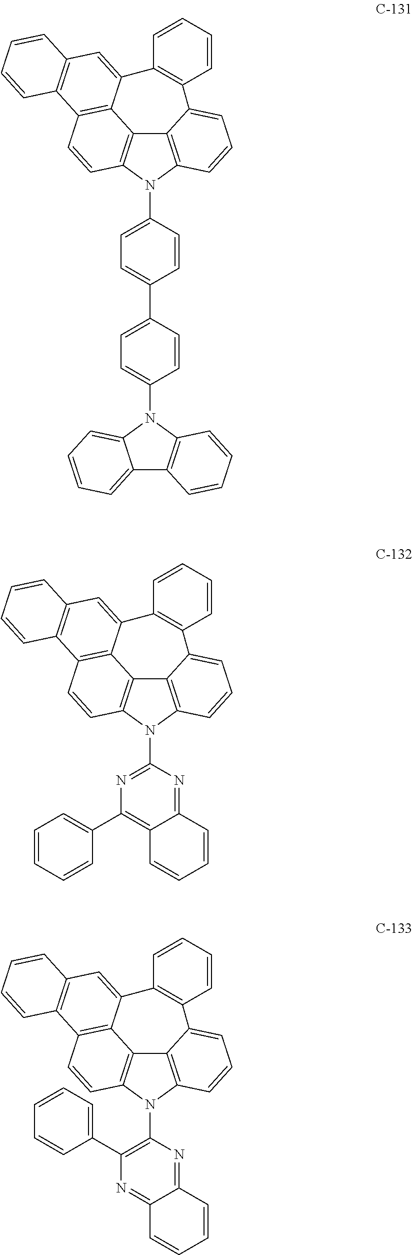 [SMILES: c1ccc2c(c1)-c1cc3ccccc3c3ccc4c(c13)c1c-2cccc1n4-c1ccc(-c2ccc(-n3c4ccccc4c4ccccc43)cc2)cc1 ; c1ccc(-c2nc(-n3c4cccc5c4c4c6c(cc7ccccc7c6ccc43)-c3ccccc3-5)nc3ccccc23)cc1 ; c1ccc(-c2nc3ccccc3nc2-n2c3cccc4c3c3c5c(cc6ccccc6c5ccc32)-c2ccccc2-4)cc1]

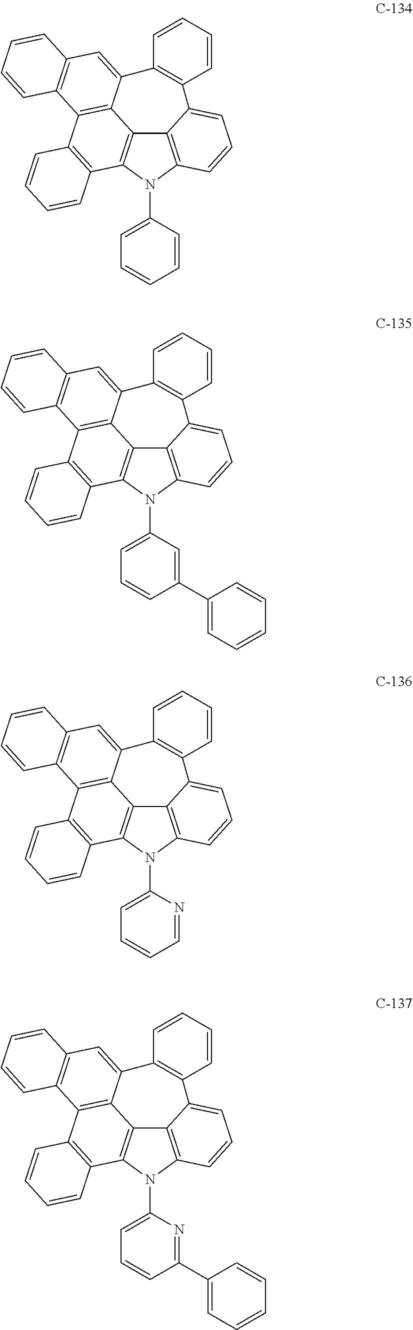 [SMILES: c1ccc(-n2c3cccc4c3c3c5c(cc6ccccc6c5c5ccccc5c32)-c2ccccc2-4)cc1 ; c1ccc(-c2cccc(-n3c4cccc5c4c4c6c(cc7ccccc7c6c6ccccc6c43)-c3ccccc3-5)c2)cc1 ; c1ccc(-n2c3cccc4c3c3c5c(cc6ccccc6c5c5ccccc5c32)-c2ccccc2-4)nc1 ; c1ccc(-c2cccc(-n3c4cccc5c4c4c6c(cc7ccccc7c6c6ccccc6c43)-c3ccccc3-5)n2)cc1]

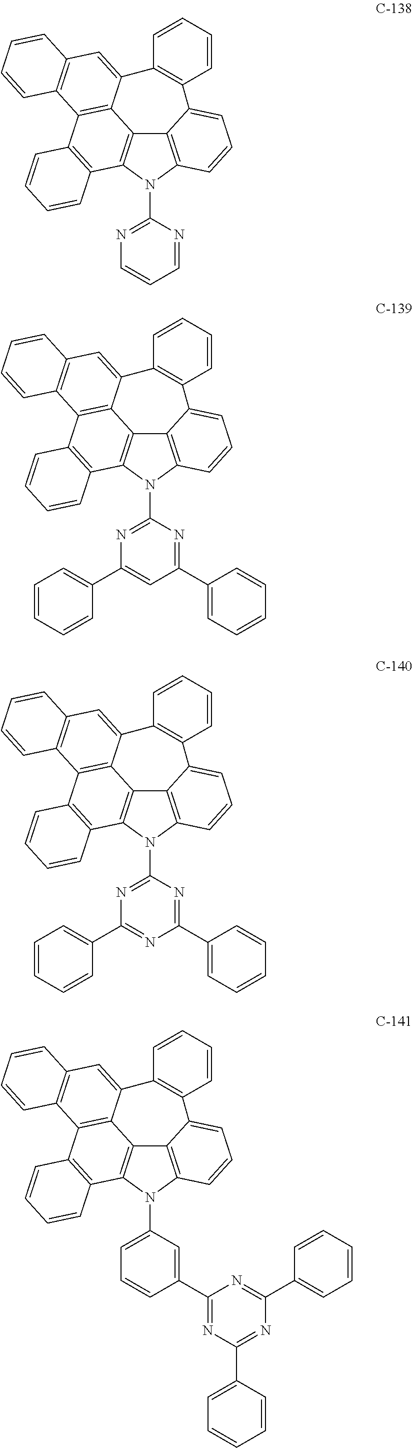 [SMILES: c1cnc(-n2c3cccc4c3c3c5c(cc6ccccc6c5c5ccccc5c32)-c2ccccc2-4)nc1 ; c1ccc(-c2cc(-c3ccccc3)nc(-n3c4cccc5c4c4c6c(cc7ccccc7c6c6ccccc6c43)-c3ccccc3-5)n2)cc1 ; c1ccc(-c2nc(-c3ccccc3)nc(-n3c4cccc5c4c4c6c(cc7ccccc7c6c6ccccc6c43)-c3ccccc3-5)n2)cc1 ; c1ccc(-c2nc(-c3ccccc3)nc(-c3cccc(-n4c5cccc6c5c5c7c(cc8ccccc8c7c7ccccc7c54)-c4ccccc4-6)c3)n2)cc1]

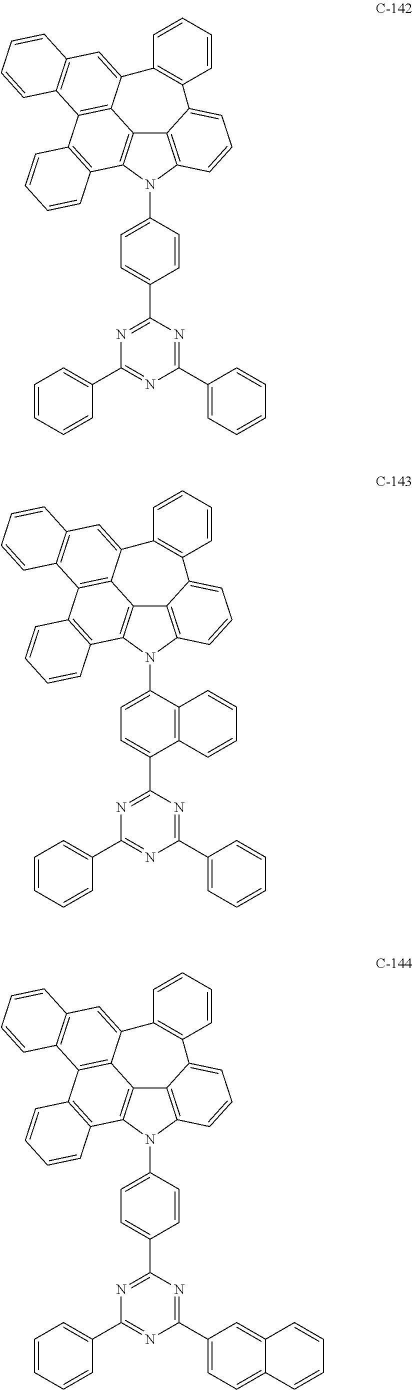 [SMILES: c1ccc(-c2nc(-c3ccccc3)nc(-c3ccc(-n4c5cccc6c5c5c7c(cc8ccccc8c7c7ccccc7c54)-c4ccccc4-6)cc3)n2)cc1 ; c1ccc(-c2nc(-c3ccccc3)nc(-c3ccc(-n4c5cccc6c5c5c7c(cc8ccccc8c7c7ccccc7c54)-c4ccccc4-6)c4ccccc34)n2)cc1 ; c1ccc(-c2nc(-c3ccc(-n4c5cccc6c5c5c7c(cc8ccccc8c7c7ccccc7c54)-c4ccccc4-6)cc3)nc(-c3ccc4ccccc4c3)n2)cc1]

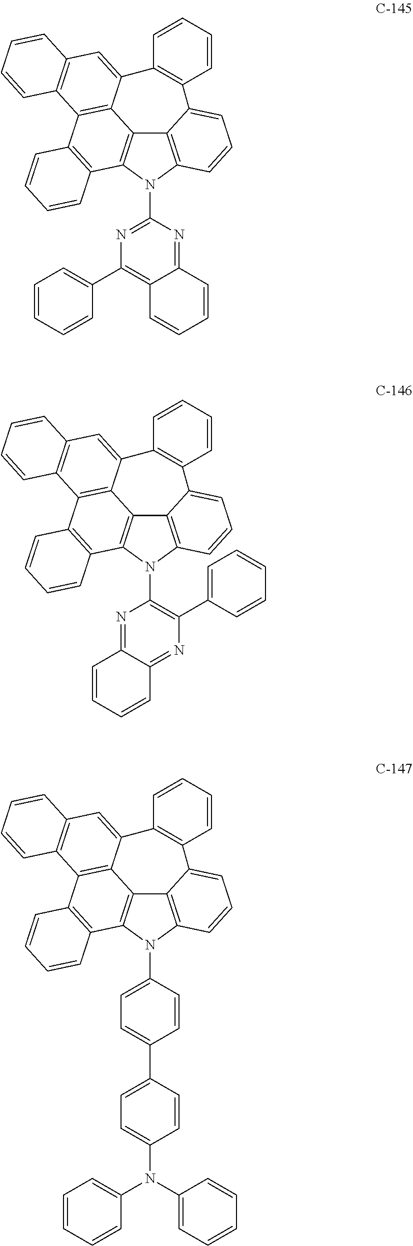 [SMILES: c1ccc(-c2nc(-n3c4cccc5c4c4c6c(cc7ccccc7c6c6ccccc6c43)-c3ccccc3-5)nc3ccccc23)cc1 ; c1ccc(-c2nc3ccccc3nc2-n2c3cccc4c3c3c5c(cc6ccccc6c5c5ccccc5c32)-c2ccccc2-4)cc1 ; c1ccc(N(c2ccccc2)c2ccc(-c3ccc(-n4c5cccc6c5c5c7c(cc8ccccc8c7c7ccccc7c54)-c4ccccc4-6)cc3)cc2)cc1]

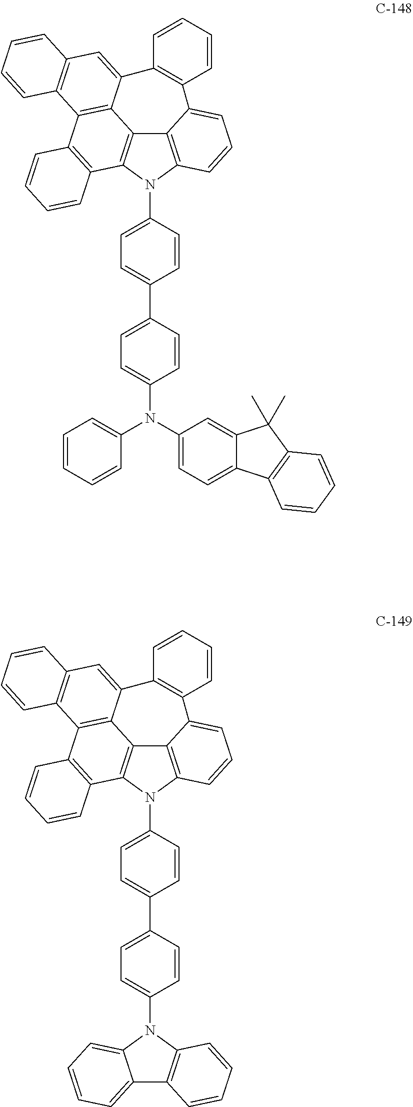 [SMILES: CC1(C)c2ccccc2-c2ccc(N(c3ccccc3)c3ccc(-c4ccc(-n5c6cccc7c6c6c8c(cc9ccccc9c8c8ccccc8c65)-c5ccccc5-7)cc4)cc3)cc21 ; c1ccc2c(c1)-c1cc3ccccc3c3c4ccccc4c4c(c13)c1c-2cccc1n4-c1ccc(-c2ccc(-n3c4ccccc4c4ccccc43)cc2)cc1]

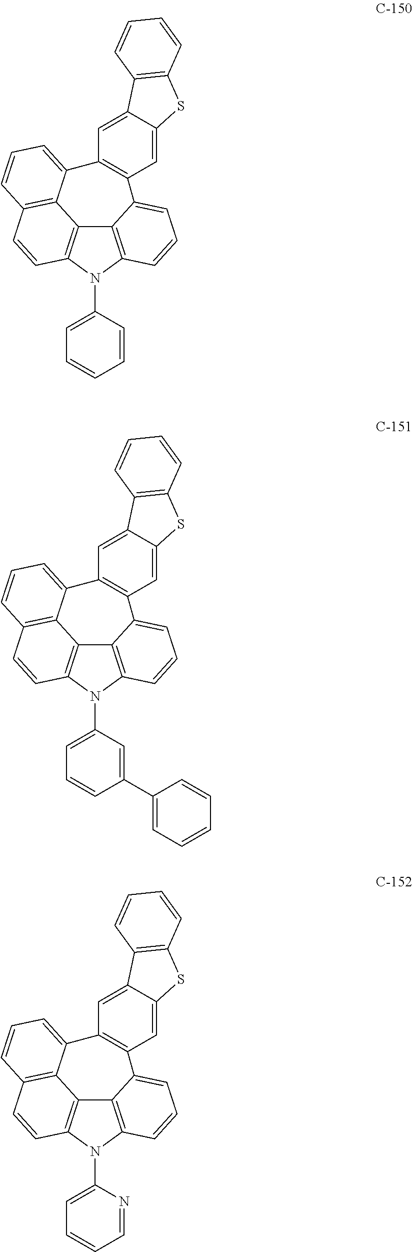 [SMILES: c1ccc(-n2c3cccc4c3c3c5c(cccc5ccc32)-c2cc3c(cc2-4)sc2ccccc23)cc1 ; c1ccc(-c2cccc(-n3c4cccc5c4c4c6c(cccc6ccc43)-c3cc4c(cc3-5)sc3ccccc34)c2)cc1 ; c1ccc(-n2c3cccc4c3c3c5c(cccc5ccc32)-c2cc3c(cc2-4)sc2ccccc23)nc1]

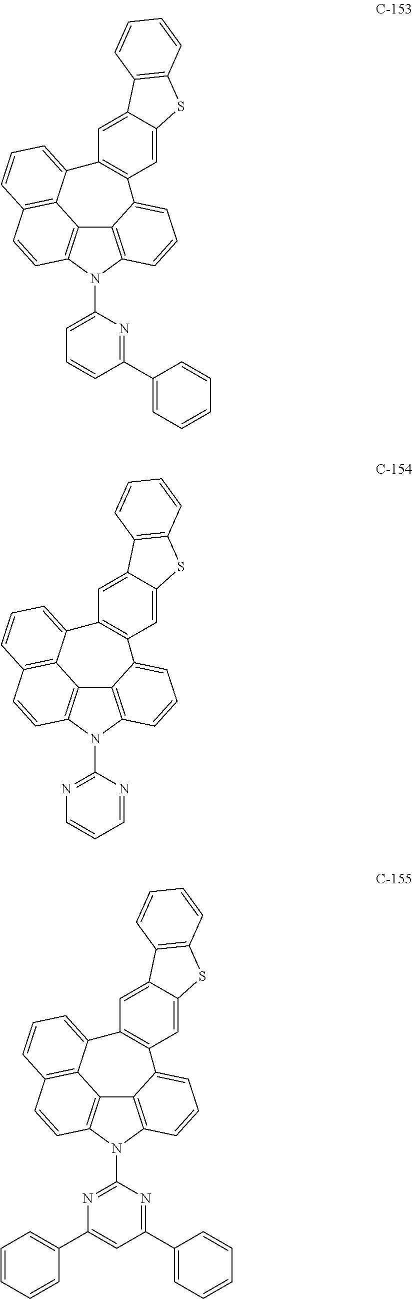 [SMILES: c1ccc(-c2cccc(-n3c4cccc5c4c4c6c(cccc6ccc43)-c3cc4c(cc3-5)sc3ccccc34)n2)cc1 ; c1cnc(-n2c3cccc4c3c3c5c(cccc5ccc32)-c2cc3c(cc2-4)sc2ccccc23)nc1 ; c1ccc(-c2cc(-c3ccccc3)nc(-n3c4cccc5c4c4c6c(cccc6ccc43)-c3cc4c(cc3-5)sc3ccccc34)n2)cc1]

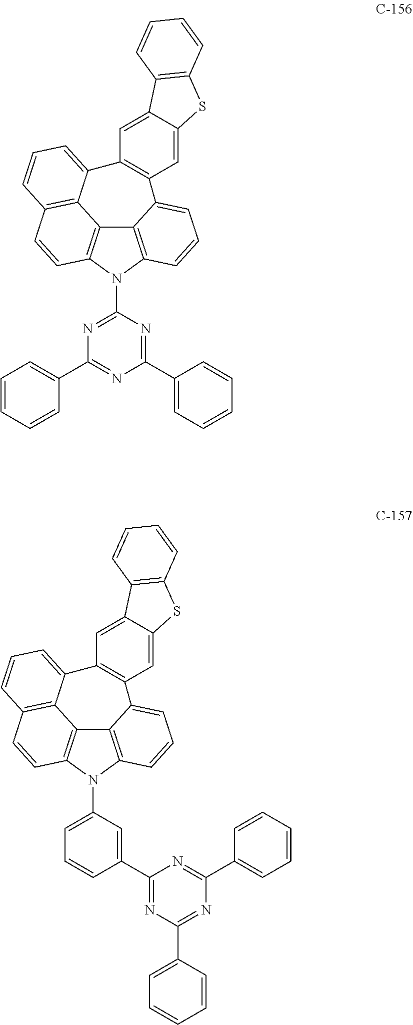 [SMILES: c1ccc(-c2nc(-c3ccccc3)nc(-n3c4cccc5c4c4c6c(cccc6ccc43)-c3cc4c(cc3-5)sc3ccccc34)n2)cc1 ; c1ccc(-c2nc(-c3ccccc3)nc(-c3cccc(-n4c5cccc6c5c5c7c(cccc7ccc54)-c4cc5c(cc4-6)sc4ccccc45)c3)n2)cc1]

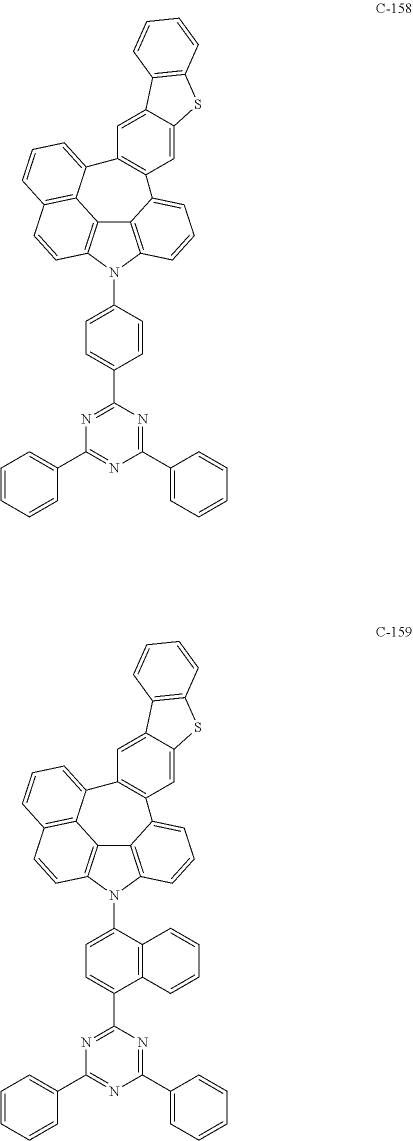 [SMILES: c1ccc(-c2nc(-c3ccccc3)nc(-c3ccc(-n4c5cccc6c5c5c7c(cccc7ccc54)-c4cc5c(cc4-6)sc4ccccc45)cc3)n2)cc1 ; c1ccc(-c2nc(-c3ccccc3)nc(-c3ccc(-n4c5cccc6c5c5c7c(cccc7ccc54)-c4cc5c(cc4-6)sc4ccccc45)c4ccccc34)n2)cc1]

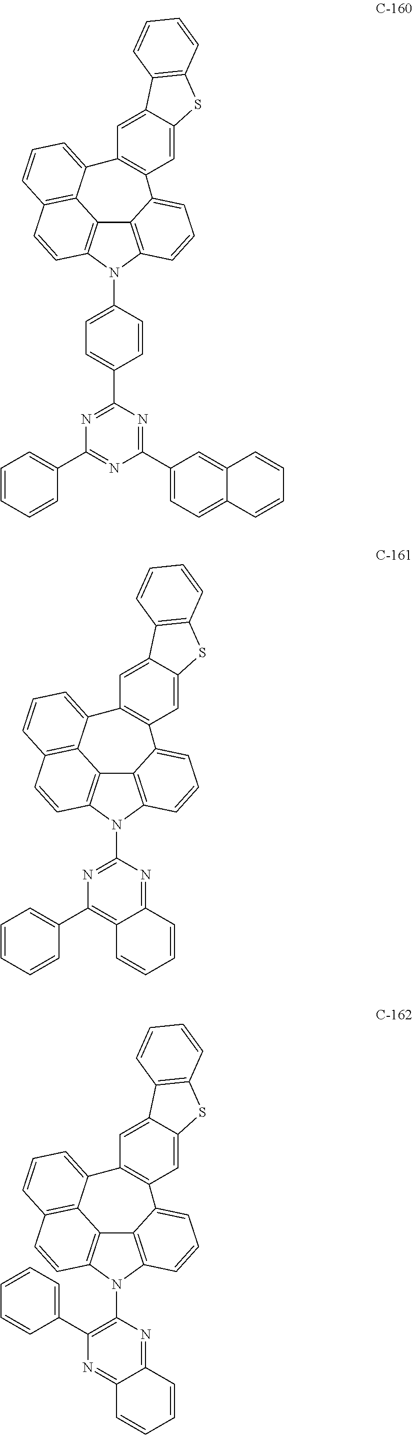 [SMILES: c1ccc(-c2nc(-c3ccc(-n4c5cccc6c5c5c7c(cccc7ccc54)-c4cc5c(cc4-6)sc4ccccc45)cc3)nc(-c3ccc4ccccc4c3)n2)cc1 ; c1ccc(-c2nc(-n3c4cccc5c4c4c6c(cccc6ccc43)-c3cc4c(cc3-5)sc3ccccc34)nc3ccccc23)cc1 ; c1ccc(-c2nc3ccccc3nc2-n2c3cccc4c3c3c5c(cccc5ccc32)-c2cc3c(cc2-4)sc2ccccc23)cc1]

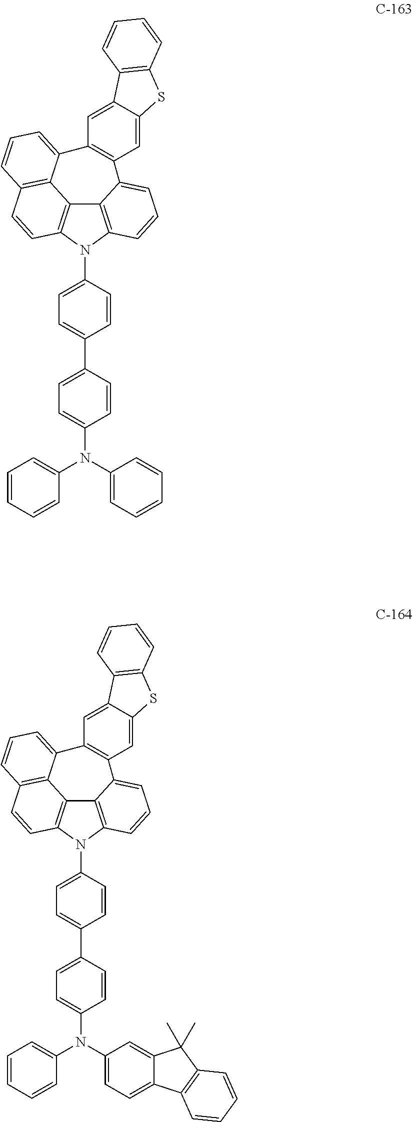 [SMILES: c1ccc(N(c2ccccc2)c2ccc(-c3ccc(-n4c5cccc6c5c5c7c(cccc7ccc54)-c4cc5c(cc4-6)sc4ccccc45)cc3)cc2)cc1 ; CC1(C)c2ccccc2-c2ccc(N(c3ccccc3)c3ccc(-c4ccc(-n5c6cccc7c6c6c8c(cccc8ccc65)-c5cc6c(cc5-7)sc5ccccc56)cc4)cc3)cc21]

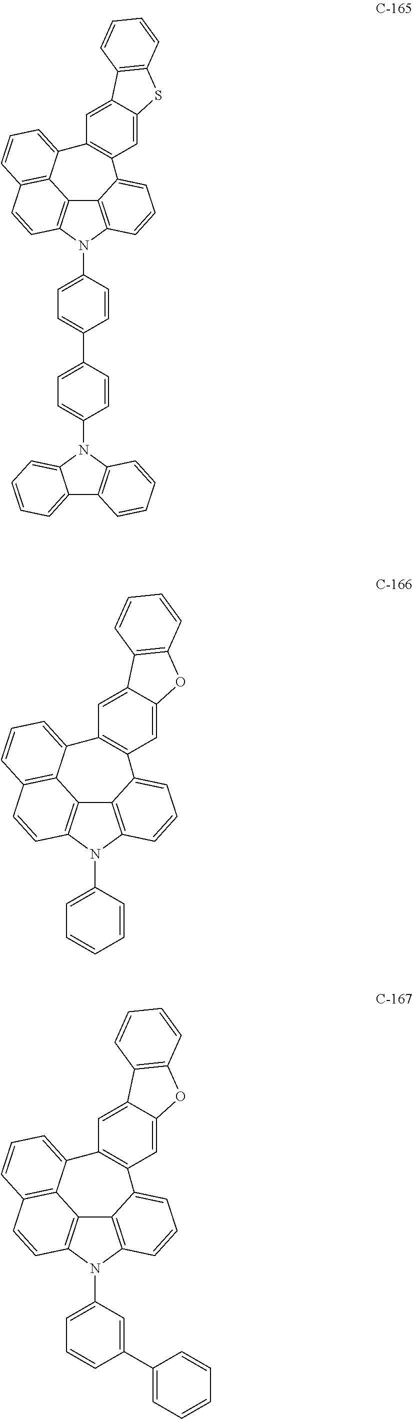 [SMILES: c1cc2c3c(c1)ccc1c3c3c(cccc3n1-c1ccc(-c3ccc(-n4c5ccccc5c5ccccc54)cc3)cc1)-c1cc3sc4ccccc4c3cc1-2 ; c1ccc(-n2c3cccc4c3c3c5c(cccc5ccc32)-c2cc3c(cc2-4)oc2ccccc23)cc1 ; c1ccc(-c2cccc(-n3c4cccc5c4c4c6c(cccc6ccc43)-c3cc4c(cc3-5)oc3ccccc34)c2)cc1]

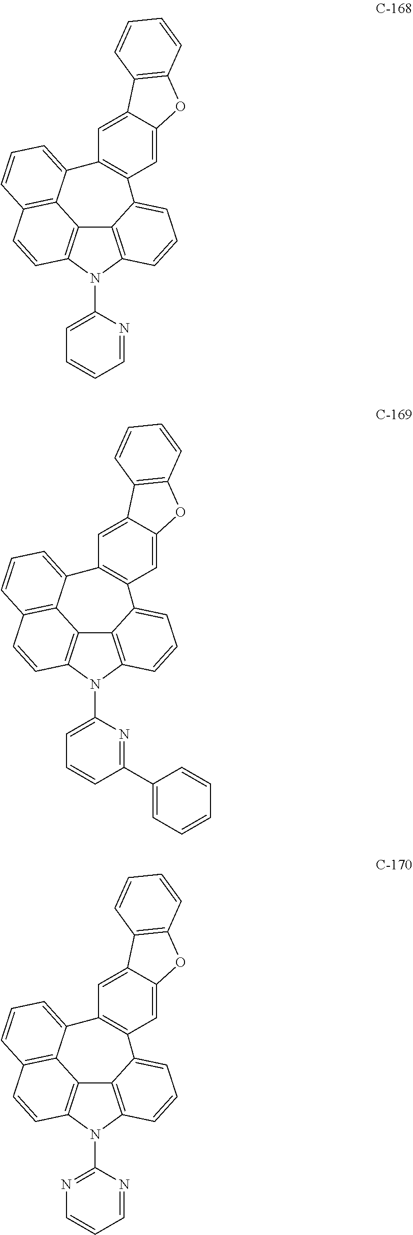

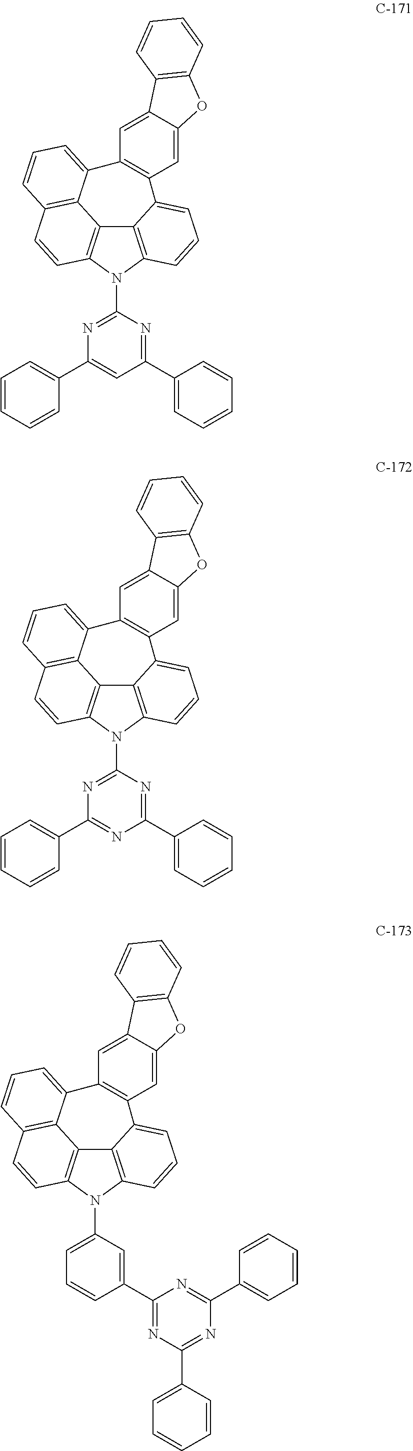 [SMILES: c1ccc(-c2cc(-c3ccccc3)nc(-n3c4cccc5c4c4c6c(cccc6ccc43)-c3cc4c(cc3-5)oc3ccccc34)n2)cc1 ; c1ccc(-c2nc(-c3ccccc3)nc(-n3c4cccc5c4c4c6c(cccc6ccc43)-c3cc4c(cc3-5)oc3ccccc34)n2)cc1 ; c1ccc(-c2nc(-c3ccccc3)nc(-c3cccc(-n4c5cccc6c5c5c7c(cccc7ccc54)-c4cc5c(cc4-6)oc4ccccc45)c3)n2)cc1]

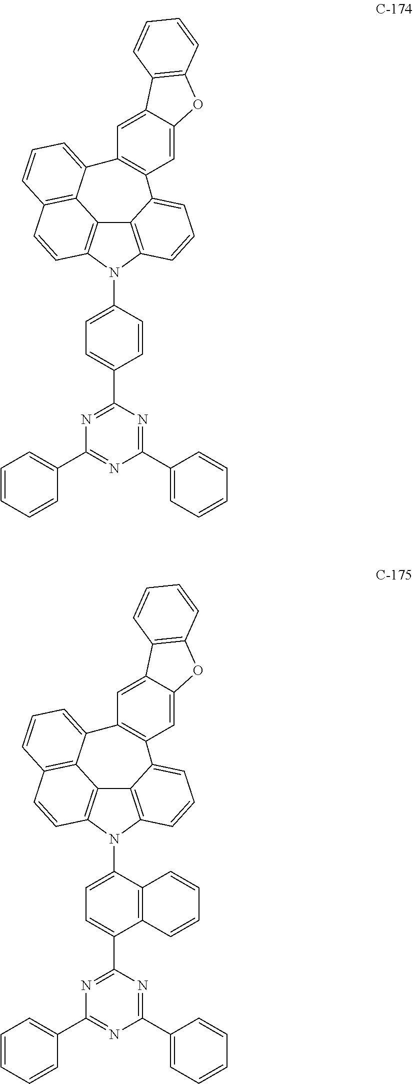 [SMILES: c1ccc(-c2nc(-c3ccccc3)nc(-c3ccc(-n4c5cccc6c5c5c7c(cccc7ccc54)-c4cc5c(cc4-6)oc4ccccc45)cc3)n2)cc1 ; c1ccc(-c2nc(-c3ccccc3)nc(-c3ccc(-n4c5cccc6c5c5c7c(cccc7ccc54)-c4cc5c(cc4-6)oc4ccccc45)c4ccccc34)n2)cc1]

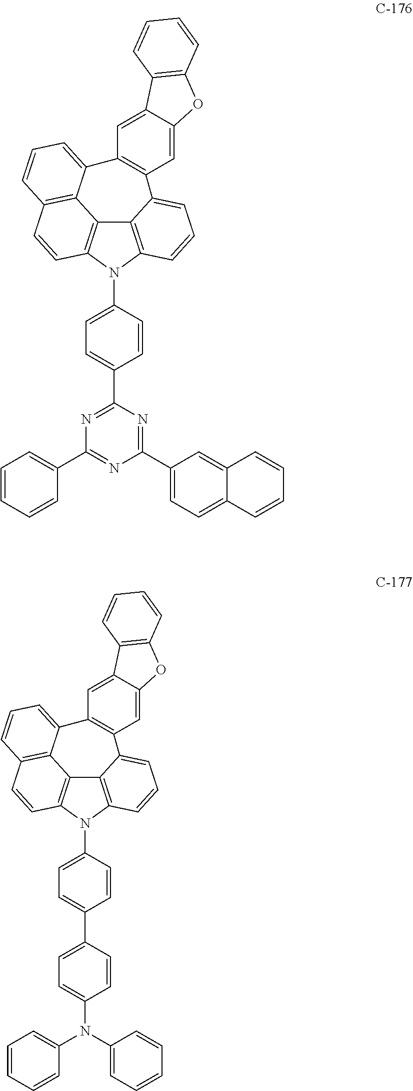 [SMILES: c1ccc(-c2nc(-c3ccc(-n4c5cccc6c5c5c7c(cccc7ccc54)-c4cc5c(cc4-6)oc4ccccc45)cc3)nc(-c3ccc4ccccc4c3)n2)cc1 ; c1ccc(N(c2ccccc2)c2ccc(-c3ccc(-n4c5cccc6c5c5c7c(cccc7ccc54)-c4cc5c(cc4-6)oc4ccccc45)cc3)cc2)cc1]

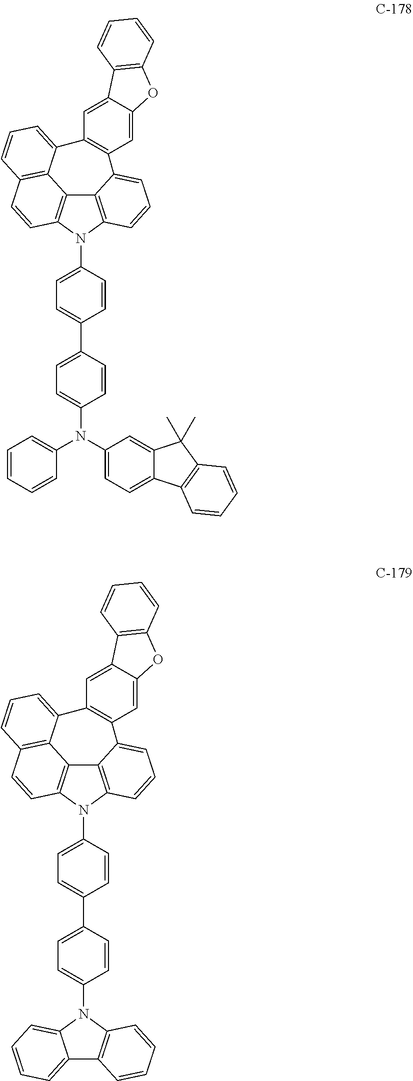 [SMILES: CC1(C)c2ccccc2-c2ccc(N(c3ccccc3)c3ccc(-c4ccc(-n5c6cccc7c6c6c8c(cccc8ccc65)-c5cc6c(cc5-7)oc5ccccc56)cc4)cc3)cc21 ; c1cc2c3c(c1)ccc1c3c3c(cccc3n1-c1ccc(-c3ccc(-n4c5ccccc5c5ccccc54)cc3)cc1)-c1cc3oc4ccccc4c3cc1-2]

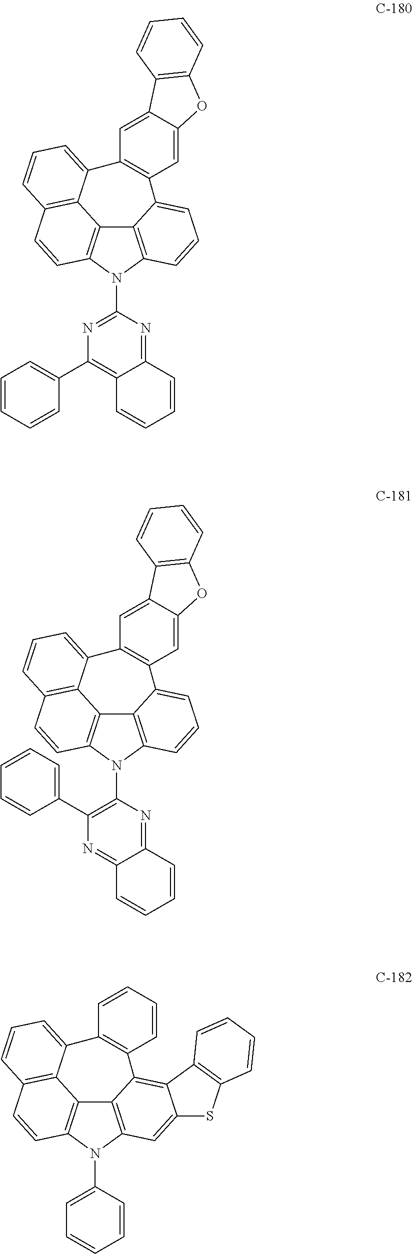 [SMILES: c1ccc(-c2nc(-n3c4cccc5c4c4c6c(cccc6ccc43)-c3cc4c(cc3-5)oc3ccccc34)nc3ccccc23)cc1 ; c1ccc(-c2nc3ccccc3nc2-n2c3cccc4c3c3c5c(cccc5ccc32)-c2cc3c(cc2-4)oc2ccccc23)cc1 ; c1ccc(-n2c3cc4sc5ccccc5c4c4c3c3c5c(cccc5ccc32)-c2ccccc2-4)cc1]

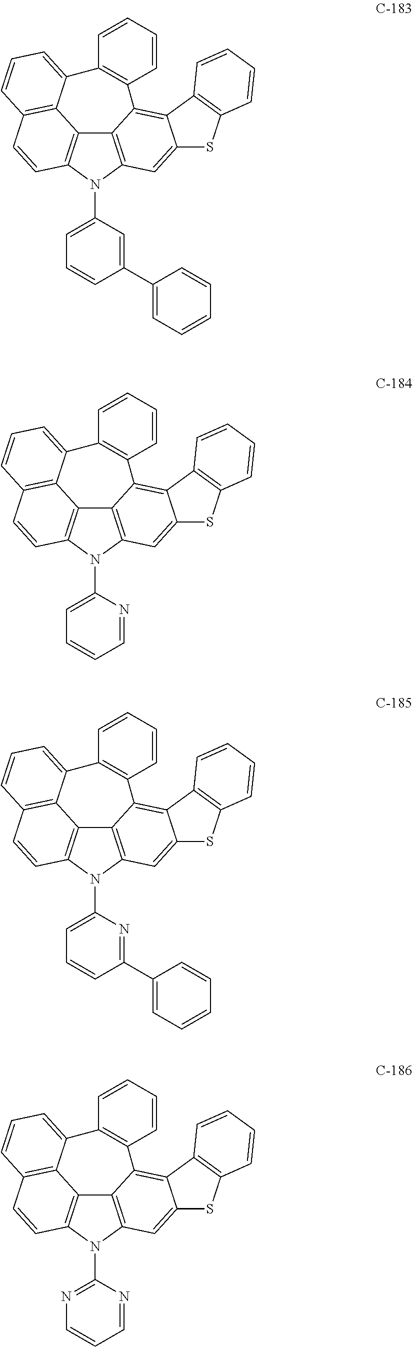 [SMILES: c1ccc(-c2cccc(-n3c4cc5sc6ccccc6c5c5c4c4c6c(cccc6ccc43)-c3ccccc3-5)c2)cc1 ; c1ccc(-n2c3cc4sc5ccccc5c4c4c3c3c5c(cccc5ccc32)-c2ccccc2-4)nc1 ; c1ccc(-c2cccc(-n3c4cc5sc6ccccc6c5c5c4c4c6c(cccc6ccc43)-c3ccccc3-5)n2)cc1 ; c1cnc(-n2c3cc4sc5ccccc5c4c4c3c3c5c(cccc5ccc32)-c2ccccc2-4)nc1]

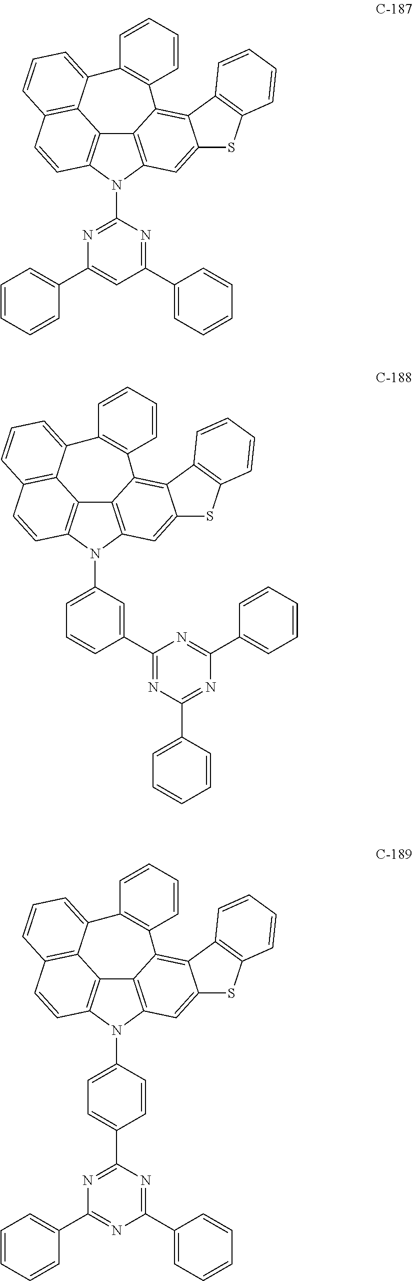 [SMILES: c1ccc(-c2cc(-c3ccccc3)nc(-n3c4cc5sc6ccccc6c5c5c4c4c6c(cccc6ccc43)-c3ccccc3-5)n2)cc1 ; c1ccc(-c2nc(-c3ccccc3)nc(-c3cccc(-n4c5cc6sc7ccccc7c6c6c5c5c7c(cccc7ccc54)-c4ccccc4-6)c3)n2)cc1 ; c1ccc(-c2nc(-c3ccccc3)nc(-c3ccc(-n4c5cc6sc7ccccc7c6c6c5c5c7c(cccc7ccc54)-c4ccccc4-6)cc3)n2)cc1]

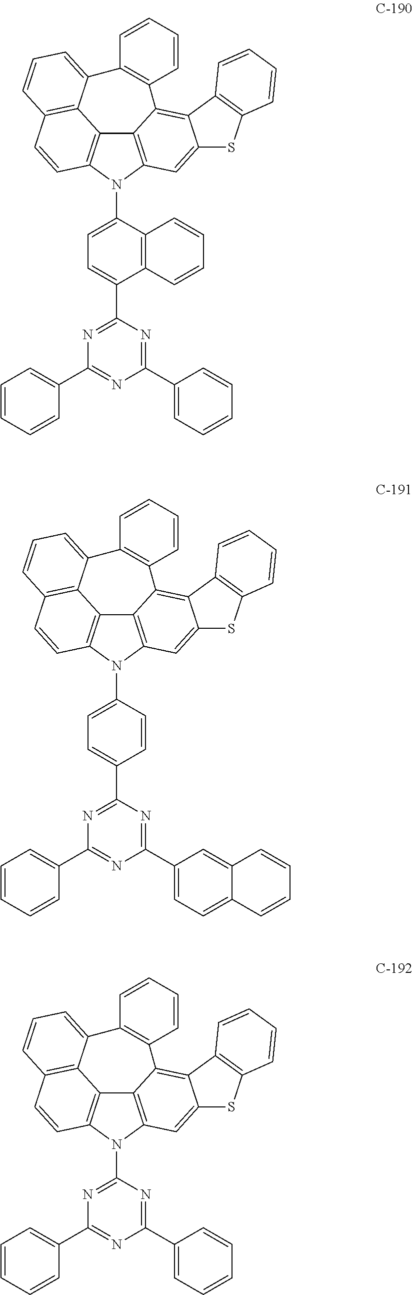 [SMILES: c1ccc(-c2nc(-c3ccccc3)nc(-c3ccc(-n4c5cc6sc7ccccc7c6c6c5c5c7c(cccc7ccc54)-c4ccccc4-6)c4ccccc34)n2)cc1 ; c1ccc(-c2nc(-c3ccc(-n4c5cc6sc7ccccc7c6c6c5c5c7c(cccc7ccc54)-c4ccccc4-6)cc3)nc(-c3ccc4ccccc4c3)n2)cc1 ; c1ccc(-c2nc(-c3ccccc3)nc(-n3c4cc5sc6ccccc6c5c5c4c4c6c(cccc6ccc43)-c3ccccc3-5)n2)cc1]

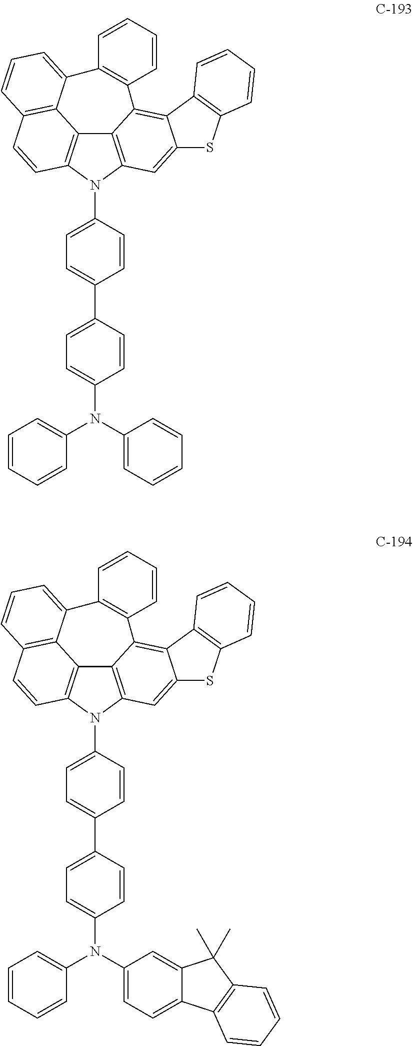 [SMILES: c1ccc(N(c2ccccc2)c2ccc(-c3ccc(-n4c5cc6sc7ccccc7c6c6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cc7sc8ccccc8c7c7c6c6c8c(cccc8ccc65)-c5ccccc5-7)cc4)cc3)cc21]

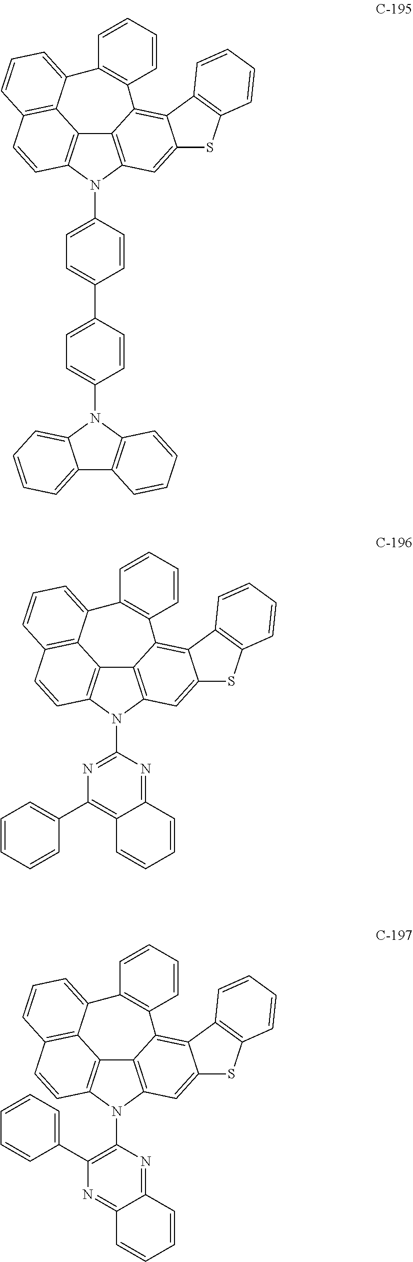 [SMILES: c1ccc2c(c1)-c1cccc3ccc4c(c13)c1c-2c2c(cc1n4-c1ccc(-c3ccc(-n4c5ccccc5c5ccccc54)cc3)cc1)sc1ccccc12 ; c1ccc(-c2nc(-n3c4cc5sc6ccccc6c5c5c4c4c6c(cccc6ccc43)-c3ccccc3-5)nc3ccccc23)cc1 ; c1ccc(-c2nc3ccccc3nc2-n2c3cc4sc5ccccc5c4c4c3c3c5c(cccc5ccc32)-c2ccccc2-4)cc1]

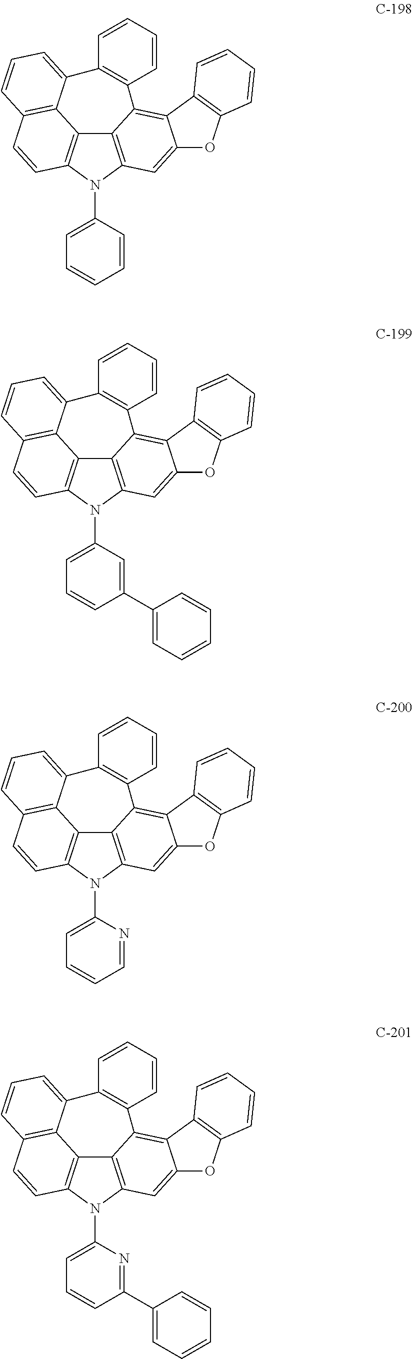 [SMILES: c1ccc(-n2c3cc4oc5ccccc5c4c4c3c3c5c(cccc5ccc32)-c2ccccc2-4)cc1 ; c1ccc(-c2cccc(-n3c4cc5oc6ccccc6c5c5c4c4c6c(cccc6ccc43)-c3ccccc3-5)c2)cc1 ; c1ccc(-n2c3cc4oc5ccccc5c4c4c3c3c5c(cccc5ccc32)-c2ccccc2-4)nc1 ; c1ccc(-c2cccc(-n3c4cc5oc6ccccc6c5c5c4c4c6c(cccc6ccc43)-c3ccccc3-5)n2)cc1]

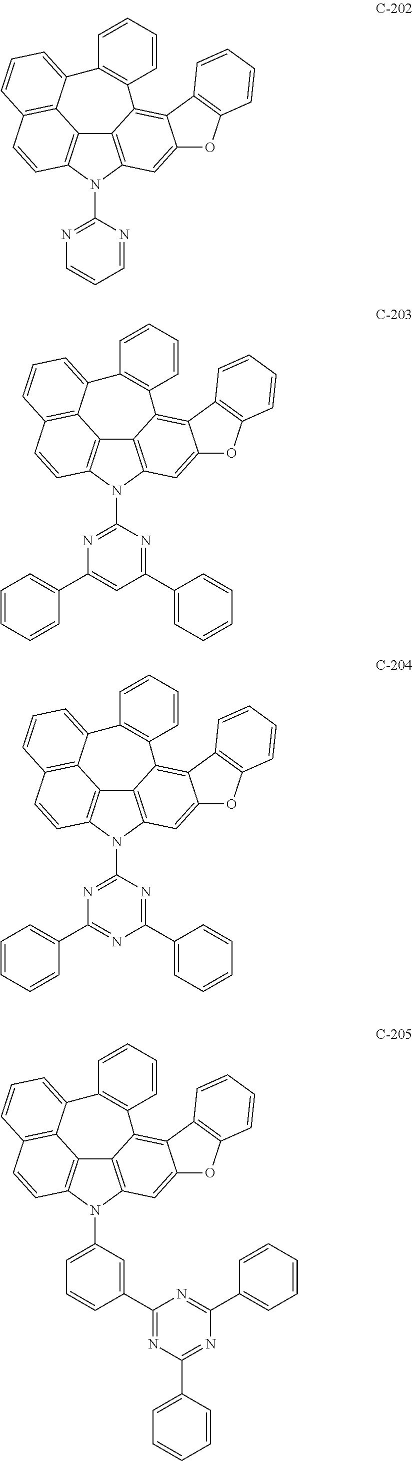 [SMILES: c1cnc(-n2c3cc4oc5ccccc5c4c4c3c3c5c(cccc5ccc32)-c2ccccc2-4)nc1 ; c1ccc(-c2cc(-c3ccccc3)nc(-n3c4cc5oc6ccccc6c5c5c4c4c6c(cccc6ccc43)-c3ccccc3-5)n2)cc1 ; c1ccc(-c2nc(-c3ccccc3)nc(-n3c4cc5oc6ccccc6c5c5c4c4c6c(cccc6ccc43)-c3ccccc3-5)n2)cc1 ; c1ccc(-c2nc(-c3ccccc3)nc(-c3cccc(-n4c5cc6oc7ccccc7c6c6c5c5c7c(cccc7ccc54)-c4ccccc4-6)c3)n2)cc1]

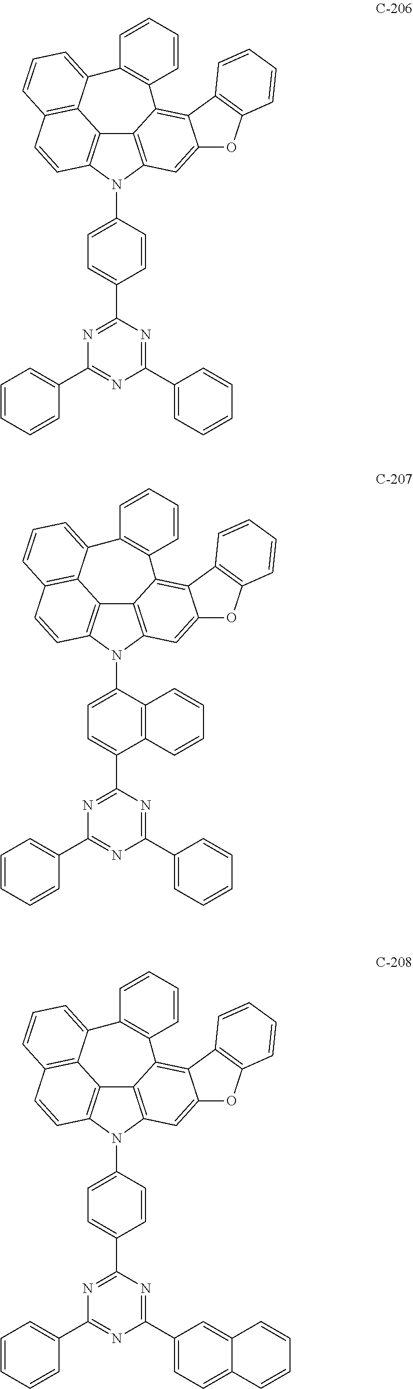 [SMILES: c1ccc(-c2nc(-c3ccccc3)nc(-c3ccc(-n4c5cc6oc7ccccc7c6c6c5c5c7c(cccc7ccc54)-c4ccccc4-6)cc3)n2)cc1 ; c1ccc(-c2nc(-c3ccccc3)nc(-c3ccc(-n4c5cc6oc7ccccc7c6c6c5c5c7c(cccc7ccc54)-c4ccccc4-6)c4ccccc34)n2)cc1 ; c1ccc(-c2nc(-c3ccc(-n4c5cc6oc7ccccc7c6c6c5c5c7c(cccc7ccc54)-c4ccccc4-6)cc3)nc(-c3ccc4ccccc4c3)n2)cc1]

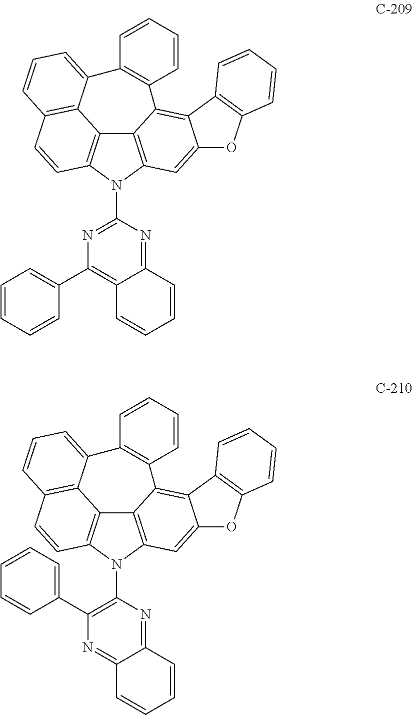 [SMILES: c1ccc(-c2nc(-n3c4cc5oc6ccccc6c5c5c4c4c6c(cccc6ccc43)-c3ccccc3-5)nc3ccccc23)cc1 ; c1ccc(-c2nc3ccccc3nc2-n2c3cc4oc5ccccc5c4c4c3c3c5c(cccc5ccc32)-c2ccccc2-4)cc1]

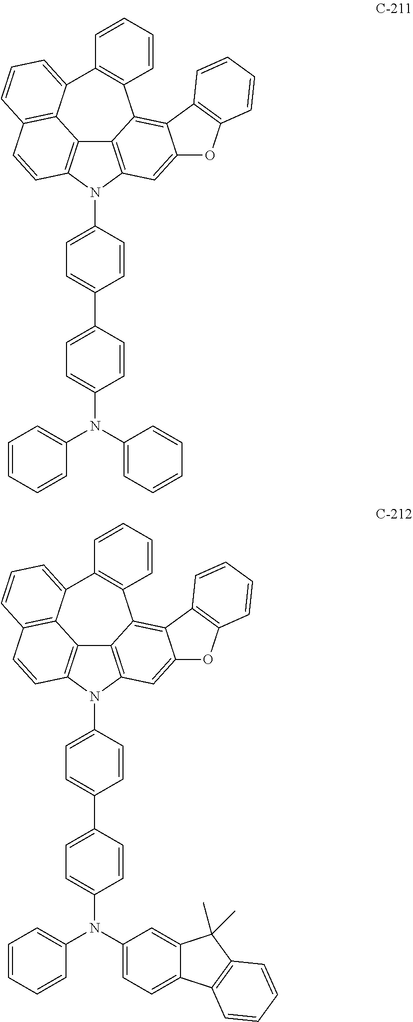

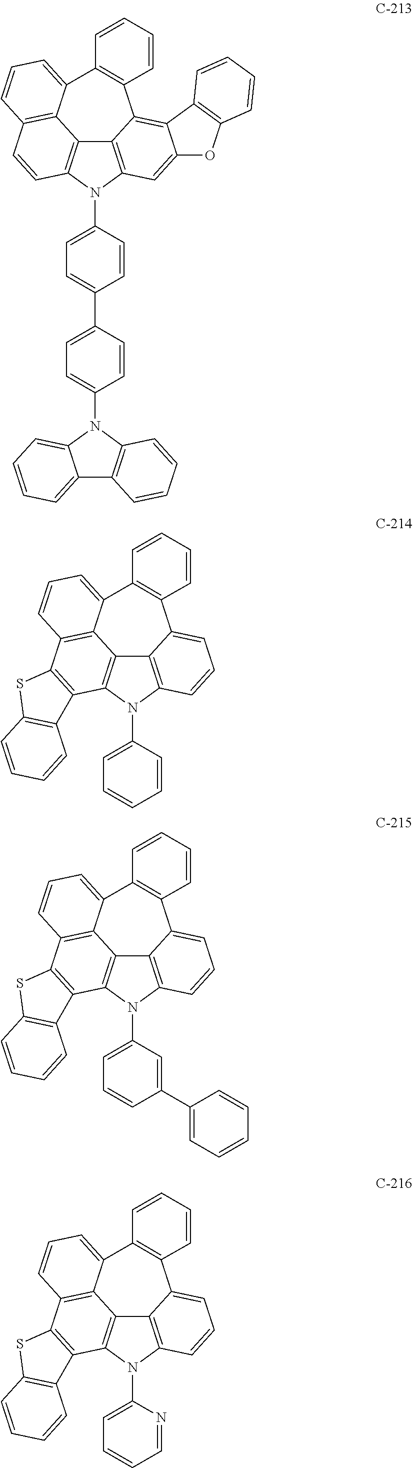

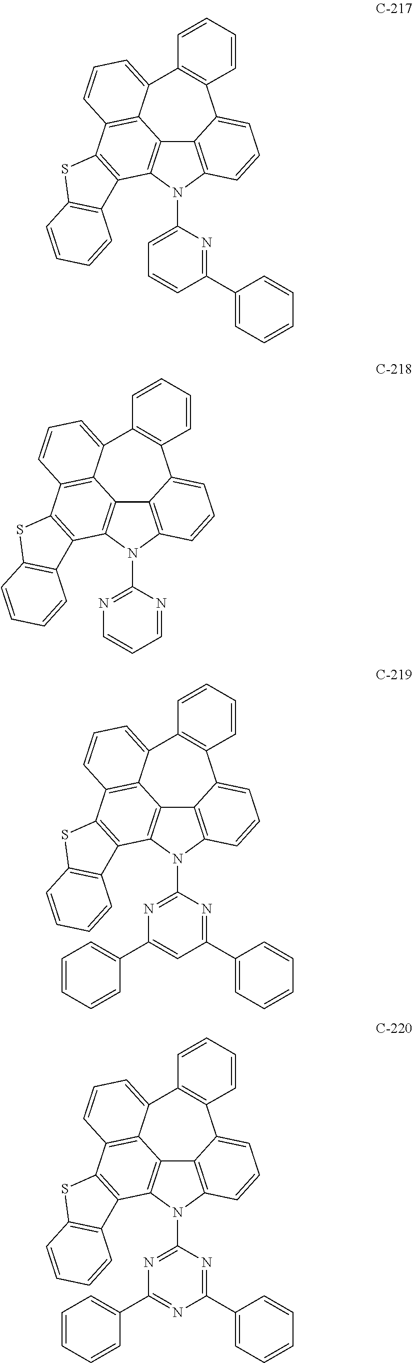 [SMILES: c1ccc(-c2cccc(-n3c4cccc5c4c4c6c(cccc6c6sc7ccccc7c6c43)-c3ccccc3-5)n2)cc1 ; c1cnc(-n2c3cccc4c3c3c5c(cccc5c5sc6ccccc6c5c32)-c2ccccc2-4)nc1 ; c1ccc(-c2cc(-c3ccccc3)nc(-n3c4cccc5c4c4c6c(cccc6c6sc7ccccc7c6c43)-c3ccccc3-5)n2)cc1 ; c1ccc(-c2nc(-c3ccccc3)nc(-n3c4cccc5c4c4c6c(cccc6c6sc7ccccc7c6c43)-c3ccccc3-5)n2)cc1]

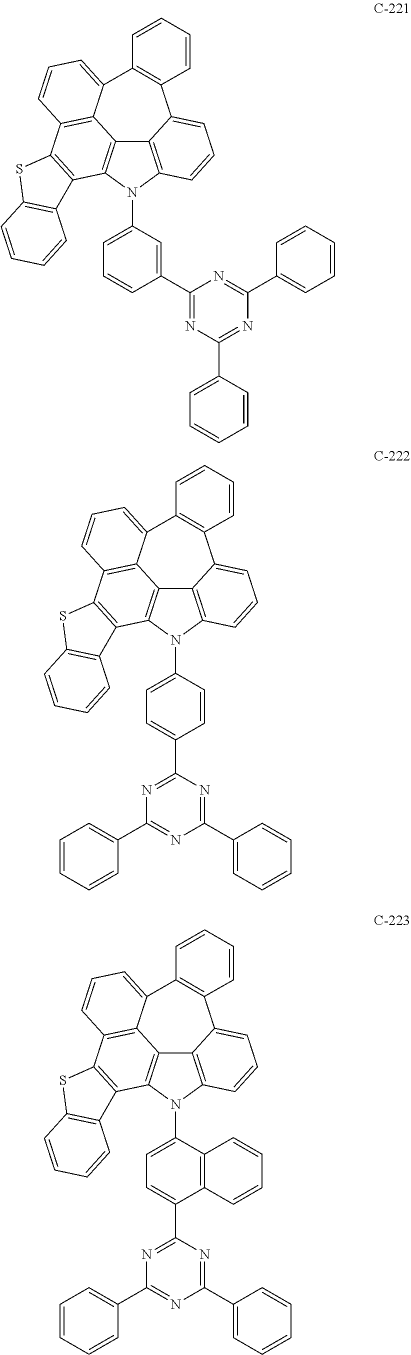

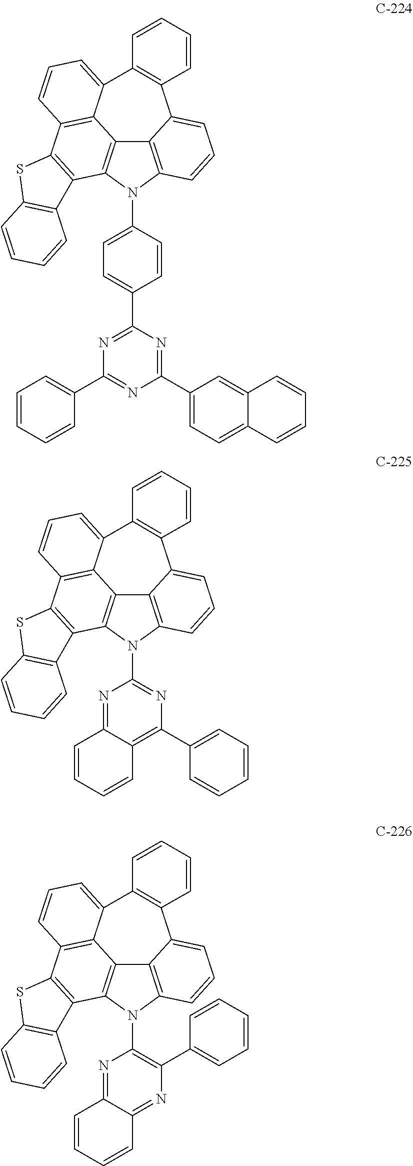 [SMILES: c1ccc(-c2nc(-c3ccc(-n4c5cccc6c5c5c7c(cccc7c7sc8ccccc8c7c54)-c4ccccc4-6)cc3)nc(-c3ccc4ccccc4c3)n2)cc1 ; c1ccc(-c2nc(-n3c4cccc5c4c4c6c(cccc6c6sc7ccccc7c6c43)-c3ccccc3-5)nc3ccccc23)cc1 ; c1ccc(-c2nc3ccccc3nc2-n2c3cccc4c3c3c5c(cccc5c5sc6ccccc6c5c32)-c2ccccc2-4)cc1]

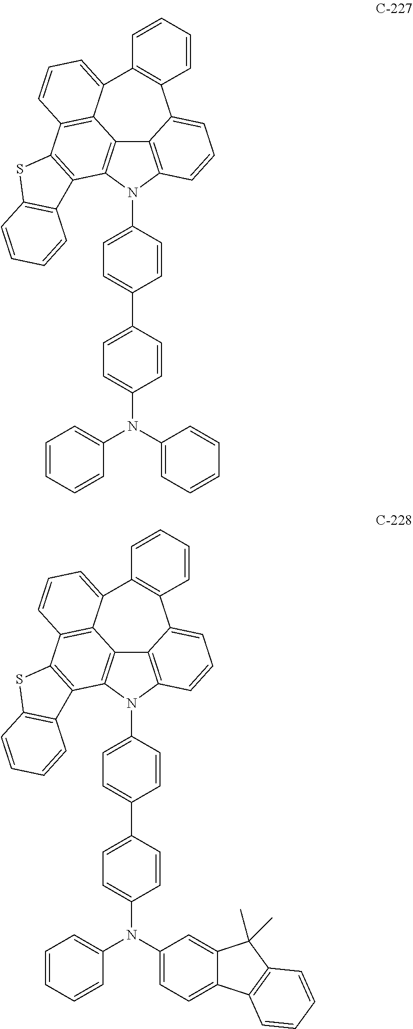 [SMILES: c1ccc(N(c2ccccc2)c2ccc(-c3ccc(-n4c5cccc6c5c5c7c(cccc7c7sc8ccccc8c7c54)-c4ccccc4-6)cc3)cc2)cc1 ; CC1(C)c2ccccc2-c2ccc(N(c3ccccc3)c3ccc(-c4ccc(-n5c6cccc7c6c6c8c(cccc8c8sc9ccccc9c8c65)-c5ccccc5-7)cc4)cc3)cc21]

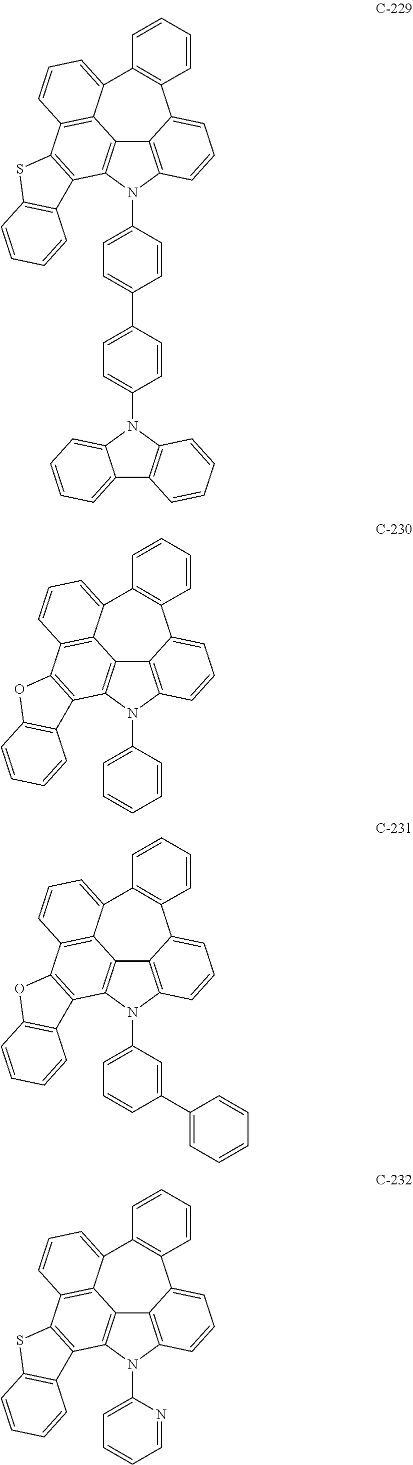

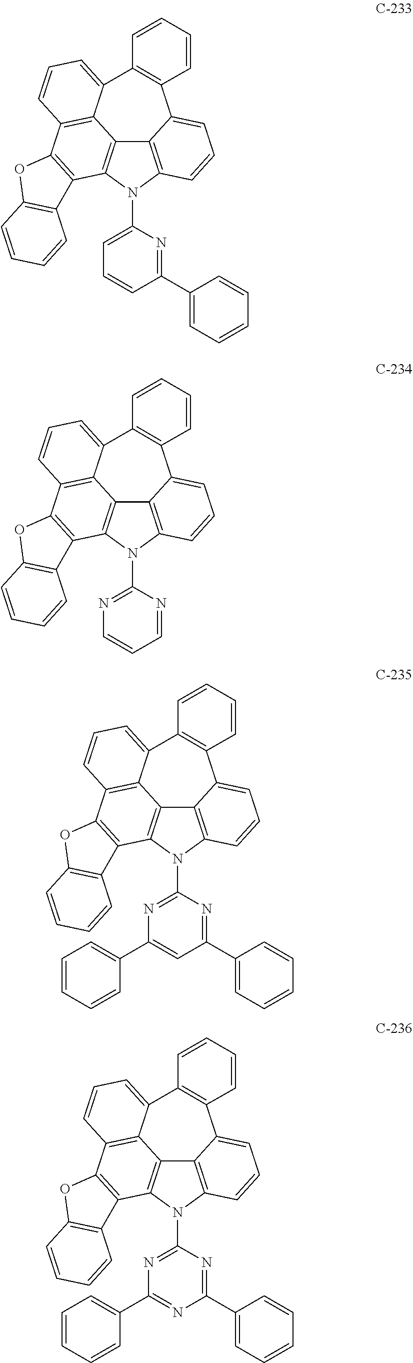 [SMILES: c1ccc(-c2cccc(-n3c4cccc5c4c4c6c(cccc6c6oc7ccccc7c6c43)-c3ccccc3-5)n2)cc1 ; c1cnc(-n2c3cccc4c3c3c5c(cccc5c5oc6ccccc6c5c32)-c2ccccc2-4)nc1 ; c1ccc(-c2cc(-c3ccccc3)nc(-n3c4cccc5c4c4c6c(cccc6c6oc7ccccc7c6c43)-c3ccccc3-5)n2)cc1 ; c1ccc(-c2nc(-c3ccccc3)nc(-n3c4cccc5c4c4c6c(cccc6c6oc7ccccc7c6c43)-c3ccccc3-5)n2)cc1]

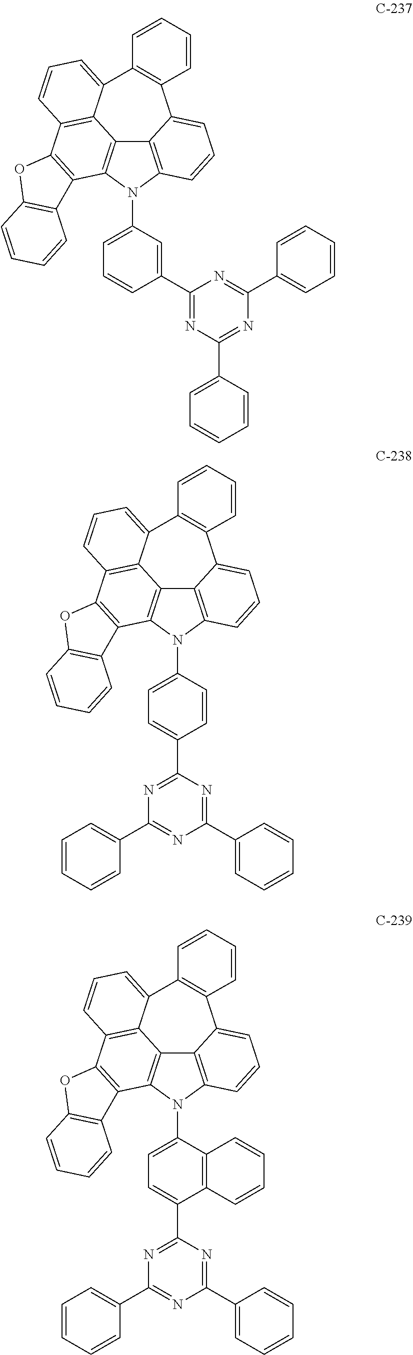

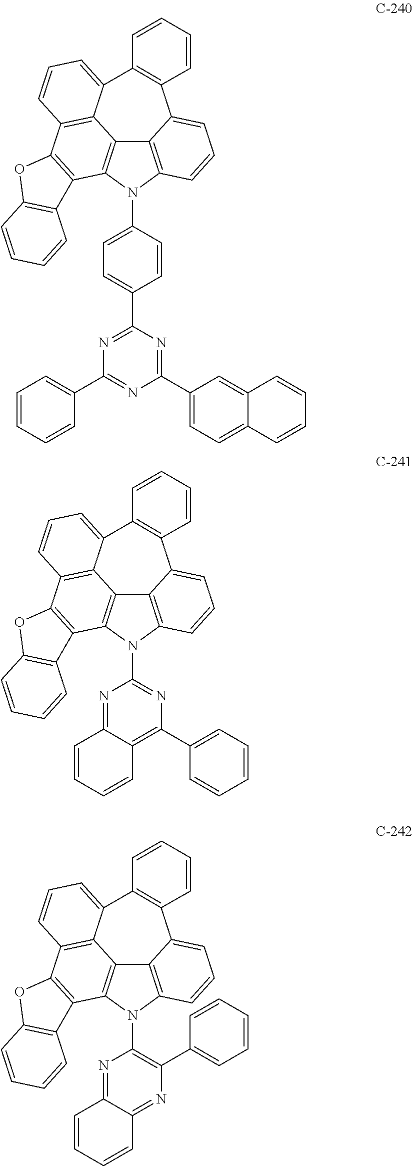 [SMILES: c1ccc(-c2nc(-c3ccc(-n4c5cccc6c5c5c7c(cccc7c7oc8ccccc8c7c54)-c4ccccc4-6)cc3)nc(-c3ccc4ccccc4c3)n2)cc1 ; c1ccc(-c2nc(-n3c4cccc5c4c4c6c(cccc6c6oc7ccccc7c6c43)-c3ccccc3-5)nc3ccccc23)cc1 ; c1ccc(-c2nc3ccccc3nc2-n2c3cccc4c3c3c5c(cccc5c5oc6ccccc6c5c32)-c2ccccc2-4)cc1]

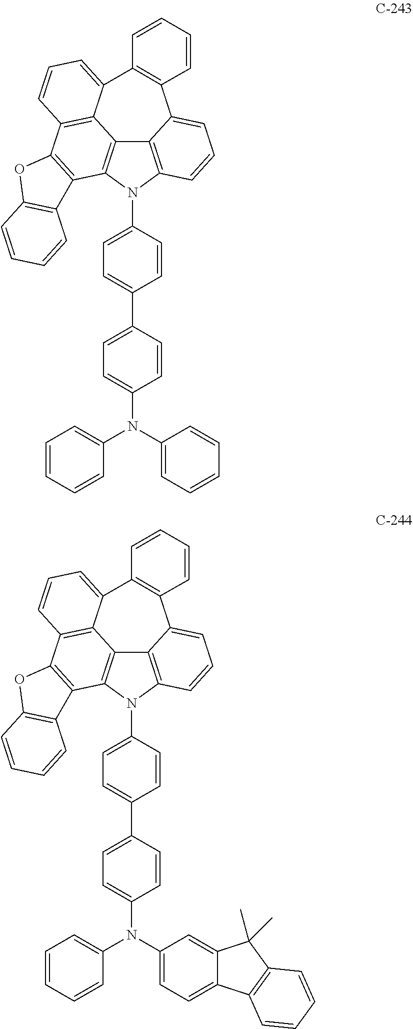 [SMILES: c1ccc(N(c2ccccc2)c2ccc(-c3ccc(-n4c5cccc6c5c5c7c(cccc7c7oc8ccccc8c7c54)-c4ccccc4-6)cc3)cc2)cc1 ; CC1(C)c2ccccc2-c2ccc(N(c3ccccc3)c3ccc(-c4ccc(-n5c6cccc7c6c6c8c(cccc8c8oc9ccccc9c8c65)-c5ccccc5-7)cc4)cc3)cc21]

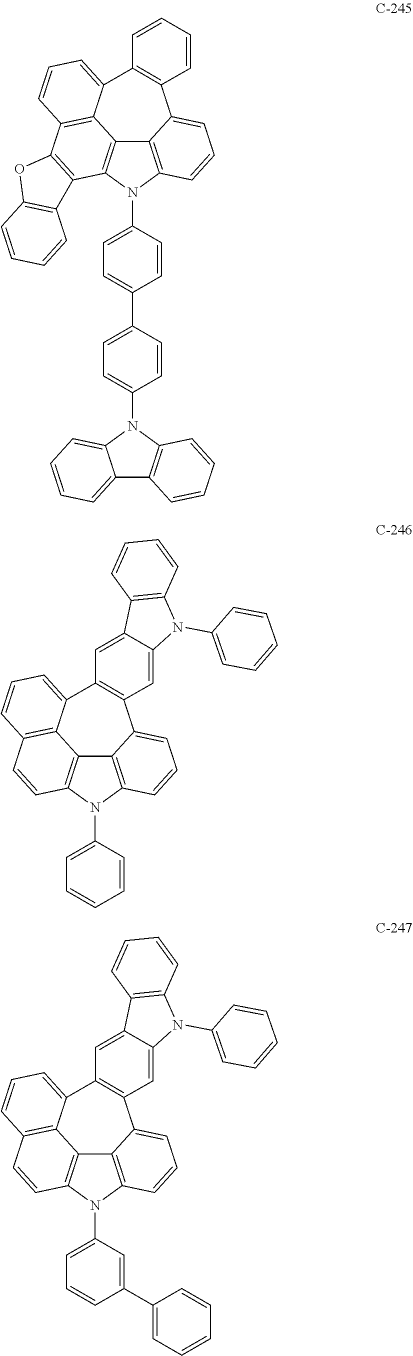

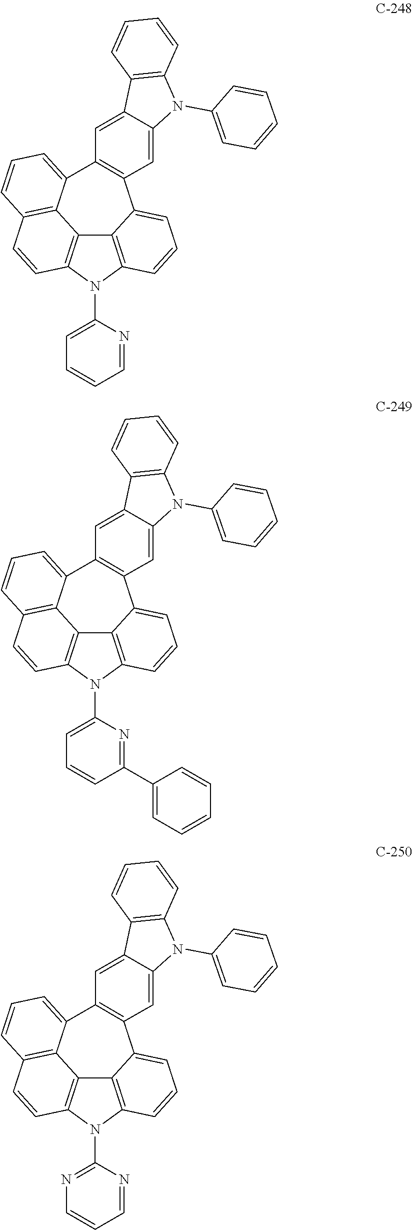

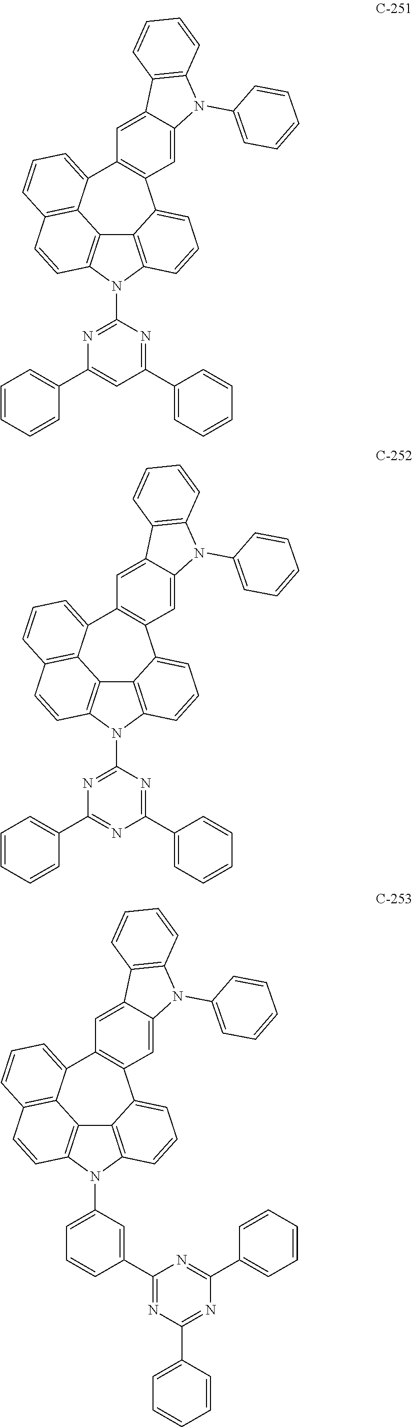

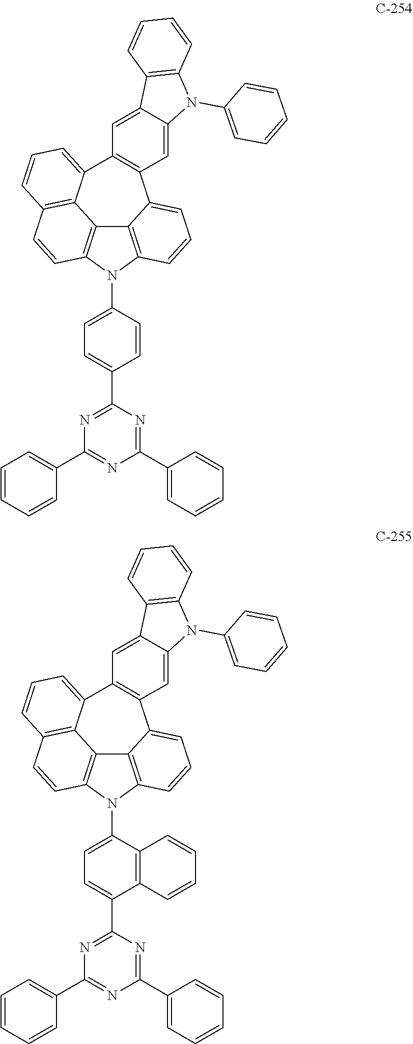

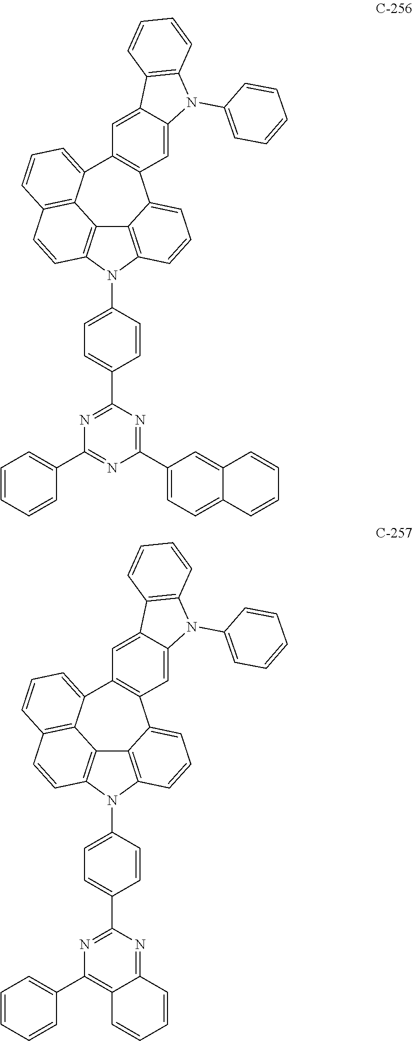

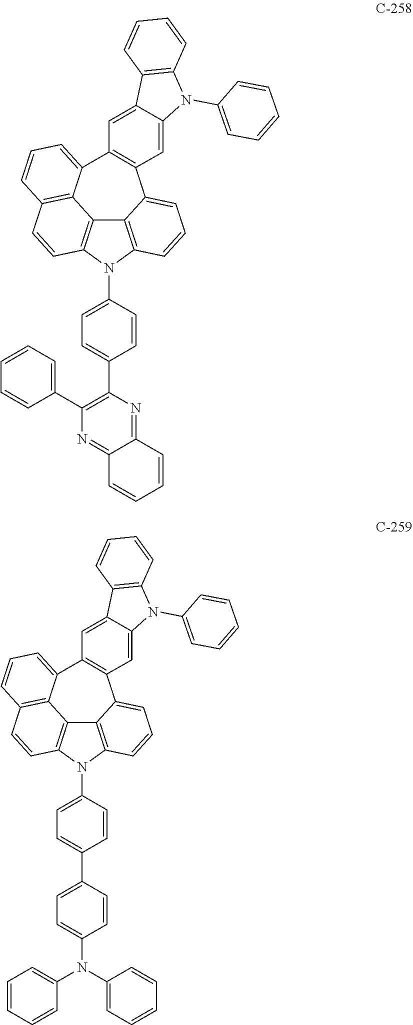

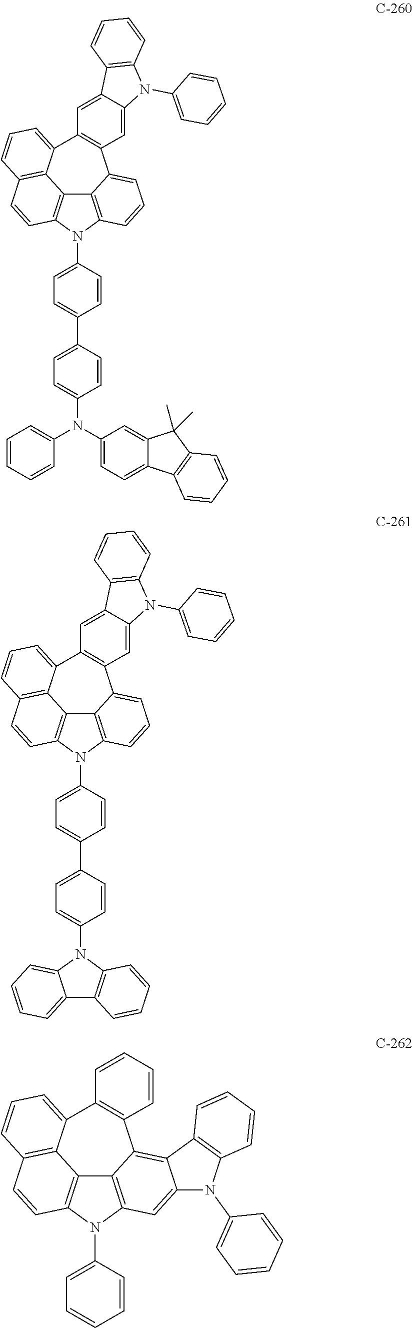

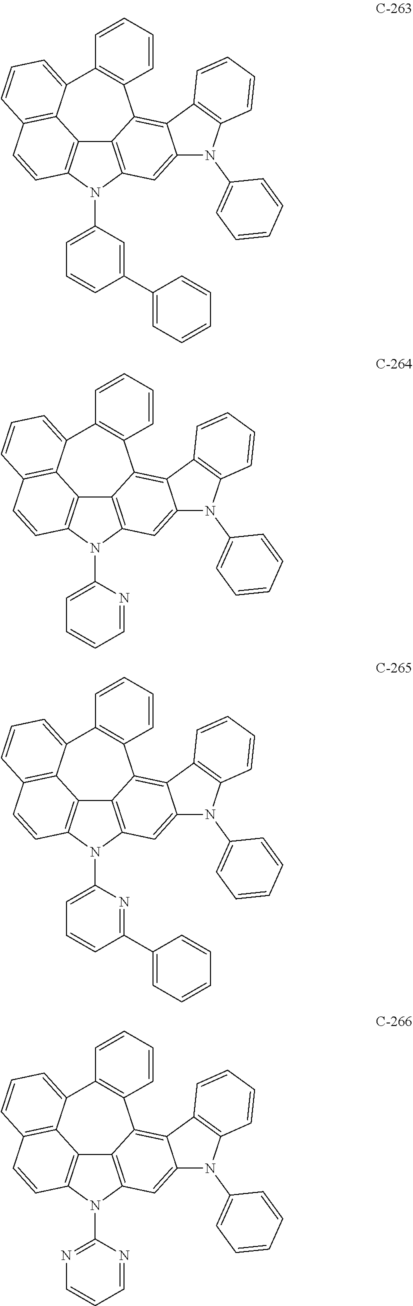

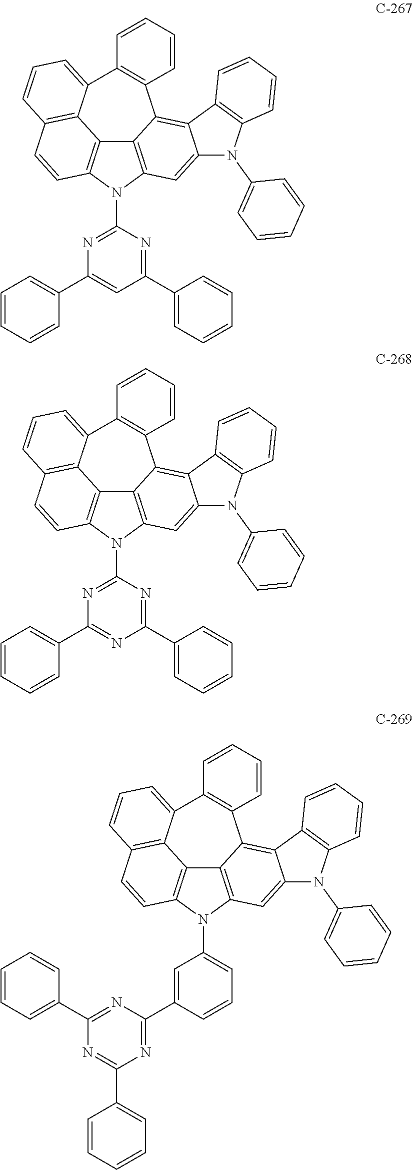 [SMILES: c1ccc(-c2cc(-c3ccccc3)nc(-n3c4cc5c(c6c4c4c7c(cccc7ccc43)-c3ccccc3-6)c3ccccc3n5-c3ccccc3)n2)cc1 ; c1ccc(-c2nc(-c3ccccc3)nc(-n3c4cc5c(c6c4c4c7c(cccc7ccc43)-c3ccccc3-6)c3ccccc3n5-c3ccccc3)n2)cc1 ; c1ccc(-c2nc(-c3ccccc3)nc(-c3cccc(-n4c5cc6c(c7c5c5c8c(cccc8ccc54)-c4ccccc4-7)c4ccccc4n6-c4ccccc4)c3)n2)cc1]

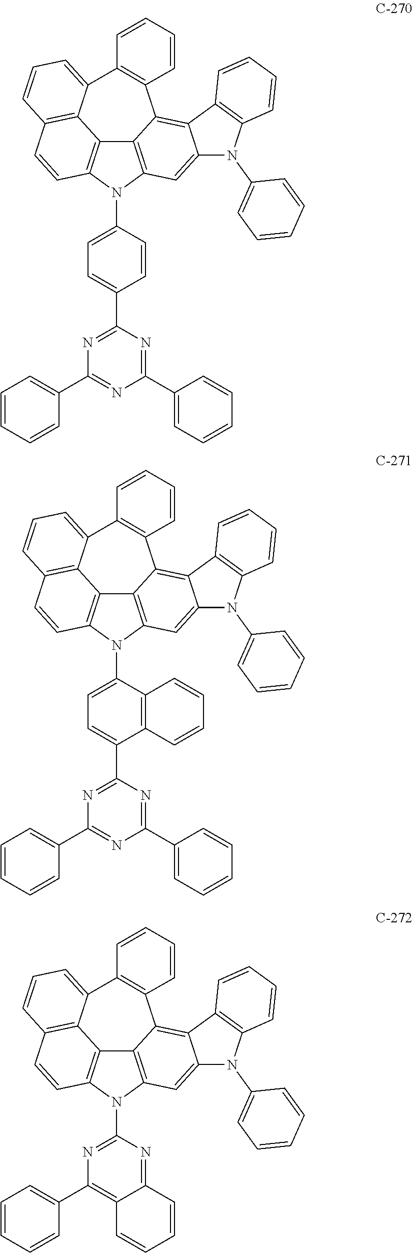 [SMILES: c1ccc(-c2nc(-c3ccccc3)nc(-c3ccc(-n4c5cc6c(c7c5c5c8c(cccc8ccc54)-c4ccccc4-7)c4ccccc4n6-c4ccccc4)cc3)n2)cc1 ; c1ccc(-c2nc(-c3ccccc3)nc(-c3ccc(-n4c5cc6c(c7c5c5c8c(cccc8ccc54)-c4ccccc4-7)c4ccccc4n6-c4ccccc4)c4ccccc34)n2)cc1 ; c1ccc(-c2nc(-n3c4cc5c(c6c4c4c7c(cccc7ccc43)-c3ccccc3-6)c3ccccc3n5-c3ccccc3)nc3ccccc23)cc1]

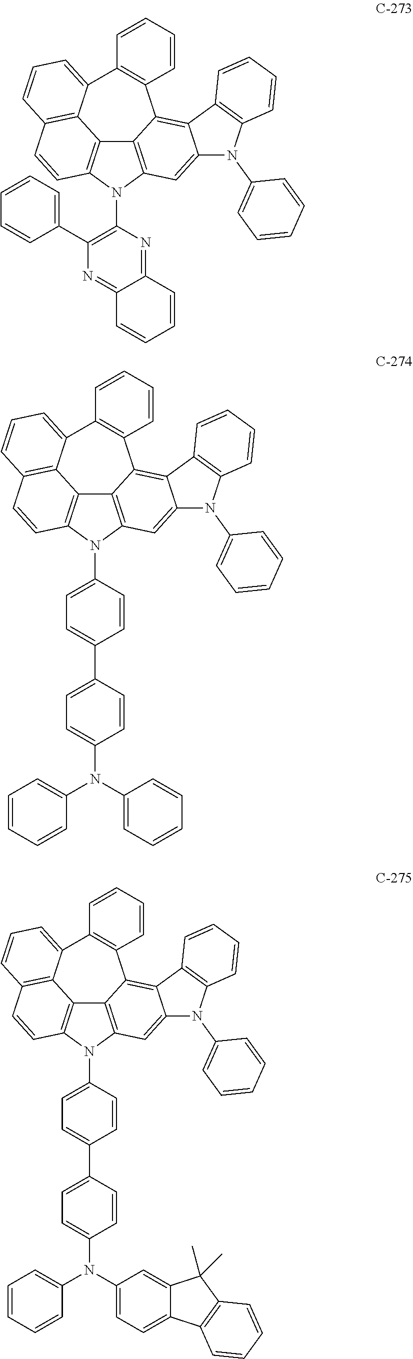

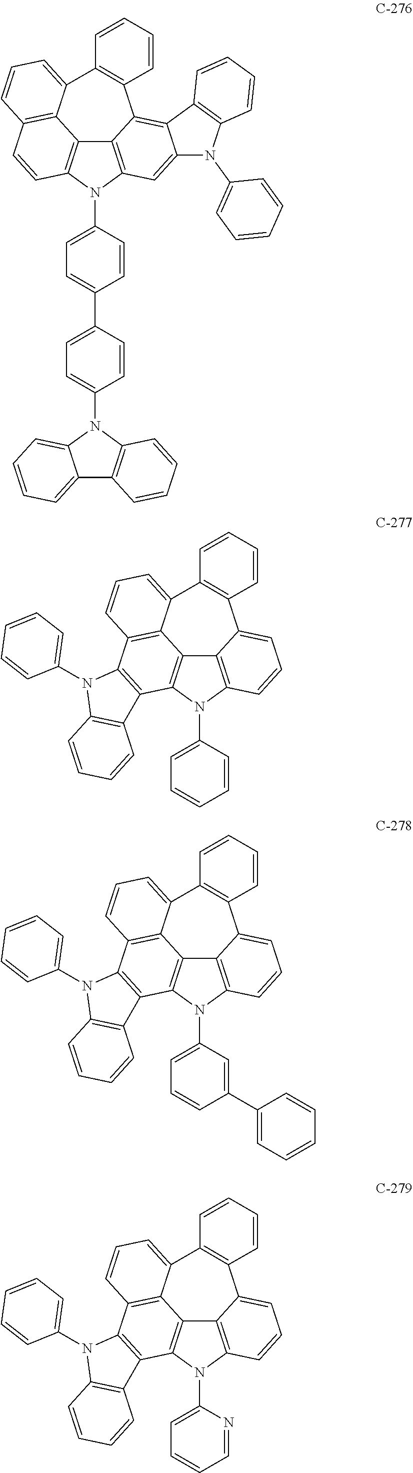

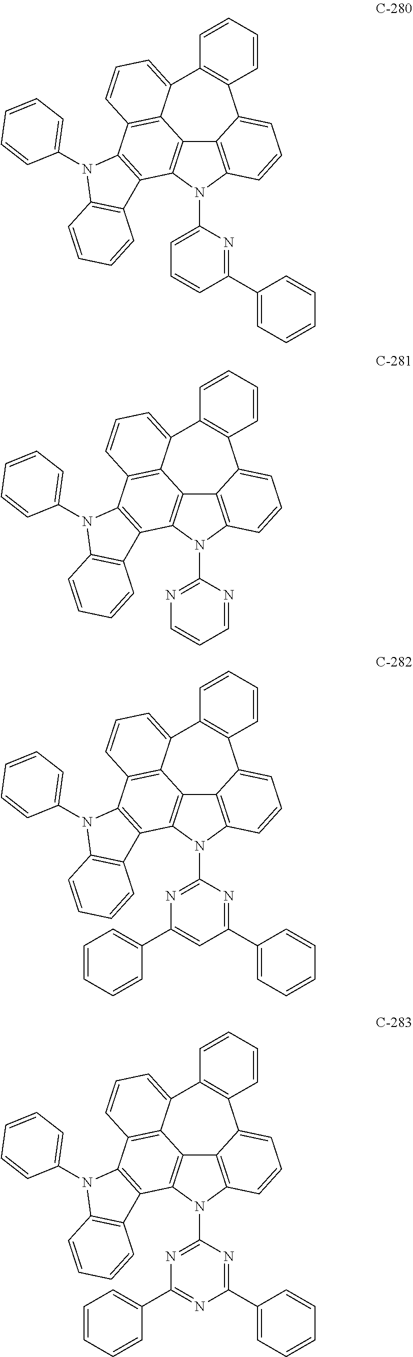

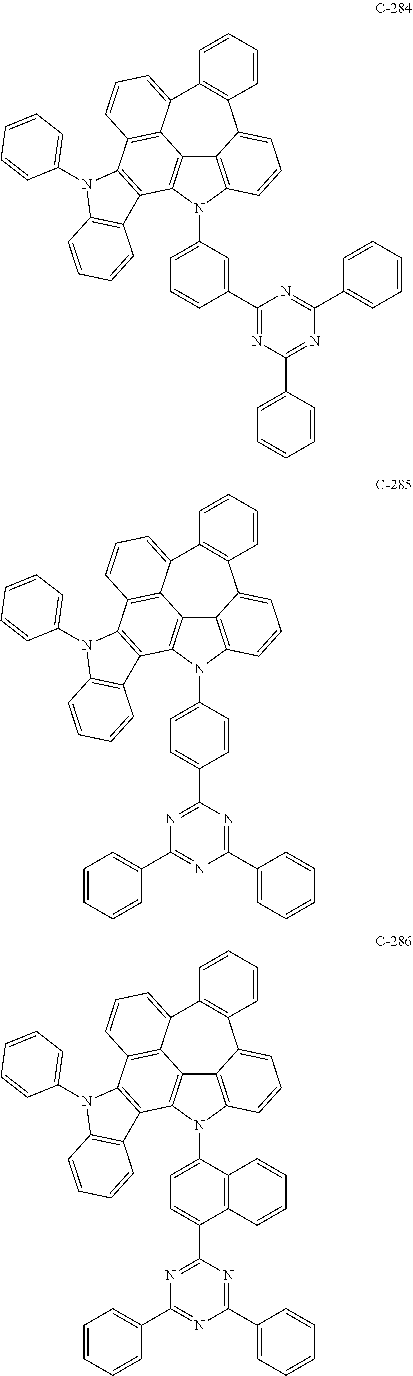 [SMILES: c1ccc(-c2nc(-c3ccccc3)nc(-c3cccc(-n4c5cccc6c5c5c7c(cccc7c7c(c8ccccc8n7-c7ccccc7)c54)-c4ccccc4-6)c3)n2)cc1 ; c1ccc(-c2nc(-c3ccccc3)nc(-c3ccc(-n4c5cccc6c5c5c7c(cccc7c7c(c8ccccc8n7-c7ccccc7)c54)-c4ccccc4-6)cc3)n2)cc1 ; c1ccc(-c2nc(-c3ccccc3)nc(-c3ccc(-n4c5cccc6c5c5c7c(cccc7c7c(c8ccccc8n7-c7ccccc7)c54)-c4ccccc4-6)c4ccccc34)n2)cc1]

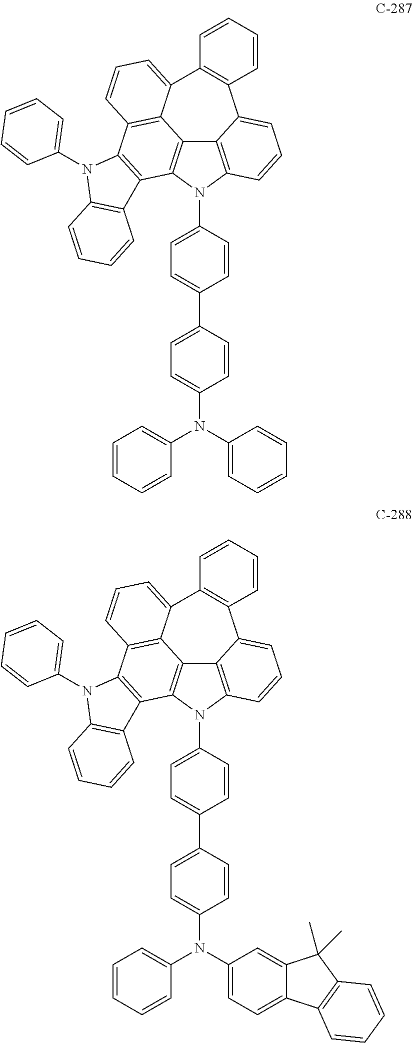 [SMILES: c1ccc(N(c2ccccc2)c2ccc(-c3ccc(-n4c5cccc6c5c5c7c(cccc7c7c(c8ccccc8n7-c7ccccc7)c54)-c4ccccc4-6)cc3)cc2)cc1 ; CC1(C)c2ccccc2-c2ccc(N(c3ccccc3)c3ccc(-c4ccc(-n5c6cccc7c6c6c8c(cccc8c8c(c9ccccc9n8-c8ccccc8)c65)-c5ccccc5-7)cc4)cc3)cc21]

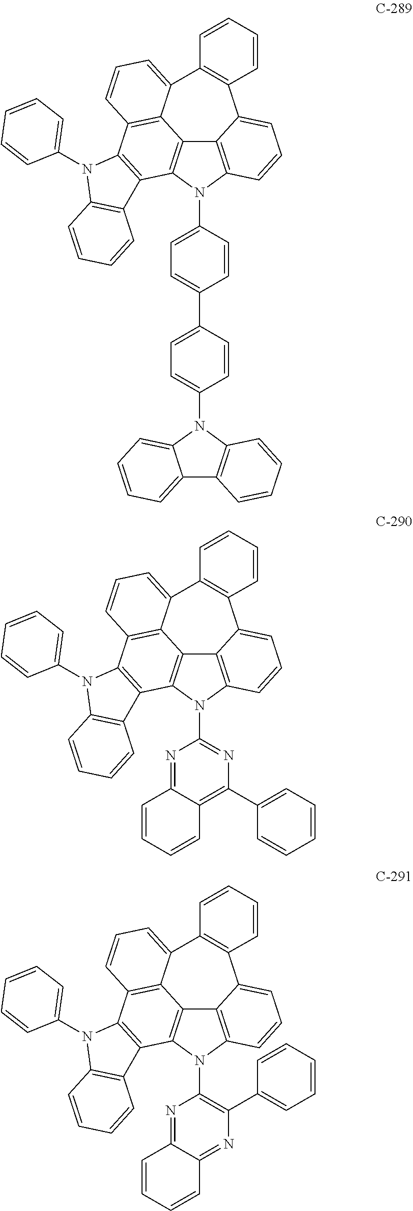

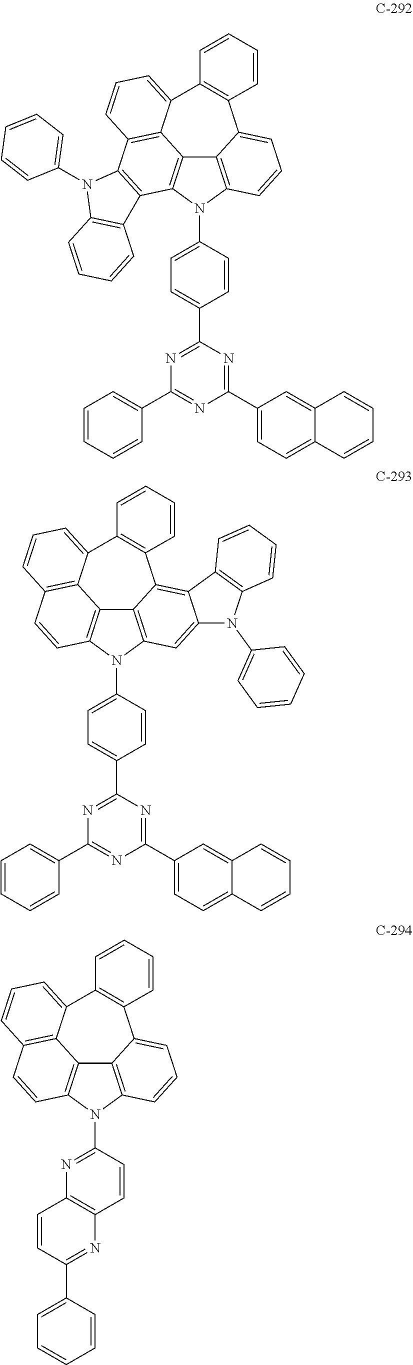

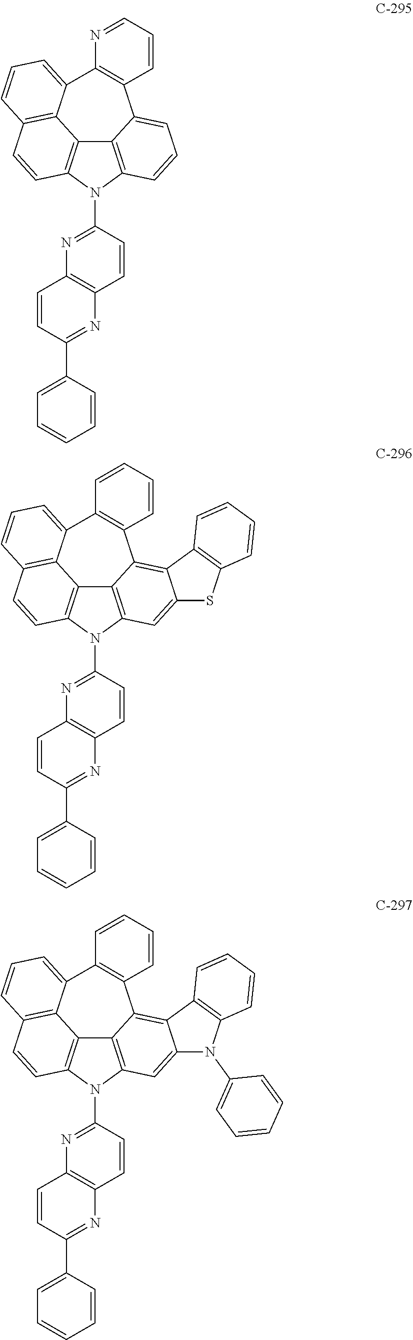 [SMILES: c1ccc(-c2ccc3nc(-n4c5cccc6c5c5c7c(cccc7ccc54)-c4ncccc4-6)ccc3n2)cc1 ; c1ccc(-c2ccc3nc(-n4c5cc6sc7ccccc7c6c6c5c5c7c(cccc7ccc54)-c4ccccc4-6)ccc3n2)cc1 ; c1ccc(-c2ccc3nc(-n4c5cc6c(c7c5c5c8c(cccc8ccc54)-c4ccccc4-7)c4ccccc4n6-c4ccccc4)ccc3n2)cc1]

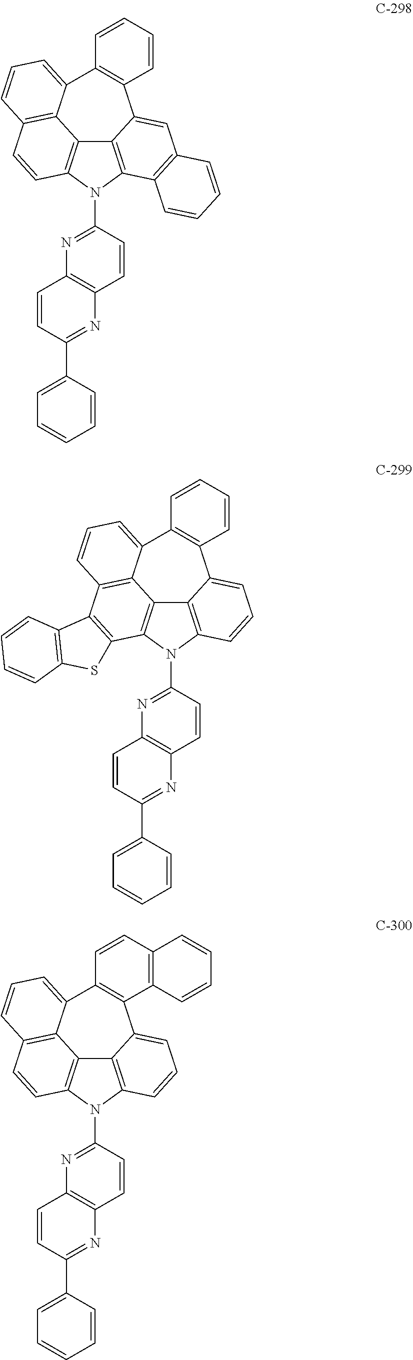

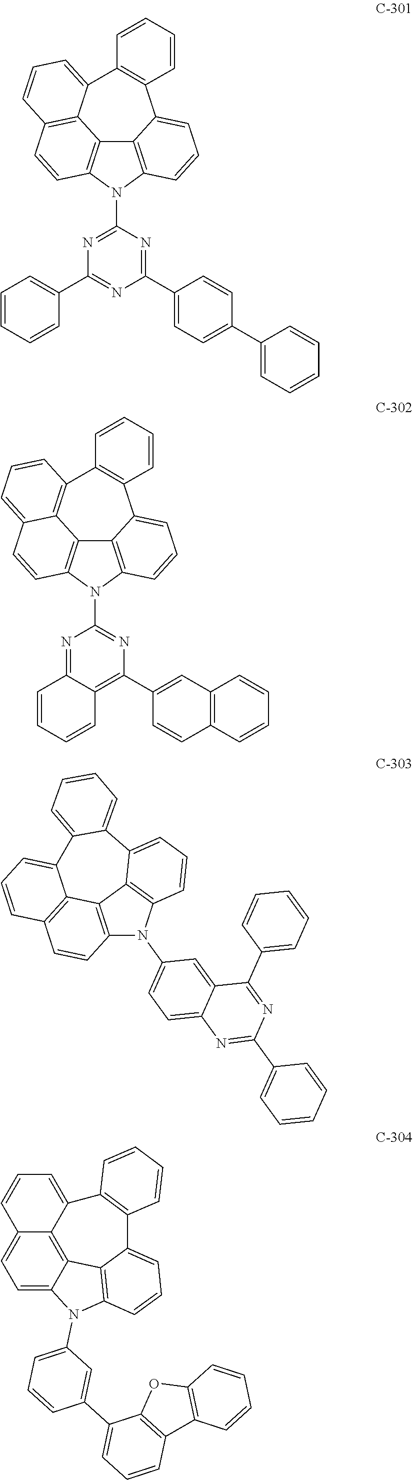

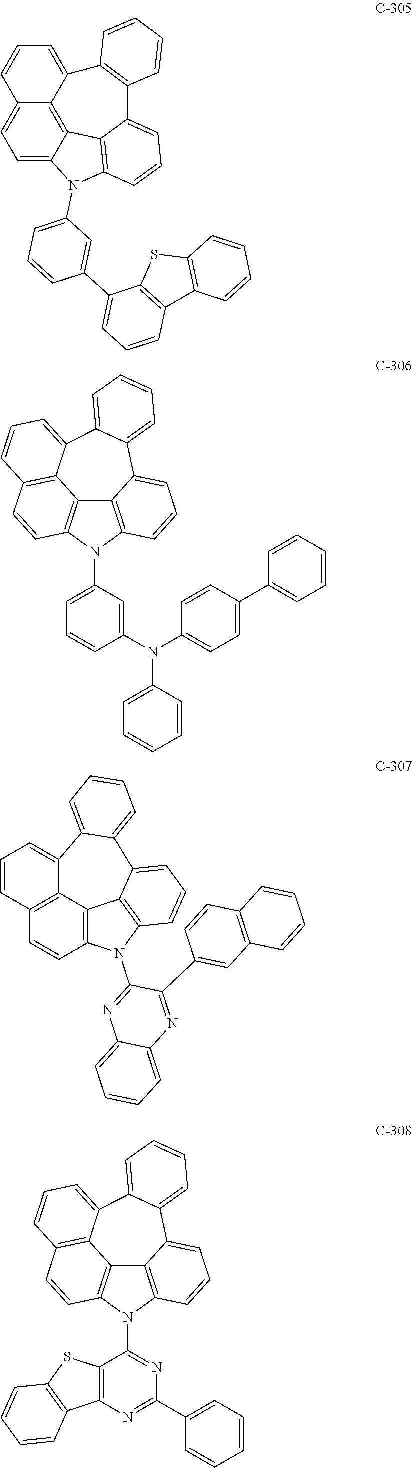

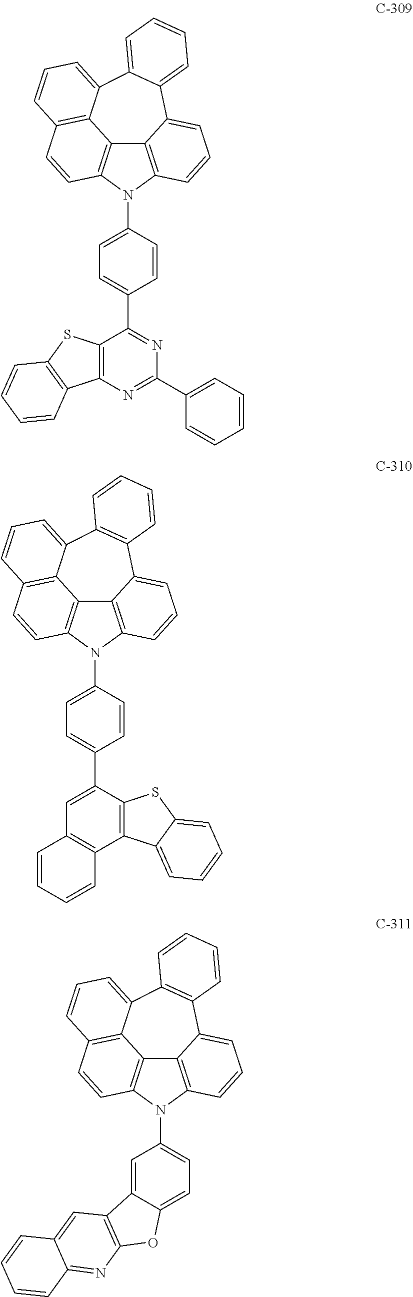 [SMILES: c1ccc(-c2nc(-c3ccc(-n4c5cccc6c5c5c7c(cccc7ccc54)-c4ccccc4-6)cc3)c3sc4ccccc4c3n2)cc1 ; c1ccc2c(c1)-c1cccc3ccc4c(c13)c1c-2cccc1n4-c1ccc(-c2cc3ccccc3c3c2sc2ccccc23)cc1 ; c1ccc2c(c1)-c1cccc3ccc4c(c13)c1c-2cccc1n4-c1ccc2oc3nc4ccccc4cc3c2c1]

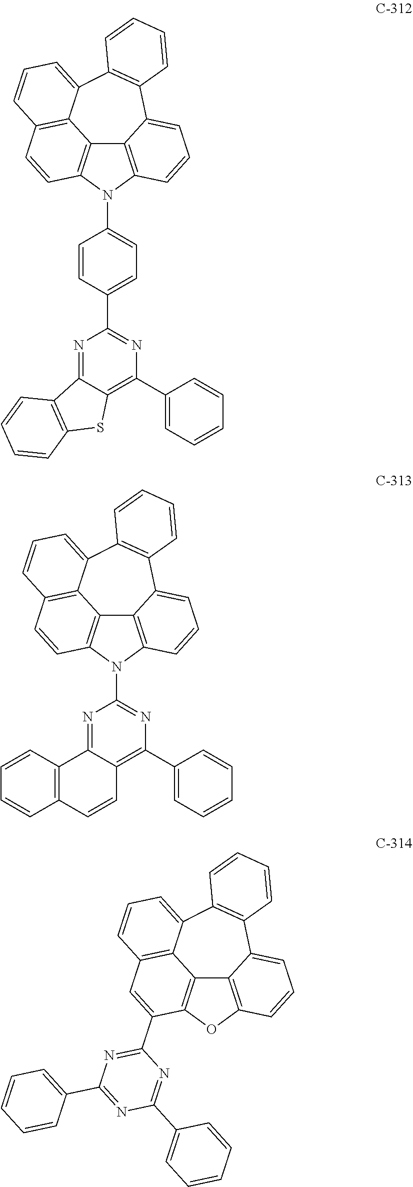 [SMILES: c1ccc(-c2nc(-c3ccc(-n4c5cccc6c5c5c7c(cccc7ccc54)-c4ccccc4-6)cc3)nc3c2sc2ccccc23)cc1 ; c1ccc(-c2nc(-n3c4cccc5c4c4c6c(cccc6ccc43)-c3ccccc3-5)nc3c2ccc2ccccc23)cc1 ; c1ccc(-c2nc(-c3ccccc3)nc(-c3cc4cccc5c4c4c3oc3cccc(c34)-c3ccccc3-5)n2)cc1]

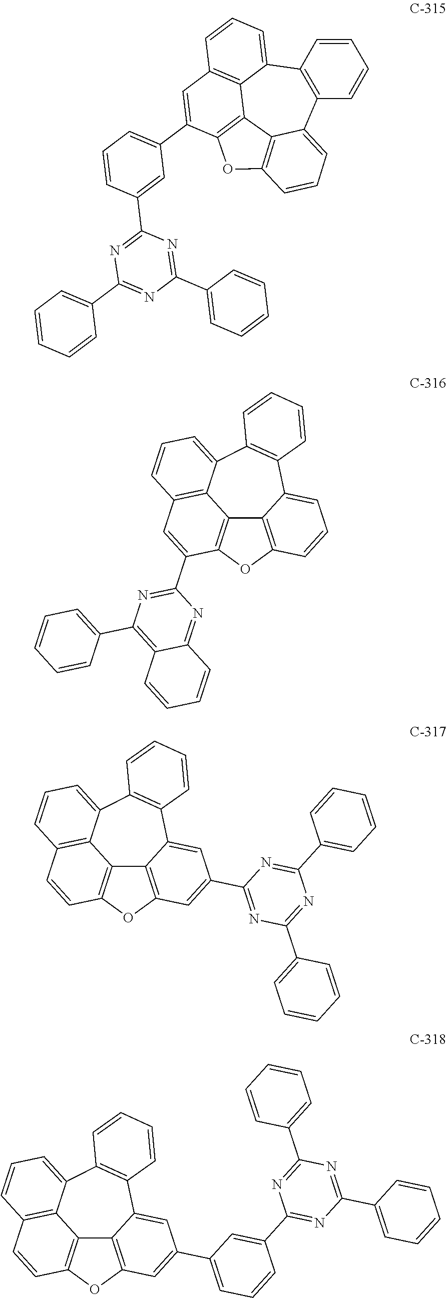

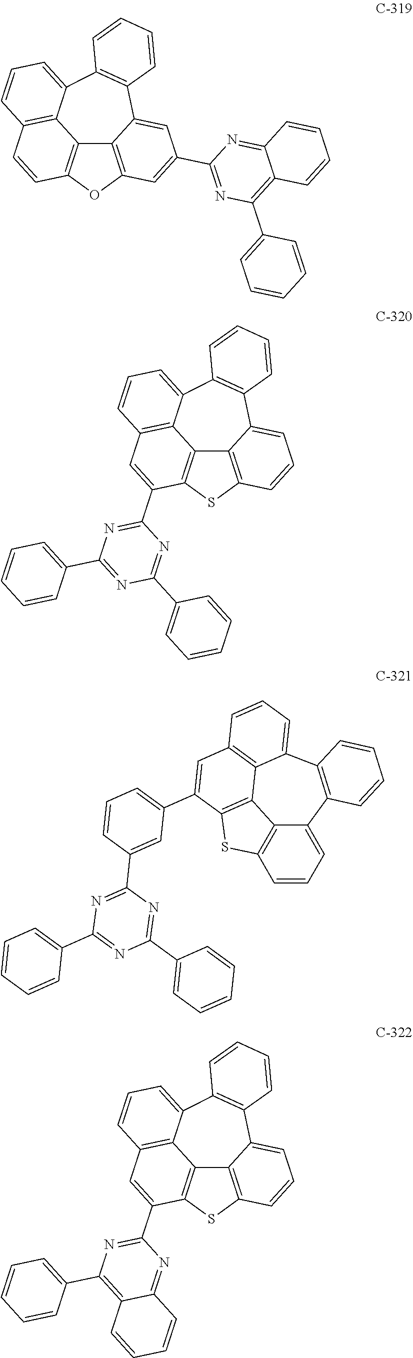

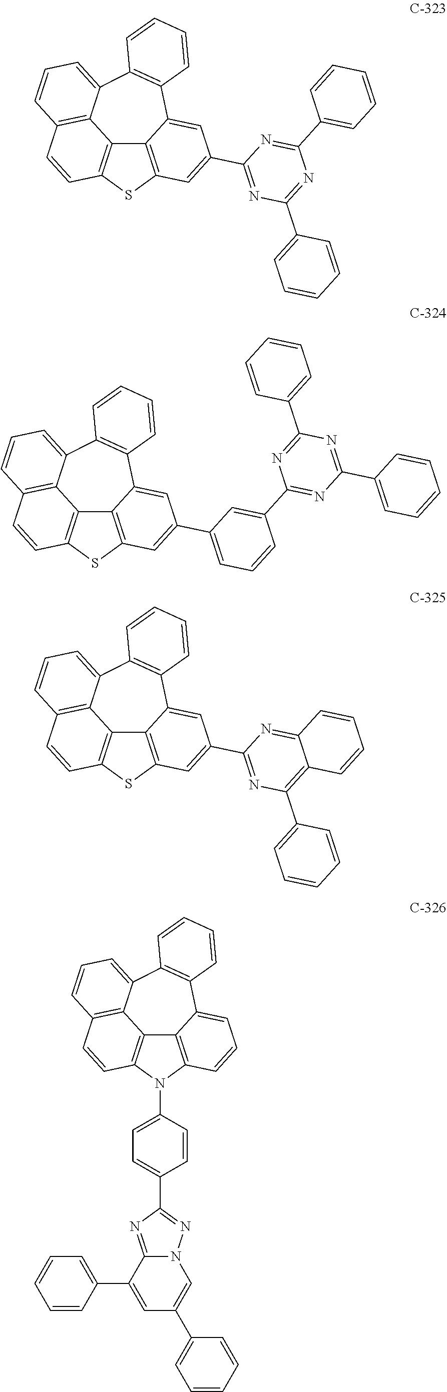 [SMILES: c1ccc(-c2nc(-c3ccccc3)nc(-c3cc4c5c(c3)sc3ccc6cccc(c6c35)-c3ccccc3-4)n2)cc1 ; c1ccc(-c2nc(-c3ccccc3)nc(-c3cccc(-c4cc5c6c(c4)sc4ccc7cccc(c7c46)-c4ccccc4-5)c3)n2)cc1 ; c1ccc(-c2nc(-c3cc4c5c(c3)sc3ccc6cccc(c6c35)-c3ccccc3-4)nc3ccccc23)cc1 ; c1ccc(-c2cc(-c3ccccc3)c3nc(-c4ccc(-n5c6cccc7c6c6c8c(cccc8ccc65)-c5ccccc5-7)cc4)nn3c2)cc1]

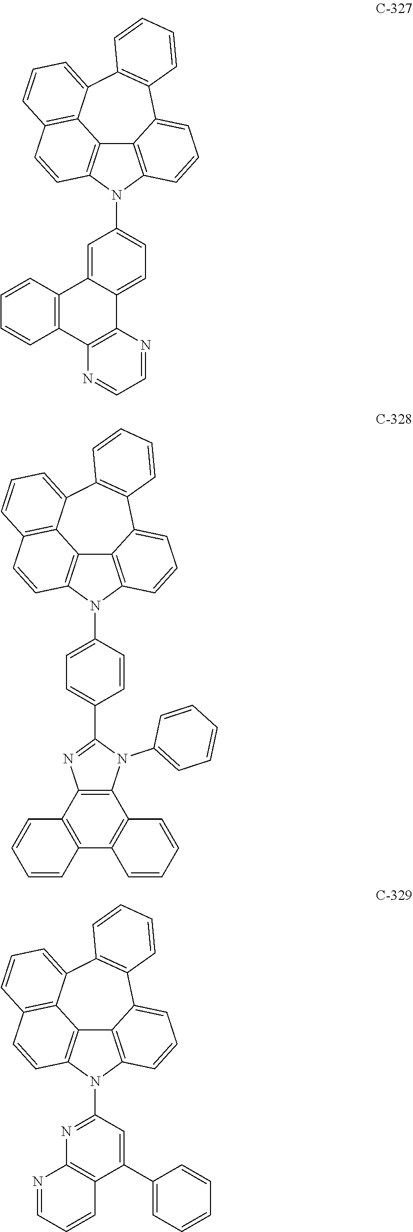

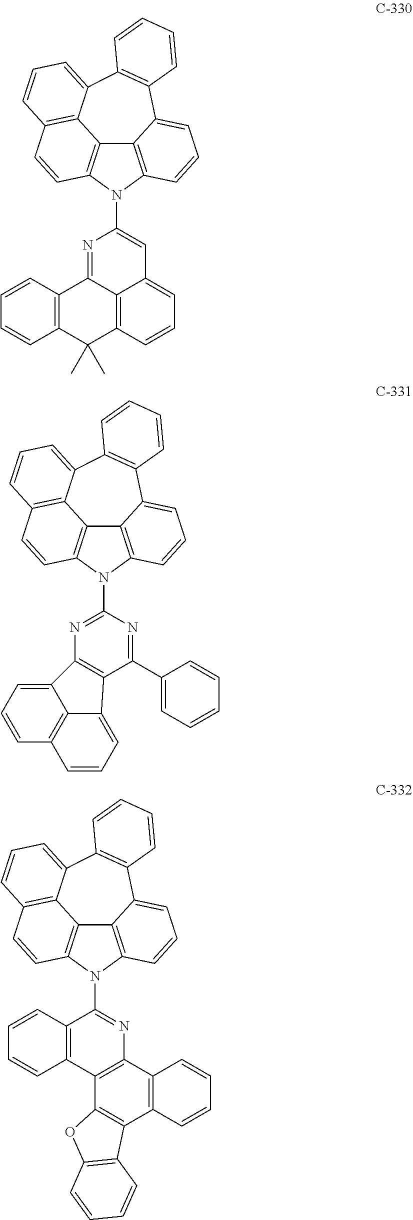

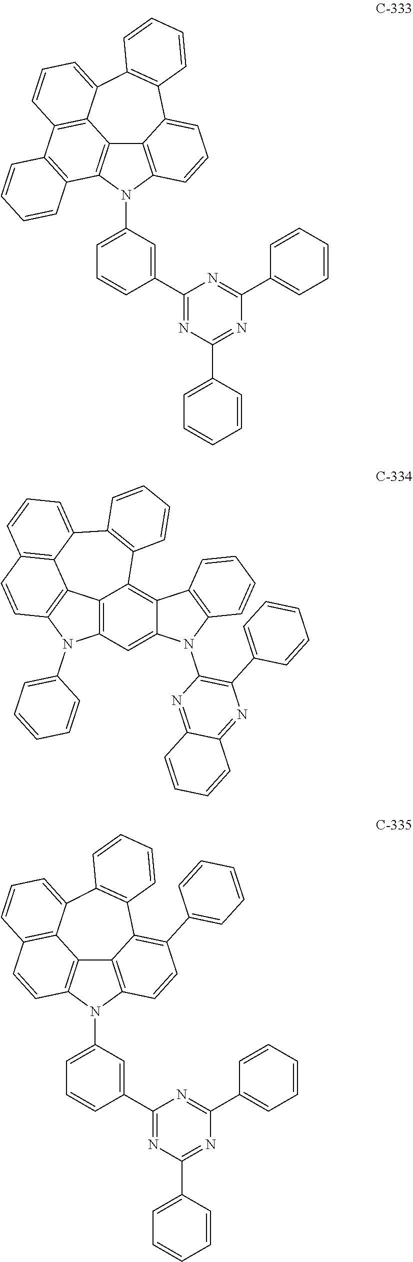 [SMILES: c1ccc(-c2nc(-c3ccccc3)nc(-c3cccc(-n4c5cccc6c5c5c7c(cccc7c7ccccc7c54)-c4ccccc4-6)c3)n2)cc1 ; c1ccc(-c2nc3ccccc3nc2-n2c3ccccc3c3c4c5c6c7c(cccc7ccc6n(-c6ccccc6)c5cc32)-c2ccccc2-4)cc1 ; c1ccc(-c2nc(-c3ccccc3)nc(-c3cccc(-n4c5ccc(-c6ccccc6)c6c5c5c7c(cccc7ccc54)-c4ccccc4-6)c3)n2)cc1]

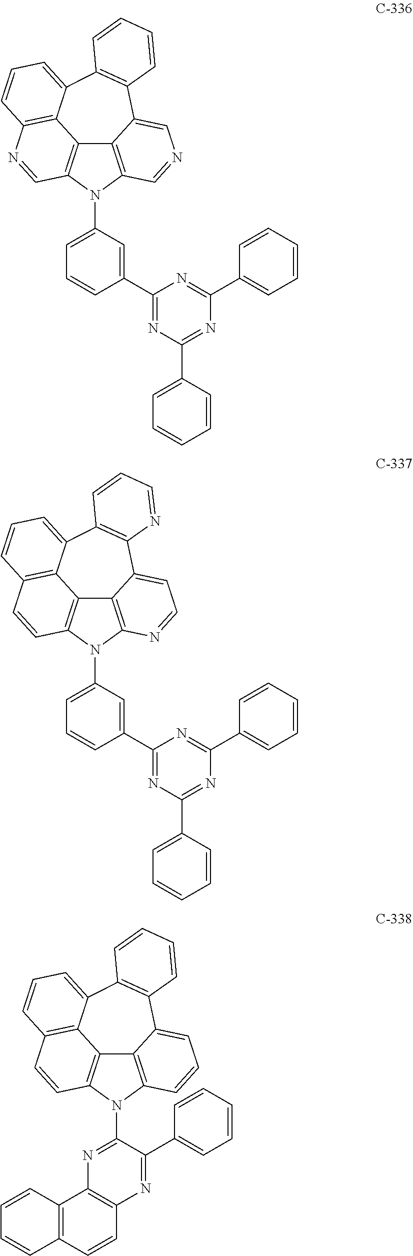

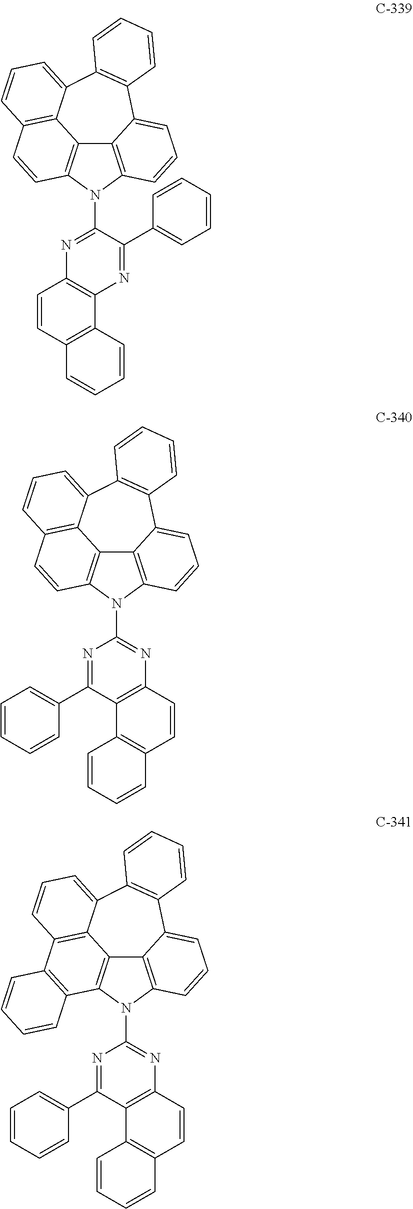

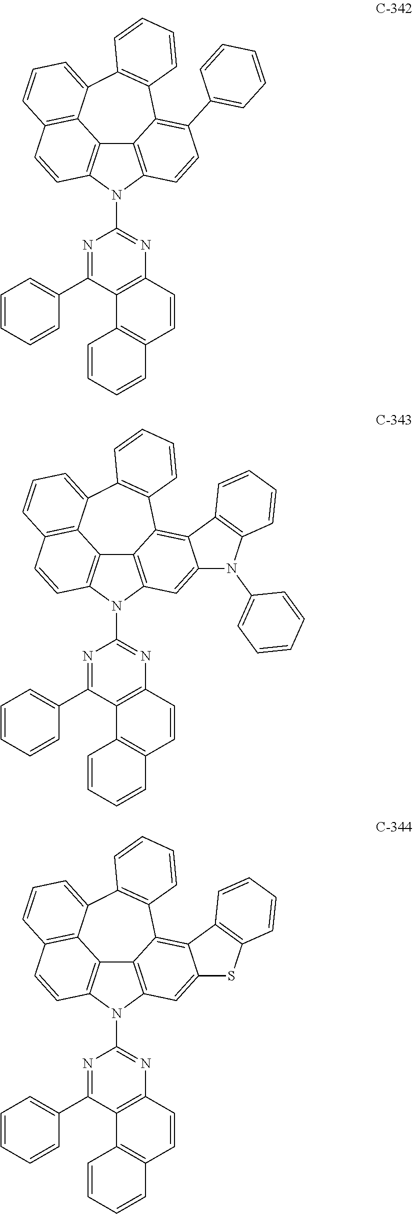

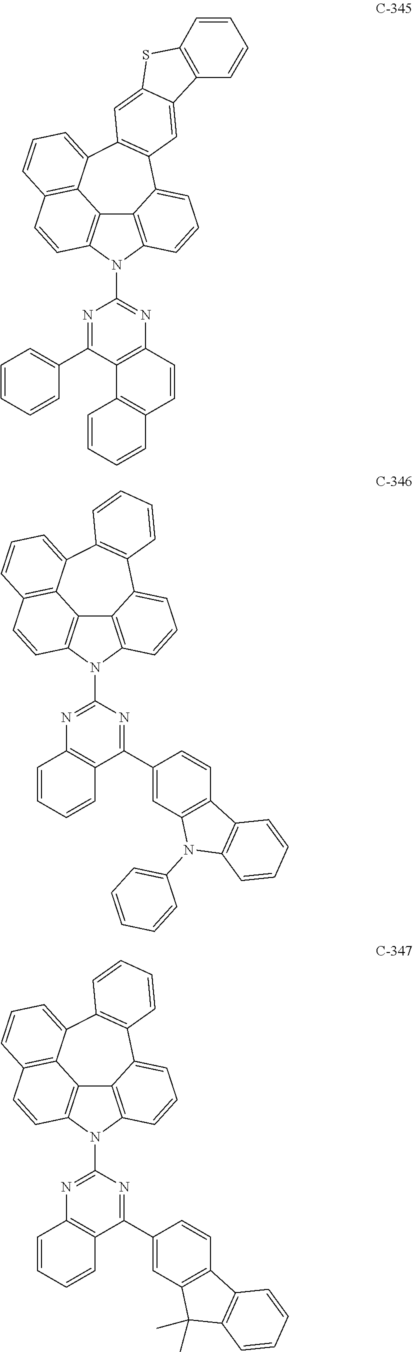

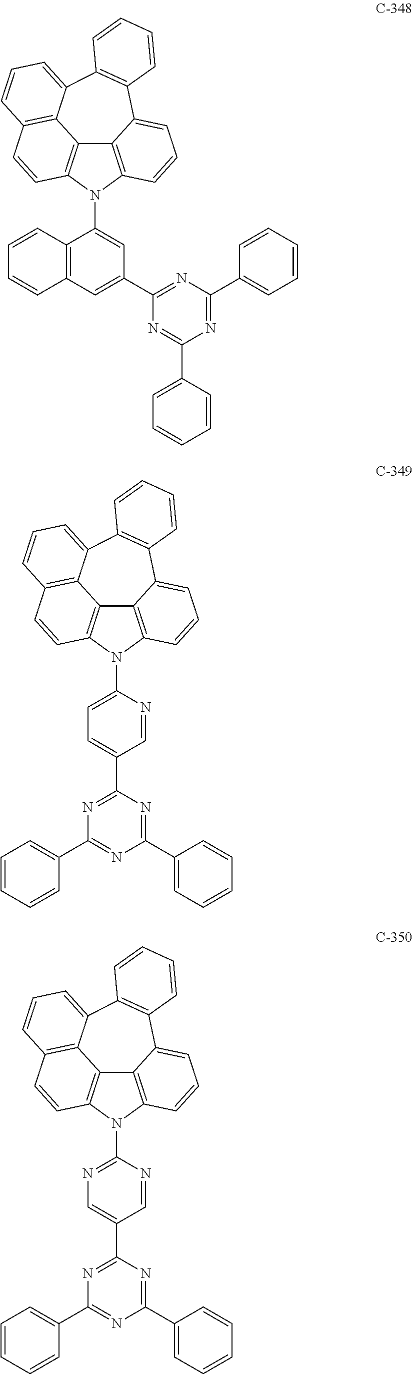 [SMILES: c1ccc(-c2nc(-c3ccccc3)nc(-c3cc(-n4c5cccc6c5c5c7c(cccc7ccc54)-c4ccccc4-6)c4ccccc4c3)n2)cc1 ; c1ccc(-c2nc(-c3ccccc3)nc(-c3ccc(-n4c5cccc6c5c5c7c(cccc7ccc54)-c4ccccc4-6)nc3)n2)cc1 ; c1ccc(-c2nc(-c3ccccc3)nc(-c3cnc(-n4c5cccc6c5c5c7c(cccc7ccc54)-c4ccccc4-6)nc3)n2)cc1]

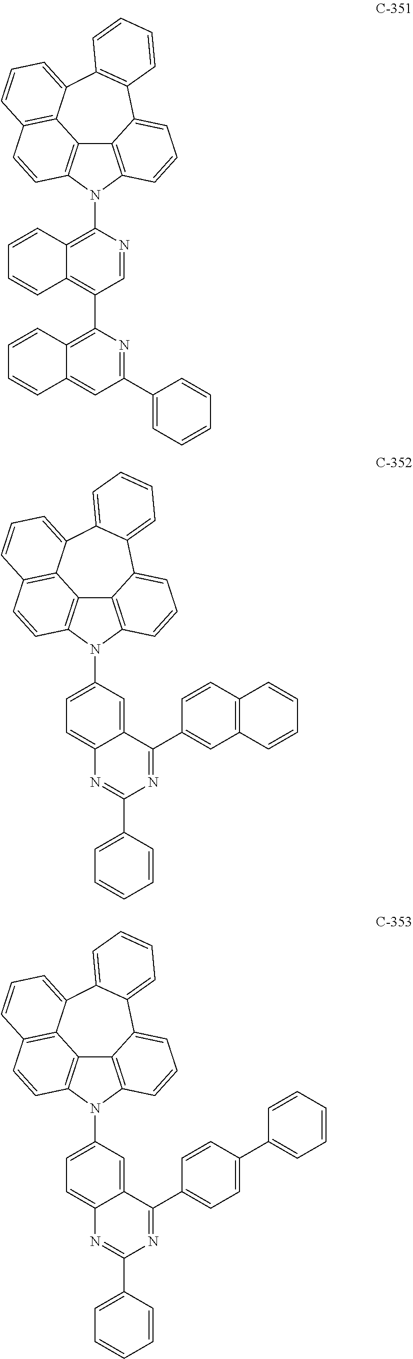

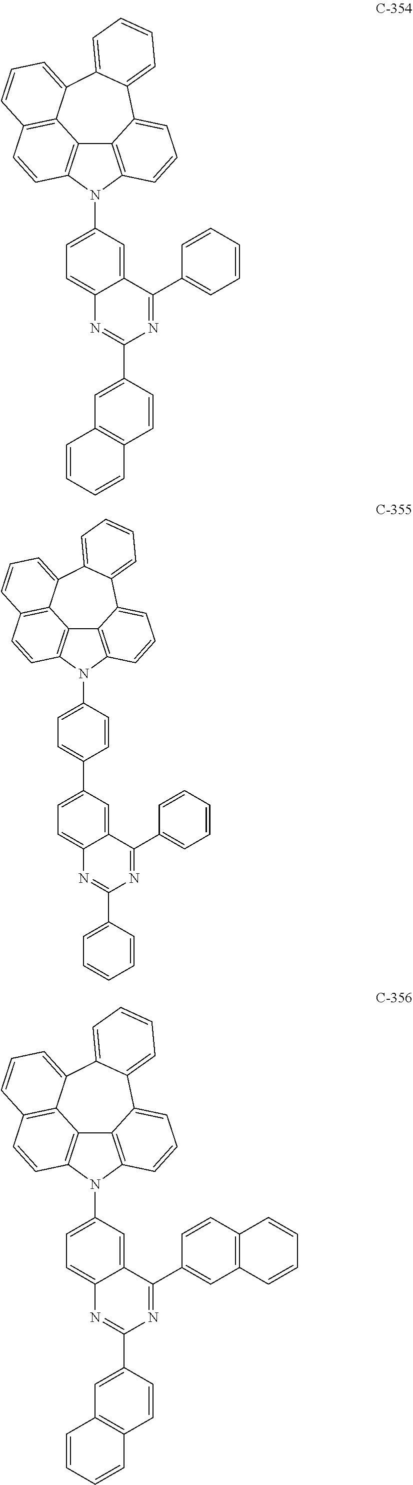

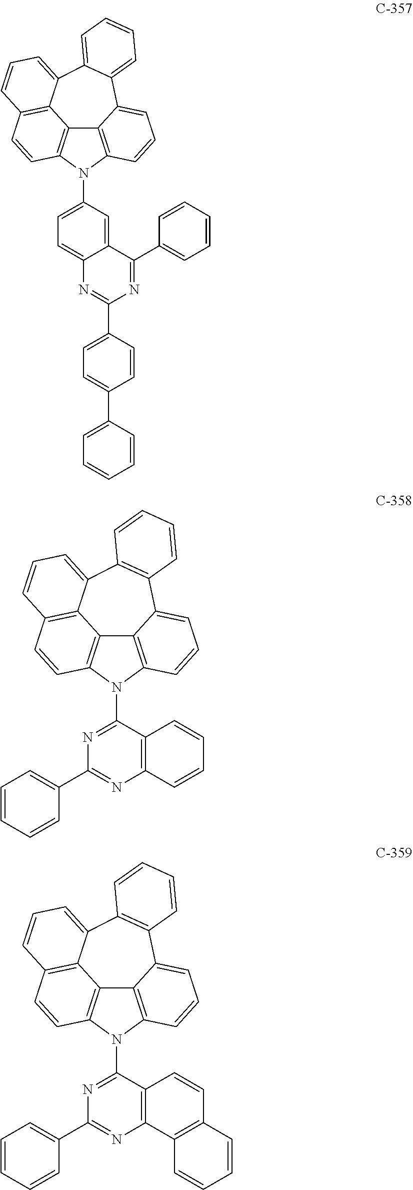

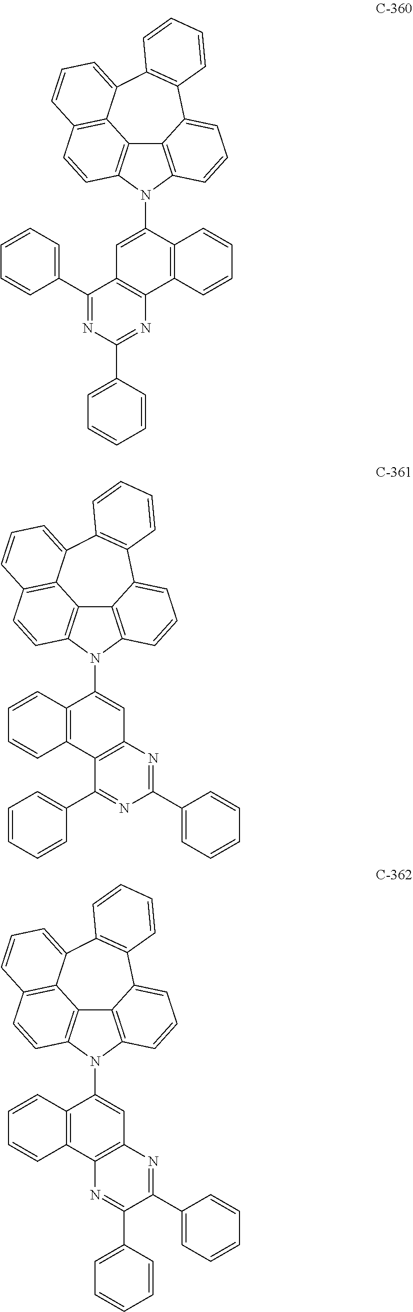

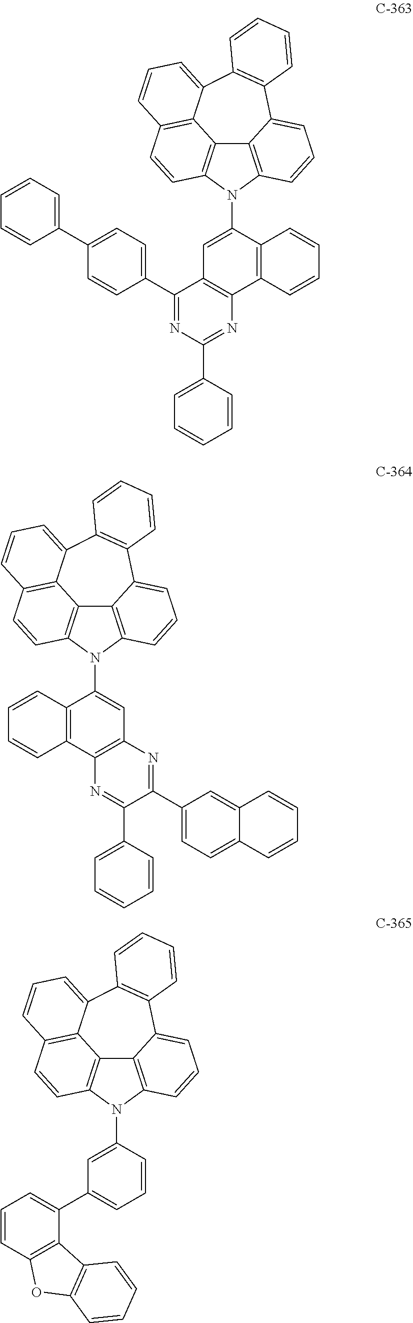

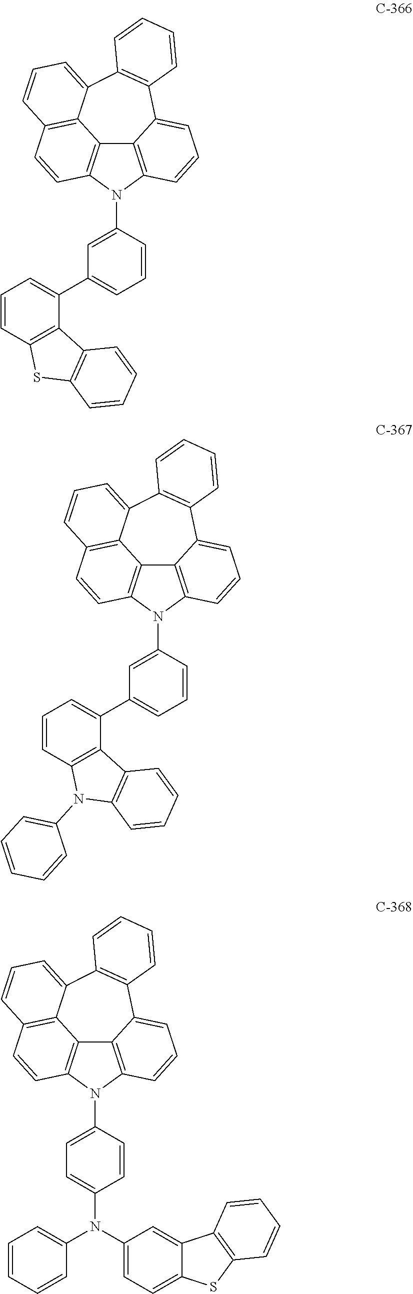 [SMILES: c1cc(-c2cccc3sc4ccccc4c23)cc(-n2c3cccc4c3c3c5c(cccc5ccc32)-c2ccccc2-4)c1 ; c1ccc(-n2c3ccccc3c3c(-c4cccc(-n5c6cccc7c6c6c8c(cccc8ccc65)-c5ccccc5-7)c4)cccc32)cc1 ; c1ccc(N(c2ccc(-n3c4cccc5c4c4c6c(cccc6ccc43)-c3ccccc3-5)cc2)c2ccc3sc4ccccc4c3c2)cc1]

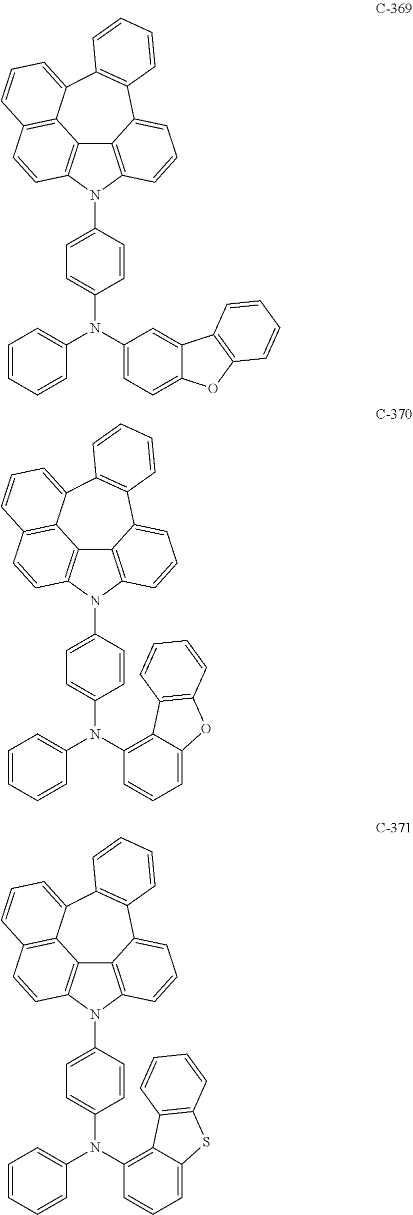

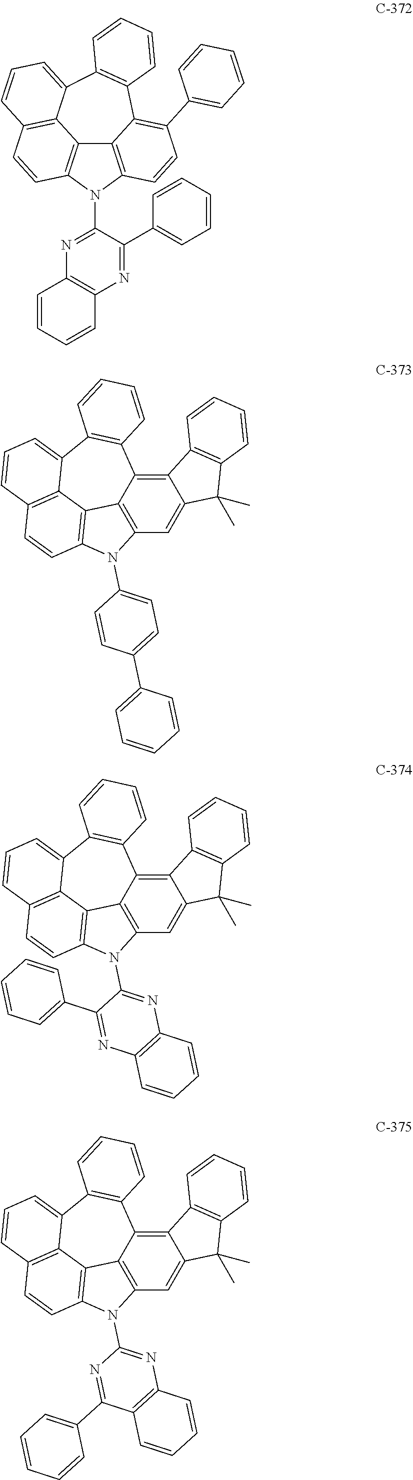

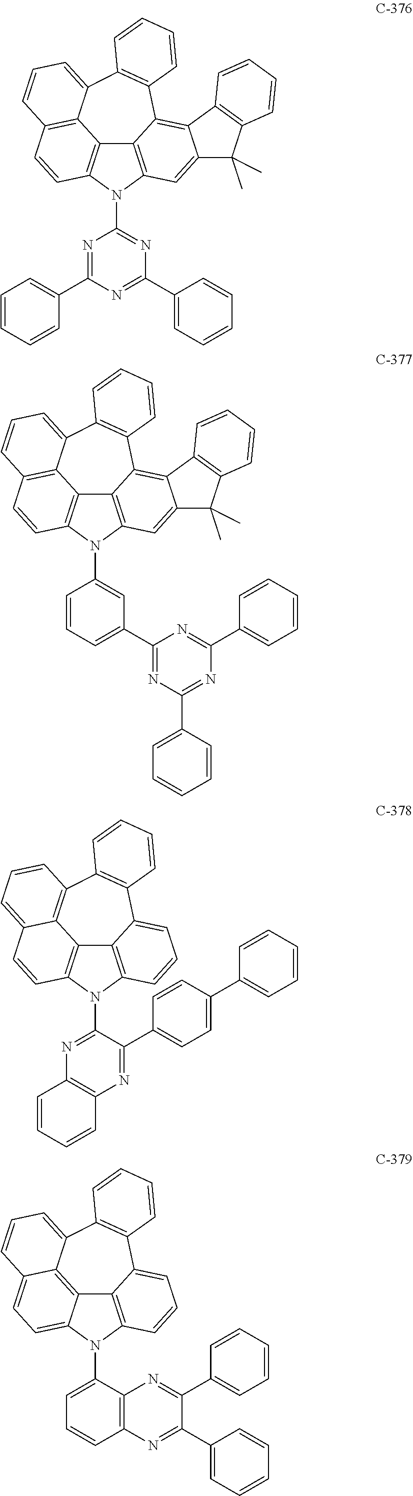

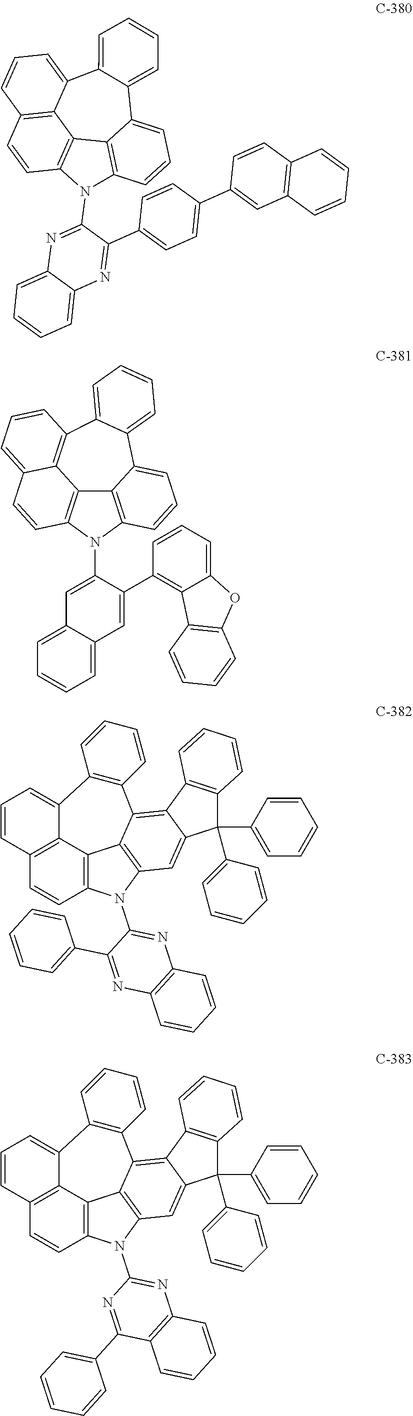

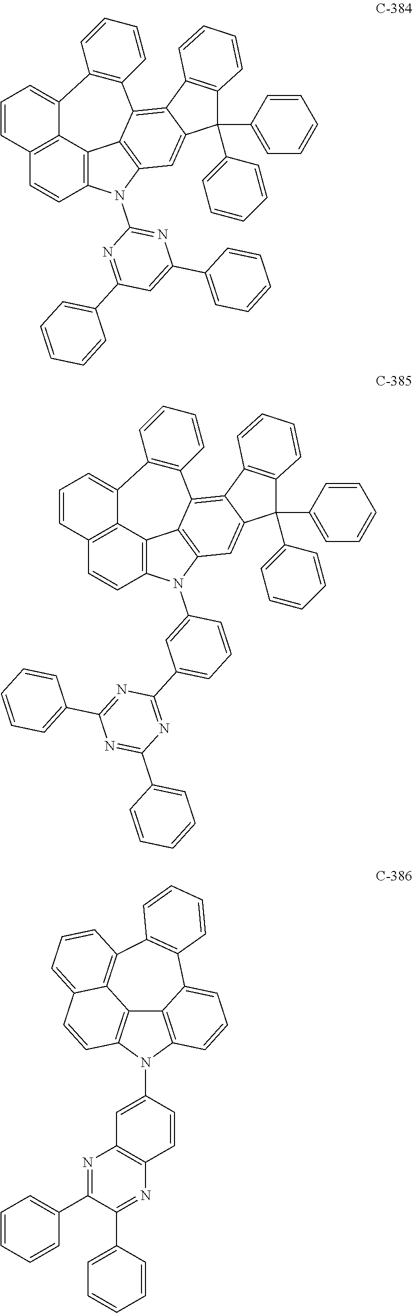

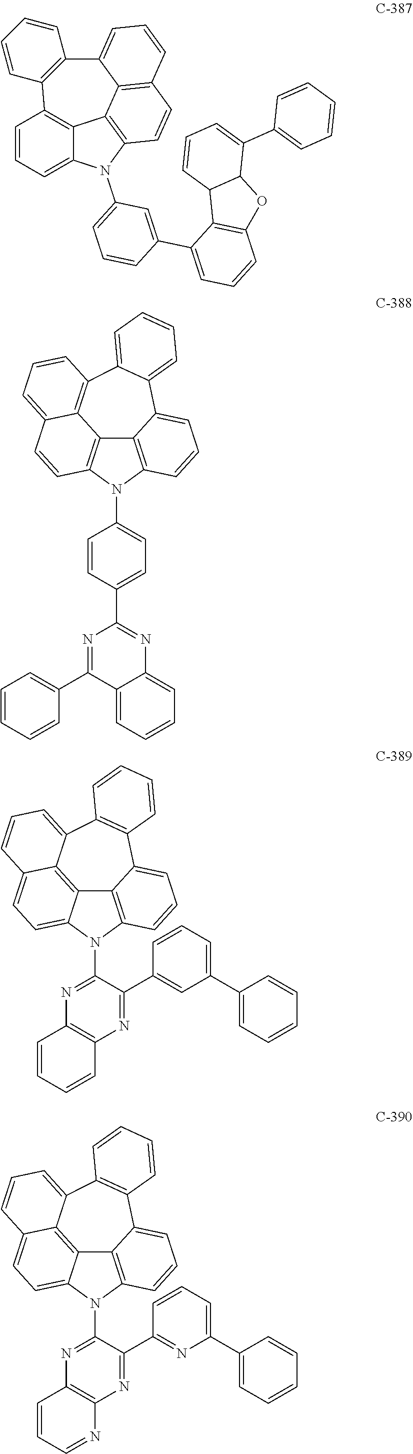

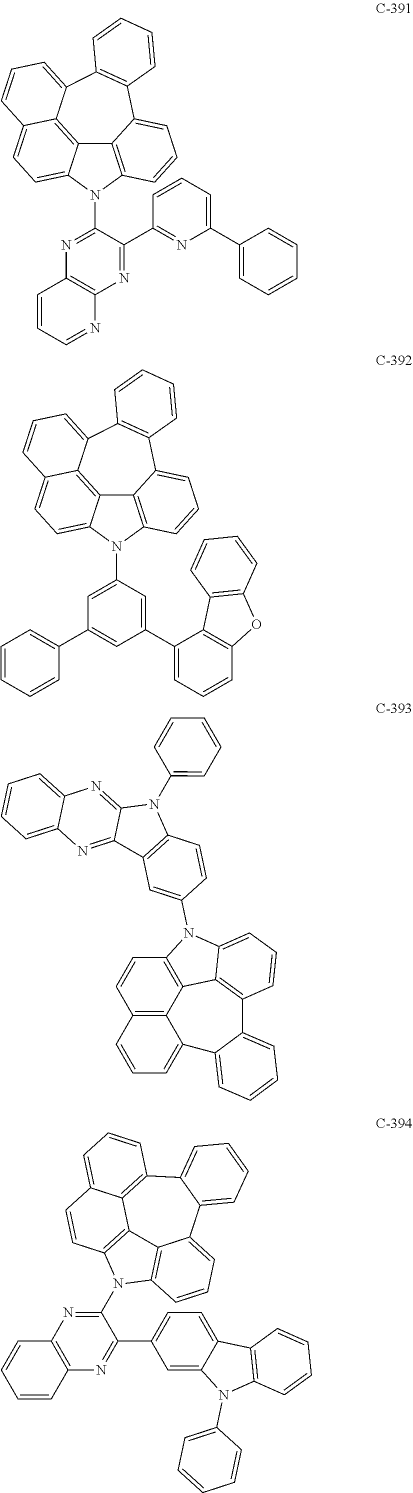

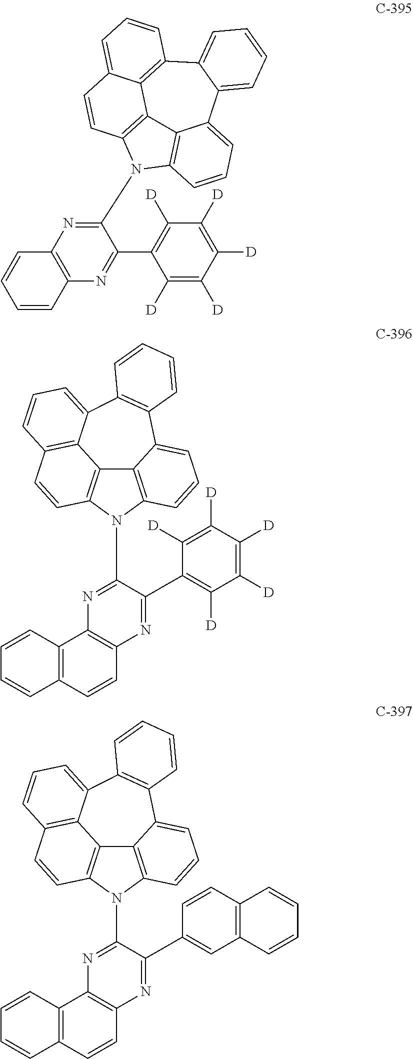

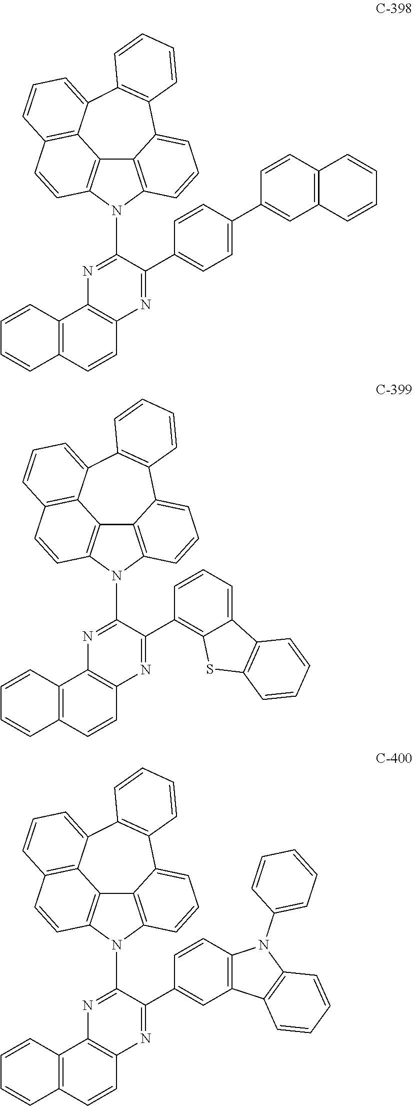 [SMILES: c1ccc2c(c1)-c1cccc3ccc4c(c13)c1c-2cccc1n4-c1nc2c(ccc3ccccc32)nc1-c1ccc(-c2ccc3ccccc3c2)cc1 ; c1ccc2c(c1)-c1cccc3ccc4c(c13)c1c-2cccc1n4-c1nc2c(ccc3ccccc32)nc1-c1cccc2c1sc1ccccc12 ; c1ccc(-n2c3ccccc3c3cc(-c4nc5ccc6ccccc6c5nc4-n4c5cccc6c5c5c7c(cccc7ccc54)-c4ccccc4-6)ccc32)cc1]

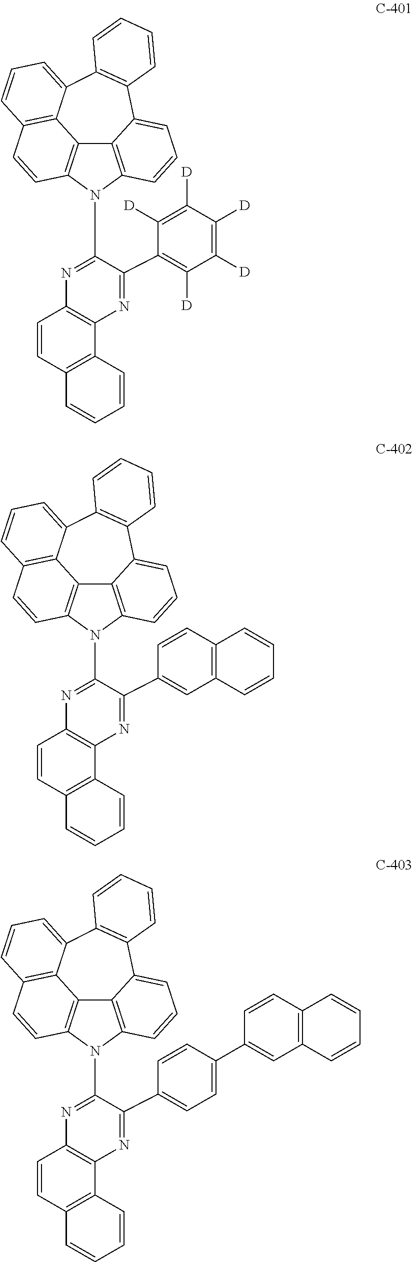

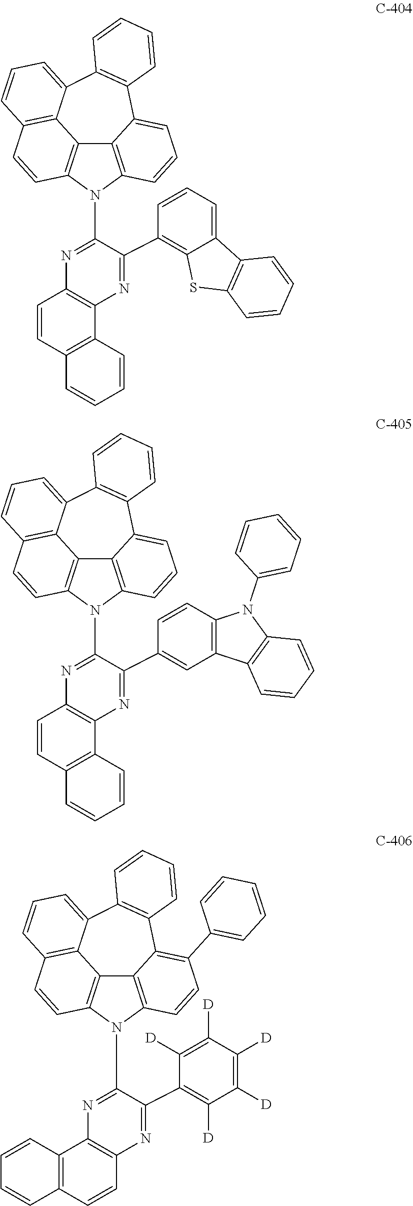

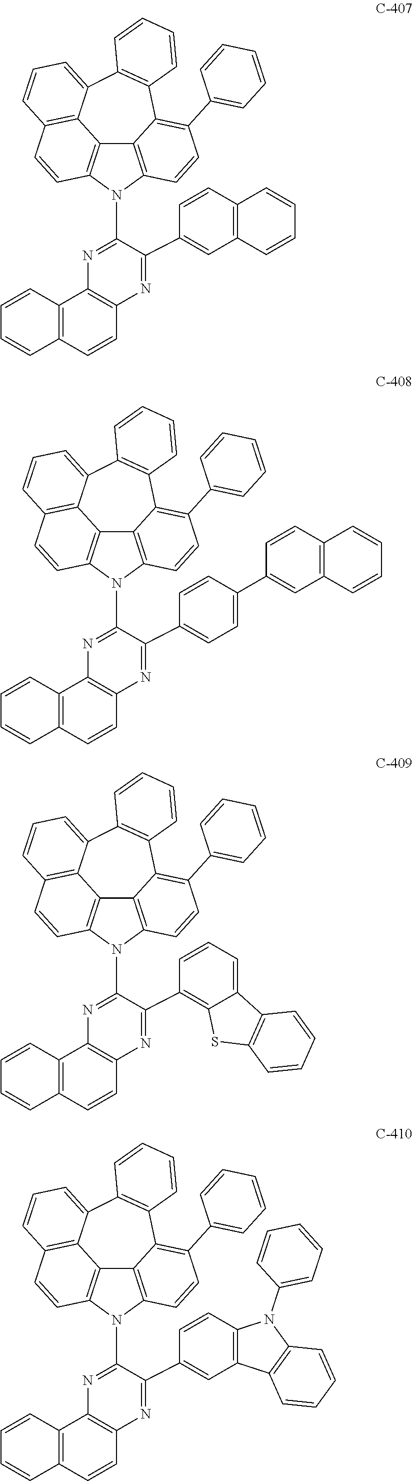 [SMILES: c1ccc(-c2ccc3c4c2-c2ccccc2-c2cccc5ccc(c4c25)n3-c2nc3c(ccc4ccccc43)nc2-c2ccc3ccccc3c2)cc1 ; c1ccc(-c2ccc3c4c2-c2ccccc2-c2cccc5ccc(c4c25)n3-c2nc3c(ccc4ccccc43)nc2-c2ccc(-c3ccc4ccccc4c3)cc2)cc1 ; c1ccc(-c2ccc3c4c2-c2ccccc2-c2cccc5ccc(c4c25)n3-c2nc3c(ccc4ccccc43)nc2-c2cccc3c2sc2ccccc23)cc1 ; c1ccc(-c2ccc3c4c2-c2ccccc2-c2cccc5ccc(c4c25)n3-c2nc3c(ccc4ccccc43)nc2-c2ccc3c(c2)c2ccccc2n3-c2ccccc2)cc1]

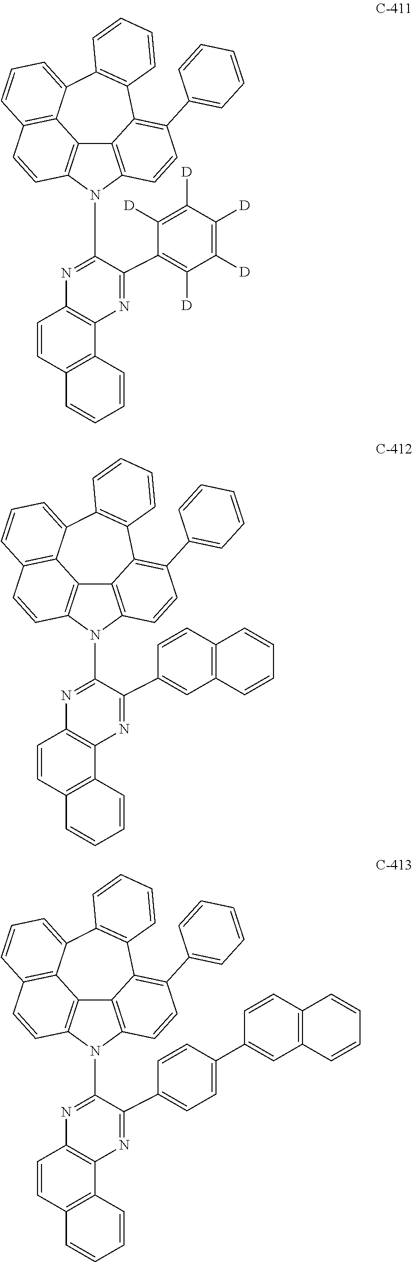

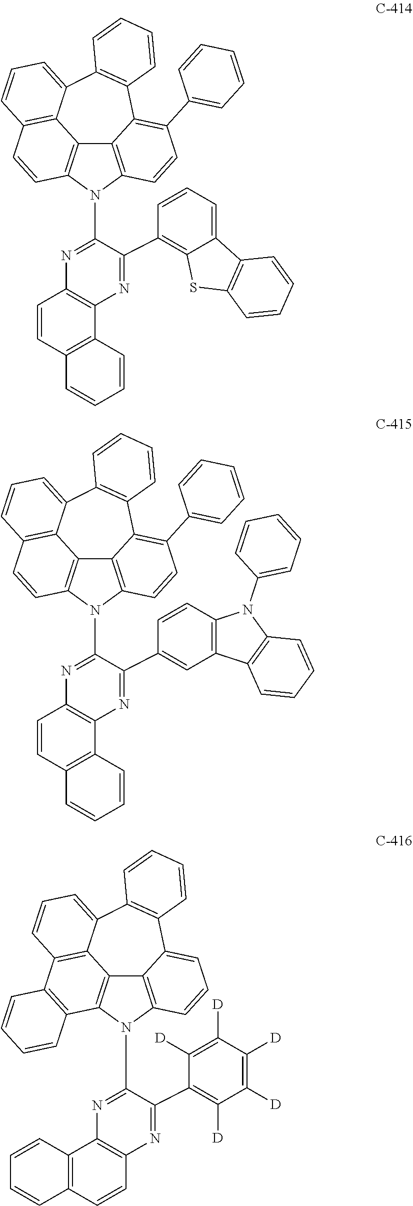

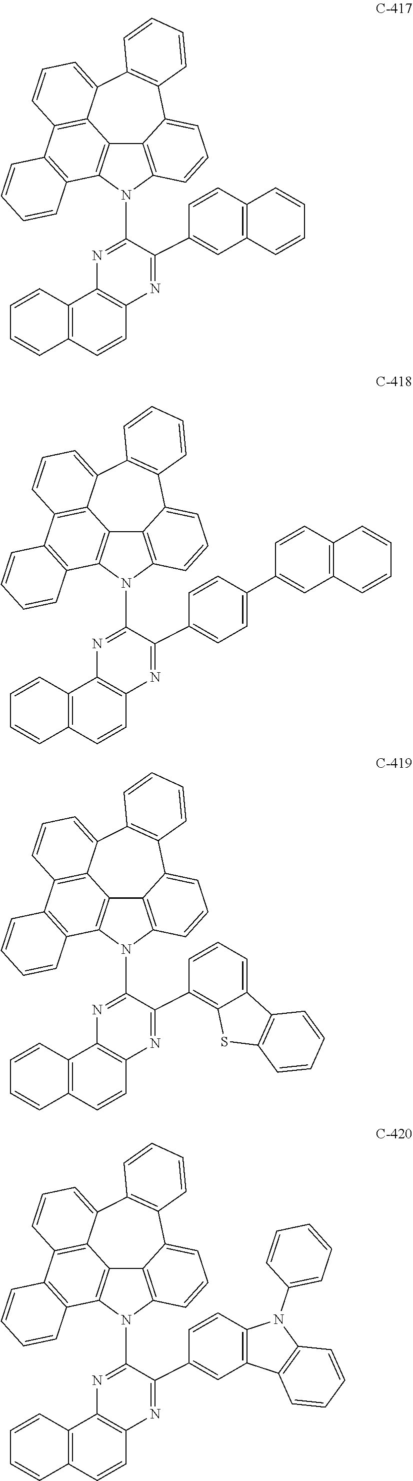 [SMILES: c1ccc2c(c1)-c1cccc3c4ccccc4c4c(c13)c1c-2cccc1n4-c1nc2c(ccc3ccccc32)nc1-c1ccc2ccccc2c1 ; c1ccc2c(c1)-c1cccc3c4ccccc4c4c(c13)c1c-2cccc1n4-c1nc2c(ccc3ccccc32)nc1-c1ccc(-c2ccc3ccccc3c2)cc1 ; c1ccc2c(c1)-c1cccc3c4ccccc4c4c(c13)c1c-2cccc1n4-c1nc2c(ccc3ccccc32)nc1-c1cccc2c1sc1ccccc12 ; c1ccc(-n2c3ccccc3c3cc(-c4nc5ccc6ccccc6c5nc4-n4c5cccc6c5c5c7c(cccc7c7ccccc7c54)-c4ccccc4-6)ccc32)cc1]

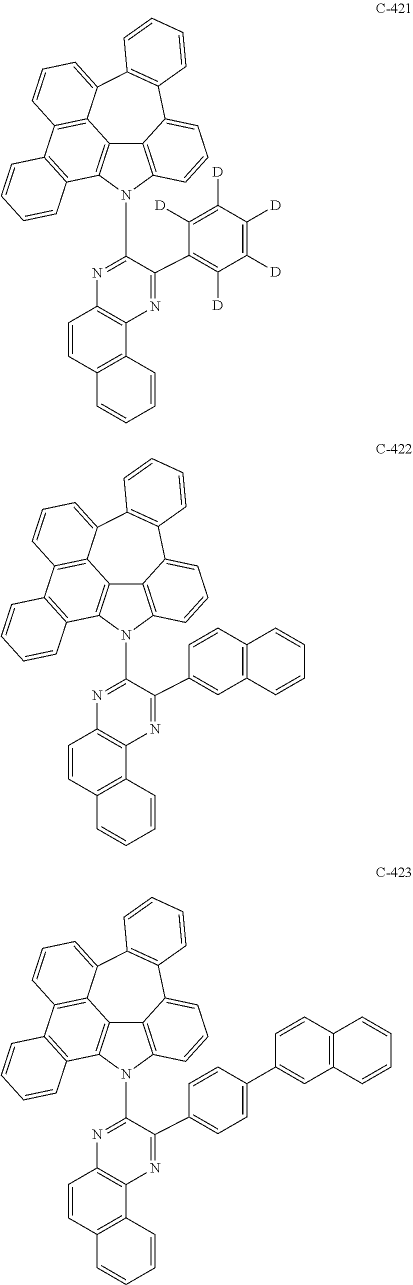

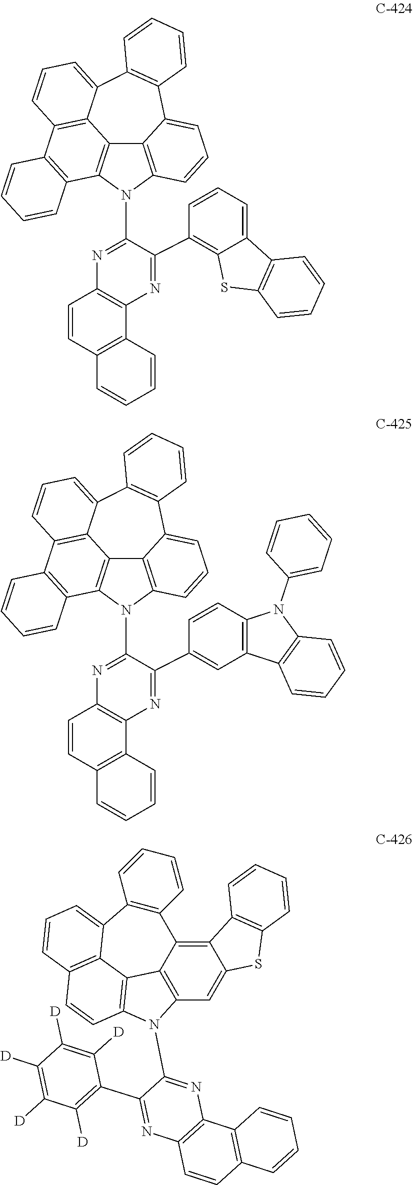

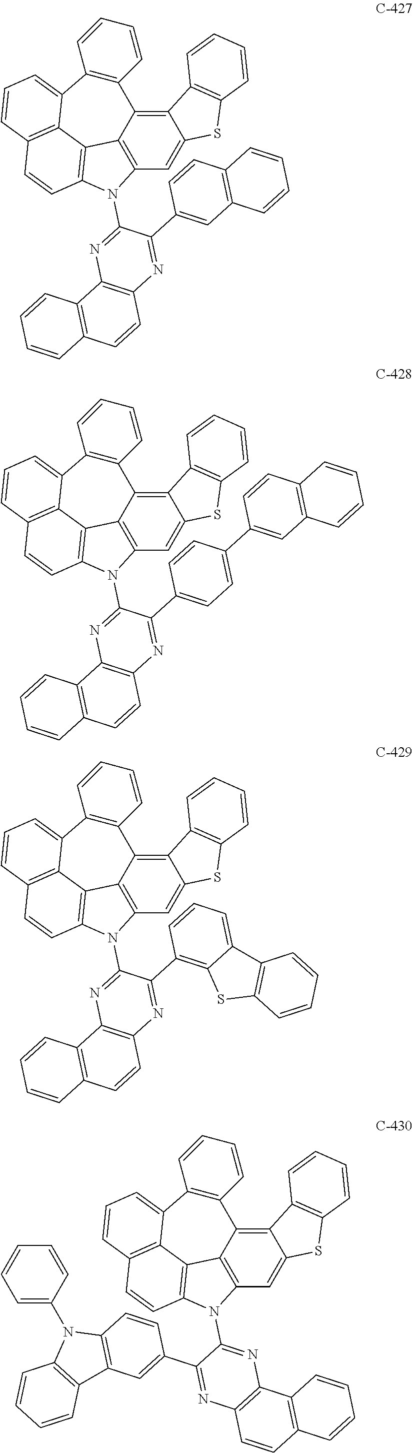

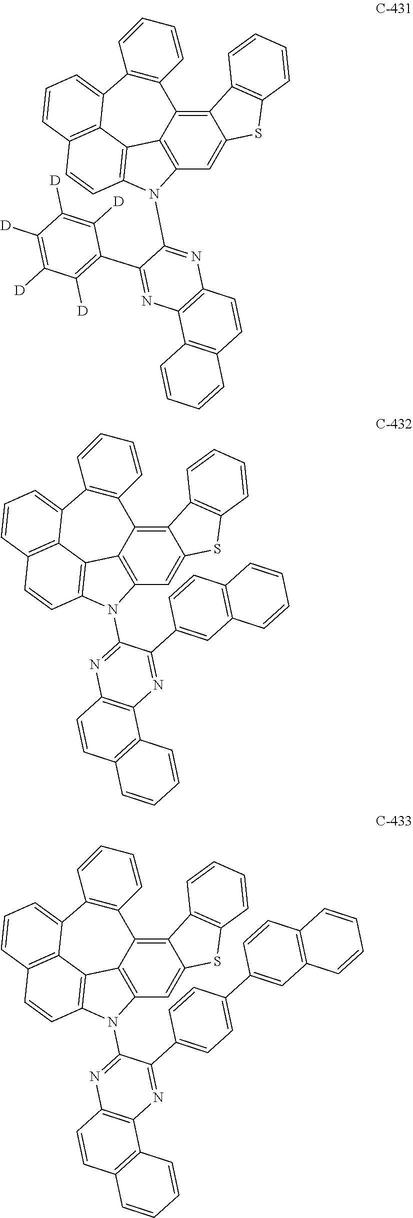

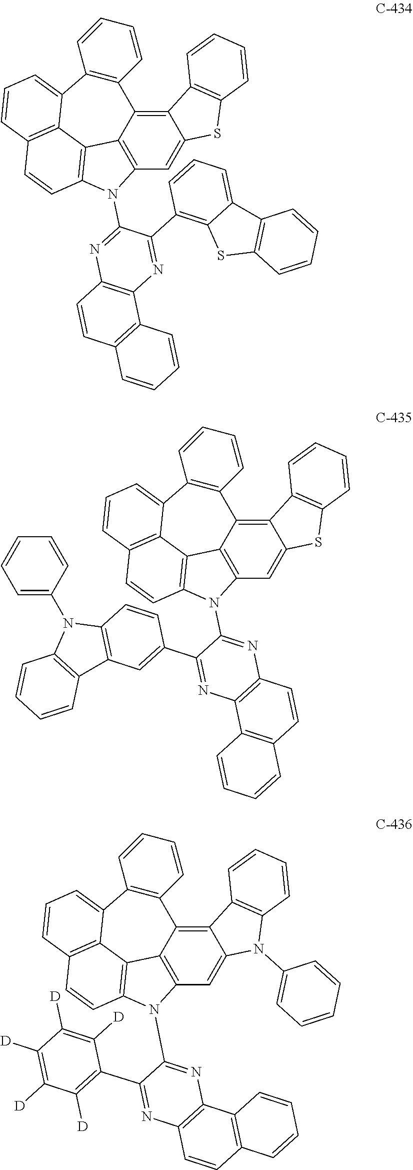 [SMILES: c1ccc2c(c1)-c1cccc3ccc4c(c13)c1c-2c2c(cc1n4-c1nc3ccc4ccccc4c3nc1-c1cccc3c1sc1ccccc13)sc1ccccc12 ; c1ccc(-n2c3ccccc3c3cc(-c4nc5c(ccc6ccccc65)nc4-n4c5cc6sc7ccccc7c6c6c5c5c7c(cccc7ccc54)-c4ccccc4-6)ccc32)cc1 ; [2H]c1c([2H])c([2H])c(-c2nc3ccc4ccccc4c3nc2-n2c3cc4c(c5c3c3c6c(cccc6ccc32)-c2ccccc2-5)c2ccccc2n4-c2ccccc2)c([2H])c1[2H]]

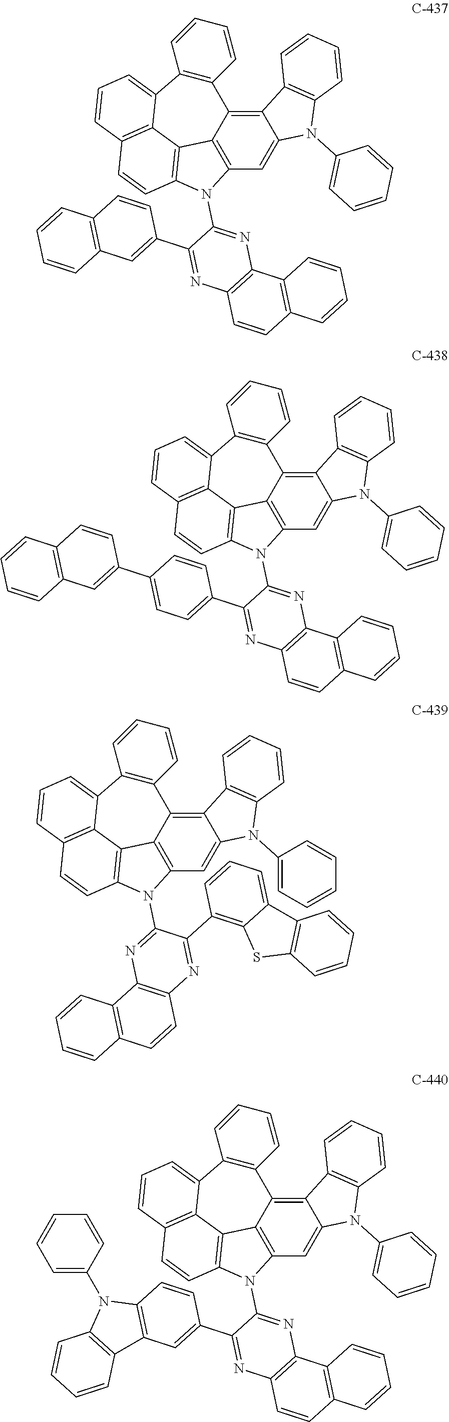 [SMILES: c1ccc(-n2c3ccccc3c3c4c5c6c7c(cccc7ccc6n(-c6nc7c(ccc8ccccc87)nc6-c6ccc7ccccc7c6)c5cc32)-c2ccccc2-4)cc1 ; c1ccc(-n2c3ccccc3c3c4c5c6c7c(cccc7ccc6n(-c6nc7c(ccc8ccccc87)nc6-c6ccc(-c7ccc8ccccc8c7)cc6)c5cc32)-c2ccccc2-4)cc1 ; c1ccc(-n2c3ccccc3c3c4c5c6c7c(cccc7ccc6n(-c6nc7c(ccc8ccccc87)nc6-c6cccc7c6sc6ccccc67)c5cc32)-c2ccccc2-4)cc1 ; c1ccc(-n2c3ccccc3c3cc(-c4nc5ccc6ccccc6c5nc4-n4c5cc6c(c7c5c5c8c(cccc8ccc54)-c4ccccc4-7)c4ccccc4n6-c4ccccc4)ccc32)cc1]

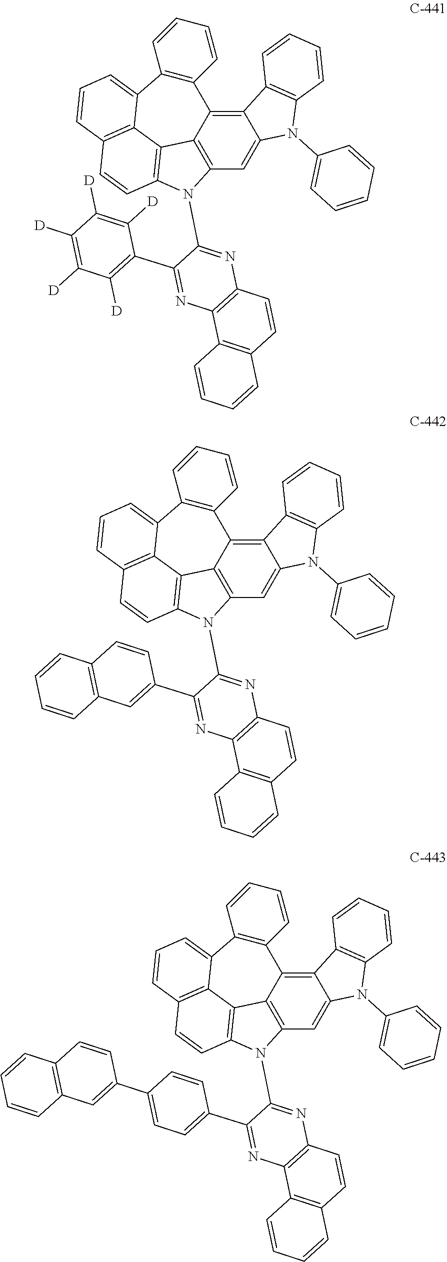

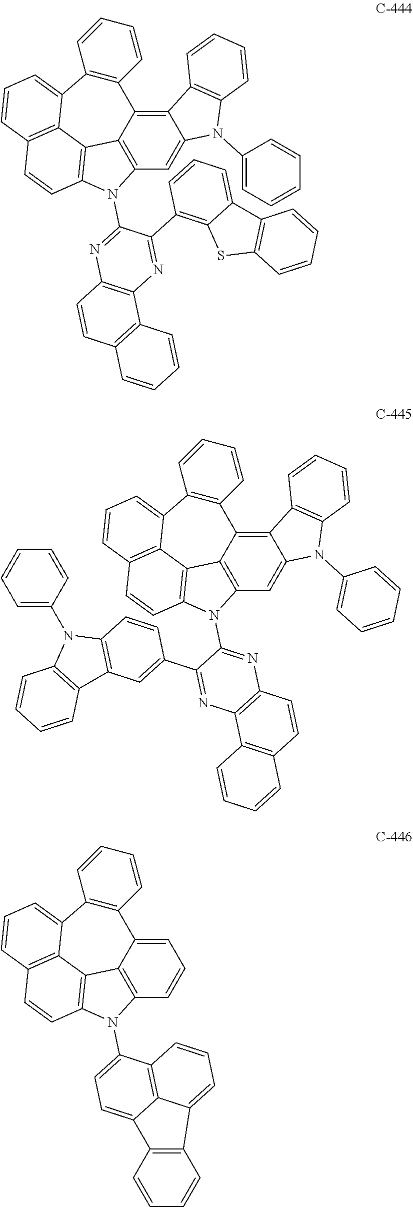 [SMILES: c1ccc(-n2c3ccccc3c3c4c5c6c7c(cccc7ccc6n(-c6nc7ccc8ccccc8c7nc6-c6cccc7c6sc6ccccc67)c5cc32)-c2ccccc2-4)cc1 ; c1ccc(-n2c3ccccc3c3cc(-c4nc5c(ccc6ccccc65)nc4-n4c5cc6c(c7c5c5c8c(cccc8ccc54)-c4ccccc4-7)c4ccccc4n6-c4ccccc4)ccc32)cc1 ; c1ccc2c(c1)-c1cccc3c(-n4c5cccc6c5c5c7c(cccc7ccc54)-c4ccccc4-6)ccc-2c13]

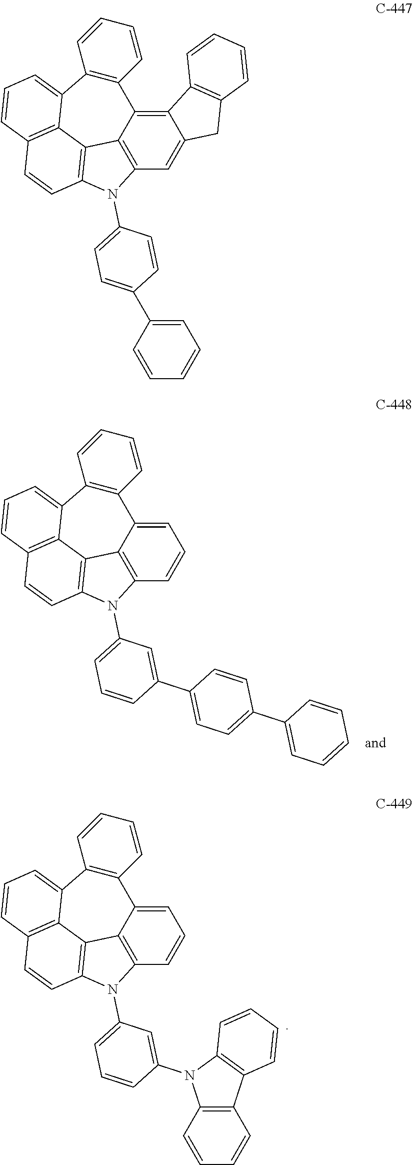 [SMILES: c1ccc(-c2ccc(-n3c4cc5c(c6c4c4c7c(cccc7ccc43)-c3ccccc3-6)-c3ccccc3C5)cc2)cc1 ; c1ccc(-c2ccc(-c3cccc(-n4c5cccc6c5c5c7c(cccc7ccc54)-c4ccccc4-6)c3)cc2)cc1 ; c1cc(-n2c3ccccc3c3ccccc32)cc(-n2c3cccc4c3c3c5c(cccc5ccc32)-c2ccccc2-4)c1]

7. The organic electroluminescent device according to claim 1, wherein the organic electroluminescent device comprises at least one charge generation layer, which is positioned between the light-emitting layers.

8. The organic electroluminescent device according to claim 1, wherein the organic electroluminescent device emits white light.

9. The organic electroluminescent device according to claim 1, wherein the organic electroluminescent device comprises a first unit, a charge generation layer and a second unit;
the first unit is positioned between the anode and the cathode, and includes one or more light-emitting layers;
the charge generation layer is positioned between the first unit and the cathode;
the second unit is positioned between the charge generation layer and the cathode, and includes one or more light-emitting layers; and
at least one of the one or more light-emitting layers included in the first unit and the one or more light-emitting layers included in the second unit comprise a compound represented by formula 1.

10. The organic electroluminescent device according to claim 9, further comprising a third unit, wherein the third unit is positioned between the second unit and the cathode, and includes one or more light-emitting layers.
